(19) United States
(12) Patent Application Publication
(10) Pub. No.: US 2026/0143852 A1
(43) Pub. Date: May 21, 2026

(54) PHOTODETECTOR

(71) Applicant: SONY SEMICONDUCTOR SOLUTIONS CORPORATION, KANAGAWA (JP)

(72) Inventors: KOICHI TAKEUCHI, KANAGAWA (JP); HIRATA AKIKO, KANAGAWA (JP); NOUDO SHINICHIRO, KANAGAWA (JP); MIZUGUCHI TETSUYA, KANAGAWA (JP); MATSUGAI HIROYASU, KANAGAWA (JP); KOJIMA TAKASHI, KANAGAWA (JP); KOBAYASHI YUUKI, KANAGAWA (JP); YOKOCHI KAITO, KANAGAWA (JP); KAWASHIMA SATOSHI, KANAGAWA (JP); SAITO HIROSHI, KANAGAWA (JP); Hasegawa Kenta, KANAGAWA (JP)

(21) Appl. No.: 19/394,989

(22) Filed: Nov. 20, 2025

(30) Foreign Application Priority Data
Feb. 3, 2023 (JP) 2023-015269

(51) Int. Cl. H10F 77/40; H10F 77/30

(52) U.S. Cl. CPC H10F 77/413; H10F 77/306

(57) ABSTRACT

A photodetector includes: a photoelectric conversion section; and an optical layer provided to cover the photoelectric conversion section, in which the optical layer includes: a plurality of pillars arranged side by side in a plane direction of a layer to guide at least light to be detected among incident light to the photoelectric conversion section; and a reflection suppressing film provided on at least one of an upper surface and a lower surface of the pillar, and the reflection suppressing film has a non-flat portion including at least one of a recess and a protrusion.

### CROSS REFERENCE TO RELATED APPLICATIONS

The present application is a Continuation Application of U.S. patent application Ser. No. 19/151,831, filed on Jul. 29, 2025, which is a US national phase entry of PCT/JP2023/047168 filed on Dec. 28, 2023, and claims priority benefit of Japanese Patent Application No. JP 2023-015269 filed in the Japan Patent Office on Feb. 3, 2023, the entire contents of which are hereby incorporated by reference.

### FIELD

The present disclosure relates to a photodetector.

### BACKGROUND

For example, as disclosed in Patent Literature 1, there is known a technique of controlling the direction of incident light by arranging a plurality of fine structures having a dimension smaller than the wavelength of light side by side in a plane direction. Since the structure has, for example, a columnar shape extending in a direction orthogonal to the plane direction or a shape based on the columnar shape, the structure is also referred to as a “pillar” in the present disclosure.

### CITATION LIST

### Patent Literature

Patent Literature 1: JP 2020-537193 A
Patent Literature 1: JP 2018-98641 A
Patent Literature 1: JP 2018-195908 A

### Non Patent Literature

Non Patent Literature 1: S. Basu, B. J. Lee, Z. M. Zhang, “Infrared Radiative Properties of Heavily Doped Silicon at Room Temperature”, Article in Journal of Heat Transfer Vol. 132, February 2010
Non Patent Literature 2: Muhammad Ajmal Khan, Porponth Sichanugrist, Shinya Kato & Yasuaki Ishikawa, “Theoretical investigation about the optical characterizationof cone-shaped pin-Si nanowire for top cell application”, Energy Science and Engineering 2016;4(6):383-393

### SUMMARY

### Technical Problem

Since the refractive index boundary surface exists in the pillar and its peripheral structure, light reflection becomes a problem.

One aspect of the present disclosure suppresses light reflection.

### Solution to Problem

A photodetector according to one aspect of the present disclosure includes: a photoelectric conversion section; and an optical layer provided to cover the photoelectric conversion section, wherein the optical layer includes: a plurality of pillars arranged side by side in a plane direction of a layer to guide at least light to be detected among incident light to the photoelectric conversion section; and a reflection suppressing film provided on at least one of an upper surface and a lower surface of the pillar, and the reflection suppressing film has a non-flat portion including at least one of a recess and a protrusion.

A photodetector according to one aspect of the present disclosure includes: a photoelectric conversion section; and an optical layer provided to cover the photoelectric conversion section, wherein the optical layer includes a plurality of pillars arranged side by side in a plane direction of a layer to guide at least light to be detected among incident light to the photoelectric conversion section, the pillar has a cross-sectional area that continuously changes as it advances in a pillar height direction, and at least one of an upper surface and a lower surface of the pillar is a curved surface.

A photodetector according to one aspect of the present disclosure includes: a photoelectric conversion section; and an optical layer provided to cover the photoelectric conversion section, wherein the optical layer includes a plurality of pillars arranged side by side in a plane direction of a layer to guide at least light to be detected among incident light to the photoelectric conversion section, and an upper surface of the pillar includes a nonflat portion including at least one of a recess and a protrusion.

A photodetector according to one aspect of the present disclosure includes: a photoelectric conversion section; and an optical layer provided to cover the photoelectric conversion section, wherein the optical layer includes: a plurality of pillars arranged side by side in a plane direction of a layer to guide at least light to be detected among incident light to the photoelectric conversion section; and a reflection suppressing film provided on at least one of an upper surface and a lower surface of the pillar, and a refractive index of the reflection suppressing film has a gradient to approach a refractive index of the pillar toward the pillar.

A photodetector according to one aspect of the present disclosure includes: a photoelectric conversion section; and an optical layer provided to cover the photoelectric conversion section, wherein the optical layer includes a plurality of pillars arranged side by side in a plane direction of a layer to guide at least light to be detected among incident light to the photoelectric conversion section, and the pillar includes: an unaltered layer including a lower surface of the pillar; and an altered layer including an upper surface of the pillar and having a refractive index different from a refractive index of the unaltered layer.

A photodetector according to one aspect of the present disclosure includes: a photoelectric conversion section; a first optical layer provided to cover the photoelectric conversion section; and a second optical layer provided to cover the first optical layer, wherein the first optical layer includes a plurality of pillars arranged side by side in a plane direction of a layer to guide at least light to be detected among incident light to the photoelectric conversion section, and the second optical layer includes a plurality of pillars arranged side by side in the plane direction of the layer to have an average refractive index different from an average refractive index of the first optical layer.

A photodetector according to one aspect of the present disclosure includes: a photoelectric conversion section; and an optical layer provided to cover the photoelectric conversion section, wherein the optical layer includes: a plurality of pillars arranged side by side in a plane direction of a layer to guide at least light to be detected among incident light to the photoelectric conversion section; and an etching stopper layer provided on at least one of an upper surface and a lower surface of the pillar, and at least one of an upper surface and a lower surface of the etching stopper layer has an uneven shape.

### BRIEF DESCRIPTION OF DRAWINGS

FIG. 1 is a diagram illustrating an example of a schematic configuration of a photodetector 100.

FIG. 2 is a diagram illustrating an example of a circuit configuration of a pixel 2.

FIG. 3 is a diagram illustrating an example of a schematic configuration of a pixel array section 1.

FIG. 4 is a diagram illustrating an example of a schematic configuration of an optical layer 6.

FIG. 5 is a diagram illustrating an example of a schematic configuration of an optical layer 6.

FIG. 6 is a diagram illustrating an example of a schematic configuration of a pillar 62 and a peripheral structure thereof.

FIG. 7 is a diagram illustrating an example of a schematic configuration of a pillar 62 and a peripheral structure thereof.

FIG. 8 is a diagram illustrating an example of a schematic configuration of a pillar 62 and a peripheral structure thereof.

FIG. 9 is a diagram illustrating an example of a schematic configuration of a pillar 62 and a peripheral structure thereof.

FIG. 10 is a diagram illustrating an example of a schematic configuration of a pillar 62 and a peripheral structure thereof.

FIG. 11 is a diagram illustrating an example of a schematic configuration of a pillar 62 and a peripheral structure thereof.

FIG. 12 is a diagram illustrating an example of a schematic configuration of a pillar 62 and a peripheral structure thereof.

FIG. 13 is a diagram illustrating an example of a schematic configuration of a pillar 62 and a peripheral structure thereof.

FIG. 14 is a diagram illustrating an example of a schematic configuration of a pillar 62 and a peripheral structure thereof.

FIG. 15 is a diagram illustrating an example of a manufacturing method.

FIG. 16 is a diagram illustrating an example of a manufacturing method.

FIG. 17 is a diagram illustrating an example of a manufacturing method.

FIG. 18 is a diagram illustrating an example of a manufacturing method.

FIG. 19 is a diagram illustrating an example of a manufacturing method.

FIG. 20 is a diagram illustrating an example of a manufacturing method.

FIG. 21 is a diagram illustrating an example of a manufacturing method.

FIG. 22 is a diagram illustrating an example of a manufacturing method.

FIG. 23 is a diagram illustrating an example of a manufacturing method.

FIG. 24 is a diagram illustrating an example of a manufacturing method.

FIG. 25 is a diagram illustrating an example of a manufacturing method.

FIG. 26 is a diagram illustrating an example of a manufacturing method.

FIG. 27 is a diagram illustrating an example of a manufacturing method.

FIG. 28 is a diagram illustrating an example of a manufacturing method.

FIG. 29 is a diagram illustrating an example of a manufacturing method.

FIG. 30 is a diagram illustrating an example of a manufacturing method.

FIG. 31 is a diagram illustrating an example of a manufacturing method.

FIG. 32 is a diagram illustrating an example of a manufacturing method.

FIG. 33 is a diagram illustrating an example of a manufacturing method.

FIG. 34 is a diagram illustrating an example of a manufacturing method.

FIG. 35 is a diagram illustrating an example of a manufacturing method.

FIG. 36 is a diagram illustrating an example of a manufacturing method.

FIG. 37 is a diagram illustrating an example of a manufacturing method.

FIG. 38 is a diagram illustrating an example of a manufacturing method.

FIG. 39 is a diagram illustrating an example of a manufacturing method.

FIG. 40 is a diagram illustrating an example of a manufacturing method.

FIG. 41 is a diagram illustrating an example of a manufacturing method.

FIG. 42 is a diagram illustrating an example of a manufacturing method.

FIG. 43 is a diagram illustrating an example of a manufacturing method.

FIG. 44 is a diagram illustrating an example of a manufacturing method.

FIG. 45 is a diagram illustrating an example of a manufacturing method.

FIG. 46 is a diagram illustrating an example of a manufacturing method.

FIG. 47 is a diagram illustrating an example of a manufacturing method.

FIG. 48 is a diagram illustrating an example of a manufacturing method.

FIG. 49 is a diagram illustrating an example of a manufacturing method.

FIG. 50 is a diagram illustrating an example of a pillar 62 formed in two stages.

FIG. 51 is a diagram illustrating an example of a pillar 62 formed in two stages.

FIG. 52 is a diagram illustrating an example of a schematic configuration of a pillar 62 and a peripheral structure thereof.

FIG. 53 is a diagram illustrating an example of a schematic configuration of a pillar 62 and a peripheral structure thereof.

FIG. 54 is a diagram illustrating an example of a schematic configuration of a pillar 62 and a peripheral structure thereof.

FIG. 55 is a diagram illustrating an example of a schematic configuration of a pillar 62 and a peripheral structure thereof.

FIG. 56 is a diagram illustrating an example of a schematic configuration of a pillar 62 and a peripheral structure thereof.

FIG. 57 is a diagram illustrating an example of a schematic configuration of a pillar 62 and a peripheral structure thereof.

FIG. 58 is a diagram illustrating an example of a schematic configuration of a pillar 62 and a peripheral structure thereof.

FIG. 59 is a diagram illustrating an example of a schematic configuration of a pillar 62 and a peripheral structure thereof.

FIG. 60 is a diagram illustrating examples of maximum widths and heights of a plurality of pillars 62.

FIG. 61 is a diagram illustrating examples of arrangement of pillars 62.

FIG. 62 is a diagram illustrating examples of cross-sectional shapes of pillars 62.

FIG. 63 is a diagram illustrating an example of a manufacturing method.

FIG. 64 is a diagram illustrating an example of a manufacturing method.

FIG. 65 is a diagram illustrating an example of a manufacturing method.

FIG. 66 is a diagram illustrating an example of a manufacturing method.

FIG. 67 is a diagram illustrating an example of a manufacturing method.

FIG. 68 is a diagram illustrating an example of a manufacturing method.

FIG. 69 is a diagram illustrating an example of a manufacturing method.

FIG. 70 is a diagram illustrating an example of a manufacturing method.

FIG. 71 is a diagram illustrating an example of a manufacturing method.

FIG. 72 is a diagram illustrating an example of a manufacturing method.

FIG. 73 is a diagram illustrating an example of a manufacturing method.

FIG. 74 is a diagram illustrating an example of a manufacturing method.

FIG. 75 is a diagram illustrating an example of a manufacturing method.

FIG. 76 is a diagram illustrating an example of a manufacturing method.

FIG. 77 is a diagram illustrating an example of a manufacturing method.

FIG. 78 is a diagram illustrating an example of a manufacturing method.

FIG. 79 is a diagram illustrating an example of a manufacturing method.

FIG. 80 is a diagram illustrating an example of a manufacturing method.

FIG. 81 is a diagram illustrating an example of a manufacturing method.

FIG. 82 is a diagram illustrating an example of multilayering of the optical layer 6.

FIG. 83 is a diagram illustrating an example of a filler 64 and a peripheral structure thereof.

FIG. 84 is a diagram illustrating an example of design of an optical function.

FIG. 85 is a diagram illustrating an example of design of an optical function.

FIG. 86 is a diagram illustrating an example of design of an optical function.

FIG. 87 is a diagram illustrating an example of design of an optical function.

FIG. 88 is a diagram illustrating an example of design of an optical function.

FIG. 89 is a diagram illustrating an example of design of an optical function.

FIG. 90 is a diagram illustrating an example of design of an optical function.

FIG. 91 is a diagram illustrating an example of design of an optical function.

FIG. 92 is a diagram illustrating an example of design of an optical function.

FIG. 93 is a diagram illustrating an example of a phase difference library.

FIG. 94 is a diagram illustrating an example of a light shielding film 52.

FIG. 95 is a diagram illustrating an example of a light shielding film 52.

FIG. 96 is a diagram illustrating an example of a light shielding film 52.

FIG. 97 is a diagram illustrating an example of a light shielding film 52.

FIG. 98 is a diagram illustrating an example of a light shielding film 52.

FIG. 99 is a diagram illustrating an example of an element separating portion ES.

FIG. 100 is a diagram illustrating an example of an element separating portion ES.

FIG. 101 is a diagram illustrating an example of an element separating portion ES.

FIG. 102 is a diagram illustrating an example of an element separating portion ES.

FIG. 103 is a diagram illustrating an example of an element separating portion ES.

FIG. 104 is a diagram illustrating an example of an element separating portion ES.

FIG. 105 is a diagram illustrating an example of a shape of an upper surface 3a of a semiconductor substrate 3.

FIG. 106 is a diagram illustrating an example of a shape of an upper surface 3a of a semiconductor substrate 3.

FIG. 107 is a diagram illustrating an example of a shape of an upper surface 3a of a semiconductor substrate 3.

FIG. 108 is a diagram illustrating an example of a shape of an upper surface 3a of a semiconductor substrate 3.

FIG. 109 is a diagram illustrating an example of a lens 10.

FIG. 110 is a diagram illustrating an example of a lens 10.

FIG. 111 is a diagram illustrating an example of a lens 10.

FIG. 112 is a diagram illustrating an example of a lens 10.

FIG. 113 is a diagram illustrating an example of a lens 10.

FIG. 114 is a diagram illustrating an example of crosstalk suppression.

FIG. 115 is a diagram illustrating an example of crosstalk suppression.

FIG. 116 is a diagram illustrating an example of crosstalk suppression.

FIG. 117 is a diagram illustrating an example of crosstalk suppression.

FIG. 118 is a diagram illustrating an example of division of the photoelectric conversion section 21.

FIG. 119 is a diagram illustrating an example of division of the photoelectric conversion section 21.

FIG. 120 is a diagram illustrating an example of a color filter 13.

FIG. 121 is a diagram illustrating an example of a color filter 13.

FIG. 122 is a diagram illustrating an example of a color filter 13.

FIG. 123 is a diagram illustrating an example of another filter.

FIG. 124 is a diagram illustrating an example of another filter.

FIG. 125 is a diagram illustrating an example of another filter.

FIG. 126 is a diagram illustrating an example of another filter.

FIG. 127 is a diagram illustrating an example of another filter.

FIG. 128 is a diagram illustrating a modification of multilayering of the optical layer 6.

FIG. 129 is a diagram illustrating a comparative example.

FIG. 130 is a diagram illustrating a comparative example.

FIG. 131 is a diagram illustrating an example of a schematic configuration of an optical layer 6.

FIG. 132 is a diagram illustrating an example of reflectance.

FIG. 133 is a diagram illustrating an example of an optimized in-pillar volume ratio α.

FIG. 134 is a diagram illustrating an example of an optimized depth d of the recess.

FIG. 135 is a diagram illustrating an example of a schematic configuration of an optical layer 6.

FIG. 136 is a diagram illustrating an example of reflectance.

FIG. 137 is a diagram illustrating an example of an optimized in-pillar volume ratio α.

FIG. 138 is a diagram illustrating an example of an optimized depth d of the recess.

FIG. 139 is a diagram illustrating an example of shapes of a non-flat portion 62v and a peripheral structure thereof.

FIG. 140 is a diagram illustrating an example of shapes of a non-flat portion 62v and a peripheral structure thereof.

FIG. 141 is a diagram illustrating an example of shapes of a non-flat portion 62v and a peripheral structure thereof.

FIG. 142 is a diagram illustrating an example of shapes of a non-flat portion 62v and a peripheral structure thereof.

FIG. 143 is a diagram illustrating an example of shapes of a non-flat portion 62v and a peripheral structure thereof.

FIG. 144 is a diagram illustrating an example of shapes of a non-flat portion 62v and a peripheral structure thereof.

FIG. 145 is a diagram illustrating an example of shapes of a non-flat portion 62v and a peripheral structure thereof.

FIG. 146 is a diagram illustrating an example of shapes of a non-flat portion 62v and a peripheral structure thereof.

FIG. 147 is a diagram illustrating an example of shapes of a non-flat portion 62v and a peripheral structure thereof.

FIG. 148 is a diagram illustrating an example of shapes of a non-flat portion 62v and a peripheral structure thereof.

FIG. 149 is a diagram illustrating an example of a manufacturing method.

FIG. 150 is a diagram illustrating an example of a manufacturing method.

FIG. 151 is a diagram illustrating an example of a manufacturing method.

FIG. 152 is a diagram illustrating an example of a manufacturing method.

FIG. 153 is a diagram illustrating an example of a manufacturing method.

FIG. 154 is a diagram illustrating an example of a manufacturing method.

FIG. 155 is a diagram illustrating an example of a manufacturing method.

FIG. 156 is a diagram illustrating an example of a manufacturing method.

FIG. 157 is a diagram illustrating an example of a manufacturing method.

FIG. 158 is a diagram illustrating an example of a manufacturing method.

FIG. 159 is a diagram illustrating an example of a manufacturing method.

FIG. 160 is a diagram illustrating an example of a manufacturing method.

FIG. 161 is a diagram illustrating an example of a manufacturing method.

FIG. 162 is a diagram illustrating an example of a manufacturing method.

FIG. 163 is a diagram illustrating an example of a manufacturing method.

FIG. 164 is a diagram illustrating an example of a manufacturing method.

FIG. 165 is a diagram illustrating an example of a manufacturing method.

FIG. 166 is a diagram illustrating an example of a manufacturing method.

FIG. 167 is a diagram illustrating an example of a manufacturing method.

FIG. 168 is a diagram illustrating an example of a manufacturing method.

FIG. 169 is a diagram illustrating an example of a manufacturing method.

FIG. 170 is a diagram illustrating an example of a manufacturing method.

FIG. 171 is a diagram illustrating an example of a manufacturing method.

FIG. 172 is a diagram illustrating an example of a manufacturing method.

FIG. 173 is a diagram illustrating an example of a manufacturing method.

FIG. 174 is a diagram illustrating an example of a manufacturing method.

FIG. 175 is a diagram illustrating an example of a manufacturing method.

FIG. 176 is a diagram illustrating an example of a manufacturing method.

FIG. 177 is a diagram illustrating an example of a manufacturing method.

FIG. 178 is a diagram illustrating an example of a manufacturing method.

FIG. 179 is a diagram illustrating an example of a manufacturing method.

FIG. 180 is a diagram illustrating an example of a manufacturing method.

FIG. 181 is a diagram illustrating an example of a manufacturing method.

FIG. 182 is a diagram illustrating an example of a manufacturing method.

FIG. 183 is a diagram illustrating an example of a schematic configuration of a pillar 62 and a peripheral structure thereof.

FIG. 184 is a diagram illustrating an example of a schematic configuration of a pillar 62 and a peripheral structure thereof.

FIG. 185 is a diagram illustrating an example of a schematic configuration of a pillar 62 and a peripheral structure thereof.

FIG. 186 is a diagram illustrating an example of a schematic configuration of a pillar 62 and a peripheral structure thereof.

FIG. 187 is a diagram illustrating an example of a schematic configuration of a pillar 62 and a peripheral structure thereof.

FIG. 188 is a diagram illustrating an example of a schematic configuration of a pillar 62 and a peripheral structure thereof.

FIG. 189 is a diagram illustrating an example of a schematic configuration of a pillar 62 and a peripheral structure thereof.

FIG. 190 is a diagram illustrating an example of a schematic configuration of an optical layer 6.

FIG. 191 is a diagram that cites Non Patent Literature 1.

FIG. 192 is a diagram that cites Non Patent Literature 2.

FIG. 193 is a diagram illustrating an example of a schematic configuration of an optical layer 6.

FIG. 194 is a diagram illustrating an example of a schematic configuration of a pillar 62 and a peripheral structure thereof.

FIG. 195 is a diagram illustrating an example of a manufacturing method.

FIG. 196 is a diagram illustrating an example of a manufacturing method.

FIG. 197 is a diagram illustrating an example of a manufacturing method.

FIG. 198 is a diagram illustrating an example of a manufacturing method.

FIG. 199 is a diagram illustrating an example of a manufacturing method.

FIG. 200 is a diagram illustrating an example of a manufacturing method.

FIG. 201 is a diagram illustrating an example of a manufacturing method.

FIG. 202 is a diagram illustrating an example of a manufacturing method.

FIG. 203 is a diagram illustrating an example of a manufacturing method.

FIG. 204 is a diagram illustrating an example of a manufacturing method.

FIG. 205 is a diagram illustrating an example of a manufacturing method.

FIG. 206 is a diagram illustrating an example of a manufacturing method.

FIG. 207 is a diagram illustrating an example of a manufacturing method.

FIG. 208 is a diagram illustrating an example of a manufacturing method.

FIG. 209 is a diagram illustrating an example of a manufacturing method.

FIG. 210 is a diagram illustrating an example of a manufacturing method.

FIG. 211 is a diagram illustrating an example of a manufacturing method.

FIG. 212 is a diagram illustrating a comparative example.

FIG. 213 is a diagram illustrating an example of a schematic configuration of an optical layer 6.

FIG. 214 is a diagram illustrating an example of a schematic configuration of an optical layer 6.

FIG. 215 is a diagram illustrating an example of calculation of an average refractive index.

FIG. 216 is a diagram illustrating a modification.

FIG. 217 is a diagram illustrating a modification.

FIG. 218 is a diagram illustrating a modification.

FIG. 219 is a diagram illustrating a modification.

FIG. 220 is a diagram illustrating a modification.

FIG. 221 is a diagram illustrating an example of a schematic configuration of an optical layer 6.

FIG. 222 is a diagram illustrating an example of a schematic configuration of an etching stopper layer 67.

FIG. 223 is a diagram illustrating an example of a schematic configuration of an etching stopper layer 67.

FIG. 224 is a diagram illustrating an example of a schematic configuration of an interface between an etching stopper layer 67-1 and a pillar 62 and a filler 64 and its periphery.

FIG. 225 is a diagram illustrating an example of a schematic configuration of an interface between an etching stopper layer 67-1 and a pillar 62 and a filler 64 and its periphery.

FIG. 226 is a diagram illustrating an example of a combination of shapes of an upper surface 67a and a lower surface 67b of an etching stopper layer 67-1.

FIG. 227 is a diagram illustrating an example of a schematic configuration of an optical layer 6.

FIG. 228 is a diagram illustrating an example of a manufacturing method.

FIG. 229 is a diagram illustrating an example of a manufacturing method.

FIG. 230 is a diagram illustrating an example of a manufacturing method.

FIG. 231 is a diagram illustrating an example of a manufacturing method.

FIG. 232 is a diagram illustrating an example of a manufacturing method.

FIG. 233 is a diagram illustrating an example of a manufacturing method.

FIG. 234 is a diagram illustrating an example of a manufacturing method.

FIG. 235 is a diagram illustrating an example of a manufacturing method.

FIG. 236 is a diagram illustrating an example of a manufacturing method.

FIG. 237 is a diagram illustrating an example of a manufacturing method.

FIG. 238 is a diagram illustrating an example of a manufacturing method.

FIG. 239 is a diagram illustrating an example of a manufacturing method.

FIG. 240 is a diagram illustrating an example of a manufacturing method.

FIG. 241 is a diagram illustrating an example of a manufacturing method.

FIG. 242 is a diagram illustrating an example of a manufacturing method.

FIG. 243 is a diagram illustrating an example of a manufacturing method.

FIG. 244 is a diagram illustrating an example.

### DESCRIPTION OF EMBODIMENTS

Hereinafter, embodiments of the present disclosure will be described in detail with reference to the drawings. Note that, in the following embodiments, the same elements are denoted by the same reference signs, and redundant description may be omitted. The same reference signs may be used for different meanings between different embodiments, and in this case, may be interpreted according to the description in the embodiment.

The present disclosure will be described according to the following order of items.
0. Example of Photodetector
1. First Embodiment
2. Second Embodiment
3. Third Embodiment
4. Fourth Embodiment
5. Fifth Embodiment
6. Sixth Embodiment
7. Seventh Embodiment
8. Conclusion

### 0. EXAMPLE OF PHOTODETECTOR

One of the disclosed techniques is a photodetector. Hereinafter, a case where the photodetector is an imaging apparatus will be described as an example. Note that imaging and images in the imaging apparatus may be understood as meanings including imaging and video within a range without contradiction, and these terms may be appropriately read.

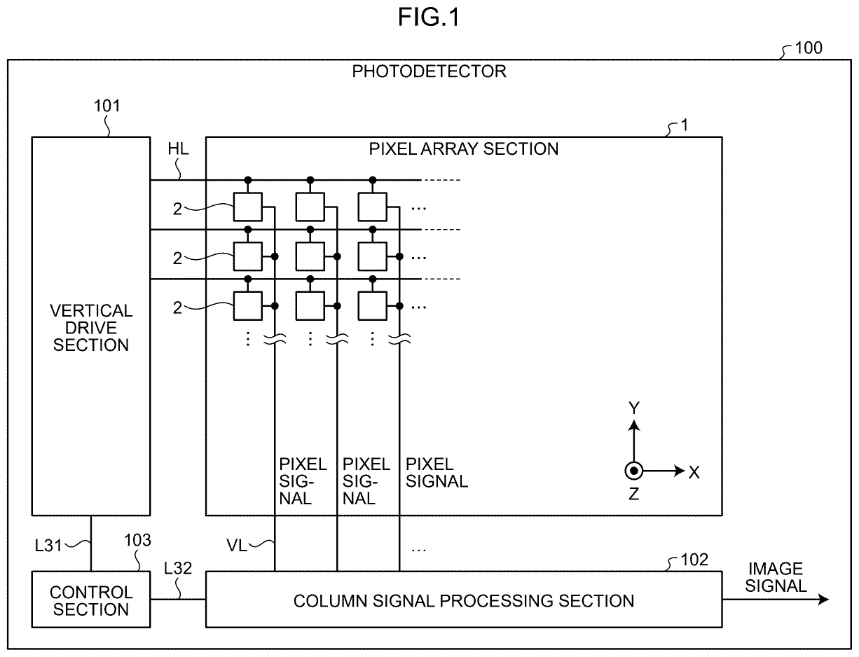

FIG. 1 is a diagram illustrating an example of a schematic configuration of a photodetector 100. The photodetector 100 includes a pixel array section 1, a vertical drive section 101, a column signal processing section 102, and a control section 103. For convenience, an XYZ system for the pixel array section 1 is also illustrated. The X-axis direction and the Y-axis direction (XY planar direction) correspond to the array direction. The X-axis direction is also referred to as a horizontal direction, a row (line) direction, or the like. The Y-axis direction is also referred to as a vertical direction, a column direction, or the like.

The pixel array section 1 includes a plurality of pixels 2. The plurality of pixels 2 are arranged in a two-dimensional manner (for example, a two-dimensional lattice shape) in the row direction and the column direction. The pixel 2 includes a photoelectric conversion section, and generates and outputs a voltage signal corresponding to the amount of incident light. The output voltage signal is referred to as a pixel signal. The pixel 2 also includes a circuit (pixel circuit) for light reception by the photoelectric conversion section, conversion into a voltage signal, and the like. The pixel signal from the pixel 2 is transmitted to the column signal processing section 102 via the signal line VL.

The vertical drive section 101 is connected to the pixel array section 1 via a signal line HL. For each row of the pixel array section 1, one or more signal lines HL extend from the vertical drive section 101 in the pixel array section 1, and are commonly connected to the pixels 2 located in the same row. The vertical drive section 101 supplies a control signal to the corresponding pixel 2 via the signal line HL.

The column signal processing section 102 is connected to the pixel array section 1 via a signal line VL. For each column of the pixel array section 1, one signal line VL extends from the column signal processing section 102 in the pixel array section 1 and is commonly connected to the pixels 2 located in the same column. The column signal processing section 102 processes the image signal from each pixel 2 for each column of the pixel array section 1. An example of the processing is analog to digital (AD) conversion processing and the like. The processed image signal is output as an image signal.

The control section 103 controls the entire photodetector 100. For example, the control section 103 generates a control signal for controlling the vertical drive section 101 and supplies the control signal to the vertical drive section 101. A signal line for this purpose is referred to as a signal line L31 in the drawing. Furthermore, the control section 103 generates a control signal for controlling the column signal processing section 102 and supplies the control signal to the column signal processing section 102. A signal line for this purpose is referred to as a signal line L32 in the drawing.

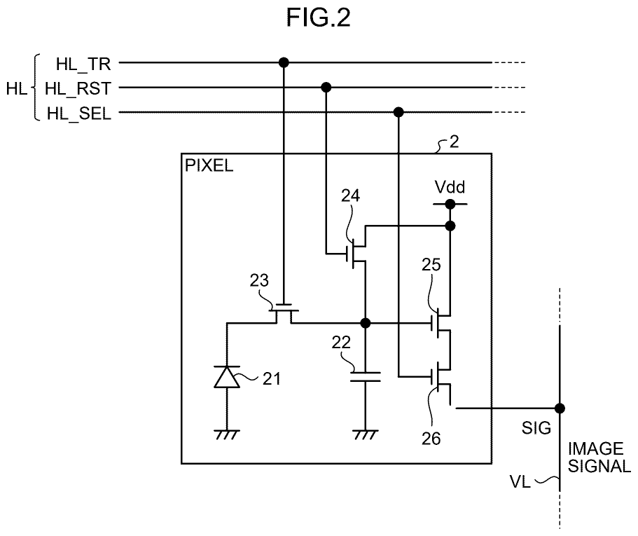

FIG. 2 is a diagram illustrating an example of a circuit configuration of the pixel 2. In this example, three signal lines HL are connected to the pixel 2. The signal lines HL are referred to as a signal line HL TR, a signal line HL_RST, and a signal line HL_SEL in the drawing so that the signal lines HL can be distinguished from one another. A power supply line Vdd is also illustrated.

The pixel 2 includes a photoelectric conversion section 21 and a pixel circuit. As components of the pixel circuit, a charge holding section 22 and transistors 23 to 26 are exemplified. Here, it is assumed that each of the transistors 23 to 26 is a field effect transistor (FET). The FET may be a MOSFET.

In the following description, the drain and the source of the transistor are also referred to as current terminals. The gate is also referred to as a control terminal. Connecting a transistor between two elements means that one current terminal (one of a drain and a source) is connected to one element and the other current terminal (the other of the drain and the source) is connected to the other element.

The photoelectric conversion section 21 generates and accumulates charges according to the amount of received light. The illustrated photoelectric conversion section 21 is a photodiode whose anode is grounded.

The charge holding section 22 holds the charge accumulated in the photoelectric conversion section 21. Examples of the charge holding section 22 include a floating diffusion capacitance, a capacitor, and the like.

The transistor 23 is a transfer transistor that is connected between the photoelectric conversion section 21 and the charge holding section 22 and transfers the charge accumulated in the photoelectric conversion section 21 to the charge holding section 22. A control terminal of the transistor 23 is connected to the signal line HL TR. On and off (the conductive state and the non-conductive state) of the transistor 23 are controlled by the control signal from the signal line HL TR.

The transistor 24 is a reset transistor that is connected between the charge holding section 22 and the power supply line Vdd and discharges the charge of the charge holding section 22 to the power supply line Vdd. A control terminal of the transistor 24 is connected to the signal line HL_RST. On and off of the transistor 24 are controlled by a control signal from the signal line HL_RST. Note that by turning on the transistor 23, the transistor 24 is also connected to the photoelectric conversion section 21, so that the charge accumulated in the photoelectric conversion section 21 can also be discharged to the power supply line Vdd.

The transistor 25 is connected between the power supply line Vdd and the transistor 26. A control terminal of the transistor 25 is connected to the charge holding section 22. The transistor 25 outputs a voltage corresponding to the amount of charge held by the charge holding section 22, that is, the amount of charge generated in the photoelectric conversion section 21.

The transistor 26 is a selection transistor that is connected between the transistor 25 and the signal line VL and causes the output voltage of the transistor 25 to selectively appear in the signal line VL. The voltage appearing in the signal line VL is a pixel signal. A control terminal of the transistor 26 is connected to the signal line HL_SEL. On and off of the transistor 26 are controlled by a control signal from the signal line HL_SEL.

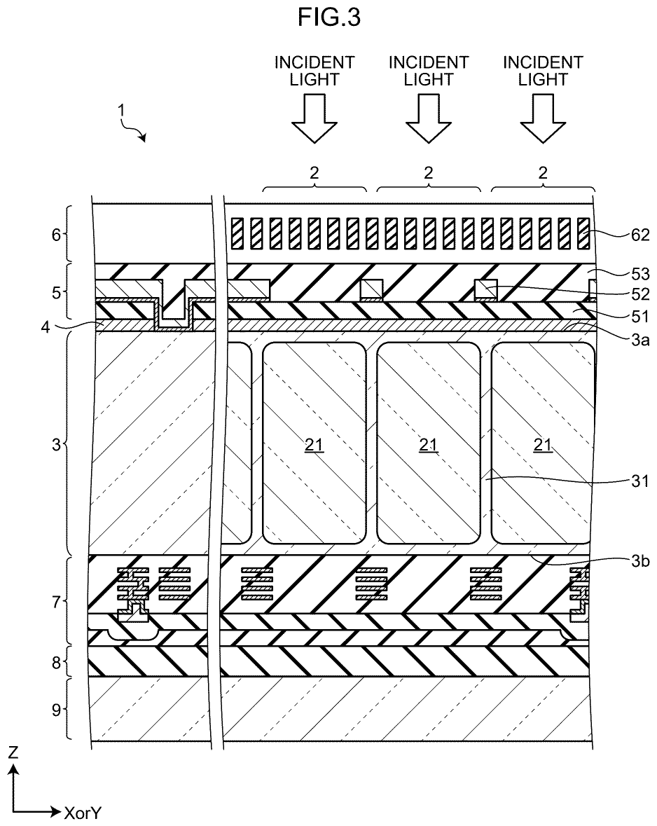

FIG. 3 is a diagram illustrating an example of a schematic configuration of the pixel array section 1. A cross section of a part of the pixel array section 1 in a side view (as viewed in the X-axis direction or the Y-axis direction) is schematically illustrated. The pixel array section 1 includes a semiconductor substrate 3, a fixed charge film 4, an insulating layer 5, an optical layer 6, a wiring layer 7, an insulating layer 8, and a support substrate 9. A plane direction of the substrate, the film, and the layer corresponds to an XY planar direction (an X-axis direction and a Y-axis direction), and a thickness direction corresponds to a Z-axis direction. The Z-axis positive direction may be referred to as an upward direction or the like. The Z-axis negative direction may be referred to as a downward direction or the like. Note that the layer and the film may be read as each other within a range without contradiction.

Note that a portion illustrated on the right side of FIG. 3 is an effective region in which the pixel 2 including the photoelectric conversion section 21 is arranged. A portion illustrated on the left side of FIG. 3 is an ineffective region (a region outside the effective region) where such a pixel 2 is not arranged. The light incident on the pixel array section 1 is referred to as incident light, and is schematically indicated by an outlined arrow. It is assumed that the incident light travels downward (Z-axis negative direction).

At least a part of the components of the circuit of the pixel 2 is formed on the semiconductor substrate 3. Examples of the material of the semiconductor substrate 3 include Si, SiGe, and InGaAs. As a component formed on the semiconductor substrate 3, the photoelectric conversion section 21 is illustrated in FIG. 3.

The upper surface (the surface on the Z-axis positive direction side) of the semiconductor substrate 3 is referred to as an upper surface 3a in the drawing. The lower surface (the surface on the Z-axis negative direction side) of the semiconductor substrate 3 is referred to as a lower surface 3b in the drawing. The light incident on the pixel array section 1 enters the semiconductor substrate 3 from the upper surface 3a of the semiconductor substrate 3 and reaches the photoelectric conversion section 21. Note that, since the wiring layer 7 to be described later is provided on the lower surface 3b of the semiconductor substrate 3, it can be said that the lower surface 3b of the semiconductor substrate 3 is the front surface of the semiconductor substrate 3 and the upper surface 3a of the semiconductor substrate 3 is the back surface of the semiconductor substrate 3. The photodetector 100 (FIG. 1) can also be referred to as a back-illuminated photodetector, an imaging apparatus, or the like.

The photoelectric conversion section 21 will be further described. In this example, the photoelectric conversion section 21 is formed over substantially the entire region in the thickness direction (Z-axis direction) of the semiconductor substrate 3. The photoelectric conversion section 21 is, for example, a pn junction type photodiode (PD) including an n-type semiconductor region and a p-type semiconductor region formed so as to face both the upper surface 3a and the lower surface 3b of the semiconductor substrate 3.

The p-type semiconductor region also serves as a hole charge accumulation region for suppressing dark current. Each pixel 2 is separated by a separation region 31. The separation region 31 is formed of a p-type semiconductor region and is grounded, for example. The transistors 23 to 26 described above with reference to FIG. 2 are configured by forming an n-type source region and a drain region in a p-type semiconductor well region formed on the lower surface 3b side of the semiconductor substrate 3, and forming a gate electrode on the lower surface 3b of the semiconductor substrate 3 between the source region and the drain region via a gate insulating film.

On the upper surface 3a of the semiconductor substrate 3, the fixed charge film 4, the insulating layer 5, and the optical layer 6 are provided in this order. It can also be said that the upper surface 3a of the semiconductor substrate 3 faces the fixed charge film 4, the insulating layer 5, and the optical layer 6.

The fixed charge film 4 has a negative fixed charge due to a dipole of oxygen and plays a role of enhancing pinning. An example of the material of the fixed charge film 4 is an oxide or a nitride. The oxide or nitride may contain at least one of Hf, Al, zirconium, Ta, and Ti. In addition, the oxide or nitride may contain at least one of lanthanum, cerium, neodymium, promethium, samarium, europium, gadolinium, terbium, dysprosium, holmium, thulium, ytterbium, lutetium, and yttrium. Another example of the material of the fixed charge film 4 is hafnium oxynitride, aluminum oxynitride, or the like. Silicon or nitrogen may be added to the fixed charge film 4 in an amount that does not impair insulating properties. Heat resistance and the like can be improved. The fixed charge film 4 may be configured to also serve as a reflection suppressing film for the semiconductor substrate 3 such as a Si substrate having a high refractive index by controlling the film thickness or laminating multiple layers.

The insulating layer 5 insulates the semiconductor substrate 3 and the fixed charge film 4 from the optical layer 6, and protects the semiconductor substrate 3 and the fixed charge film 4. In this example, the insulating layer 5 includes an insulating film 51, a light shielding film 52, and an insulating film 53. An example of the material of the insulating film 51 and the insulating film 53 is SiO₂ or the like.

The insulating film 51 is also a base layer for providing the light shielding film 52 thereon.

The light shielding film 52 is provided on the insulating film 51. The light shielding film 52 is arranged in a boundary region between (the photoelectric conversion sections 21 of) the adjacent pixels 2, and shields stray light leaking from the adjacent pixels 2. The light shielding film 52 includes a material that shields light. A material having a strong light shielding property and capable of being accurately processed by microfabrication, for example, etching may be used. Examples of the material include metal materials such as Al, W, and copper. The light shielding film 52 may be formed of a metal film containing such a metal material. In addition, silver, gold, platinum, Mo, Cr, Ti, nickel, iron, tellurium, and the like, an alloy containing these, and the like may be used as the material of the light shielding film 52. A plurality of these materials may be laminated. In order to enhance adhesion to the underlying insulating film 51, a barrier metal, for example, Ti, Ta, W, Co, Mo, an alloy thereof, a nitride thereof, an oxide thereof, or a carbide thereof may be provided under the light shielding film 52.

The light shielding film 52 may also serve as light shielding for a pixel for determining an optical black level or may also serve as light shielding for preventing noise to a peripheral circuit region. The light shielding film 52 is desirably grounded so as not to be destroyed by plasma damage due to accumulated charges during processing. The ground structure may be formed in the pixel array, but may be grounded in a region outside the effective region of the pixel 2 as illustrated on the left side of FIG. 3 after all the conductors are electrically connected.

The insulating film 53 is provided so as to cover the insulating film 51 and the light shielding film 52. The insulating film 53 also plays a role of planarization.

In this example, the optical layer 6 is provided so as to cover the photoelectric conversion section 21 of the semiconductor substrate 3 with the fixed charge film 4 and the insulating layer 5 interposed therebetween. As components of the optical layer 6, a plurality of pillars 62 are illustrated in FIG. 3. Details of the optical layer 6 will be described later.

On the lower surface 3b of the semiconductor substrate 3, the wiring layer 7, the insulating layer 8, and the support substrate 9 are provided in this order. It can also be said that the lower surface 3b of the semiconductor substrate 3 faces the wiring layer 7, the insulating layer 8, and the support substrate 9.

The wiring layer 7 transmits an image signal generated by the pixel 2. Furthermore, the wiring layer 7 further transmits a signal applied to the circuit of the pixel 2. Specifically, the wiring layer 7 constitutes the signal line HL and the power supply line Vdd (FIGS. 1 and 2). The wiring layer 7 and the circuit are connected by a via plug. In addition, the wiring layer 7 includes multiple layers, and the layers of each wiring layer are also connected by a via plug. An example of the material of the wiring layer 7 is a metal material such as Al or Cu. Examples of the material of the via plug include metal materials such as W and Cu. For insulation of the wiring layer 7, for example, a silicon oxide film or the like is used.

The insulating layer 8 insulates the wiring layer 7 from the support substrate 9. Various known materials may be used.

The support substrate 9 reinforces and supports the semiconductor substrate 3 and the like in the manufacturing process of the pixel array section 1. An example of the material of the support substrate 9 is silicon or the like. The support substrate 9 may be bonded to the semiconductor substrate 3 by plasma bonding or an adhesive material. The support substrate 9 may be configured to include a logic circuit. By forming the connection vias between the substrates, various peripheral circuit functions can be stacked vertically, and the chip size can be reduced.

The optical layer 6 will be further described. The optical layer 6 controls a phase and the like of the incident light. The optical layer 6 can also be referred to as a light control section, an optical phase control section, or the like.

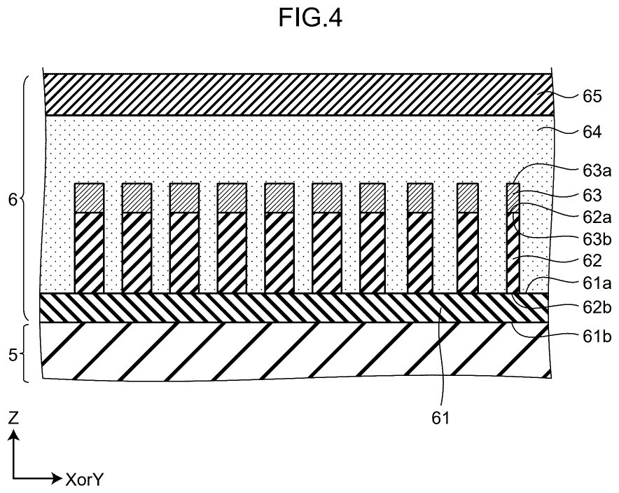

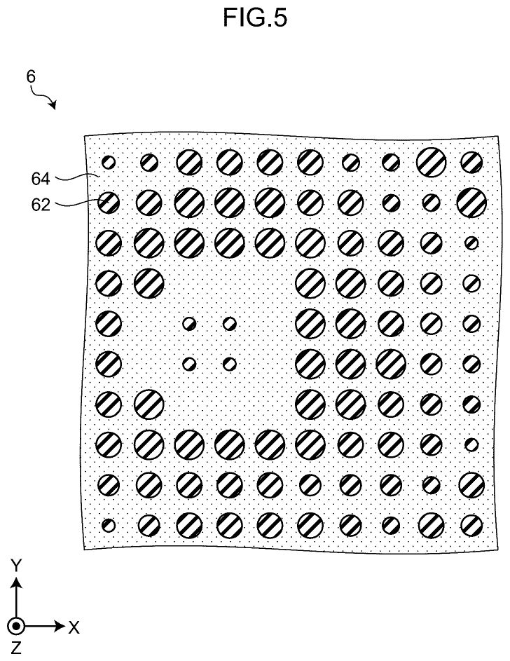

FIGS. 4 and 5 are diagrams illustrating an example of a schematic configuration of the optical layer 6. Note that FIG. 5 schematically illustrates a cross section of a portion including the pillars 62 of the optical layer 6 in plan view (as viewed in the Z-axis direction).

The optical layer 6 includes a reflection suppressing film 61, a plurality of pillars 62, a reflection suppressing film 63, a filler 64, and a protective film 65. The upper surface and the lower surface of the reflection suppressing film 61 are referred to as an upper surface 61a and a lower surface 61b in the drawing. The upper surface and the lower surface of the pillar 62 are referred to as an upper surface 62a and a lower surface 62b in the drawing. The upper surface and the lower surface of the reflection suppressing film 63 are referred to as an upper surface 63a and a lower surface 63b in the drawing.

The reflection suppressing film 61 is provided between the pillar 62 and the insulating layer 5, more specifically, on the insulating layer 5 and on the lower surface 62b of the pillar 62. The upper surface 61a of the reflection suppressing film 61 is in surface contact with the lower surface 62b of the pillar 62 and the filler 64. This surface serves as a refractive index boundary surface between the reflection suppressing film 61 and the pillar 62, and also serves as a refractive index boundary surface between the reflection suppressing film 61 and the filler 64.

The reflection suppressing film 61 suppresses light reflection on the lower surface 62b of the pillar 62 and the vicinity thereof. For example, the reflection suppressing film 61 has a refractive index between the refractive index of the insulating layer 5 and the refractive index of the pillar 62. Assuming that a wavelength of light to be detected in a medium is λ, the reflection suppressing film 61 may have a thickness of λ/4n (n is a refractive index of the medium) or an integral multiple thereof. By providing such a reflection suppressing film 61, light reflection on the lower surface 62b of the pillar 62 and the vicinity thereof can be suppressed. An example of the material of the reflection suppressing film 61 is SiN or the like.

The pillar 62 is a fine structure having a dimension shorter than the wavelength of the incident light, more specifically, the detection target light. The pillar 62 is processed to have a columnar shape or a shape based on the columnar shape, and extends in the thickness direction of the optical layer 6. An example of the material of the pillar 62 is amorphous silicon or the like.

The plurality of pillars 62 are arranged side by side at intervals, for example, in the plane direction of the optical layer 6 so as to guide light to be detected among the incident light to the photoelectric conversion section 21 (FIG. 3). The light to be detected may be visible light or invisible light. Examples of the visible light include red light, green light, and blue light. Examples of the invisible light include infrared light (IR) and the like, and more specifically may be near-infrared light (NIR).

The plurality of pillars 62 imparts an optical function to the optical layer 6. An example of the optical function is a function of controlling the direction of light, more specifically, a prism function, a lens function, and the like. The prism function is a function of separating light included in incident light for each wavelength and guiding (directing) light to be detected among the light to the photoelectric conversion section 21, and can also be called a splitter function, a color separation function, a filter function, or the like. The lens function is a function of condensing light on the photoelectric conversion section 21 (condensing function).

Each pillar 62 is designed to give a local phase difference to the light passing through the optical layer 6. Examples of the design of the pillar 62 include a design of a dimension of the pillar 62, a design of a shape of the pillar 62, a design of an arrangement of the pillar 62, and the like. Examples of the dimensions of the pillar 62 include the width of the pillar 62 (length in X-axis direction, length in Y-axis direction), the height of the pillar 62 (the length in the Z-axis direction), and the like. Examples of the shape of the pillar 62 include a shape when the pillar 62 is viewed in plan view (when viewed in the Z-axis direction), a shape when the pillar 62 is viewed in a side view (when viewed in X-axis direction and Y-axis direction), and the like. The shape may be a cross-sectional shape. The arrangement of the pillars 62 is a planar layout of the pillars 62 or the like, and includes, for example, an interval (pillar pitch) between adjacent pillars 62.

For example, in a case where the pillar 62 has a refractive index higher than the refractive index of its peripheral region (for example, the refractive index of the filler 64), the effective refractive index of a portion where the proportion occupied by the pillar 62 is large becomes high, and the effective refractive index of a portion where the proportion occupied by the pillar 62 is small becomes low. A phase of light passing through a portion having a high effective refractive index is delayed from a phase of light passing through a portion having a low effective refractive index. The direction of the light can be controlled by making the phase delay amount of the light different.

The reflection suppressing film 63 is provided on the upper surface 62a of the pillar 62. The lower surface 63b of the reflection suppressing film 63 is in surface contact with the upper surface 62a of the pillar 62. This surface serves as a refractive index boundary surface between the reflection suppressing film 63 and the pillar 62.

The reflection suppressing film 63 suppresses light reflection on the upper surface 62a of the pillar 62 and the vicinity thereof. For example, the reflection suppressing film 63 has a refractive index between the refractive index of the pillar 62 and the refractive index of the upper region (in this example, the filler 64) of the reflection suppressing film 63. The reflection suppressing film 63 may have a thickness of λ/4n (n is a refractive index of the medium) or an integral multiple thereof. By providing such a reflection suppressing film 63, light reflection on the upper surface 62a of the pillar 62 and the vicinity thereof can be suppressed. An example of the material of the reflection suppressing film 63 is SiN or the like. The reflection suppressing film 63 may be a low temperature oxide film (LTO film, for example, a silicon oxide film) or the like.

The filler 64 is provided so as to fill a gap between the pillars 62, and is provided so as to cover the reflection suppressing film 61, the pillars 62, and the reflection suppressing film 63. Pillar collapse (collapse of pillars 62) can be suppressed, and tape residue in the assembly process can be suppressed. An example of the material of the filler 64 is resin or the like. The refractive index of the filler 64 may be lower than the refractive index of each of the reflection suppressing film 61, the pillar 62, and the reflection suppressing film 63. The filler 64 is, for example, in surface contact with the upper surface 63a of the reflection suppressing film 63, and this surface becomes a refractive index boundary surface between the filler 64 and the reflection suppressing film 63.

The protective film 65 is provided on the filler 64. For example, it is possible to avoid the filler 64 from being damaged when the PAD resist of the PAD opening is peeled off in the subsequent process. The material of the protective film 65 may be an inorganic material such as SIO2. The protective film 65 in this case can also be referred to as an inorganic protective film.

The thickness of the portion of the filler 64 located between the pillar 62 (more specifically, the reflection suppressing film 63) and the protective film 65 and the thickness of the protective film 65 may be designed such that the reflected waves cancel each other as a whole using, for example, the Fresnel coefficient method or the like in consideration of the refractive index and the wavelength of the light to be detected.

Note that the filler 64 may be omitted. In this case, for example, the peripheral materials of the reflection suppressing film 61, the pillars 62, and the reflection suppressing film 63 may be air (air region). As long as there is no contradiction, the filler 64 may be appropriately read as a peripheral material, air (air region), or the like. Further, the protective film 65 may not be provided.

In the optical layer 6 having the configuration described above, since the refractive index boundary surface exists in the pillar 62 and its peripheral structure, light reflection becomes a problem. Specific techniques for suppressing light reflection will be described as first to sixth embodiments described later.

### 1. FIRST EMBODIMENT

In the first embodiment, light reflection is suppressed by devising the shape of at least one of the reflection suppressing film 63 and the reflection suppressing film 61.

### <Example of Shape of Reflection Suppressing Film 63>

FIGS. 6 to 9 are diagrams illustrating an example of a schematic configuration of the pillar 62 and its peripheral structure. Hereinafter, it is assumed that, among the refractive indexes of the pillar 62, the reflection suppressing film 63, and the filler 64, the refractive index of the filler 64 is the lowest and the refractive index of the pillar 62 is the highest. In other words, the reflection suppressing film 63 has a refractive index lower than the refractive index of the pillar 62, and meanwhile, has a refractive index higher than the refractive index of the filler 64.

The reflection suppressing film 63 has a non-flat portion 63v on the upper surface 63a. The non-flat portion 63v includes at least one of a recess and a protrusion. The non-flat portion 63v has a shape in which the cross-sectional area as viewed in the thickness direction of the reflection suppressing film 63 (as viewed in the Z-axis direction) gradually decreases as it advances upward (Z-axis positive direction). Gradually decreasing may mean decreasing stepwise or continuously decreasing. Since the reflection suppressing film 63 has a refractive index higher than the refractive index of the upper region thereof, more specifically, the refractive index of the filler 64 in this example, the effective refractive index gradually changes so as to approach the refractive index of the upper region toward the upper region. As a result, light reflection on the upper surface 63a of the reflection suppressing film 63 and the vicinity thereof can be suppressed.

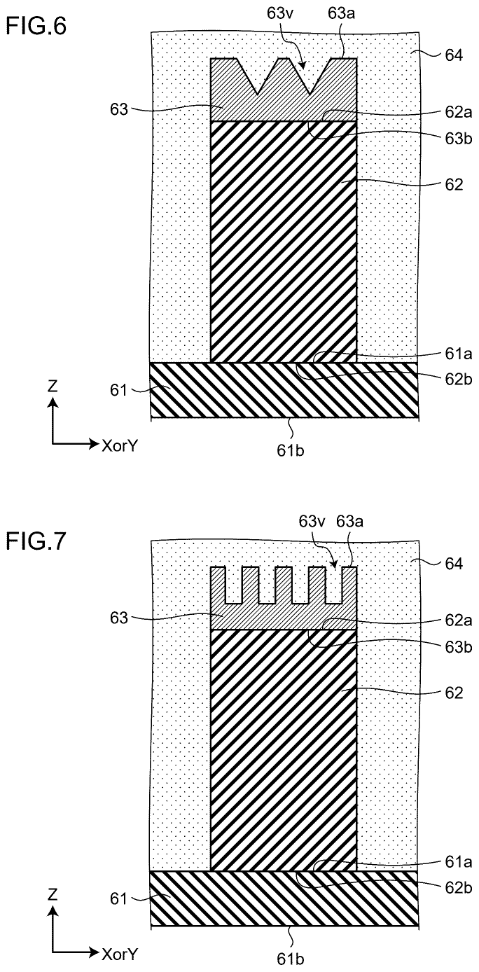

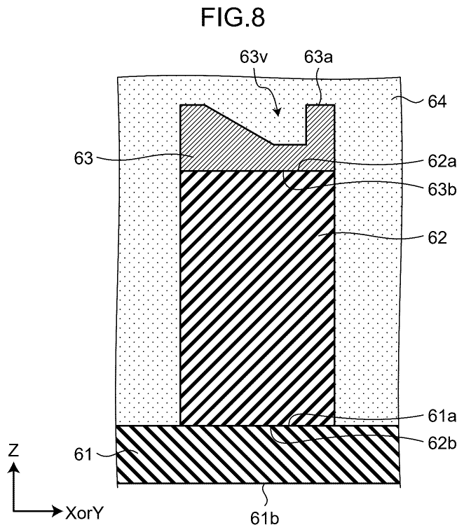

The shape of the recess of the non-flat portion 63v may be a pyramid shape as illustrated in FIG. 6 or a rectangular shape as illustrated in FIG. 7. The shape is not limited thereto, and an arbitrary shape may be the shape of the non-flat portion 63v. FIG. 8 illustrates an example of an arbitrary shape.

The height (length in the Z-axis direction) of the non-flat portion 63v, for example, the depth of the recess may be designed to have low reflection at the wavelength of the light to be detected. The height of the non-flat portion 63v may be designed to be equal to or less than a value (λ/refractive index) obtained by dividing the wavelength λ by the refractive index of the material. For example, in a case where the light to be detected is infrared light, the non-flat portion 63v may have a height of 400 nm or less. The effect of suppressing light reflection is further enhanced.

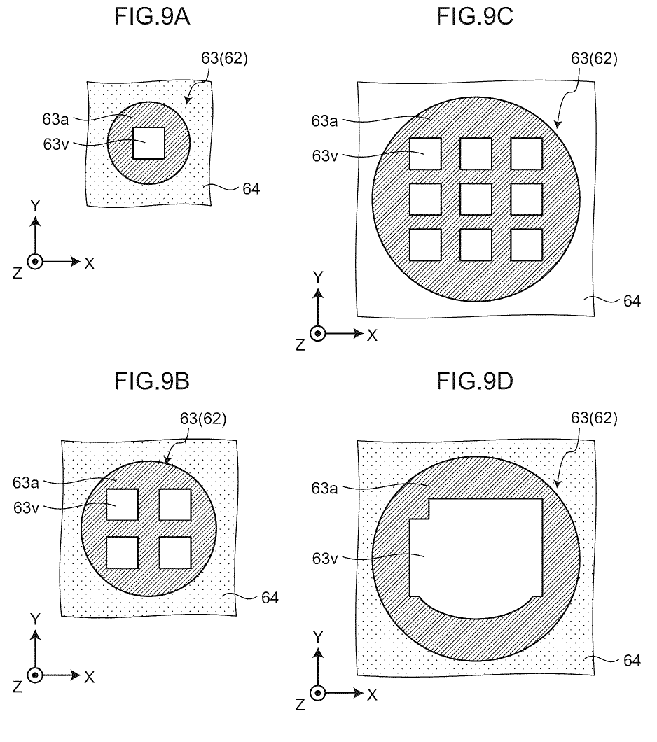

The reflection suppressing film 63 may have a plurality of non-flat portions 63v. In this case, the non-flat portions 63v may have different heights. Furthermore, as illustrated in (A) to (C) of FIG. 9, the reflection suppressing film 63 may include a larger number of non-flat portions 63v as the cross-sectional area thereof increases. Alternatively, as illustrated in (D) of FIG. 9, the reflection suppressing film 63 may include one large non-flat portion 63v.

### <Example of Shape of Reflection Suppressing Film 61>

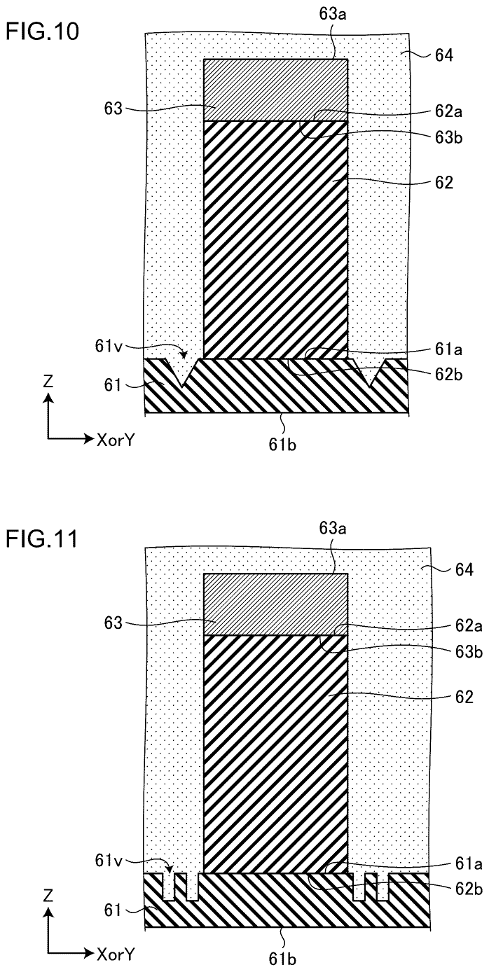

FIGS. 10 to 13 are diagrams illustrating an example of a schematic configuration of the pillar 62 and its peripheral structure. Among the refractive indexes of the reflection suppressing film 61, the pillar 62, and the filler 64, the refractive index of the filler 64 is the lowest, and the refractive index of the pillar 62 is the highest. In other words, the reflection suppressing film 61 has a refractive index lower than the refractive index of the pillar 62, and meanwhile, has a refractive index higher than the refractive index of the filler 64.

The reflection suppressing film 61 has a non-flat portion 61v on the upper surface 61a, more specifically, on a surface of the upper surface 61a in contact with the filler 64 instead of the pillar 62. The non-flat portion 61v includes at least one of a recess and a protrusion. The non-flat portion 61v has a shape in which the cross-sectional area of the reflection suppressing film 61 gradually decreases as it advances upward. Since the reflection suppressing film 63 has a refractive index higher than the refractive index of the upper region (in this example, the filler 64), the effective refractive index gradually changes so as to approach the refractive index of the upper region toward the upper region. As a result, light reflection on the upper surface 61a of the reflection suppressing film 61 and the vicinity thereof can be suppressed.

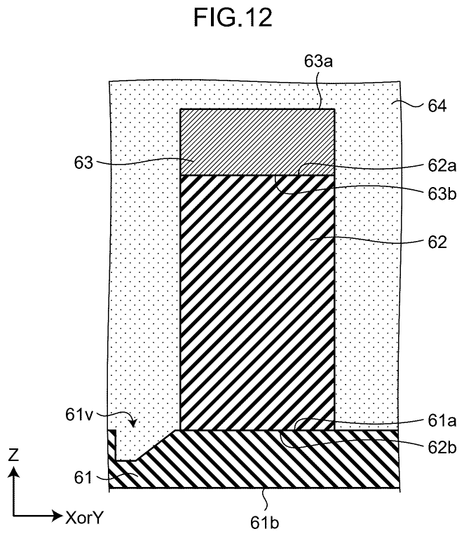

The shape of the recess of the non-flat portion 61v may be a pyramid shape as illustrated in FIG. 10 or a rectangular shape as illustrated in FIG. 11. The shape is not limited thereto, and an arbitrary shape may be the shape of the non-flat portion 61v. FIG. 12 illustrates an example of an arbitrary shape. In the example illustrated in (A) of FIG. 13, a plurality of non-flat portions 61v having a rectangular shape in plan view (when viewed in the Z-axis negative direction) are located around the reflection suppressing film 63, that is, around the pillar 62. In the example illustrated in (B) of FIG. 13, the non-flat portion 61v having a circular shape is located in the periphery of the reflection suppressing film 63, that is, in the periphery of the pillar 62.

Similarly to the non-flat portion 63v of the reflection suppressing film 63 described above, the height of the non-flat portion 61v of the reflection suppressing film 61, for example, the depth of the recess may be designed to have low reflection at the wavelength of the light to be detected. In addition, the reflection suppressing film 61 may have a plurality of non-flat portions 61v, and in this case, the non-flat portions 61v may have different heights.

In the above-described examples illustrated in FIGS. 10 to 12, the non-flat portion 61v is filled with the filler 64. Accordingly, adhesion between the reflection suppressing film 61 and the filler 64 can be improved. The non-flat portion 61v may be provided in the vicinity of the lower surface 62b of the pillar 62. By improving the adhesion of the filler 64 near the base of the pillar 62, the effect of suppressing pillar collapse can be further enhanced.

### <Example of Shape of Reflection Suppressing Film 63 and Shape of Reflection Suppressing Film 61>

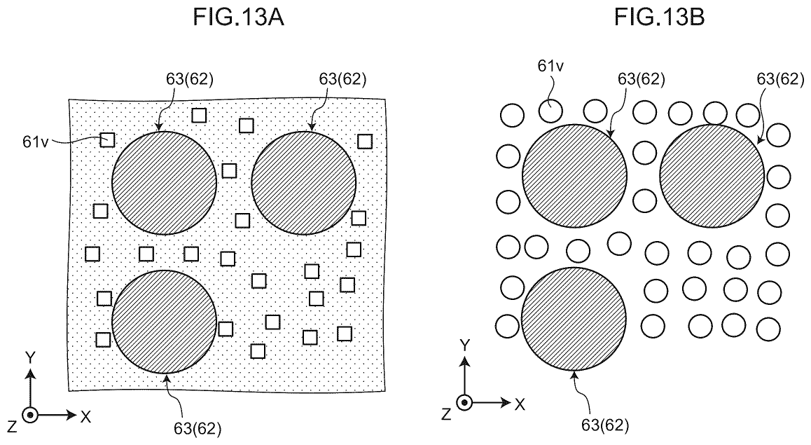

FIG. 14 is a diagram illustrating an example of a schematic configuration of the pillar 62 and its peripheral structure. The reflection suppressing film 63 has the non-flat portion 63v, and the reflection suppressing film 61 has the non-flat portion 61v. Both light reflection at the upper surface 63a of the reflection suppressing film 63 and the vicinity thereof and light reflection at the upper surface 61a of the reflection suppressing film 61 and the vicinity thereof can be suppressed.

### <Example of Manufacturing Method>

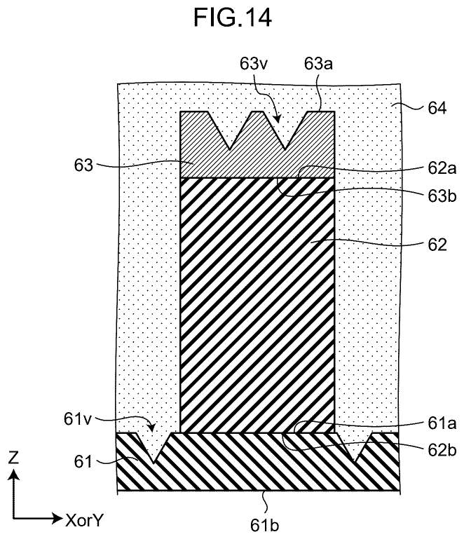

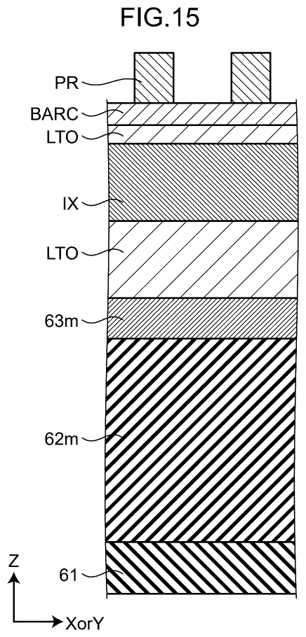

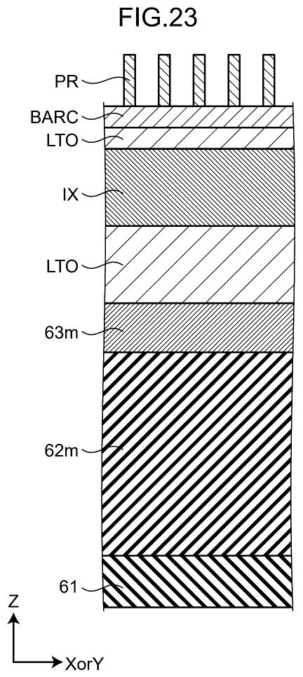

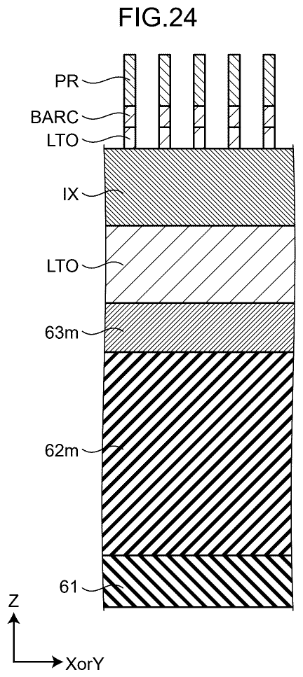

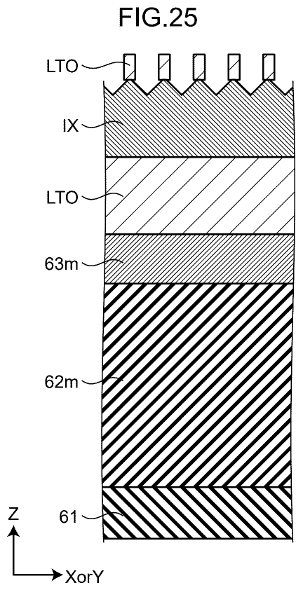

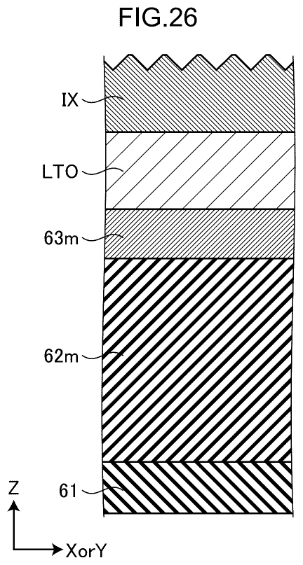

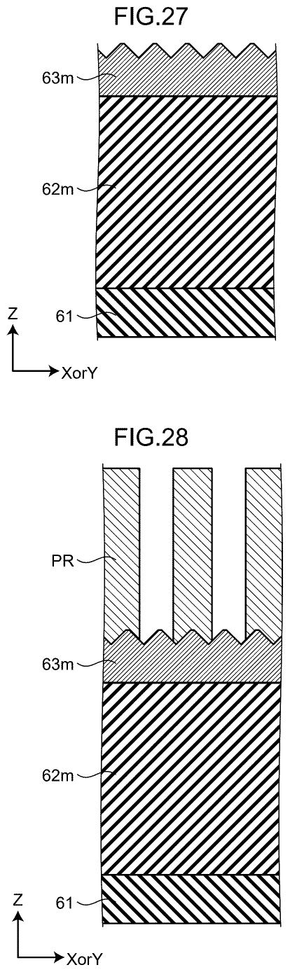

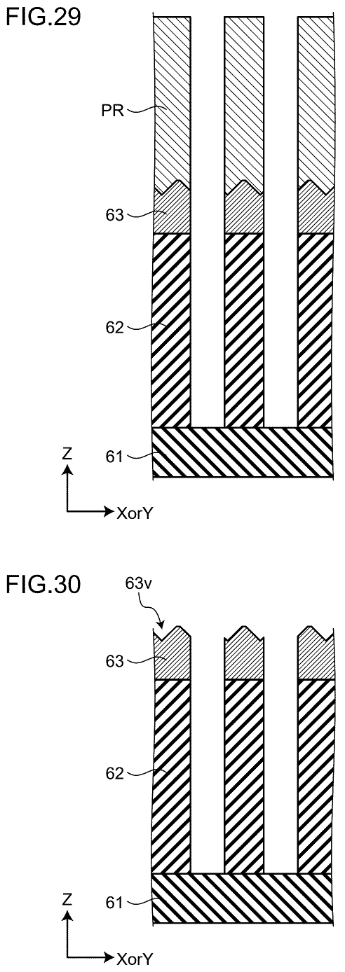

FIGS. 15 to 49 are diagrams illustrating an example of a manufacturing method.

FIGS. 15 to 30 illustrate an example of a method for manufacturing the reflection suppressing film 63 having the non-flat portion 63v and the peripheral structure thereof. A multilayer resist process using a photoresist PR, a reflection suppressing film BARC located under the photoresist PR, an upper layer film LTO, a coating-type carbon film IX, and a lower layer film LTO is used. A pattern formed of a thin resist PR is transferred to a lower layer film (upper layer LTO and carbon film IX) having a sufficient thickness and etching resistance as a mask when etching an etching target film. Next, the underlying etching target film (lower layer LTO) is accurately processed using the lower layer film (carbon film IX) as a mask.

FIGS. 15 to 22 illustrate an example of a manufacturing method in a case where the non-flat portion 63v is relatively large. The material of the pillar 62 is referred to as a pillar material 62m. The material of the reflection suppressing film 63 is referred to as a reflection suppressing film material 63m.

As illustrated in FIG. 15, a lower layer film LTO, a carbon film IX, an upper layer film LTO, and a reflection suppressing film BARC are sequentially laminated on the reflection suppressing film material 63m. A photoresist PR is formed (applied or the like) on the reflection suppressing film BARC by lithography.

As illustrated in FIG. 16, the reflection suppressing film BARC and the upper layer film LTO are processed in accordance with the pattern of the photoresist PR. For example, dry etching is used.

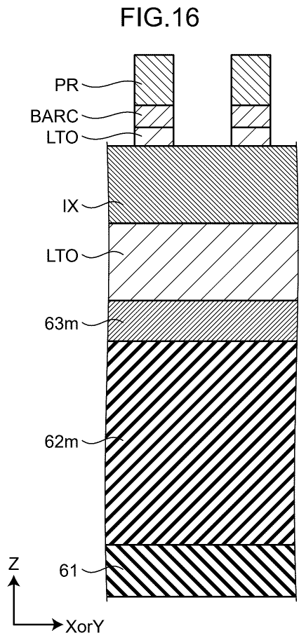

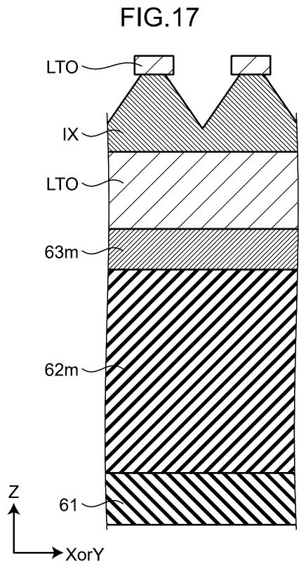

As illustrated in FIG. 17, carbon film IX is processed (for example, tapered) so that carbon film IX has a non-flat portion. For example, dry etching is used. The lower layer film LTO functions as a hard mask.

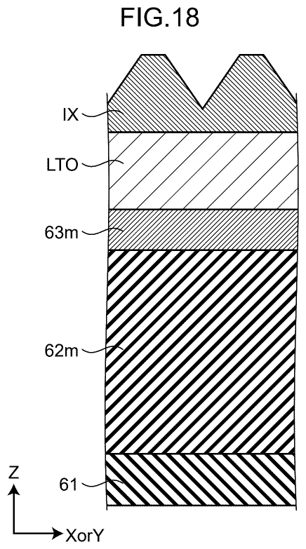

As illustrated in FIG. 18, the upper layer film LTO is removed.

As illustrated in FIG. 19, etch-back is performed such that the shape of the non-flat portion is reflected on the shape of the carbon film IX.

As illustrated in FIG. 20, a photoresist PR for pillar formation is disposed.

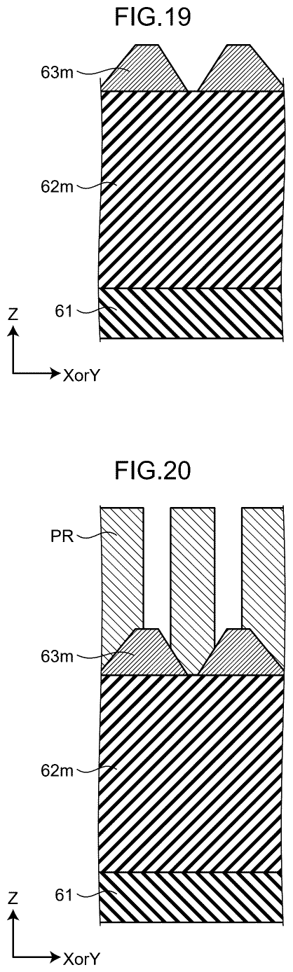

As illustrated in FIG. 21, the pillar material 62m and the reflection suppressing film material 63m are processed in accordance with the shape of the photoresist PR to obtain the pillars 62 and the reflection suppressing film 63. For example, dry etching is used.

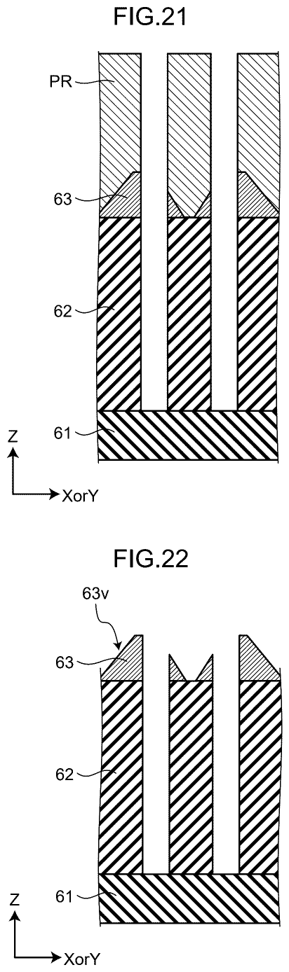

As illustrated in FIG. 22, the photoresist PR is ashing. The reflection suppressing film 63 having the non-flat portion 63v and the peripheral structure thereof are obtained.

FIGS. 23 to 30 illustrate an example of a manufacturing method in a case where the non-flat portion 63v is relatively small. Since the basic process is similar to that of FIGS. 15 to 22 described above, description thereof is omitted. Note that, for example, self-assembly (DSA) lithography may be used for lithography of the photoresist PR in FIG. 23. More fine patterning is possible.

FIGS. 31 to 38 are diagrams illustrating an example of a method for manufacturing the reflection suppressing film 61 having the non-flat portion 61v and its peripheral structure. The material of the reflection suppressing film 61 is referred to as a reflection suppressing film material 61m.

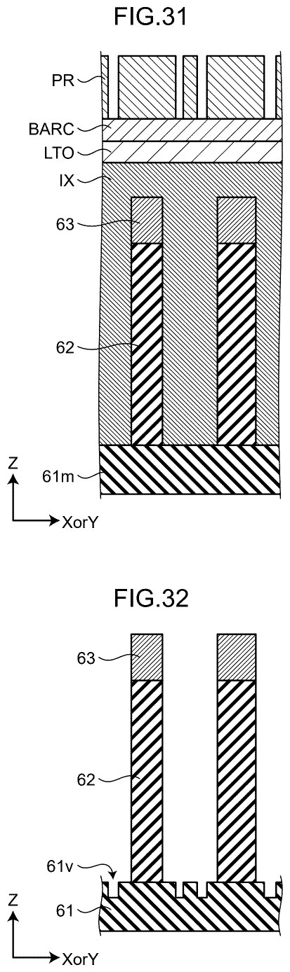

In the examples illustrated in FIGS. 31 and 32, etching is used to obtain the non-flat portion 61v.

As illustrated in FIG. 31, a carbon film IX is provided so as to cover the reflection suppressing film material 61m, the pillars 62, and the reflection suppressing film 63, and a film LTO and a reflection suppressing film BARC are sequentially laminated thereon. A photoresist PR is formed (applied or the like) on the reflection suppressing film BARC by lithography.

As illustrated in FIG. 32, for example, dry etching is performed so that the shape of the photoresist PR is reflected in the reflection suppressing film material 61m. The reflection suppressing film 61 having the non-flat portion 61v and the peripheral structure thereof are obtained.

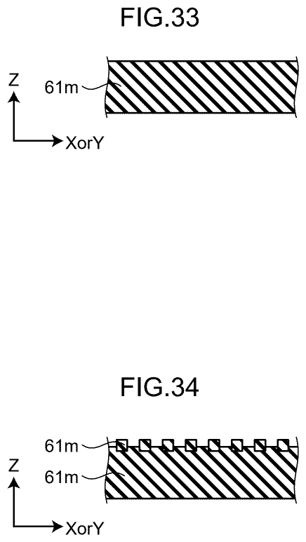

In the examples illustrated in FIGS. 33 to 38, deposit adsorption and transfer are used to obtain the non-flat portion 61v.

As illustrated in FIG. 33, a wafer containing the reflection suppressing film material 61m is prepared. As illustrated in FIG. 34, the reflection suppressing film material 61m is randomly deposited (for example, adsorbed) on the wafer. For example, in a case where the material contains Si, a deposit gas such as SiH4 is used.

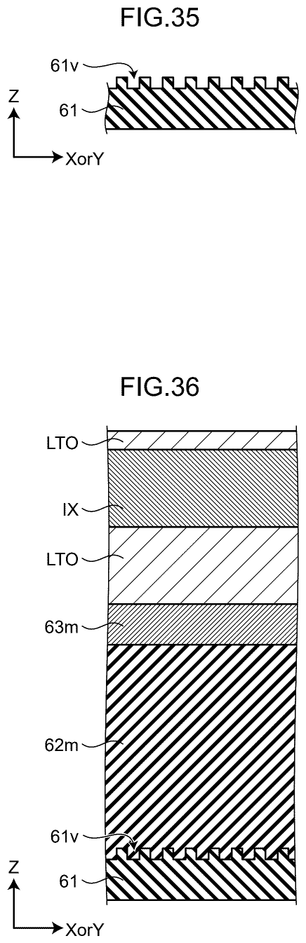

As illustrated in FIG. 35, the deposit is transferred, and the reflection suppressing film material 61m is processed so as to obtain the reflection suppressing film 61 having the non-flat portion 61v.

As illustrated in FIG. 36, the pillar material 62m is formed and planarized on the reflection suppressing film 61, and the reflection suppressing film material 63m, the lower layer film LTO, the carbon film IX, and the upper layer film LTO are formed thereon.

As illustrated in FIG. 37, a reflection suppressing film BARC is further provided, and a photoresist PR is formed thereon.

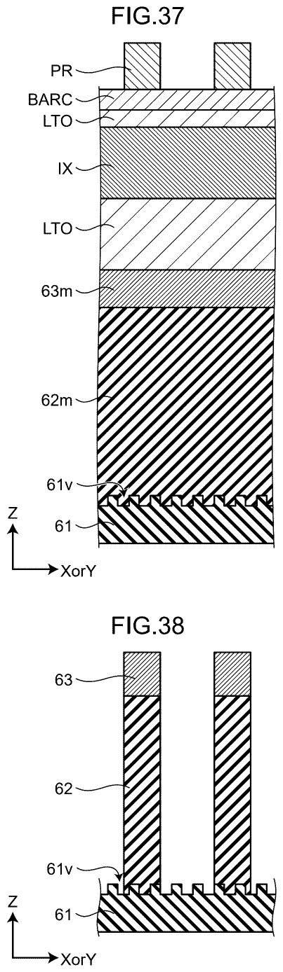

As illustrated in FIG. 38, for example, dry etching is performed so as to obtain the pillars 62 and the reflection suppressing film 63 corresponding to the shape of the photoresist PR. The reflection suppressing film 61 having the non-flat portion 61v and the peripheral structure thereof are obtained.

Sputtering with a rare gas may be used instead of using the above-described deposit adsorption and transfer. For example, instead of the process illustrated in FIGS. 34 and 35 described above, a wafer containing the reflection suppressing film material 61m is irradiated with a rare gas. By forming random non-flat portions on the wafer, the reflection suppressing film 61 having the non-flat portions 61v is obtained similarly to FIG. 35. Examples of the rare gas include He gas and Ar gas.

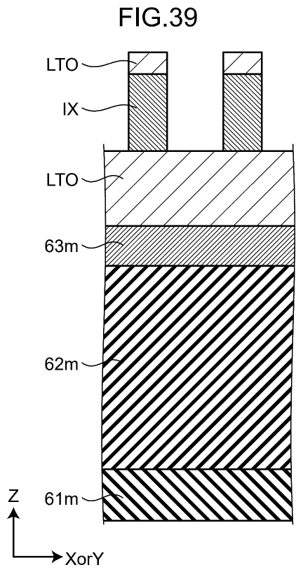

FIGS. 39 to 49 illustrate examples of a method for manufacturing the reflection suppressing film 63 having the non-flat portion 63v, the reflection suppressing film 61 having the non-flat portion 61v, and the peripheral structure thereof.

In the examples illustrated in FIGS. 39 to 44, deposit adsorption and transfer are used to obtain the non-flat portion 63v and the non-flat portion 61v. As a premise, it is assumed that the processes of FIGS. 15 and 16 described above have been completed.

As illustrated in FIG. 39, the carbon film IX is processed in accordance with the shape of the upper layer film LTO.

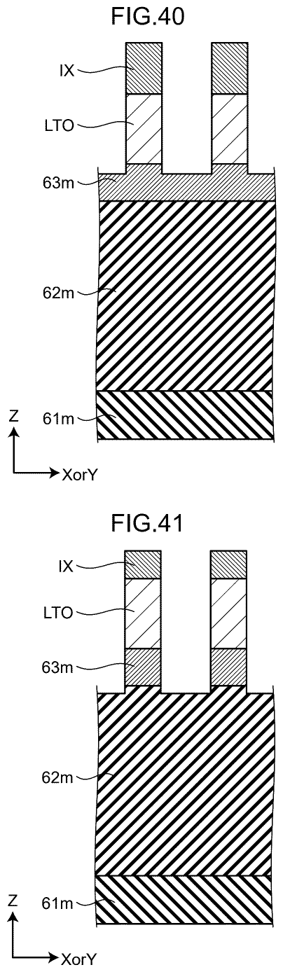

As illustrated in FIG. 40, the upper layer film LTO is removed.

As illustrated in FIG. 41, the reflection suppressing film material 63m is processed in accordance with the shapes of the carbon film IX and the upper layer film LTO.

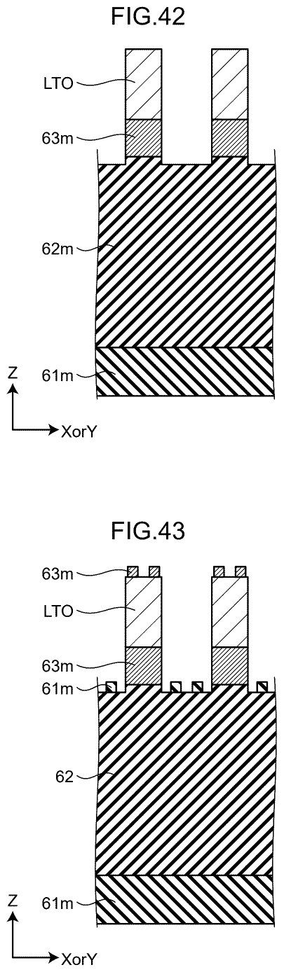

As illustrated in FIG. 42, the carbon film IX is removed.

As illustrated in FIG. 43, the reflection suppressing film material 63m and the reflection suppressing film material 61m (for example, Si) are randomly deposited.

As illustrated in FIG. 44, the deposit is transferred, the reflection suppressing film material 63m is processed so as to obtain the reflection suppressing film 63 having the non-flat portion 63v, and the reflection suppressing film material 61m is processed so as to obtain the reflection suppressing film 61 having the non-flat portion 61v. The reflection suppressing film 61 having the non-flat portion 63v, the reflection suppressing film 61 having the non-flat portion 61v, and the peripheral structure thereof are obtained.

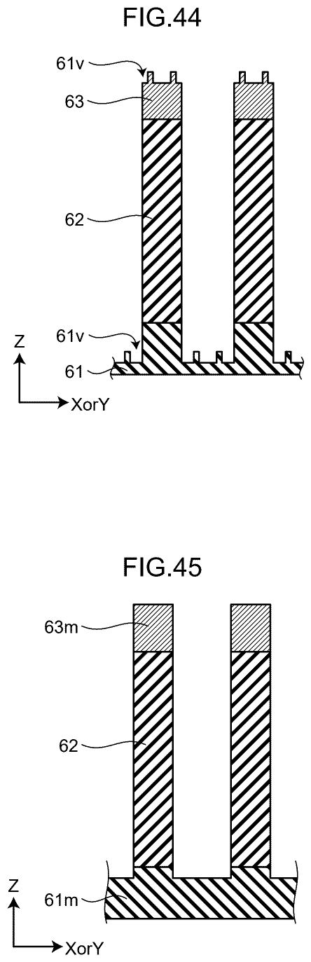

Sputtering with a rare gas may be used instead of using the above-described deposit adsorption and transfer. For example, instead of the processes illustrated in FIGS. 43 and 44 described above, the processes of FIGS. 45 and 46 described below may be adopted.

In the example illustrated in FIG. 45, after the process of FIG. 42 described above, processing is performed to obtain the pillar 62, and the upper layer film LTO is removed. As illustrated in FIG. 46, a rare gas is irradiated, and random non-flat portions are formed on the reflection suppressing film material 61m and the reflection suppressing film material 63m. The reflection suppressing film 63 having the non-flat portion 63v, the reflection suppressing film 61 having the non-flat portion 61v, and the peripheral structure thereof are obtained.

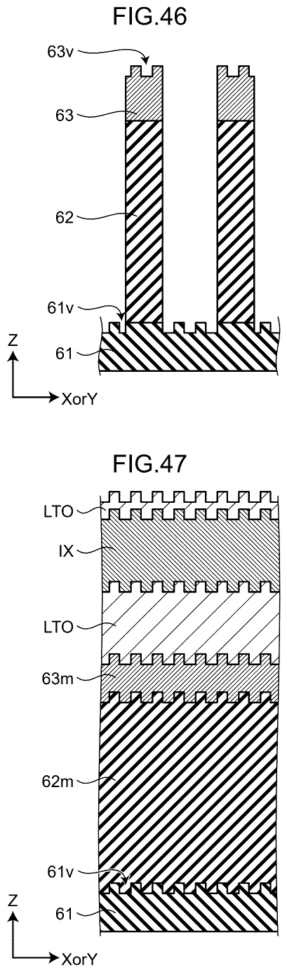

Also in the examples illustrated in FIGS. 47 to 49, deposit adsorption and transfer are used. As a premise, it is assumed that the processes of FIGS. 33 to 35 described above have been completed.

As illustrated in FIG. 47, a pillar material 62m, a reflection suppressing film material 63m, a lower layer film LTO, a carbon film IX, and an upper layer film LTO are formed on the reflection suppressing film 61. The shape of the non-flat portion 61v of the reflection suppressing film 61 is reflected on these shapes.

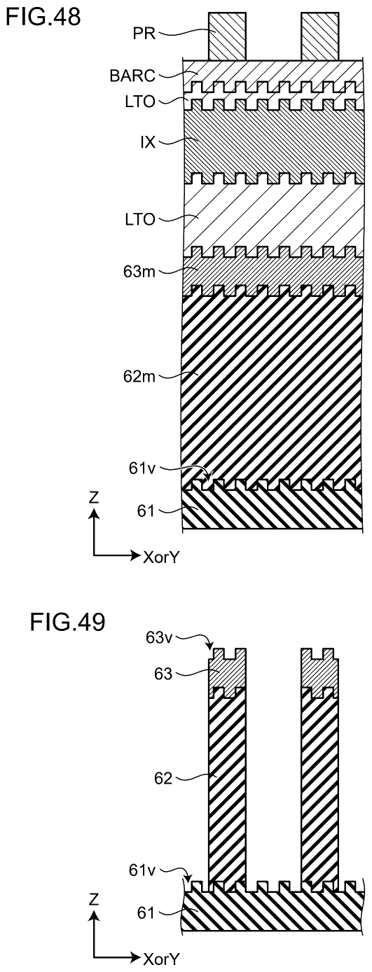

As illustrated in FIG. 48, a reflection suppressing film BARC is further provided, and a photoresist PR is formed thereon.

As illustrated in FIG. 49, for example, dry etching is performed so as to obtain the pillars 62 and the reflection suppressing film 63 corresponding to the shape of the photoresist PR. The reflection suppressing film 63 having the non-flat portion 63v, the reflection suppressing film 61 having the non-flat portion 61v, and the peripheral structure thereof are obtained.

Instead of the above-described processes of FIGS. 45 and 46, a wafer containing the reflection suppressing film material 61m may be irradiated with a rare gas. By forming random recesses on the wafer, similarly to FIG. 46, the reflection suppressing film 63 having the non-flat portion 63v, the reflection suppressing film 61 having the non-flat portion 61v, and the peripheral structure thereof are obtained.

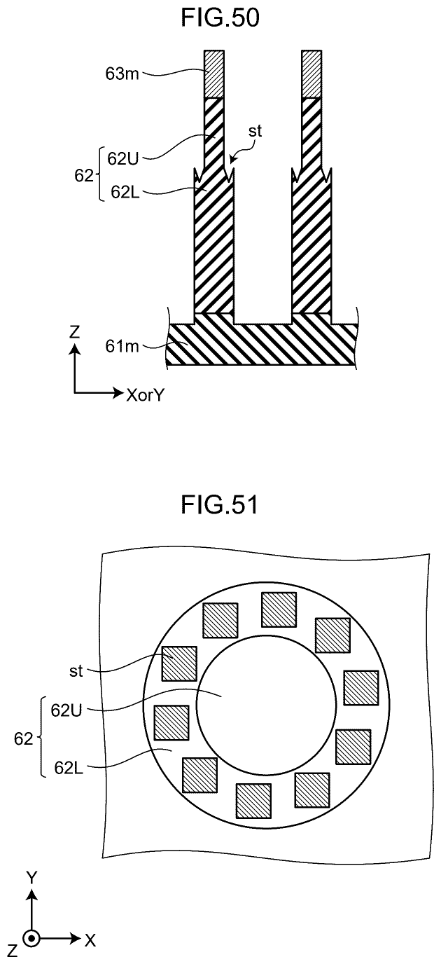

In one embodiment, pillars 62 having a two-stage configuration (two-layer configuration) may be formed. This will be described with reference to FIGS. 50 and 51.

FIGS. 50 and 51 are diagrams illustrating examples of the pillar 62 having the two-stage configuration. The portion of the first stage in the pillar 62 is referred to as a pillar 62L. The portion of the second stage is referred to as a pillar 620. After the pillar 62L is formed, the pillar 62U is formed thereon. The pillar 620 has a smaller width (for example, cross-sectional area) than the pillar 62L. A step st is formed at the boundary between the pillar 62L and the pillar 62U, thereby generating irregularities. Since interface reflection can be suppressed by the irregularities, the effect of suppressing light reflection is further enhanced. Note that FIG. 51 schematically illustrates the pillar 62 when a portion including the step st is viewed in plan view.

### <Section Summary>

The technology according to the first embodiment described above is specified as follows, for example. One of the disclosed techniques is the photodetector 100. As described with reference to FIGS. 1 to 14 and the like, the photodetector 100 includes the photoelectric conversion section 21 and the optical layer 6 provided to cover the photoelectric conversion section 21. The optical layer 6 includes the plurality of pillars 62 arranged side by side in a plane direction (XY planar direction) of the layer so as to guide at least light to be detected among the incident light to the photoelectric conversion section 21, and the reflection suppressing film (reflection suppressing film 63 and reflection suppressing film 61) provided on at least one of the upper surface 62a and the lower surface 62b of the pillar 62. The reflection suppressing film has the non-flat portion (non-flat portion 63v and non-flat portion 61v) including at least one of a recess and a protrusion. This makes it possible to suppress light reflection on the upper surface (upper surface 63a of reflection suppressing film 63 and upper surface 61a of reflection suppressing film 61) of the reflection suppressing film and in the vicinity thereof.

As described with reference to FIGS. 6 to 8, 10 to 12, and the like, the reflection suppressing film (reflection suppressing film 63 and reflection suppressing film 61) may have a refractive index higher than the refractive index of the upper region thereof, and the non-flat portion (non-flat portion 63v and non-flat portion 61v) of the reflection suppressing film may have a shape in which the cross-sectional area when viewed in the thickness direction (Z-axis direction) of the reflection suppressing film gradually decreases as it advances upward (Z-axis positive direction). Since the effective refractive index gradually changes so as to approach the refractive index of the upper region, light reflection can be suppressed.

As described with reference to FIGS. 6, 7, 10, 11, and the like, the non-flat portion (non-flat portion 63v and non-flat portion 61v) may include a recess, and the shape of the recess may include at least one of a pyramid shape and a rectangular shape. For example, light reflection can be suppressed by using a reflection suppressing film having such a non-flat portion.

As described with reference to FIGS. 6 to 14 and the like, the light to be detected may include infrared light, and the non-flat portion (non-flat portion 63v and non-flat portion 61v) may have a height of 400 nm or less (for example, the depth of the recess). This makes it possible to suitably suppress light reflection of infrared light.

As described with reference to FIGS. 6 to 9 and the like, the optical layer 6 may include the reflection suppressing film 63 provided on the upper surface 62a of the pillar 62. As a result, light reflection on the upper surface 63a of the reflection suppressing film 63 and the vicinity thereof can be suppressed.

As described with reference to FIGS. 10 to 13 and the like, the optical layer 6 may include the reflection suppressing film 61 provided on the lower surface 62b of the pillar 62. As a result, light reflection on the upper surface 61a of the reflection suppressing film 61 and the vicinity thereof can be suppressed.

As described with reference to FIG. 14 and the like, the optical layer 6 may include the reflection suppressing film 63 provided on the upper surface 62a of the pillar 62 and the reflection suppressing film 61 provided on the lower surface 62b of the pillar 62. This makes it possible to suppress both light reflection at the upper surface 63a of the reflection suppressing film 63 and the vicinity thereof and light reflection at the upper surface 61a of the reflection suppressing film 61 and the vicinity thereof.

### 2. SECOND EMBODIMENT

In the second embodiment, light reflection is suppressed by devising the shape of the pillar 62. In addition, various other devices are also used.

The problem will be described. In a case where the incident angle of light is different for each pixel 2, there remains a problem that it becomes difficult to design the film thickness or the like of the reflection suppressing film provided for the pillar 62. As will be described later, the problem can be addressed by devising the shape of the pillar 62 itself.

### <First Example of Shape of Pillar 62>

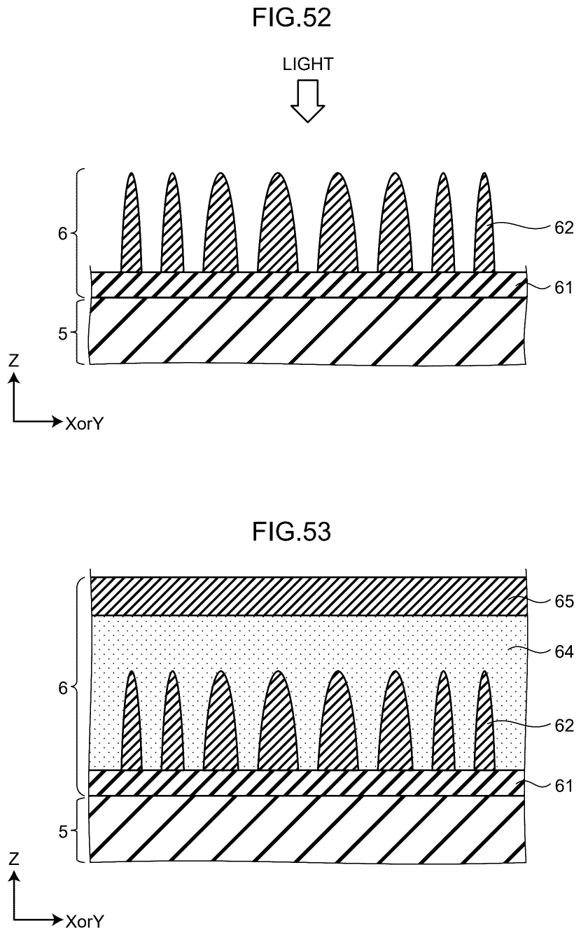

FIGS. 52 to 54 are diagrams illustrating an example of a schematic configuration of the pillar 62 and its peripheral structure. In the example illustrated in FIG. 52, the filler 64 and the protective film 65 are not provided, and the peripheral material of the pillar 62 is air. In the example illustrated in FIG. 53, the filler 64 and the protective film 65 are present, and the peripheral material of the pillar 62 is the filler 64.

The plurality of pillars 62 are arranged in a shape as if forming a moth-eye structure. The pillar 62 can also be referred to as a meta atom or the like. The pillar 62 has a cross-sectional area (an area as viewed in the Z-axis direction) that continuously changes as it advances in the pillar height direction (Z-axis direction).

As illustrated in FIG. 54, the upper end portion of the pillar 62 is referred to as an upper end portion 621. The lower end portion of the pillar 62 is referred to as a lower end portion 622. The upper end portion 621 is a portion including the upper surface 62a in the pillar 62. The lower end portion 622 is a portion including the lower surface 62b in the pillar 62. At least one of the upper surface 62a and the lower surface 62b of the pillar 62 is a curved surface. The curved surface is a surface (non-flat surface) having no flat surface extending along the XY plane. In other words, at least one of the upper surface 62a and the lower surface 62b of the pillar 62 has curvature.

In the example illustrated in FIGS. 52 to 54, the upper surface 62a of the pillar 62 is a curved surface. The lower surface 62b of the pillar 62 is a flat surface. It can also be said that the pillar 62 has a bell shape with the lower surface 62b as a base end and the upper surface 62a as a tip end. The pillar 62 has a cross-sectional area that monotonically decreases toward the upper surface 62a. In other words, the pillar 62 has a cross-sectional area that monotonically increases toward the lower surface 61b.

The right side of FIG. 54 schematically illustrates the effective refractive index at each position from the position at the same height as the lower surface 62b of the pillar 62 to the position at the same height as the upper surface 62a in the optical layer 6. The effective refractive index changes so as to gradually approach the refractive index of the upper region of the pillar 62 (the air region or the filler 64). Here, gradually approaching may mean continuously approaching. As a result, light reflection on the upper surface 62a of the pillar 62 and the vicinity thereof can be suppressed. It is also possible to further improve the light detection sensitivity and to suppress flare in imaging.

In a case where the peripheral material of the pillar 62 is air, since the refractive index of the air is low, a phase difference between light that has passed through the pillar 62 and light that has not passed through the pillar 62 is easily obtained. It is also advantageous from the viewpoint of reflection suppression. In addition, when compared with the same volume, since the pillar 62 has a bell shape, the area of the lower surface 62b is larger than that in a case where the pillar has a cylindrical shape, for example. As a result, the installation area of the pillar 62 increases, and the peeling resistance of the pillar 62 is improved.

The filler 64 and the protective film 65 will be described again with reference to FIG. 53. The filler 64 is provided so as to fill the space between the plurality of pillars 62. The filler 64 is a transparent filler material. The refractive index of the filler 64 is desirably separated from the refractive index of the pillar 62 to some extent. For example, the filler 64 may have a refractive index that differs from the refractive index of the pillar 62 by 0.3 or more (for example, 0.3 or more lower). The filler 64 may be an organic material.

The protective film 65 is provided so as to cover the filler 64. For example, the protective film 65 may be provided as a countermeasure against resist mixing at the time of PAD processing in a case where the filler 64 is an organic material. An example of the material of the protective film 65 is SiO₂ or the like.

The refractive index of the filler 64 and the refractive index of the protective film 65 are desirably close to each other to some extent. For example, the refractive index difference between the two may be 0.1 or less. In a case where a refractive index difference occurs, the protective film 65 may have a thickness of λ/4n (n is a refractive index of the medium) or an integral multiple thereof so as to minimize light reflection.

By providing the filler 64 and the protective film 65, for example, resistance at the time of peeling off the tape whose surface is protected in the BGR process of assembly is enhanced, and the risk of adhesive residue is also reduced. From the viewpoint of reliability, resistance to drop impact is improved, and a passivation effect can also be expected.

### <Second Example of Shape of Pillar 62>

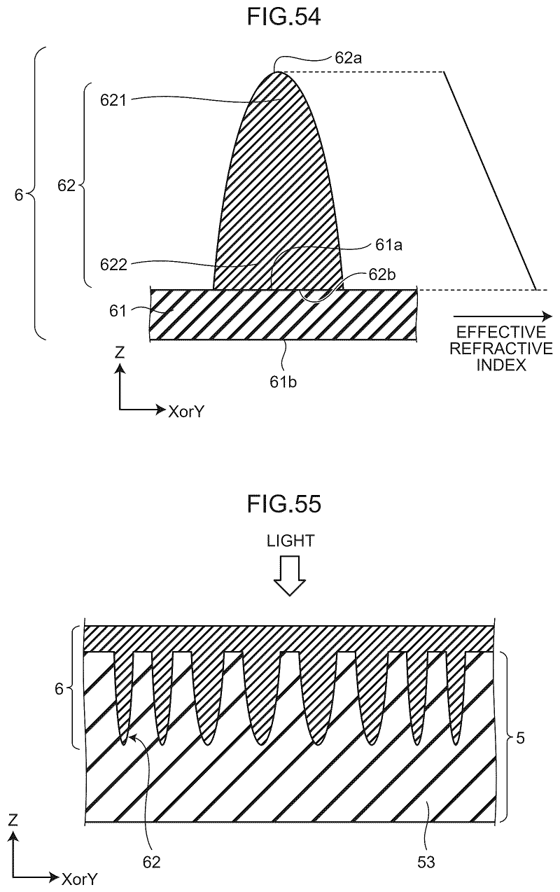

FIGS. 55 and 56 are diagrams illustrating an example of a schematic configuration of the pillar 62 and its peripheral structure. In this example, the upper surface 62a of the pillar 62 is a flat surface. The lower surface 62b of the pillar 62 is a curved surface. It can also be said that the pillar 62 has a bell shape with the upper surface 62a as a base end and the lower surface 62b as a tip end. The pillar 62 has a cross-sectional area that monotonically decreases toward a lower surface 61ba. In other words, the pillar 62 has a cross-sectional area that monotonically increases toward the upper surface 61a.

In this example, the pillars 62 extend into the insulating layer 5. Specifically, the optical layer 6 further includes a base layer 620. The base layer 620 is commonly provided on the upper surface 62a of each of the plurality of pillars 62. The material of the base layer 620 may be the same as the material of the pillars 62. The base layer 620 may have a thickness of λ/4n (n is a refractive index of the medium) or an integral multiple thereof. Light reflection there is minimized. The pillar 62 extends from the base layer 620 into the insulating film 53 of the insulating layer 5. The refractive index of the insulating film 53 is different from the refractive index of the pillar 62, and is lower than the refractive index of the pillar 62, for example.

The effective refractive index of the optical layer 6 changes so as to gradually approach the refractive index of the lower region of the pillar 62 (in this example, the insulating film 53). Thus, light reflection on the lower surface 62b of the pillar 62 and the vicinity thereof can be suppressed.

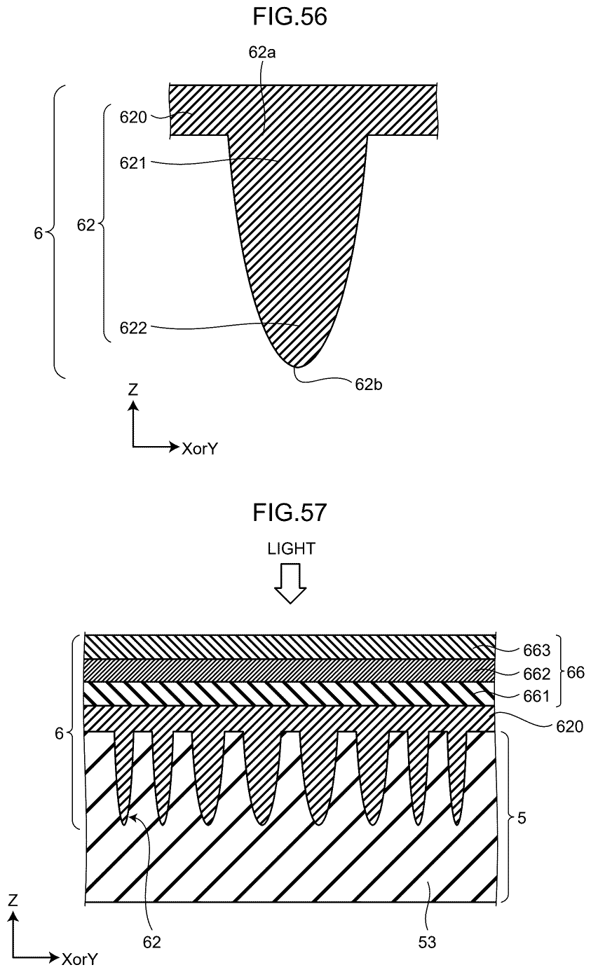

A refractive index boundary surface is created between the base layer 620 and its upper region. Further layers may be provided to suppress light reflection there. This will be described with reference to FIG. 57.

FIG. 57 is a diagram illustrating an example of a schematic configuration of the pillar 62 and its peripheral structure. The optical layer 6 further includes an additional layer 66. The additional layer 66 is provided on the base layer 620.

The additional layer 66 may include a reflection suppressing film, and the additional layer 66 in that case may include a plurality of films each having a different refractive index. FIG. 57 illustrates, as the plurality of films, a first film 661, a second film 662, and a third film 663 sequentially laminated in the Z-axis positive direction. Each film has a refractive index between the refractive index of the base layer 620 and the refractive index of the upper region of the additional layer 66. The refractive index of the first film 661 is closest to the refractive index of the base layer 620, and the refractive index of the third film 663 is farthest from the refractive index of the base layer 620. Light reflection can be suppressed by changing the refractive index stepwise.

In one embodiment, the film included in the additional layer 66 may be a band pass filter that passes only the light to be detected out of the incident light. It is possible to suppress incidence of unnecessary light on the photoelectric conversion section 21.

### <Third Example of Shape of Pillar 62>

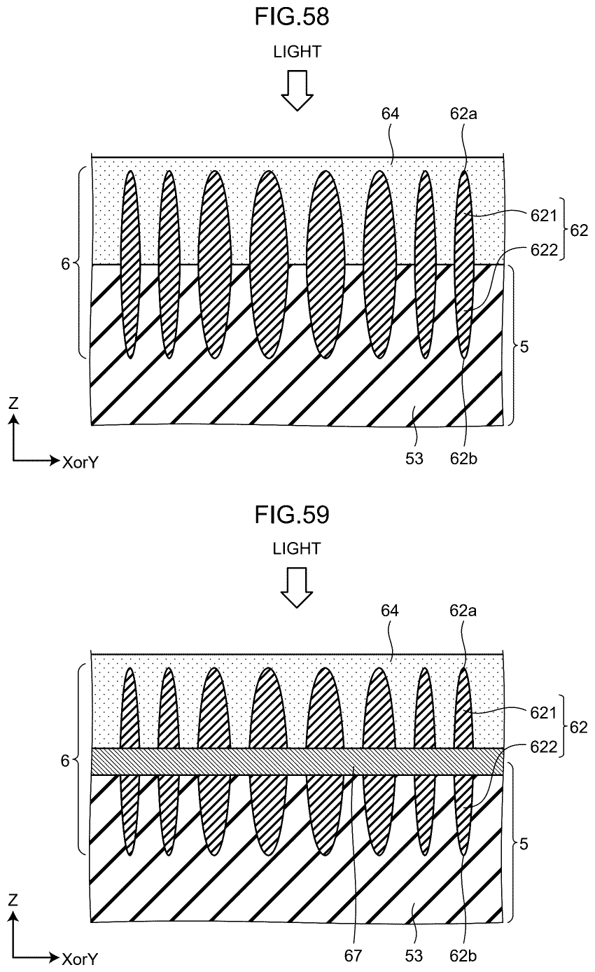

FIGS. 58 and 59 are diagrams illustrating an example of a schematic configuration of the pillar 62 and its peripheral structure. In this example, both the upper surface 62a and the lower surface 62b of the pillar 62 are curved surfaces. The pillar 62 has a cross-sectional area that monotonically increases and monotonically decreases from one surface to the other surface of the upper surface 62a and the lower surface 62b (as it advances in the Z-axis direction). Both light reflection at the upper surface 62a of the pillar 62 and the vicinity thereof and light reflection at the lower surface 62b of the pillar 62 and the vicinity thereof can be suppressed.

In the example illustrated in FIG. 59, the optical layer 6 further includes an etching stopper layer 67. The upper end portion 621 and the lower end portion 622 of the pillar 62 are located opposite to each other with the etching stopper layer 67 interposed therebetween. By processing the upper portion of the etching stopper layer 67 using the etching stopper layer, it is easy to process the pillar 62. The material of the etching stopper layer 67 may be a transparent material that transmits light to be detected. The etching stopper layer 67 may have a thickness of an integral multiple of λ/4n (n is a refractive index of the medium). Light reflection there is minimized.

### <Example of Designing Height of Pillar 62>

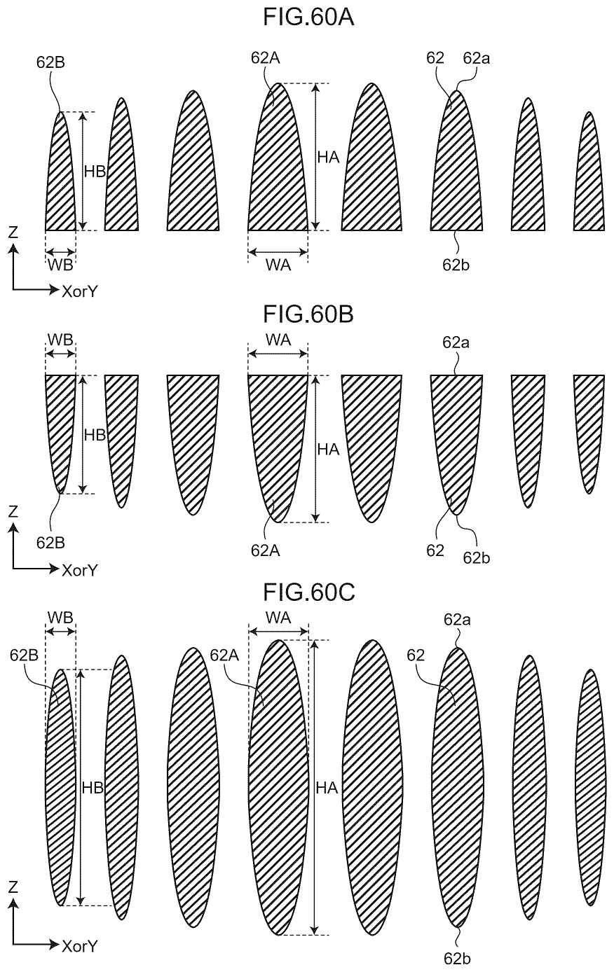

As described above, the dimensions and the like of each pillar 62 are designed. In one embodiment, the height of the pillars 62 may be designed to match the maximum width of the pillars 62. This will be described with reference to FIG. 60.

FIG. 60 is a diagram illustrating examples of maximum widths and heights of the plurality of pillars 62. (A) of FIG. 60 illustrates several pillars 62 in which the upper surface 62a is a curved surface. (B) of FIG. 60 illustrates several pillars 62 in which the lower surface 62b is a curved surface. (C) of FIG. 60 illustrates several pillars 62 in which both the upper surface 62a and the lower surface 62b are curved surfaces.

The maximum width of the pillar 62 is referred to as a maximum width W. The maximum width W is the width of the portion having the largest width in the pillar 62. The height of the pillar 62 is referred to as a height H. At least some 62 of the plurality of pillars 62 have different maximum widths W. Among the plurality of pillars 62, the pillar 62 having the largest maximum width W is referred to as a pillar 62A in the drawing. The pillar 62 having the smallest maximum width W is referred to as a pillar 62B in the drawing.

The maximum width W of the pillar 62A is referred to as a maximum width WA in the drawing. The height H of the pillar 62A is referred to as a height HA in the drawing. The maximum width W of the pillar 62B is referred to as a maximum width WB in the drawing. The height H of the pillar 62B is referred to as a height HB in the drawing. In this example, the height HA of the pillar 62A is greater than the height HB of the pillar 62B (HA>HB).

In general terms including the other pillars 62, the pillars 62 are designed such that the height H increases as the maximum width W increases. The pillars 62 having a large maximum width W are intended to provide a large phase delay. By increasing the height H of the pillar 62, a large phase delay is more easily obtained. Conversely, the pillars 62 are designed such that the smaller the maximum width W, the smaller the height H. The pillars 62 having a small maximum width W are intended to provide a small phase delay. By reducing the height H of the pillar 62, a small phase delay is more easily obtained. In addition, the pillars 62 having a smaller maximum width are more likely to collapse, but the risk can be reduced by reducing the height.

### <Example of Material of Pillar 62>

Examples of the material of the pillar 62 in a case where the light to be detected is near-infrared light include amorphous silicon (a-Si), polycrystalline silicon (Poly-Si), germanium, and the like. The pillar 62 may have a height of 200 nm or more. The optical layer 6 suitable for controlling near-infrared light can be obtained.

Examples of the material of the pillar 62 in a case where the light to be detected is visible light include titanium oxide, niobium oxide, tantalum oxide, aluminum oxide, hafnium oxide, silicon nitride, silicon oxide, silicon nitride oxide, silicon carbide, silicon carbide oxide, silicon carbide nitride, and zirconium oxide. Two or more materials may be used, and in this case, the pillar 62 may be a laminated structure in which layers including the respective materials are laminated. The pillar 62 may have a height of 300 nm or more. The optical layer 6 suitable for visible light control can be obtained.

### <Example of Arrangement of Pillars 62>

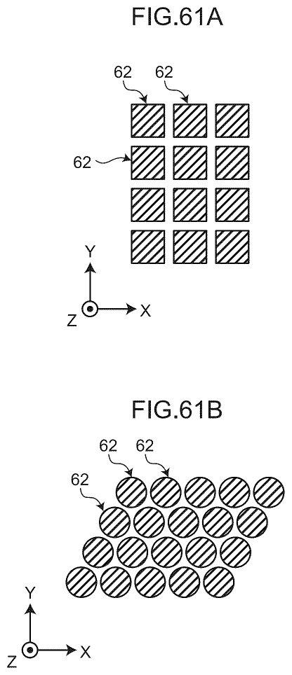

FIG. 61 is a diagram illustrating examples of the arrangement of the pillars 62. A planar layout of a portion having the largest cross-sectional area of each pillar 62 is illustrated. In the example illustrated in (A) of FIG. 61, each pillar 62 has a square cross-sectional shape, and the plurality of pillars 62 are arranged in a square manner. In the example illustrated in (B) of FIG. 61, each pillar 62 has a circular cross-sectional shape, and the plurality of pillars 62 are arranged in a hexagonal close-packed manner. Note that the cross-sectional shape of each pillar 62 may be an octagonal shape or the like. For example, by arranging the plurality of pillars 62 in this manner, a high filling rate can be obtained.

### <Example of Cross-Sectional Shape of Pillar 62>

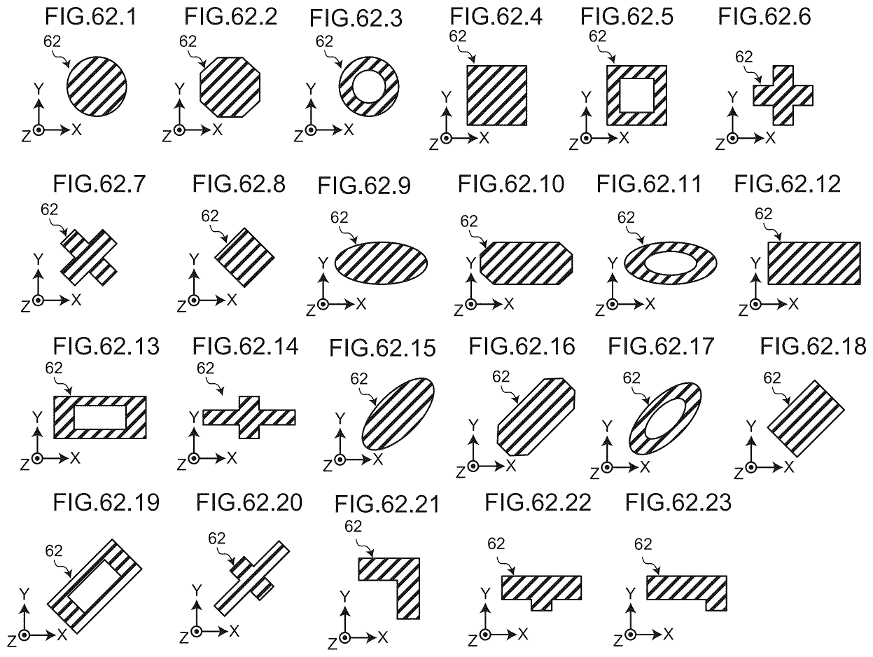

FIG. 62 is a diagram illustrating examples of cross-sectional shapes of the pillars 62. Some cross-sectional shapes of the portion having the largest cross-sectional area of the pillars 62 are illustrated. The cross-sectional shape of the pillar 62 is designed from various viewpoints such as anisotropy control of the polarization component, a reflection component depending on the area ratio, process processability, and pattern collapse resistance in addition to the control of the effective refractive index.

(1) to (3) of FIG. 62 illustrate a circular shape, a regular octagonal shape, and an annular shape (ring shape) as cross-sectional shapes excellent in isotropy of polarization control. (4) to (8) of FIG. 62 illustrate a cross-sectional shape having 4-fold rotational symmetry with respect to horizontal and vertical or 45 degree and 135 degree axes and mirror inversion symmetry at the polarization viewpoint, specifically, a square shape, a square ring shape, a cross shape, an X shape, and a square rhombus shape.

(9) to (21) of FIG. 62 illustrate cross-sectional shapes exhibiting uniaxial characteristics at the polarization viewpoint. The cross-sectional shapes illustrated in (9) to (20) of FIG. 62 are obtained based on the shapes of (1) to (8) described above. For example, (12) of FIG. 62 illustrates a rectangular shape having long sides and short sides. Further, (21) of FIG. 62 illustrates an L shape.

(22) and (23) of FIG. 62 illustrate variations of (12) of FIG. 62. Specifically, in the shape illustrated in (12) of FIG. 62, in a case where the short side is further shortened (the cross section is thinned), the auxiliary pattern is arranged such that the pillar 62 does not easily fall. In the examples illustrated in (22) and (23) of FIG. 62, a portion extending in the lateral direction from a part of the long side corresponds to the auxiliary pattern.

When the comparison is made with the same cross-sectional area, the annular shape as illustrated in (3), (5), (11), (13), (17), and (19) of FIG. 62 can provide a small effective refractive index difference while avoiding the collapse risk of the pillar 62. In addition, when compared at the same pillar pitch, the pillars 62 having a cross-sectional shape as illustrated in (4) or (5) of FIG. 62 are arranged in a square manner, or the pillars 62 having a cross-sectional shape as illustrated in (1) to (3) of FIG. 62 are arranged in a honeycomb manner, so that the filling rate of the pillars 62 can be increased to easily provide a phase difference.

### <Example of Manufacturing Method>

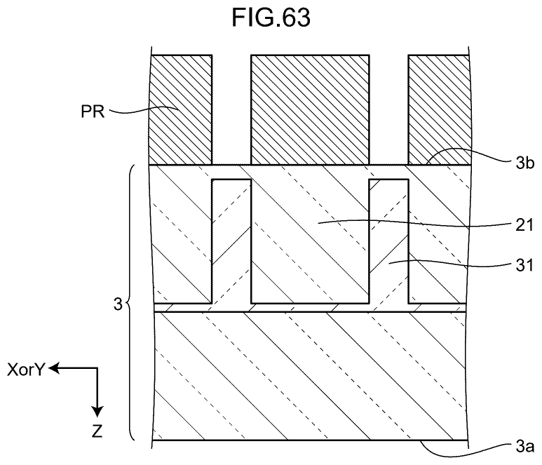

FIGS. 63 to 81 are diagrams illustrating an example of a manufacturing method. Unless otherwise specified, the semiconductor substrate 3 is assumed to be a silicon (Si) semiconductor substrate. The material of the light shielding film 52 is referred to as a light shielding film material 52m. The material of the insulating film 53 is referred to as an insulating film material 53m.

FIGS. 63 to 74 illustrate an example of a manufacturing method in a case where the upper surface 62a of the pillar 62 is a curved surface.

As illustrated in FIG. 63, desired impurities are formed by ion implantation from the lower surface 3b side of the semiconductor substrate 3 using the photoresist PR as a mask. A p-type semiconductor well region in contact with the separation region 31 is formed in a region corresponding to each pixel on the lower surface 3b of the semiconductor substrate 3, and transistors (for example, transistors 23 to 26 in FIG. 2) of a pixel circuit are formed in the p-type semiconductor well region. Each transistor is formed by a source region and a drain region, a gate insulating film, and a gate electrode. Furthermore, a wiring layer made of aluminum, copper, or the like is formed on the upper portion (in this example, the Z-axis negative direction side) of the lower surface 3b of the semiconductor substrate 3 with an interlayer insulating film such as a SiO₂ film interposed therebetween. A through-via is formed between the transistor formed on the lower surface 3b of the semiconductor substrate 3 and the wiring layer, and is electrically connected to drive the pixel 2. An interlayer insulating film such as a SiO₂ film is laminated on the wiring, and this interlayer insulating film is planarized by chemical mechanical polishing (CMP) to make the surface of the wiring layer substantially flat, and wiring is formed on the wiring while being connected to the lower layer wiring by a through-via, which is repeated to sequentially form the wiring of each layer.

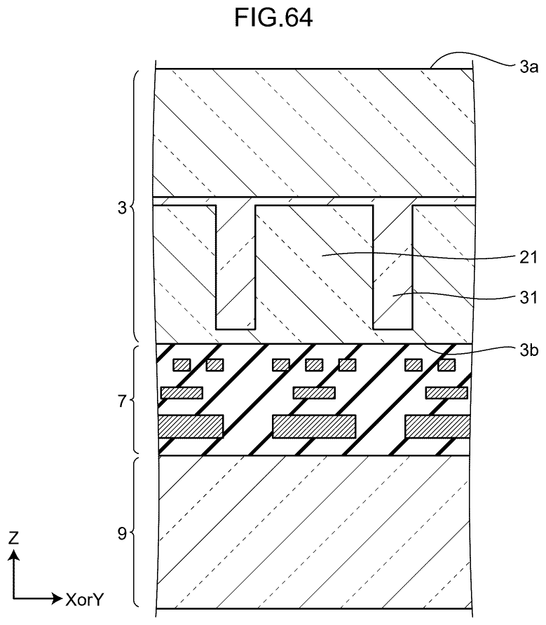

As illustrated in FIG. 64, the semiconductor substrate 3 is turned upside down and bonded to the support substrate 9 by plasma bonding or the like. The semiconductor substrate 3 is thinned from the upper surface 3a side (back surface side) by, for example, wet etching, dry etching, or the like.

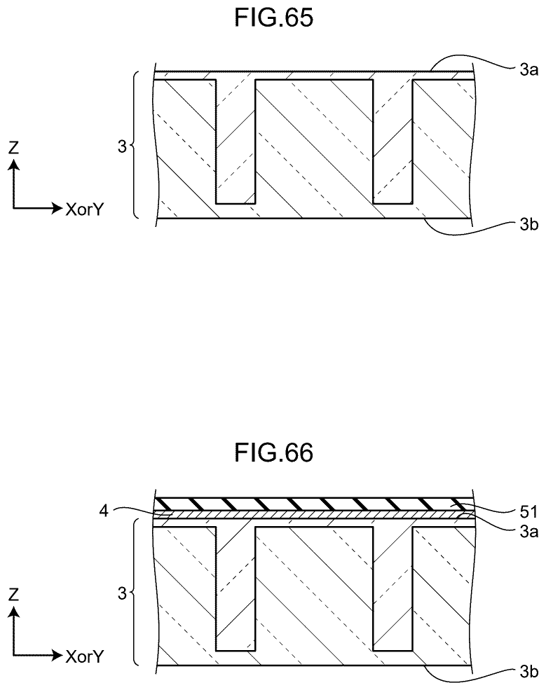

As illustrated in FIG. 65, the semiconductor substrate 3 is thinned to a desired thickness by, for example, CMP. The thickness of the semiconductor substrate 3 is adjusted according to the wavelength region of the light to be detected. As an example, the semiconductor substrate 3 corresponding to only the visible light region may have a thickness in a range of 2 to 6 μm, for example. The semiconductor substrate 3 in a case of also corresponding to the near-infrared region may have a thickness in a range of 3 to 15 μm, for example.

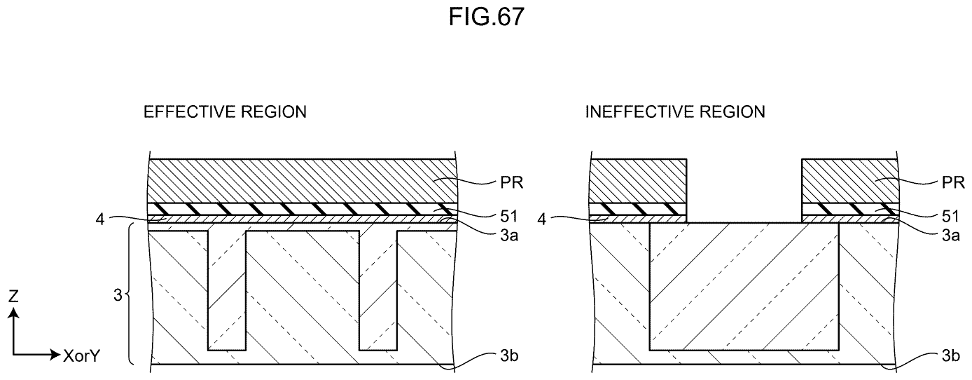

As illustrated in FIG. 66, the fixed charge film 4 is formed by CVD, sputtering, or atomic layer deposition (ALD). In a case where ALD is adopted, good coverage can be obtained at an atomic layer level, and a silicon oxide film that reduces an interface state can be formed at the same time during formation of the fixed charge film 4. The fixed charge film 4 may also serve as a reflection suppressing film for the semiconductor substrate 3 (Si semiconductor substrate) having a high refractive index by controlling the film thickness or laminating multiple layers. The insulating film 51 may be, for example, SiO₂ formed by ALD, and may have a thickness of 20 nm or more, more preferably a thickness of 50 nm or more because film peeling due to a blister phenomenon is likely to occur when the insulating film is thinned.

The light shielding film 52 is formed by using the above-described material by CVD, sputtering, or the like. When the metal is processed in an electrically floating state, there is a risk that plasma damage occurs. In order to cope with this, as illustrated in FIG. 67, a punching pattern of a photoresist PR having a width of, for example, several μm is transferred in an ineffective region (region outside the effective region), and a groove is formed by anisotropic etching, wet etching, or the like to expose the upper surface 3a of the semiconductor substrate 3.

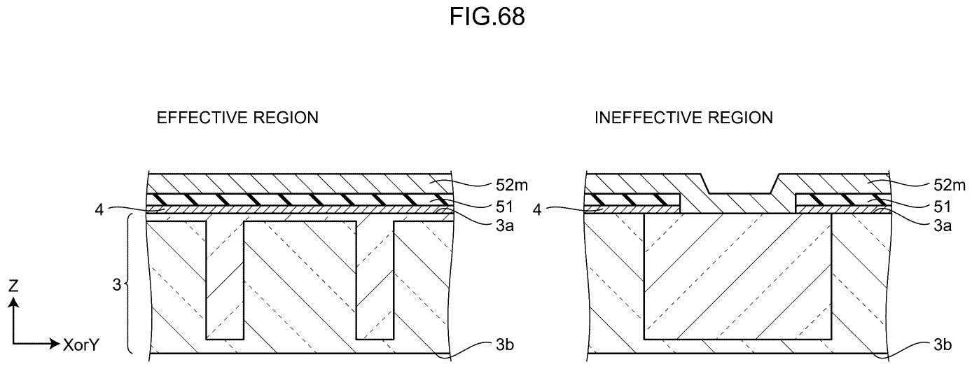

As illustrated in FIG. 68, the light shielding film material 52m is formed on the semiconductor substrate 3 in a grounded manner. The region of the semiconductor substrate 3 to be grounded is set to a ground potential as, for example, a p-type semiconductor region. The light shielding film material 52m is configured by laminating a plurality of layers, and for example, titanium, titanium nitride, or a laminated film thereof may be used as an adhesion layer with respect to the insulating film 51. Alternatively, only titanium, titanium nitride, or a laminated film thereof can be used as the light shielding film material 52m. Furthermore, the light shielding film material 52m can also serve as a light shielding film of a black level calculation pixel (not illustrated), which is a pixel for calculating a black level of an image signal, or a light shielding film for preventing a malfunction of a peripheral circuit.

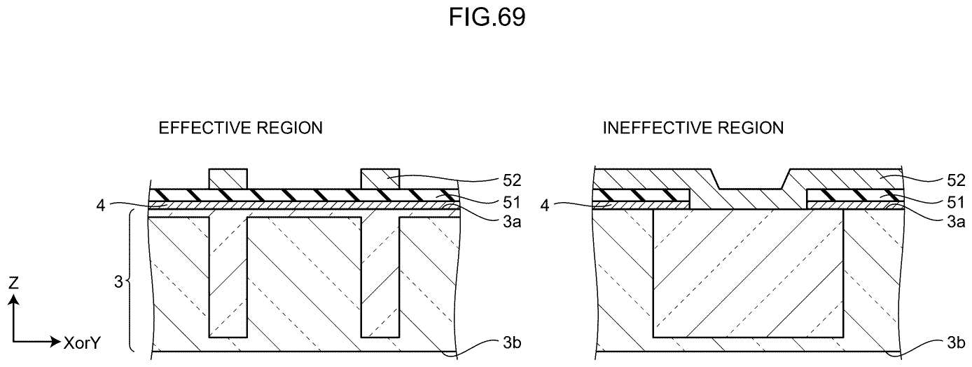

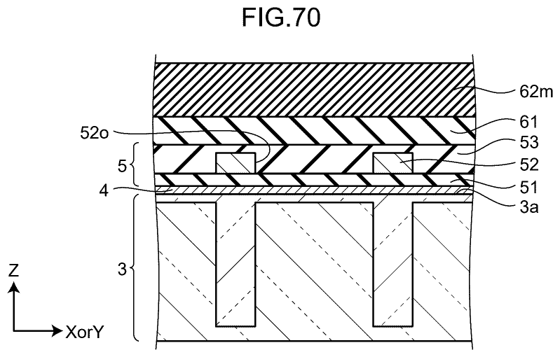

As illustrated in FIG. 69, for the light shielding film material 52m, for example, a resist punching pattern is formed in an opening for guiding light to the photoelectric conversion section 21, a pad portion, a scribe line portion, and the like. The light shielding film material 52m is partially removed by anisotropic etching or the like, and a residue is removed by chemical cleaning as necessary. The light shielding film 52 is obtained.

As illustrated in FIG. 70, the insulating film 53 is formed on the light shielding film 52 by using, for example, SiO₂ by CVD, sputtering, or the like. After planarization by CMP, the reflection suppressing film 61 (for example, SiN of 125 nm) is formed by using, for example, CVD, and the pillar material 62m, for example, amorphous silicon of 800 nm is formed.

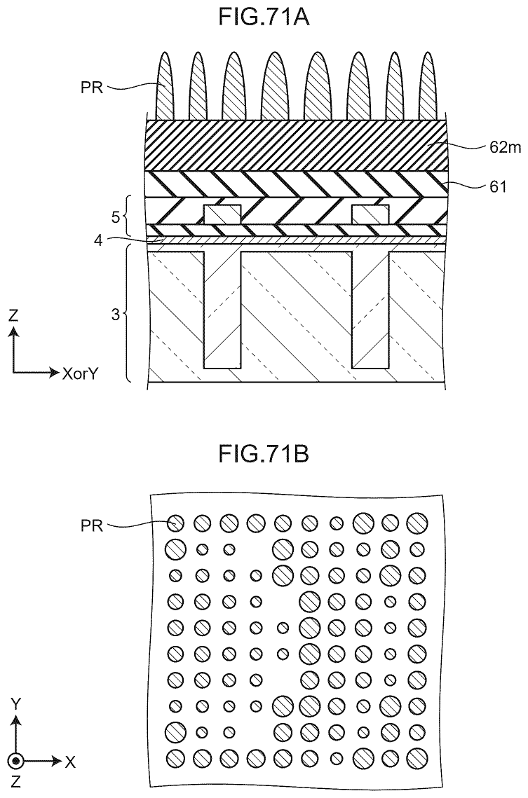

As illustrated in (A) of FIG. 71, the photoresist PR having a pillar shape (bell shapes having different widths in this example and protruding upwards) is formed in the lithography process. Note that (B) of FIG. 71 schematically illustrates a planar layout of the photoresist PR. The shape of the photoresist PR may be formed by thermal reflow after being transferred in a lithography process, or a grayscale lithography technique may be used. It may be formed by nanoimprinting, and the bell shape is advantageous for mold release.

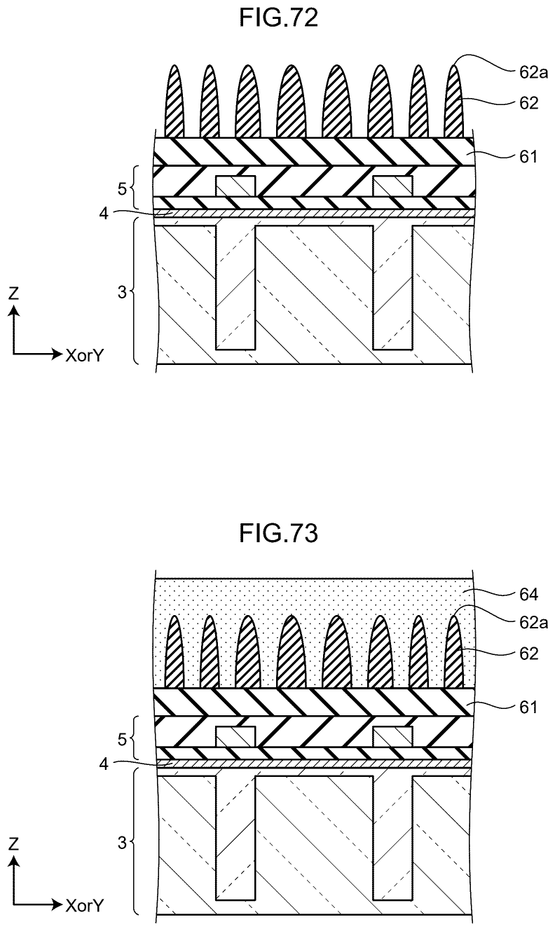

As illustrated in FIG. 72, the pillar material 62m is transferred using the photoresist PR as a mask. The pillar 62 in which the upper surface 62a is a curved surface is obtained. In a case where the selection ratio of the photoresist PR is insufficient, the resist pattern may be transferred once to a hard mask, for example, SiO₂, and processed by a hard mask process of etching through the hard mask. Note that the reflection suppressing film 61 located below the pillar 62 can also function as an etching stopper layer at the time of etching.

Next, Wet chemical cleaning is performed to remove resist residues and processing residues. In normal shaking off drying after chemical cleaning, the risk of pillar collapse increases due to surface tension imbalance during chemical drying. As a countermeasure against this, IPA having a weak surface tension may be replaced with IPA and then dried, or supercritical cleaning may be used.

As illustrated in FIG. 73, the filler 64 is formed between the pillars 62. A transparent material having a large refractive index difference from the pillars 62 is used as the filler 64. The filler 64 may be formed, for example, by spin coating a fluorine-containing siloxane resin. As a result, it is possible to avoid damage of the pillar 62 and failure of the adhesive remaining when the protective tape is peeled off at the time of assembly, and it is possible to avoid a failure mode due to a drop impact in the market.

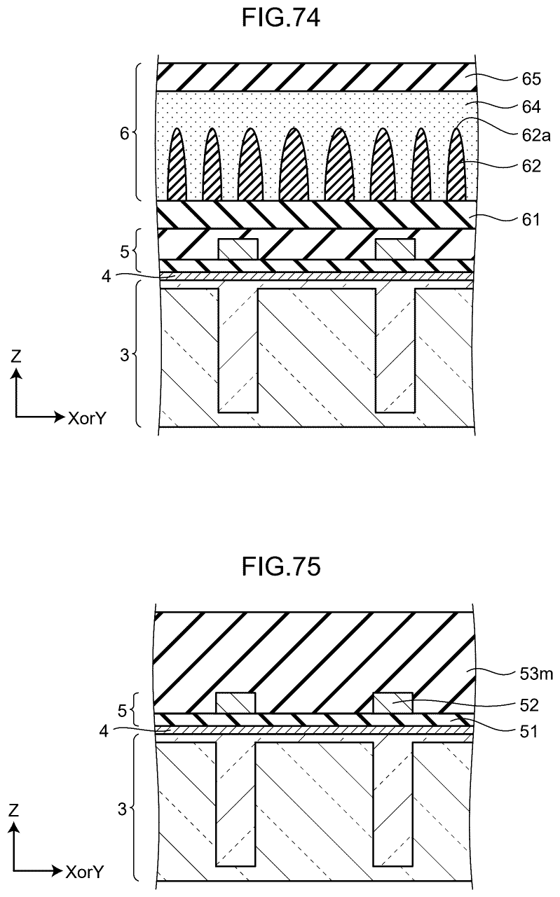

As illustrated in FIG. 74, the protective film 65, for example, SiO₂ may be provided on the uppermost portion of the filler 64. As a result, it is possible to avoid damage to the filler 64 due to resist peeling at the time of PAD processing.

FIGS. 75 to 80 illustrate an example of a manufacturing method in a case where the lower surface 62b of the pillar 62 is a curved surface. As a premise, it is assumed that the processes up to FIG. 69 described above are completed.

As illustrated in FIG. 75, the insulating film material 53m is formed on the light shielding film 52 using, for example, SiO₂ by CVD, sputtering, or the like, and planarized by CMP. The thickness of the residual film after planarizing is set to be equal to or larger than the height of the pillar 62.

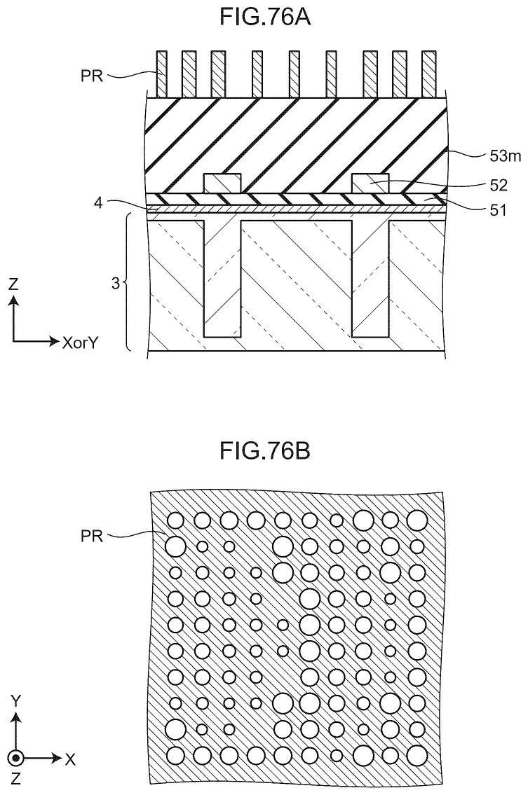

As illustrated in FIG. 76, photoresist PR resists having hole shapes with different widths (for example, diameters) are formed in a lithography process. Note that (B) of FIG. 76 schematically illustrates a planar layout of the photoresist PR.

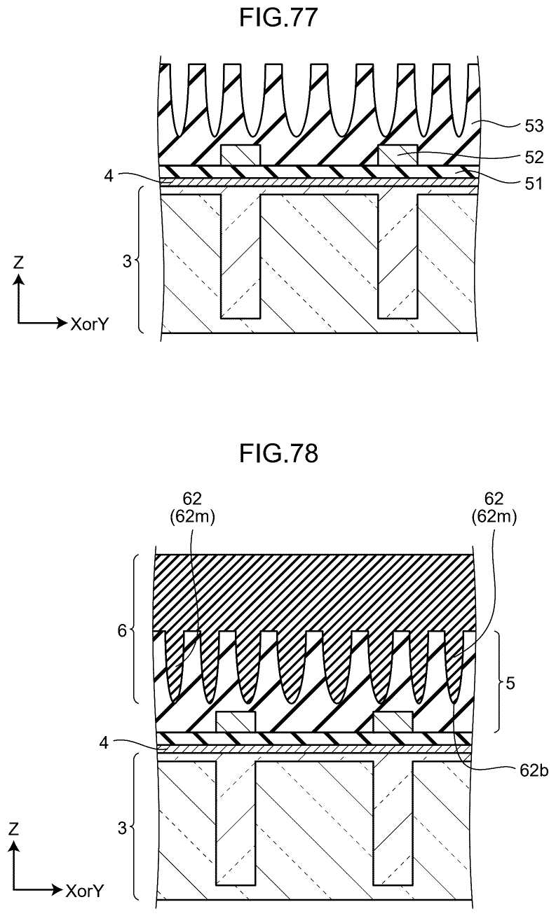

As illustrated in FIG. 77, using the photoresist PR as a mask, the insulating film material 53m is processed by dry etching so as to obtain the insulating film 53 having the void portion corresponding to the pillar shape (a downwardly convex bell shape with different widths in this example). Specifically, processing is performed so as to be tapered under the deposition-rich condition. Alternatively, at the stage of the process of FIG. 76 described above, a similar shape may be formed in the photoresist PR using grayscale lithography, nanoimprint, or the like, and then transfer processing may be performed by dry etching. Then, Wet chemical cleaning is performed to remove resist residues and processing residues.

As illustrated in FIG. 78, a film of the pillar material 62m is formed by CVD, sputtering, or the like, and planarized by CMP. The pillar 62 in which the lower surface 62b is a curved surface is obtained.

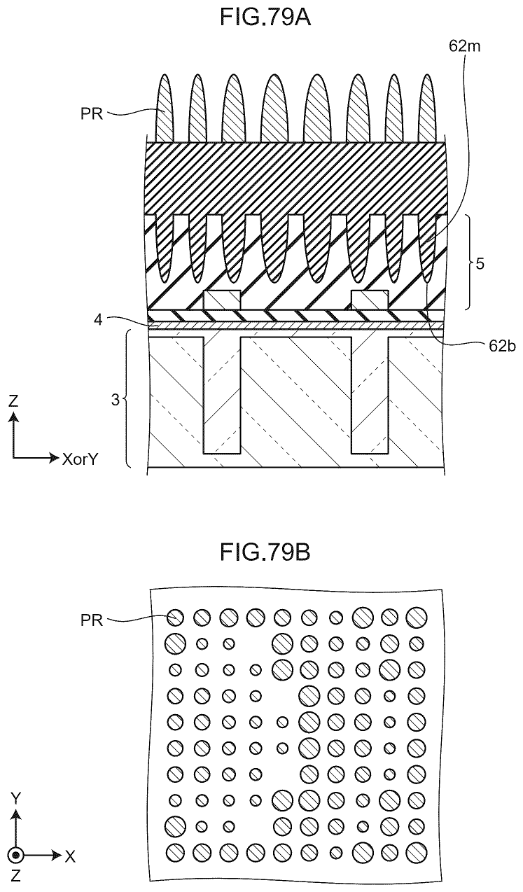

FIGS. 79 to 81 illustrate an example of a manufacturing method in a case where both the upper surface 62a and the lower surface 62b of the pillar 62 are curved surfaces. It is assumed that the processes up to FIG. 78 described above are completed.

As illustrated in FIG. 79, a photoresist PR having a pillar shape (bell shapes having different widths in this example and protruding upwards) is formed in a lithography process. Note that (B) of FIG. 79 schematically illustrates a planar layout of the photoresist PR. The shape of the photoresist PR may be formed by thermal reflow after being transferred in a lithography process, or a grayscale lithography technique may be used. It may be formed by nanoimprinting, and the bell shape is advantageous for mold release.

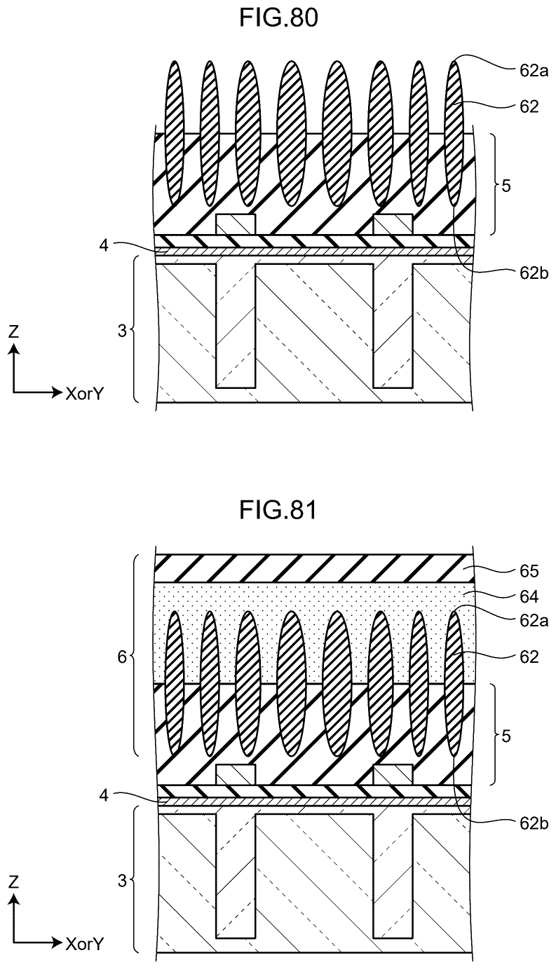

As illustrated in FIG. 80, the pillar material 62m is transferred into a bell shape using the photoresist PR as a mask. Then, Wet chemical cleaning is performed to remove resist residues and processing residues. In the normal shaking off drying after the chemical cleaning, the risk of falling of the pillars 62 increases due to the imbalance of surface tension during the chemical drying. As a countermeasure against this, IPA having a weak surface tension may be replaced with IPA and then dried, or supercritical cleaning may be used. The pillar 62 in which both the upper surface 62a and the lower surface 62b are curved surfaces is obtained.

As illustrated in FIG. 81, the filler 64 is formed between the pillars 62. The filler 64 is transparent, and a material having a large refractive index difference from the pillars 62 is used. The filler 64 may be formed, for example, by spin coating a fluorine-containing siloxane resin. As a result, it is possible to avoid damage of the pillar 62 and failure of the adhesive remaining when the protective tape is peeled off at the time of assembly, and it is possible to avoid a failure mode due to a drop impact in the market. The protective film 65, for example, SiO₂ may be provided on the uppermost portion of the filler 64. As a result, it is possible to avoid damage to the filler 64 due to resist peeling at the time of PAD processing.

### <Example of Multilayering of Optical Layer 6>

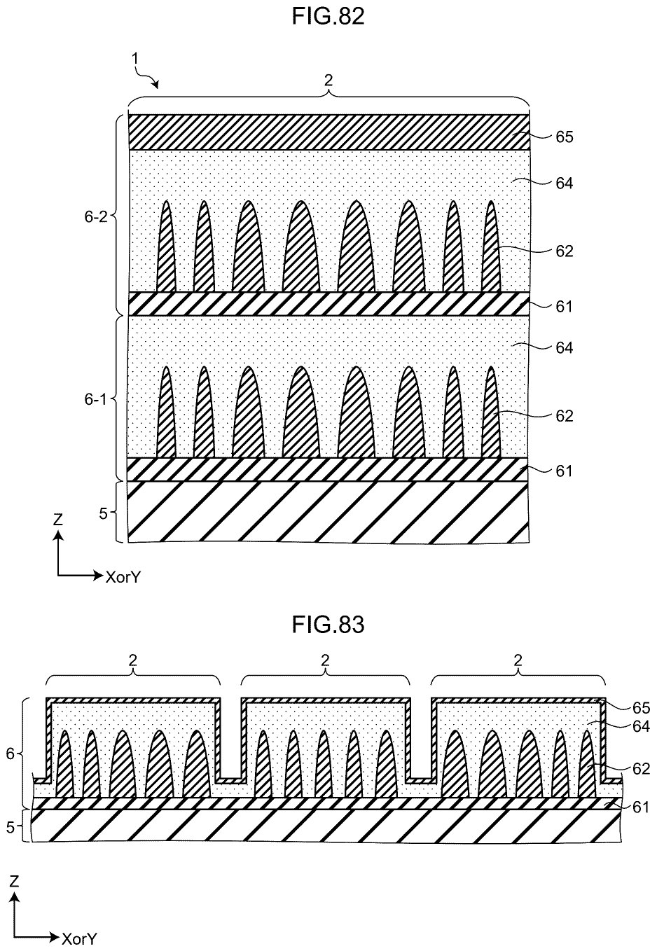

FIG. 82 is a diagram illustrating an example of multilayering of the optical layer 6. The pixel array section 1 includes a plurality of laminated optical layers 6, in this example, two optical layers 6. The first optical layer 6 is referred to as an optical layer 6-1 in the drawing. The second optical layer 6 is referred to as an optical layer 6-2 in the drawing. The optical layer 6-1 and the optical layer 6-2 are provided in this order on the insulating layer 5. The optical layer 6-1 includes the reflection suppressing film 61, the plurality of pillars 62, and the filler 64. The optical layer 6-2 includes the reflection suppressing film 61, the plurality of pillars 62, the filler 64, and the protective film 65.

By adopting the multilayer structure (multistage configuration) using the plurality of optical layers 6, the height of the pillars 62 can be made lower than in the case of the single-layer structure (one-stage configuration) using only one optical layer 6. For example, it is effective in a case where it is difficult to increase the height of the pillars 62 due to pillar collapse in the Wet cleaning. In addition, in the case of the single-layer structure, the pillars 62 are designed on the premise of a single wavelength, but by changing and combining the designs of the pillars 62 of each layer by forming the multilayer structure, it is possible to broaden the wavelength, achieve multispectral capabilities, and the like. It is also possible to realize polarization control.

### <Example of Shape of Filler 64>

FIG. 83 is a diagram illustrating an example of the filler 64 and a peripheral structure thereof. In this example, the filler 64 has a box shape for each pixel 2. A gap (for example, an air region) is provided between the fillers 64 covering the pillars 62 of each pixel 2, and the portion has a refractive index different from that of the filler 64. A lens function using a refractive index difference is obtained. For example, light near the boundary between the adjacent pixels 2 can be guided to the corresponding pixel 2. Effects such as suppression of color mixing and improvement in sensitivity of photodetection can be expected. Describing an example of the manufacturing method, after the pillars 62 and the filler 64 are formed, the resist mask is processed by anisotropic etching, and after cleaning, the protective film 65 is formed.

### <Example of Design of Optical Function>

As described above, the plurality of pillars 62 give a lens function to the optical layer 6 and gives a prism function to the optical layer 6. An example of designing such an optical function will be described.

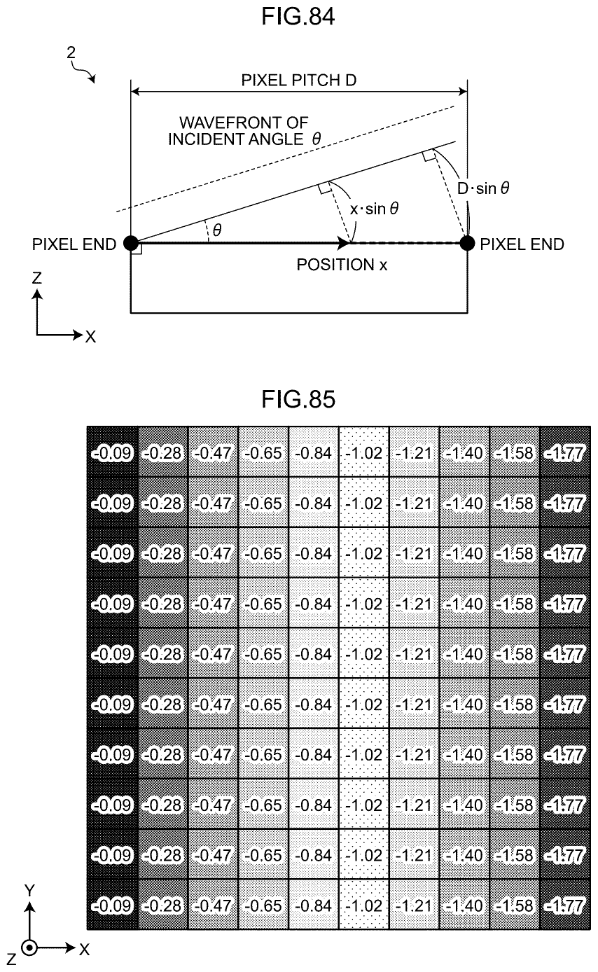

FIGS. 84 to 92 are diagrams illustrating examples of optical function design. FIGS. 84 to 87 illustrate examples of the design of optical functions, including prism functions. step1, step2, and step3 will be separately described.

<step1>

A phase difference map for each pixel 2 is derived. As illustrated in FIG. 84, the wavelength of light incident on a certain pixel 2 is λ, the incident angle is θ, the pixel pitch is D, and the position of the pillar 62 in the pixel 2 is x. In this case, the phase difference necessary for normal incidence is obtained as in the following Formula (1).

$${Δφ}_{pri} ( x ) = \frac{x \cdot sin θ - D \cdot sin θ}{λ} \qquad ( 1 )$$

By obtaining the phase difference for each pixel 2, for example, a phase difference map as illustrated in FIG. 85 is obtained. In the illustrated phase difference map, a value obtained by normalizing the phase difference of each of the 10×10 pillars 62 with 2× is described (mapped) in association with the position of the pillar 62.

Although only the prism angle in the X-axis direction has been described here for easy understanding, it is possible to create a phase difference map corresponding to a prism angle of an arbitrary orientation by extending the prism angle in two dimensions. Note that, in the design of the prism function, since it is sufficient to obtain a relative phase difference between the pillars 62, indefiniteness of a constant is allowed.

<step2>

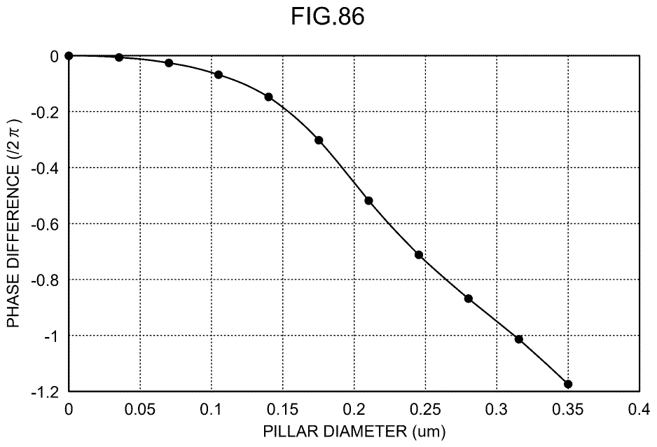

A phase difference library is derived. In consideration of the pitch, height, refractive index, extinction coefficient, shape, film configuration in the vicinity of the pillars 62, and the like of the pillars 62, for example, a phase difference library as illustrated in FIG. 86 is created. The exemplified phase difference library is described in association with the pillar diameter and the phase difference.

The value indicated in the phase difference library may be calculated by optical simulation such as FDTD or RCWA, or may be experimentally obtained. Note that, when the phase difference is α, the light of the phase difference α is equivalent to α+2π×N (N is an integer). That is, even in a case where a phase difference of 2π+Φ is required, only a phase difference of Φ may be given. Such replacement with an equivalent phase is also referred to as “2π folding”.

<step3>

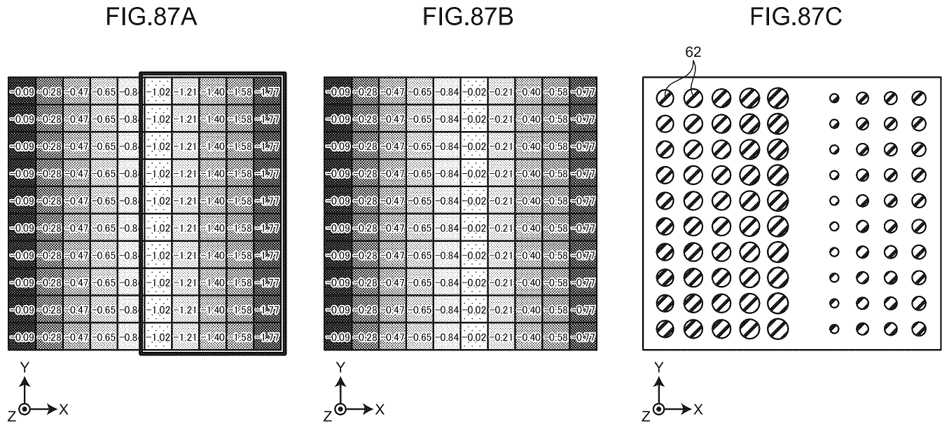

A layout of the pillars 62 is derived. By referring to the phase difference library, the phase difference indicated in the phase difference map is replaced with the diameter of the pillar 62. Since there are restrictions on process limits due to various factors such as resolving power of lithography and pillar collapse of pillars 62 having a high aspect ratio, these are defined as design rules and designed so as to satisfy the design rules. Specifically, adjustment of a constant term (uniform offset processing), 2π folding, and the like are performed on the phase difference. For example, the value of the region indicated by the thick line in (A) of FIG. 87 is folded back by2π to obtain the phase difference map illustrated in (B) of FIG. 87. By replacing the phase difference indicated in the phase difference map with the pillar diameter with reference to the phase difference library, the layout of the pillars 62 as illustrated in (C) of FIG. 87 is obtained.

Note that, in a case where the design rule is not satisfied only by the above-described 2π folding process or the like, a forced folding (measure 1), a forced rounding process (measure 2), or the like other than 2π may be performed. The measure 2 is a process of approximating and rounding the pattern outside the design rule to the pillar diameter of the closest phase in the design rule. Note that, in the measure 1, there is a possibility that scattering occurs at the folded portion and stray light occurs.

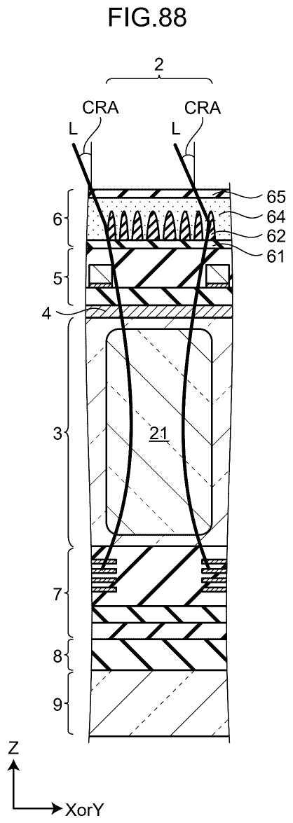

FIGS. 88 to 92 illustrate examples of the design of optical functions including both prism and lens functions.

In FIG. 88, light control is schematically illustrated. The principal ray of the light to be detected is referred to as a principal ray L in the drawing. The incident angle of the principal ray L on the optical layer 6 is referred to as a principal ray incident angle CRA in the drawing. The optical layer 6 including the plurality of pillars 62 brings the direction of the principal ray L close to the vertical direction (Z-axis negative direction) and condenses the principal ray L on the photoelectric conversion section 21.

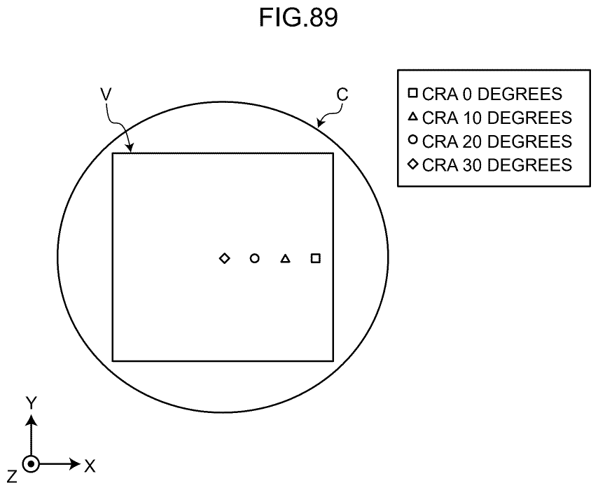

FIG. 89 schematically illustrates the relationship between the angle of view V in the planar layout and the image circle C of the module lens that can be included in the photodetector 100. The center of the angle of view V and the center of the image circle C are located at the same position. The principal ray incident angle CRA increases from the end portion of the angle of view V toward the central portion.

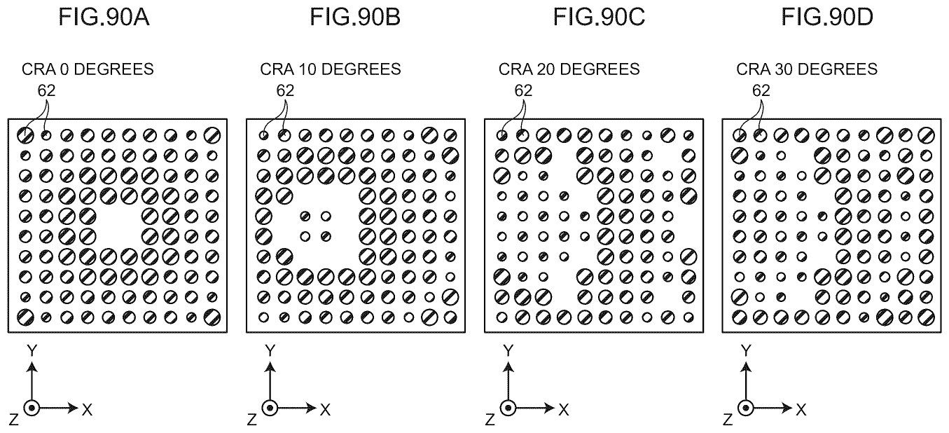

For each pixel 2, the pillar 62 is designed so as to obtain both a prism function of providing polarization (prism angle) according to the principal ray incident angle CRA and a lens function of condensing light at the center of the pixel 2. To conclude, for example, a layout of the pillars 62 as illustrated in FIG. 90 is obtained. (A), (B), (C), and (D) of FIG. 90 illustrate the layout of the pillars 62 in a case where the principal ray incident angle CRA is 0 degrees, 10 degrees, 20 degrees, and 30 degrees. Different layouts of the pillars 62 according to different principal ray incident angles CRA are obtained.

In the specific design, a phase difference map and a phase difference library are used as described above. The phase difference map that provides both the prism function and the lens function is obtained by combining the phase difference map (prism phase difference map) that provides the prism function and the phase difference map (lens phase difference map) that provides the lens function.

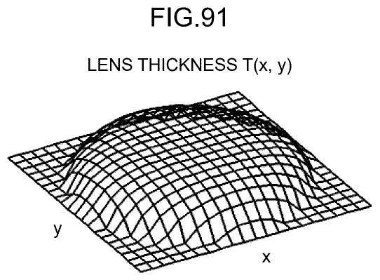

If the assumed lens shape and refractive index are known, the phase difference map that provides the lens function can be calculated from the lens thickness corresponding to the position of each pillar 62 and the wavelength λ of the light to be detected. Specifically, as illustrated in FIG. 91, a function of the lens thickness T (x, y) is given with respect to the position (x, y) of the pillar 62. Assuming that the refractive index of the lens is n1 and the refractive index of the upper region (for example, the air region) of the lens is n2, the necessary phase difference is obtained as in the following Formula (2).

$${Δφ}_{lens} ( x , y ) = \frac{T ( x , y )}{( {n}_{1} - {n}_{2} ) λ} \qquad ( 2 )$$

By obtaining the phase difference for each pixel 2, a lens phase difference map is obtained. Note that this map may be calculated using optical simulation such as FDTD or RCWA, or may be experimentally obtained.

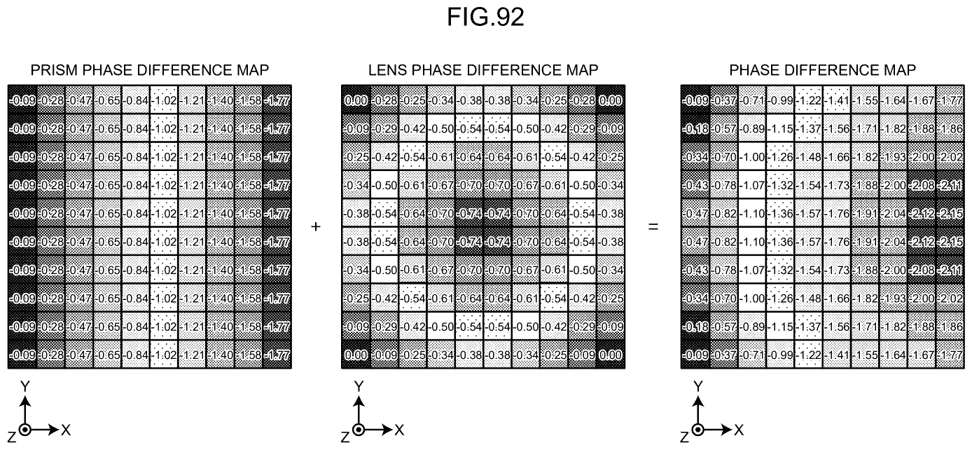

By combining the prism phase difference map and the lens phase difference map, a phase difference map that provides both a prism function and a lens function can be obtained. For example, as illustrated in FIG. 92, by simply adding phase differences of the corresponding pillars 62 of the prism phase difference map and the lens phase difference map, a phase difference map that provides both functions of the prism function and the lens function is obtained. The layout of the pillars 62 is obtained by replacing the phase difference indicated in the obtained phase difference map with the pillar diameter with reference to the phase difference library.

Note that it is naturally possible to design only the lens function using only the lens phase difference map.

More generally, if it is possible to give a geometric shape when an optical element having a certain function to each pixel 2 is to be mounted, the shape can be reworked into a phase difference map. By using the phase difference library, the function can be realized by converting the phase difference into an element in the pillar 62. Furthermore, a plurality of phase difference maps designed as described above can be combined to simultaneously realize a plurality of functions.

### <Example of Designing Height of Pillar 62>

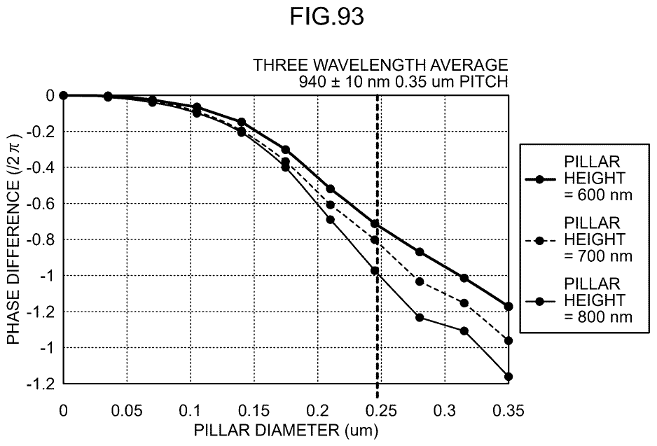

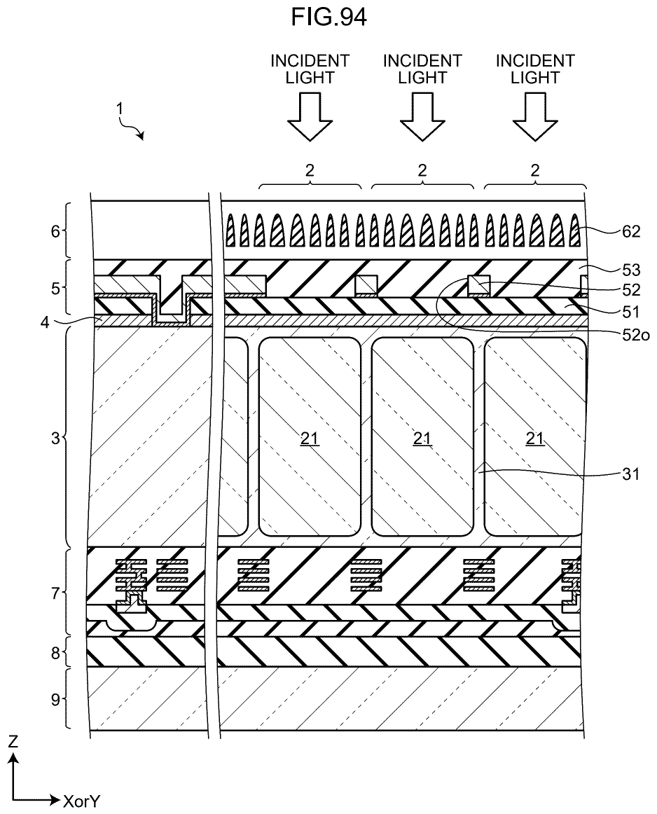

The height of the pillar 62 is desirably set to a height capable of turning the phase by2π or more within a range of the pillar diameter that can be processed by the process with respect to the phase difference library defined by the wavelength of the light to be detected, the refractive index of the pillar 62/peripheral material, the shape and height of the pillar 62, and the like. An example will be described with reference to FIG. 93.

FIG. 93 is a diagram illustrating an example of a phase difference library. A phase difference library in a case where the material of the pillars 62 is amorphous silicon and the pillar pitch is 350 nm is exemplified. The relationship between the pillar diameter and the phase difference in a case where the height (pillar height) of the pillar 62 is 600 nm, 700 nm, and 800 nm is described. For example, in a case where the process processing limit is a pillar diameter of 250 nm (0.25 μm), the height of the pillar 62 may be set to 800 nm.

### <Example of Folded Portion of Phase>

Due to the phase folding back, scattering may occur and stray light may be generated. Furthermore, if the area ratio is different for each pixel 2, the reflection component (sensitivity loss) changes. In order to cope with this, for example, the phase may be folded back on a pixel basis. The reflectance variation can be suppressed. Furthermore, in a case where the phase is folded back in the pixel, the phase may be folded back at the pixel center. Crosstalk can be suppressed.

### <Example of Thickness of Reflection Suppressing Film 61>

As described above, the reflection suppressing film 61 in a case where the lower surface 62b of the pillar 62 is a flat surface may have a thickness at which the phases of the reflected waves cancel each other out, that is, a thickness of λ/4n (n is the refractive index of the medium) or an integral multiple thereof. For example, in a case where the wavelength λ is 940 nm, the material of the reflection suppressing film 61 is SiN, and the refractive index thereof is about 1.9, the thickness of the reflection suppressing film 61 may be about 125 nm. However, the interference effect and oblique incidence characteristics of the multilayer film may be further considered, and may be further optimized on the basis of optical simulation, actual measurement, or the like. Note that the reflection suppressing film 61 may be etched so as to remain only below the pillars 62.

### <Example of Material of Filler 64>

The material of the filler 64 may be an organic material or an inorganic material.

Examples of the organic material include a siloxane resin, a styrene resin, an acrylic resin, and a styrene-acrylic copolymer resin. The material may be an F-containing material of any resin, or a material that internally fills any resin with beads having a refractive index lower than that of the resin. For example, after the pillar 62 is processed, it is rotationally applied.

Examples of the inorganic material include silicon oxide, niobium oxide, tantalum oxide, aluminum oxide, hafnium oxide, silicon nitride, silicon nitride oxide, silicon carbide, silicon carbide oxide, silicon carbide nitride, and zirconium oxide. The reflection suppressing film 61 may have a laminated structure in which some of these inorganic materials are laminated. For example, an inorganic material is deposited first, the shape of the pillar 62 is processed in a resist mask, and then the pillar 62 is embedded. The protective film 65 is formed after the CP treatment.

<Example of Configuration of Light Shielding Film 52>

The light shielding film 52 included in the insulating layer 5 will be described with reference to FIGS. 94 to 98.

FIGS. 94 to 98 are diagrams illustrating examples of the light shielding film 52. As illustrated in FIG. 94, the light shielding film 52 of the insulating layer 5 is provided between the photoelectric conversion section 21 and the optical layer 6. The light shielding film 52 has an opening 520 facing at least a part of the photoelectric conversion section 21. For example, when viewed in the Z-axis direction, the opening 520 overlaps the photoelectric conversion section 21. The light that has passed through the optical layer 6 reaches the photoelectric conversion section 21 via the opening 520 of the light shielding film 52.

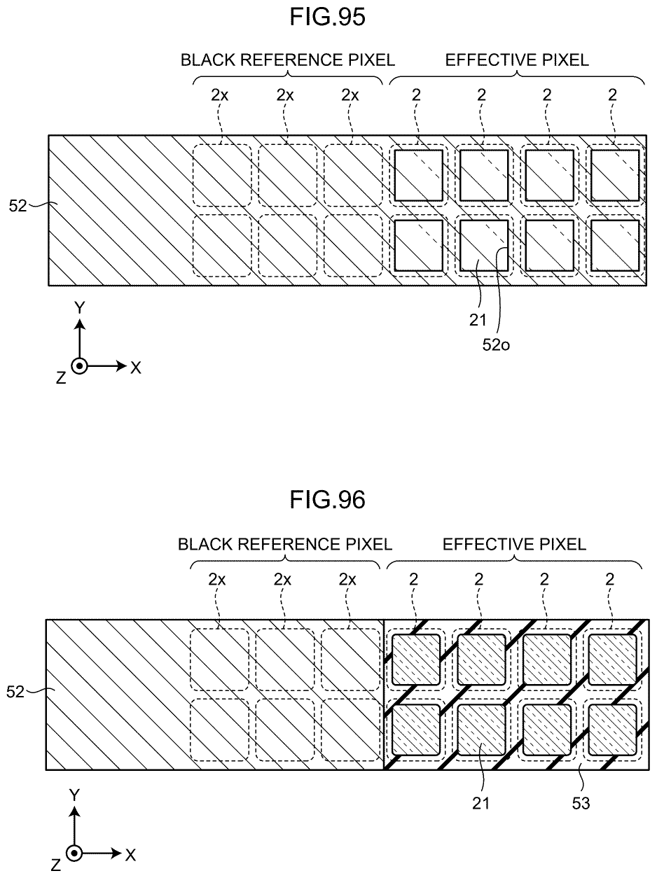

FIGS. 95 to 98 illustrate some examples of the planar layout of the light shielding film 52. The black reference pixel is referred to as a pixel2π in the drawing. An effective pixel is referred to as a pixel 2 in the drawing in a manner similar to that described above.

In the example illustrated in FIG. 95, the light shielding film 52 is provided between the pixels in both the pixel 2 and the pixel 2x. It is possible to suppress crosstalk due to inter-pixel light shielding. In addition, the black reference pixel is also shielded from light.

In the example illustrated in FIG. 96, the light shielding film 52 is not provided between the pixels 2. By eliminating the inter-pixel light shielding, the detection sensitivity of the photodetector 100 can be improved. The stray light at the pixel boundary is suppressed by the optical layer 6 including the plurality of pillars 62 described above.

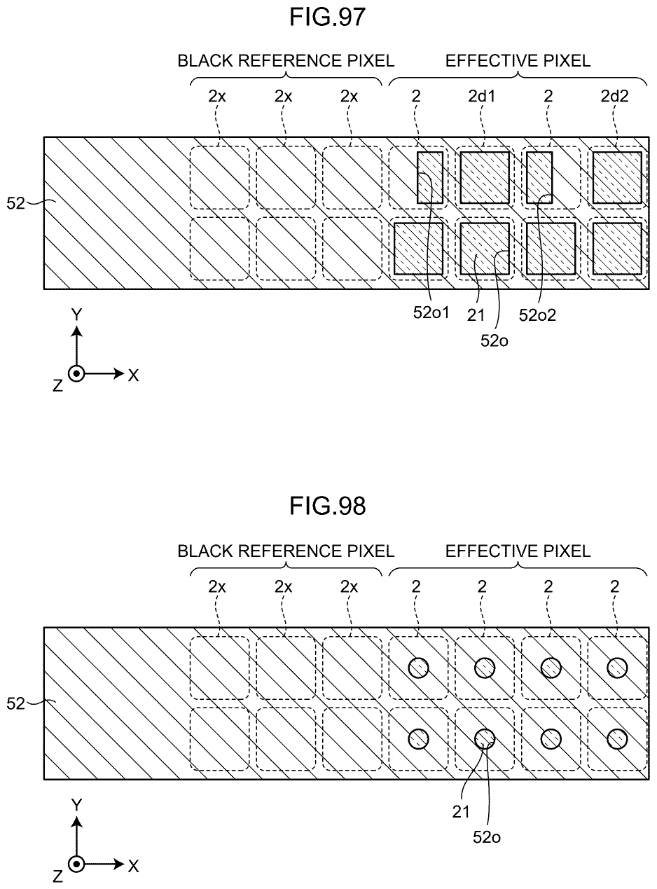

In the example illustrated in FIG. 97, the light shielding film 52 is provided such that the plurality of pixels 2 include image plane phase difference pixels. In this example, the image plane phase difference pixel includes two types of image plane phase difference pixels. The first image plane phase difference pixel is referred to as an image plane phase difference pixel 2d1 in the drawing. The second image plane phase difference pixel is referred to as an image plane phase difference pixel 2d2 in the drawing.

Among the openings 520 of the light shielding film 52, the opening 520 facing the photoelectric conversion section 21 of the image plane phase difference pixel 2d1 is referred to as an opening 5201 (first opening) in the drawing. The opening 520 of the image plane phase difference pixel 2d2 facing the photoelectric conversion section 21 is referred to as an opening 5202 (second opening) in the drawing. The opening 5201 and the opening 5202 face different portions of the photoelectric conversion section 21 of the image plane phase difference pixel 2d1 and the photoelectric conversion section 21 of the image plane phase difference pixel 2d2. It can be said that the centroids of the opening 5201 and the opening 5202 in the light shielding film 52 are different in the respective pixels 2.

By forming the pixels 2 having different parallaxes with the light shielding film 52, the image plane phase difference pixel 2d1 and the image plane phase difference pixel 2d2 are obtained. The subject distance is calculated from the shift amount of the images obtained in each case, and high-speed focusing processing and distance measurement (sensing) of the camera lens can be performed. In the case of the interchangeable camera, since the incident angle at the field angle end changes for each lens, it is necessary to provide the image plane phase difference pixel in accordance with each angle. In the on-chip lens (OCL) of the related art, pupil correction cannot be changed for each pixel 2, and there is a problem that the pixel 2 in which the opening size of the opening 520 of the light shielding film 52 is narrowed occurs and sensitivity is lowered. When the optical layer 6 including the plurality of pillars 62 is used, light can be condensed at the pixel center for any incident angle, so that it is possible to prevent generation of the pixel 2 having a narrow opening size.

In the example illustrated in FIG. 98, the opening 520 of the light shielding film 52 is a pinhole. The light to be detected may include near-infrared light. Examples of the material of the pillar 62 are amorphous silicon, polycrystalline silicon, germanium, and the like as described above. In one embodiment, the aperture ratio of the pinholes may be 25% or less. Note that not all of the plurality of 2 but only the openings 520 facing some of the pixels 2 may be pinholes.

Effects such as improvement of detection sensitivity by optical confinement, suppression of chip reflection, and suppression of flare sensitivity can be obtained. A high-bending material is required to narrow the near-infrared light, but strong light reflection may occur when an interface on a plane having a large refractive index difference is present. By using the pillar 62 having a shape in which the upper surface 62a described so far is a curved surface, the effective refractive index decreases, and light reflection can be suppressed.

By matching the light condensing point with the pinhole, the detection sensitivity is improved. Meanwhile, it is also possible to generate a low-sensitivity pixel and a high-sensitivity pixel and to realize a high dynamic range (HDR) by defocusing by changing the design of the pillar 62 for each pixel 2. HDR can be realized even if the pinhole size is changed for each pixel 2.

### <Example of Element Separating Portion>

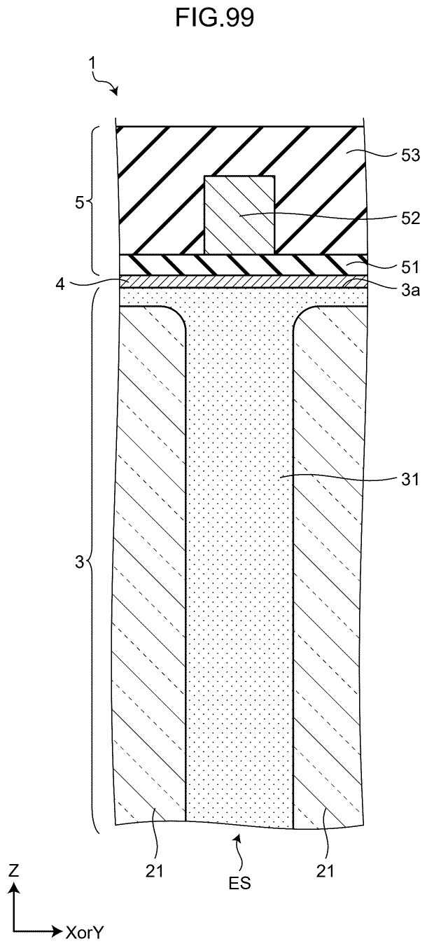

The light control by the pillars 62 can also be said to be phase/wavefront control of light by a microstructure, but there remains a possibility that microscopic stray light is generated at a discontinuous material interface. Element separation may be enhanced so that the stray light does not cause crosstalk between pixels. This will be described with reference to FIGS. 99 to 104.

FIGS. 99 to 104 are diagrams illustrating examples of the element separating portion ES. A part of the region between the pixels 2 is illustrated. The pixel array section 1 includes the element separating portion ES. The element separating portion ES optically separates or electrically separates the adjacent pixels 2, more specifically, the adjacent photoelectric conversion sections 21. The element separating portion ES is provided so as to extend at least from the upper surface 3a of the semiconductor substrate 3 between the adjacent photoelectric conversion sections 21 in the semiconductor substrate 3. The element separating portion ES is realized by including, for example, the separation region 31, the fixed charge film 4, the insulating film 51, the light shielding film 52, and the like.

In the example illustrated in FIG. 99, the light shielding film 52 is provided immediately above the semiconductor substrate 3 via only the fixed charge film 4 and the insulating film 51. On the semiconductor substrate 3 side, charge crosstalk is reduced by a potential due to ion implantation (implantation). Although the problem of suppressing crosstalk of stray light entering the semiconductor substrate 3 may remain, processing damage to the semiconductor substrate 3 is low, which is advantageous in dark time characteristics.

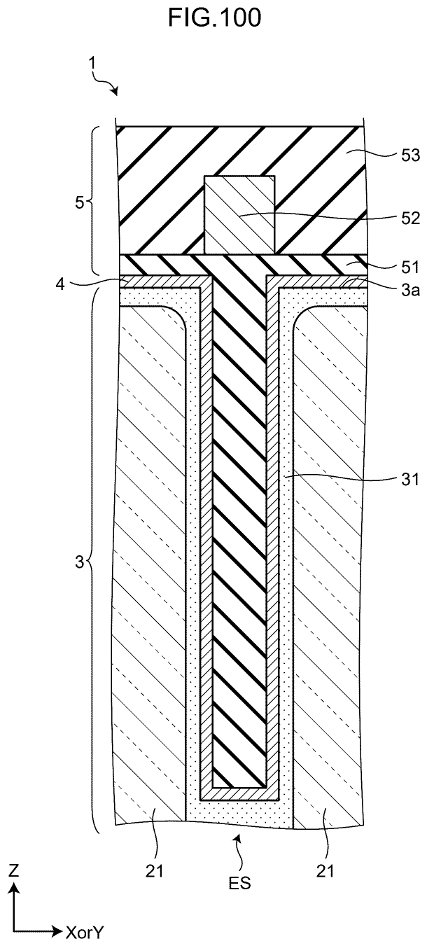

In the example illustrated in FIG. 100, the semiconductor substrate 3 is deeply trench processed or penetrated. Pinning of the side wall is enhanced by the fixed charge film 4, and the insulating film 51 is embedded. The charge crosstalk is enhanced as compared with the configuration of FIG. 99 described above, and a part of the stray light can be returned to the photoelectric conversion section 21 of the self-pixel due to the refractive index difference between the semiconductor substrate 3 and the insulating film 51. There is a possibility that the number of steps increases and the dark time characteristics deteriorate due to interface damage by trench processing.

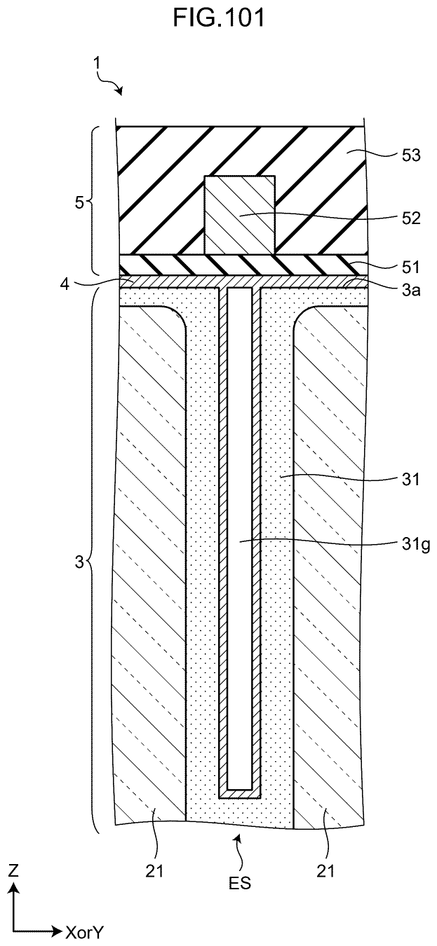

In the example illustrated in FIG. 101, the semiconductor substrate 3 is subjected to trench processing with a fine width (for example, 100 nm or less). By closing the upper end portion of the trench when the fixed charge film 4 is formed on the side wall, a void 31g is formed. The refractive index difference is larger than that of the insulating film 51 in FIG. 100 described above, and interface reflection easily occurs, so that the effect of confining stray light in the self-pixel can be enhanced. The problem of large variations in occlusiveness may remain.

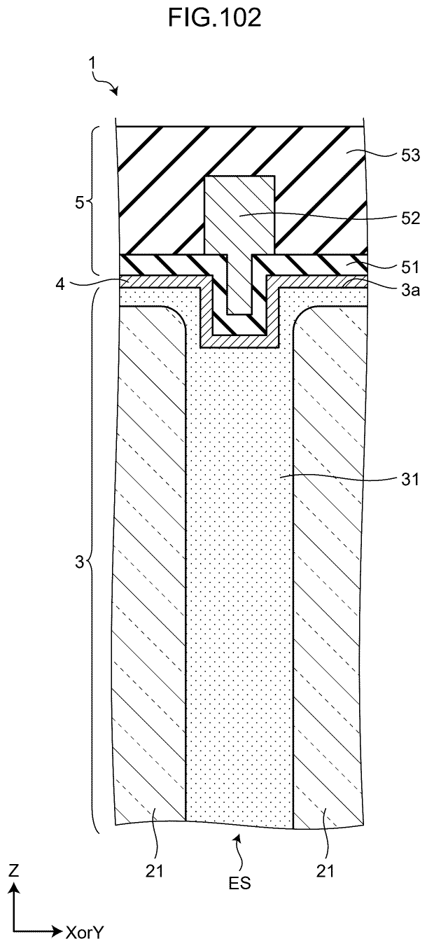

In the example illustrated in FIG. 102, the semiconductor substrate 3 is shallowly trench processed (for example, about 100 nm to 400 nm). After the fixed charge film 4 and the insulating film 51 are provided, a part of the light shielding film 52 extends in the semiconductor substrate 3. As compared with the configuration of FIG. 99 described above, it is possible to block the crosstalk path between the inter-pixel light shielding and the semiconductor substrate 3. There is a possibility of deterioration in dark time characteristics due to damage due to processing or contamination.

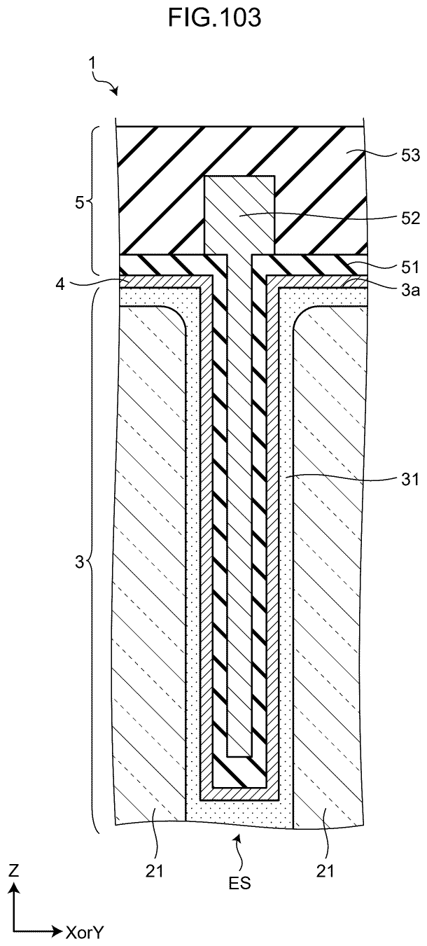

In the example illustrated in FIG. 103, the semiconductor substrate 3 is deeply trench processed or penetrated. Pinning of the side wall is enhanced by the fixed charge film 4, and the insulating film 51 is embedded. The light shielding film 52 is embedded in the gap of the insulating film 51. Since stray light is absorbed by the light shielding film 52 as compared with the configuration of FIG. 100 described above, crosstalk is suppressed. There is a possibility that the self-pixel return component of stray light is reduced, the sensitivity is slightly lowered, and the dark time characteristics are deteriorated due to processing damage or contamination.

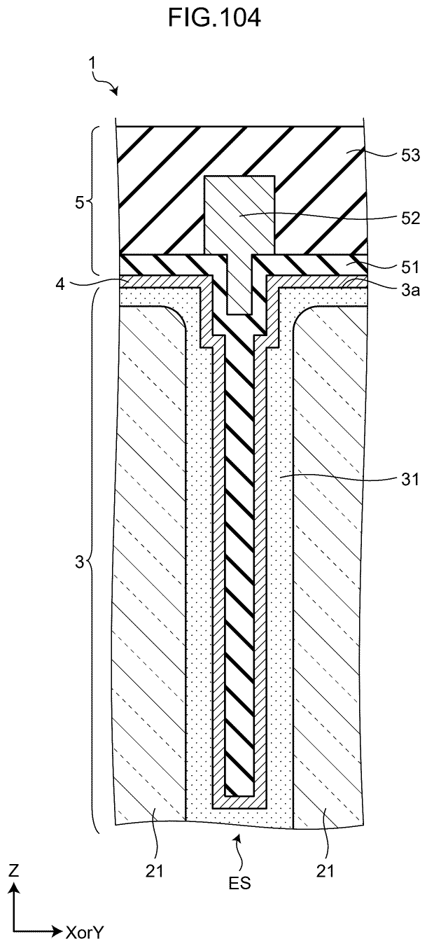

In the example illustrated in FIG. 104, pinning of the side wall is enhanced by the fixed charge film 4 with respect to a deep trench having a narrow line width and a trench formed to have a shallower line width than the deep trench, and the insulating film 51 is embedded. The light shielding film 52 is embedded only in the shallow trench. As compared with the configuration of FIG. 99 described above, after the crosstalk path between the light shielding film 52 and the semiconductor substrate 3 is blocked, the suppression of the charge crosstalk in the semiconductor substrate 3 at a deep position is enhanced, and the effect of confining the stray light in the self-pixel can be exhibited even at a deep position. It is also possible to reduce sensitivity reduction that may occur in the above-described configuration of FIG. 103. There is a possibility of an increase in the number of steps and deterioration of dark time characteristics due to processing damage and contamination.

### <Example of Shape of Upper Surface 3a of Semiconductor Substrate 3>

Since the element separation is enhanced as described above, other stray light is also suppressed. As described below, by further devising (processing or the like) the shape of the upper surface 3a corresponding to the boundary on the light receiving surface side of the semiconductor substrate 3, it is possible to enjoy a synergistic effect in which incident light is obliquely directed, thereby improving detection sensitivity.

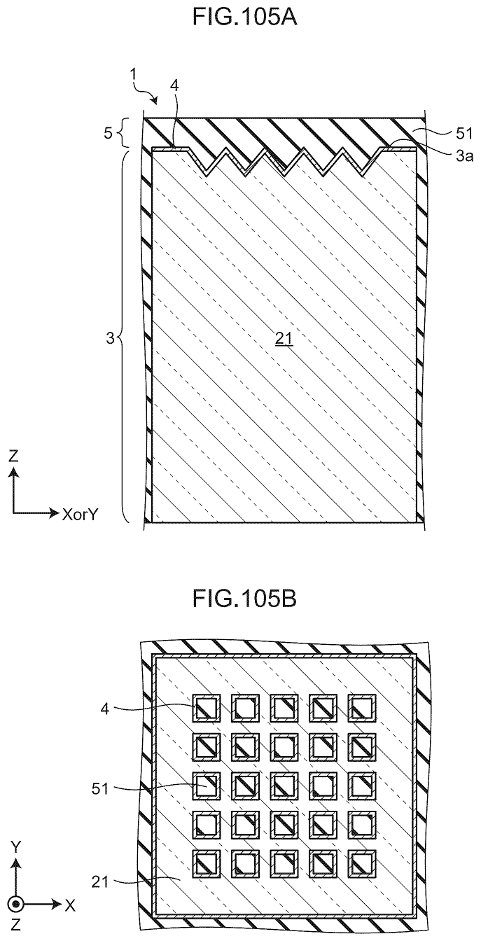

FIGS. 105 to 108 are diagrams illustrating examples of the shape of the upper surface 3a of the semiconductor substrate 3. (B) of each drawing illustrates a configuration when a characteristic portion of the upper surface 3a of the semiconductor substrate 3 is viewed in plan view (viewed in the Z-axis negative direction). The upper surface 3a of the semiconductor substrate 3 has an uneven shape.

In the example illustrated in FIG. 105, the upper surface 3a of the semiconductor substrate 3 has a periodic uneven shape (also referred to as a moth-eye structure), thereby providing a diffraction/scattering structure. Since the uneven shape functions as a diffraction grating, high-order components of incident light are diffracted in an oblique direction, whereby an optical path length in the photoelectric conversion section 21 can be increased, and in particular, detection sensitivity of near-infrared light can be improved.

As this diffraction/scattering structure, for example, a quadrangular pyramid formed by using wet etching of a Si (111) surface using AKB can be applied. Alternatively, the diffraction/scattering structure may be formed by dry etching. Furthermore, by adopting a shape in which the cross-sectional area changes in the depth direction, reflection is suppressed, and sensitivity is slightly improved.

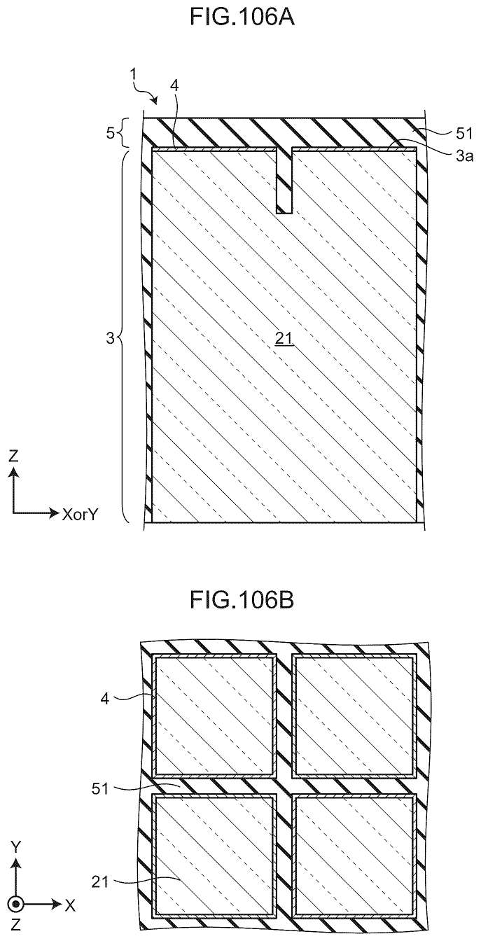

In the example illustrated in FIG. 106, the upper surface 3a of the semiconductor substrate 3 has a recess extending in the X-axis direction and a recess extending in the Y-axis direction at the center of the photoelectric conversion section 21, thereby providing an optical branch portion (optical branch structure). By branching light with a shallow groove embedded in an oxide film and making an angle, zero-order light is reduced, and an effect of improving detection sensitivity can be expected. The optical branch portion is formed by forming a trench in the top portion of the photoelectric conversion section 21 and embedding the fixed charge film 4 and the insulating film 51, for example, SiO₂ with ALD or the like. The optical branch portion can be provided to cross at an angle of 90 degrees when viewed from the incident light side. At this time, the crossing angle is not limited to 90 degrees.

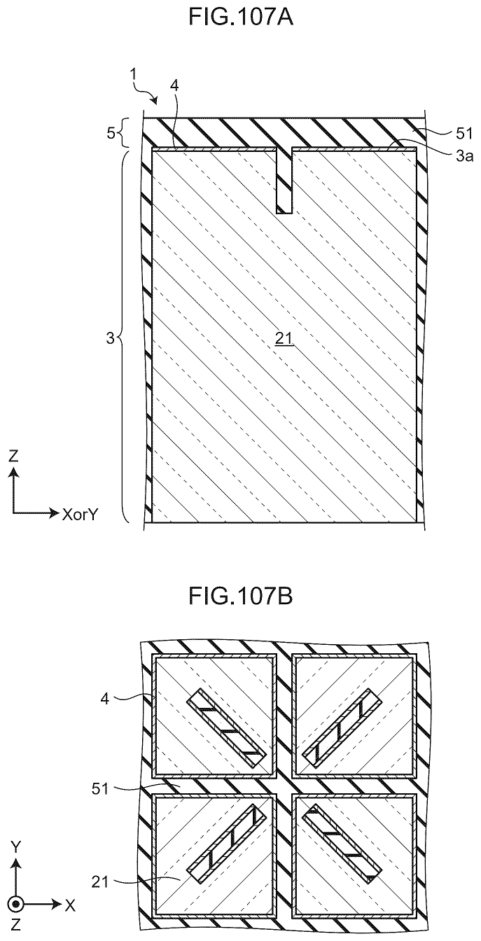

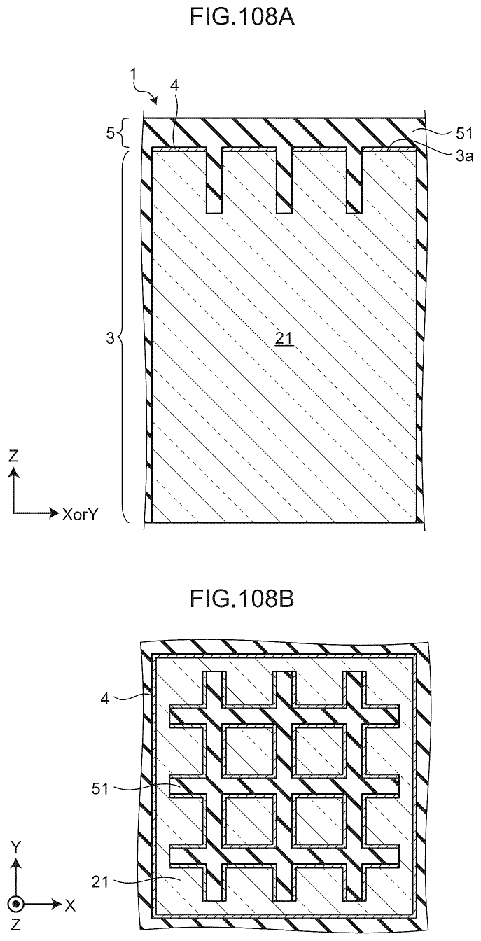

In the example illustrated in FIG. 107, the upper surface 3a of the semiconductor substrate 3 further has four recesses extending in a direction (oblique direction) between the X-axis direction and the Y-axis direction in addition to the configuration of FIG. 106 described above. In the example illustrated in FIG. 108, the upper surface 3a of the semiconductor substrate 3 has a plurality of recessed portions extending in a mesh shape in the X-axis direction and the Y-axis direction. Another optical branch portion is provided for the crossed optical branch portion. The embedding of the fixed charge film 4 and the insulating film 51 into the trench groove of the optical branch portion may be performed simultaneously with the embedding of the element separating portion described above. The number of steps can be reduced.

### <Combination With Lens>

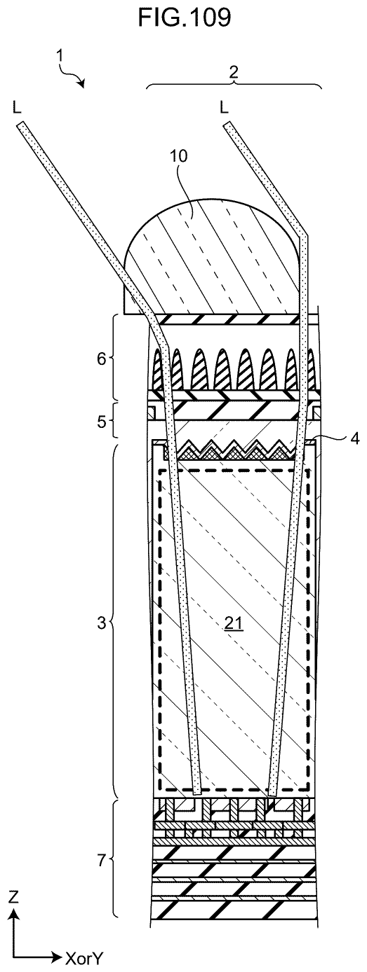

The optical function of the optical layer 6 including the plurality of pillars 62 can include a prism function and a lens function, but a phase difference is required. In a case where folding of the phase difference is required due to the restriction of the height of the pillar 62, a problem of stray light due to scattering of the folded portion may remain. In order to cope with this, a lens may further be provided. The lens is referred to as a lens 10, and will be described with reference to FIGS. 109 to 113.

FIGS. 109 to 113 are diagrams illustrating examples of the lens 10. The pixel array section 1 further includes the lens 10.

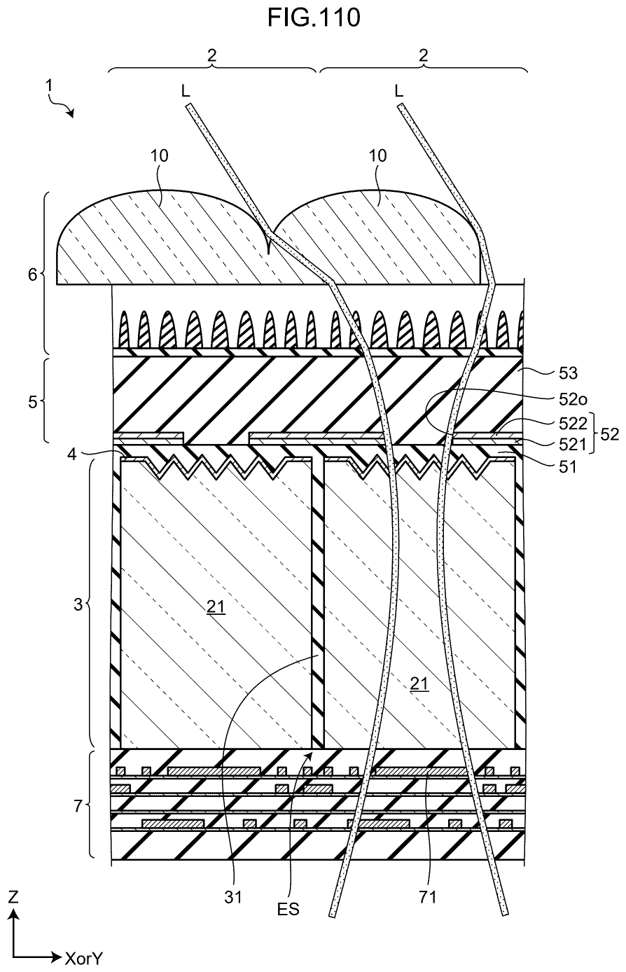

In the example illustrated in FIGS. 109 and 110, the lens 10 is provided on the side opposite to the photoelectric conversion section 21 with the optical layer 6 interposed therebetween. More specifically, the lens 10 is an on-chip lens provided on the optical layer 6. Examples of the material of the lens 10 include organic materials such as a styrene resin, an acrylic resin, a styrene-acrylic resin, and a siloxane resin. Titanium oxide particles may be dispersed in these organic materials or a polyimide resin. The material of the lens 10 may be an inorganic material such as silicon nitride or silicon oxynitride. A material film having a refractive index different from that of the lens 10 for suppressing reflection may be disposed on the surface of the lens 10. In the case of near-infrared light applications, materials such as amorphous silicon, polycrystalline silicon, and germanium may be used.

In the example illustrated in FIG. 109, the optical function of the optical layer 6 includes a prism function but does not include a lens function. For example, the principal ray L is designed to be specialized in a prism function of guiding the principal ray L substantially perpendicularly to the photoelectric conversion section 21. The lens function of condensing the principal ray L on the photoelectric conversion section 21 is provided by the lens 10. In the optical layer 6, the phase difference required within the angle of view can be reduced, and folding back can be prevented as much as possible. Furthermore, for example, by providing the lens 10 on the optical layer 6, it is possible to reduce the amount of light that hits the folding back of the pixel boundary and reduce stray light.

In the example illustrated in FIG. 110, the opening 520 of the light shielding film 52 is a pinhole as described above. The pinhole diameter can be reduced by increasing the lens power to further narrow the light. If the pinhole diameter can be reduced, the effect of confining near-infrared light and the effect of suppressing flare sensitivity can be enhanced. In order to enhance the lens power, the optical function of the optical layer 6 includes a prism function and a lens function, and a lens function by the lens 10 is further added. Pupil correction may be added to the lens 10 to reduce stray light caused by light hitting pixel boundaries of the pillars 62.

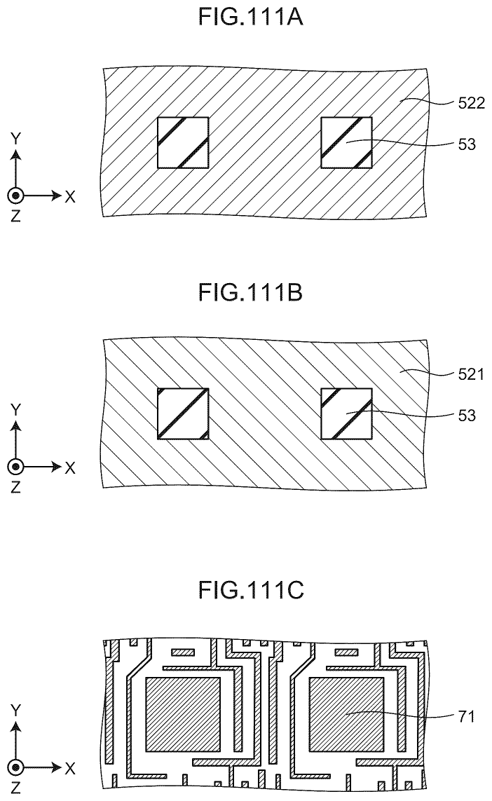

Note that the light shielding film 52 illustrated in FIG. 110 includes two types of laminated light shielding films. The first light shielding film is referred to as a light shielding film 521 in the drawing. The second light shielding film is referred to as a light shielding film 522 in the drawing. Describing an example of the material, the material of the light shielding film 521 may be aluminum, and the material of the light shielding film 522 may be tungsten. In this regard, (A) of FIG. 111 schematically illustrates a planar layout of a portion including the light shielding film 522. (B) of FIG. 111 schematically illustrates a planar layout of a portion including the light shielding film 521.

Returning to FIG. 110, the wiring layer 7 includes a wiring 71. In this regard, (C) of FIG. 111 schematically illustrates a planar layout of a portion including the wiring 71. The wiring 71 extends in the XY planar direction so as to face the photoelectric conversion section 21. The light transmitted through the semiconductor substrate 3 is reflected by the wiring 71 and enters the photoelectric conversion section 21 of the semiconductor substrate 3, so that the sensitivity of photodetection can be improved.

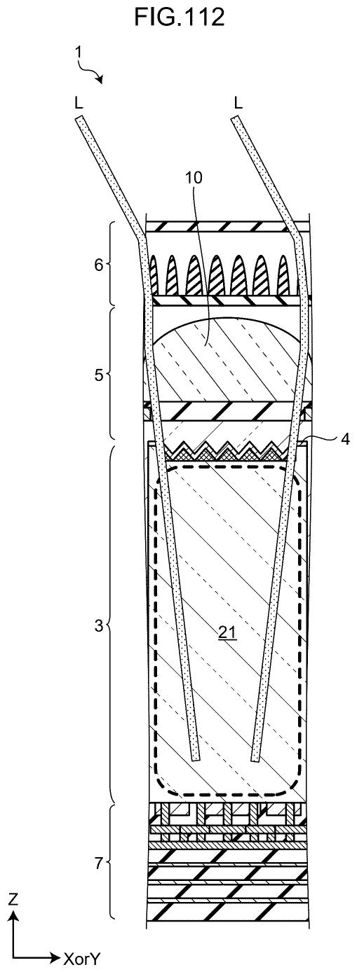

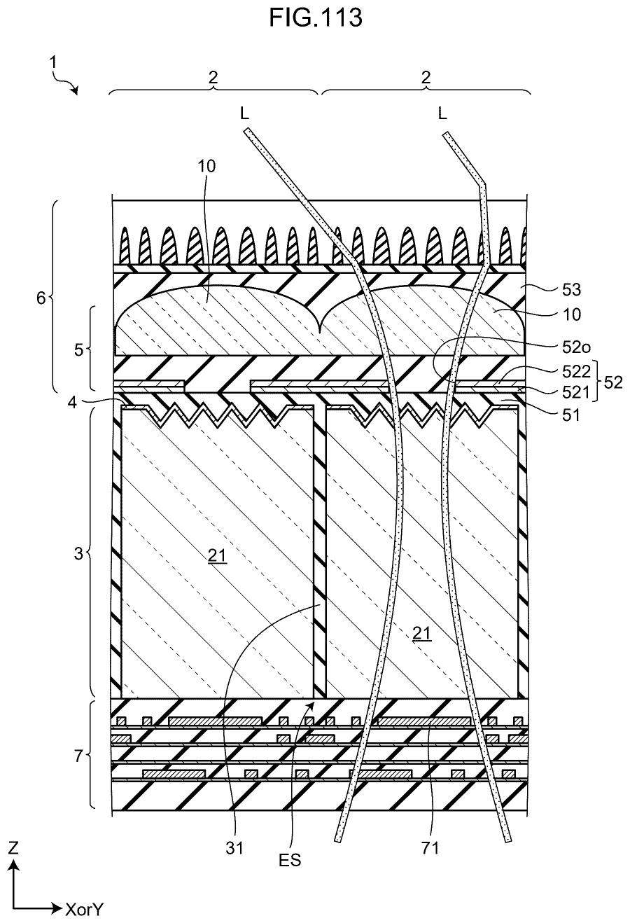

In the example illustrated in FIGS. 112 and 113, the lens 10 is an inner lens provided between the photoelectric conversion section 21 and the optical layer 6. The material and the like may be similar to those of the above-described on-chip lens. The lens 10 may be a box lens having a rectangular cross-sectional shape. Even in the case of a rectangular shape, it is possible to bend the wavefront due to a refractive index difference from the material between the box lenses to provide a lens action.

<Example of Crosstalk Suppression Configuration (Light Shielding Wall and Cladding Portion)>

In the case of increasing the height by separating the distance between the optical layer 6 and the semiconductor substrate 3, for example, when the light condensing point is aligned with the pinhole structure or the optical layer 6 is multilayered, the crosstalk path between the optical layer 6 and the semiconductor substrate 3 is widened, and the problem of characteristic deterioration may occur. In order to cope with this, a light shielding wall or a cladding portion as described below may be provided.

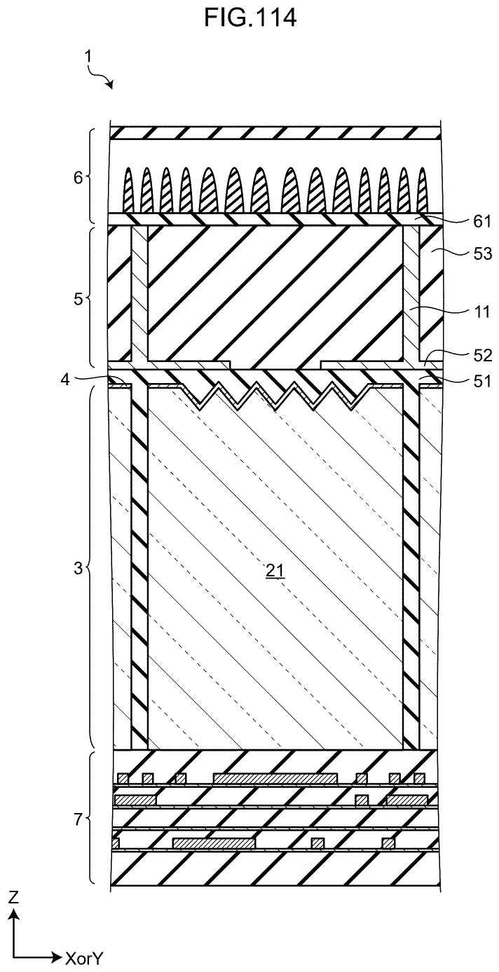

FIGS. 114 to 117 are diagrams illustrating examples of crosstalk suppression. The insulating layer 5 of the pixel array section 1 can also be said to be an example of a light guide section that guides light from the optical layer 6 to the semiconductor substrate 3 (via the fixed charge film 4 in this example).

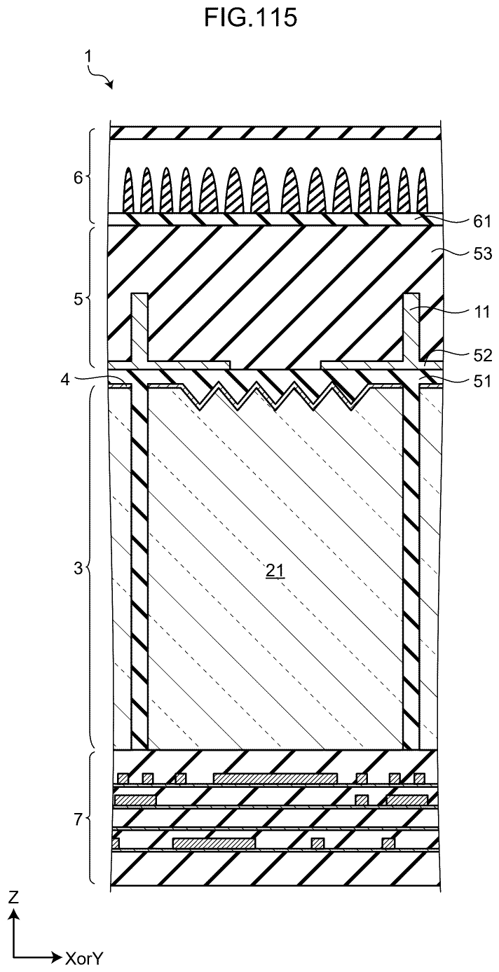

In the example illustrated in FIGS. 114 and 115, the insulating layer 5 includes a light shielding wall 11. The light shielding wall 11 is provided at a position corresponding to a boundary between the photoelectric conversion sections 21 of the adjacent pixels 2. For example, when viewed in the Z-axis direction, the light shielding wall 11 overlaps the boundary between the adjacent photoelectric conversion sections 21.

In the example illustrated in FIG. 114, the light shielding wall 11 is formed by trench processing on the insulating film 53 up to the light shielding film 52, embedding a light shielding material, for example, tungsten, and performing CMP. The light shielding wall 11 extends from the light shielding film 52 to the reflection suppressing film 61. By providing such a light shielding wall 11, a crosstalk path between the semiconductor substrate 3 and the optical layer 6 can be blocked.

In the example illustrated in FIG. 115, the upper end of the light shielding wall 11 is separated from the optical layer 6. Vignetting of the upper end portion of the light shielding wall 11 is reduced. Although the crosstalk is slightly deteriorated, a decrease in detection sensitivity can be suppressed.

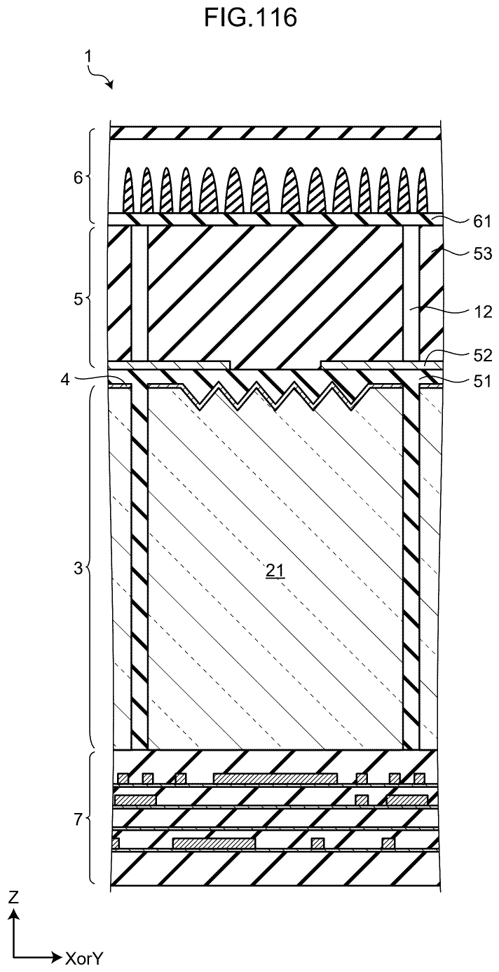

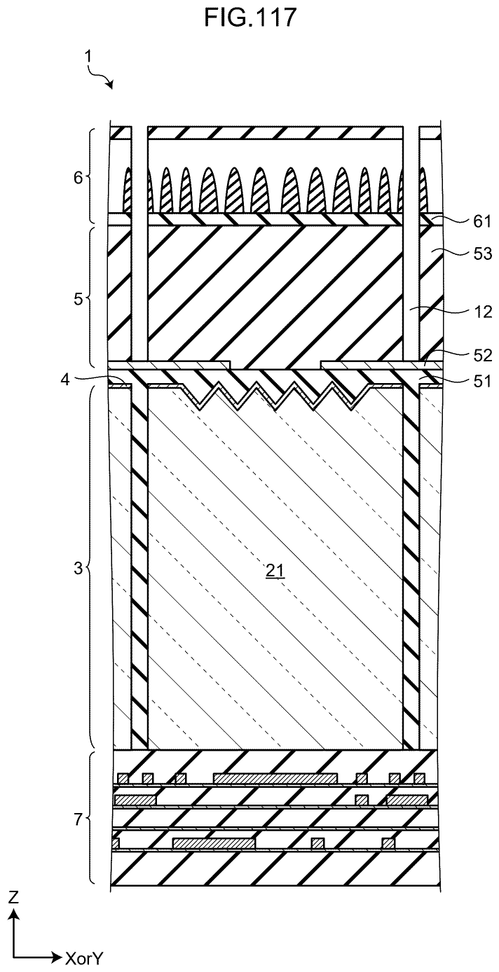

In the example illustrated in FIGS. 116 and 117, the insulating layer 5 includes a cladding portion 12. Similarly to the light shielding wall 11 described above, the cladding portion 12 is provided at a position corresponding to a boundary between the photoelectric conversion sections 21 of the adjacent pixels 2. The cladding portion 12 has a refractive index lower than that of a peripheral portion, more specifically, a portion other than the cladding portion 12 in the insulating layer 5, for example, the insulating film 53.

In the example illustrated in FIG. 116, the cladding portion 12 extends from above the light shielding film 52 to below the optical layer 6. Since light absorption by the light shielding wall is eliminated, a decrease in detection sensitivity can be suppressed. However, the blocking property of crosstalk may be reduced. Note that the cladding portion 12 may be a void portion and may be closed by formation of the insulating film 53.

In the example illustrated in FIG. 117, the cladding portion 12 extends from the light shielding film 52 onto the optical layer 6. By providing the cladding portion 12 extending over the optical layer 6, the waveguide effect can be enhanced. Structural fragility may be possible.

### <Configuration Example of Division of Photoelectric Conversion Section 21>

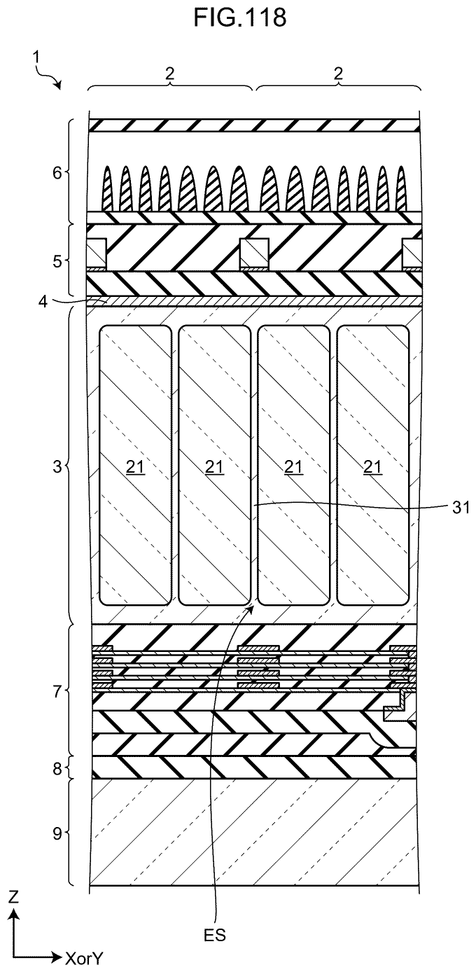

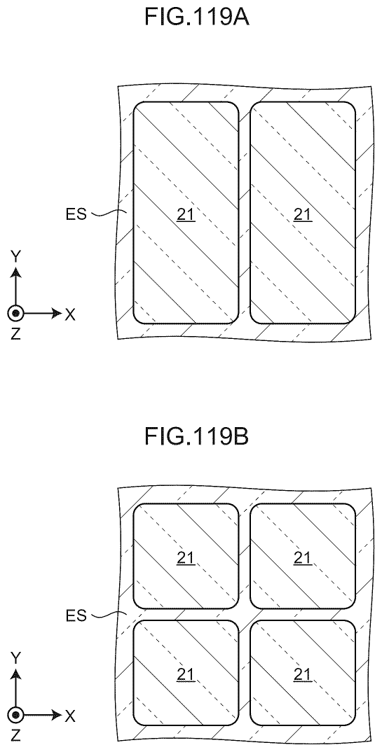

By dividing the photoelectric conversion section 21 of one pixel 2 into a plurality of parts and making a difference, the subject distance can be calculated from the image shift amount obtained by each part, and high-speed focusing processing and distance measurement of the camera lens can be performed. At the time of image generation signal processing, the S/N may be improved by output addition of the pixels 2, or images having different parallaxes may be shifted and added to reduce the blur amount. This will be described with reference to FIGS. 118 and 119.

FIGS. 118 and 119 are diagrams illustrating an example of division of the photoelectric conversion section 21. The photoelectric conversion section 21 included in one pixel 2 is a plurality of divided photoelectric conversion sections 21. Note that only the photoelectric conversion sections 21 of some of the plurality of pixels 2 may be divided.

FIG. 119 schematically illustrates some examples of the planar layout of the photoelectric conversion section 21. In the example illustrated in (A) of FIG. 119, one pixel 2 includes photoelectric conversion sections 21 divided into two on the left and right sides (for example, in the X-axis direction) in plan view, that is, two photoelectric conversion sections 21. The distance can be measured with respect to the subject having the vertical stripe contrast. In the example illustrated in (B) of FIG. 119, one pixel 2 includes four photoelectric conversion sections 21 divided into upper, lower, left, and right (Y-axis direction and X-axis direction) in plan view, that is, four photoelectric conversion sections 21. The distance can be measured for both vertical stripes and horizontal stripes. Of course, the mode of division of the photoelectric conversion section 21 is not limited to the example illustrated in FIG. 119.

Furthermore, the element separating portion ES in the pixel 2 may have various configurations as described above with reference to FIGS. 99 to 104. By increasing the number of steps, element separation in the pixel 2 and element separation between pixels can be made into different combinations.

### <Example of Configuration of Color Filter>

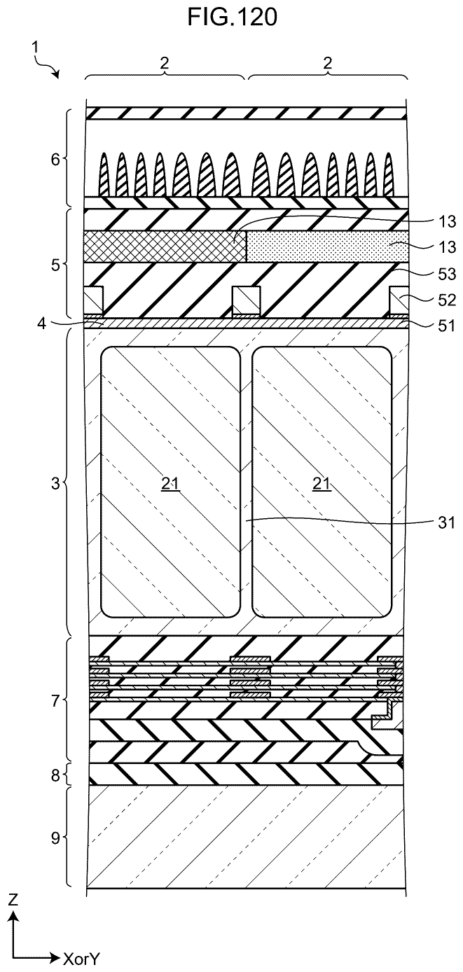

Since the design of the optical layer 6 changes depending on the wavelength in principle, it is desirable to target a single wavelength as much as possible. For example, in sensing, it is suitable for a case where light reflected by projecting a monochromatic IR-LED to Active is detected. Meanwhile, in the case of imaging a subject based on a light source having a broadband continuous wavelength, it is difficult to design as it is, but by providing a filter in the pixel 2 to limit the wavelength band, it is easy to find a design solution of the optical layer 6. An example of the filter is a color filter, which is referred to as a color filter 13, and will be described with reference to FIGS. 120 to 122.

FIGS. 120 to 122 are diagrams illustrating examples of the color filter 13. The pixel array section 1 includes the color filter 13. The color filter 13 allows light of a corresponding color of the pixel 2, for example, any one of red (R) light, green (G) light, and blue (B) light to pass therethrough. In the figure, the color filters 13 corresponding to different colors are indicated by different hatching. The color filter 13 includes, for example, a general pigment, dye, and the like.

In the example illustrated in FIG. 120, the color filter 13 is provided between the photoelectric conversion section 21 and the optical layer 6, more specifically, in the insulating layer 5 located below the optical layer 6. As a result, the wavelength range can be narrowed, and the controllability of light can be enhanced. The optical function of the optical layer 6 may include a prism function and a lens function. Note that the pillar 62 in this case is designed to be different for each color corresponding to the pixel 2.

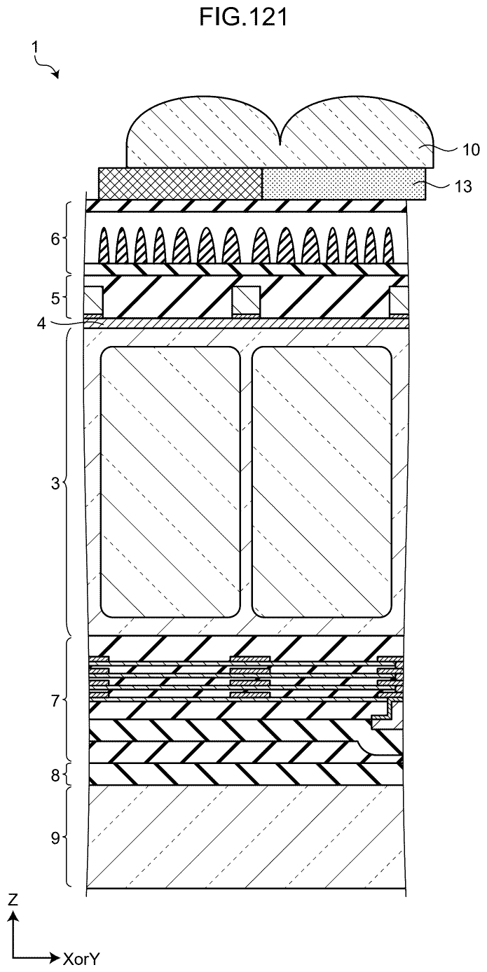

In the example illustrated in FIG. 121, the color filter 13 is provided on the side opposite to the photoelectric conversion section 21 with the optical layer 6 interposed therebetween, more specifically, on the optical layer 6. Since the color filter 13 has less variation in transmission spectrum with respect to oblique incidence, such a configuration is possible. In the case of this configuration, the lens 10 that is an on-chip lens may be provided on the color filter 13 to apply pupil correction to the obliquely incident light at the field angle end. It is possible to reduce sensitivity loss due to inter-pixel light shielding.

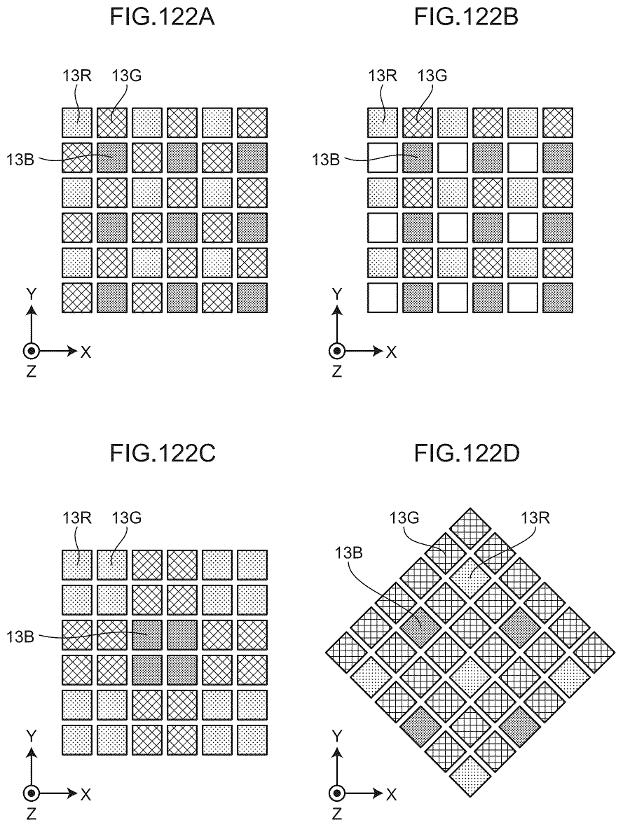

FIG. 122 illustrates some examples of the array (planar layout) of the color filters 13. The array illustrated in (A) of FIG. 122 is a Bayer array including three primary colors of RGB. The array illustrated in (B) of FIG. 122 is a GRB-W array including pixels in which the color filters 13 are not provided. The array illustrated in (C) of FIG. 122 is a Quad-Bayer array capable of 2×2 pixel addition, individual output, and the like. The array illustrated in (D) of FIG. 122 is a Clearvid array in which the resolution is improved by the array rotated by 45 degrees. For example, a complementary color-based array may be used, or a primary color-based array and a complementary color-based array may be used. Alternatively, an infrared ray absorption film made of an organic material, an infrared ray transmission film in a specific wavelength region, or the like may be provided, and further, they may be provided by being laminated in a vertical structure, and the present invention is not limited thereto.

### <Example of Configuration of Another Filter>

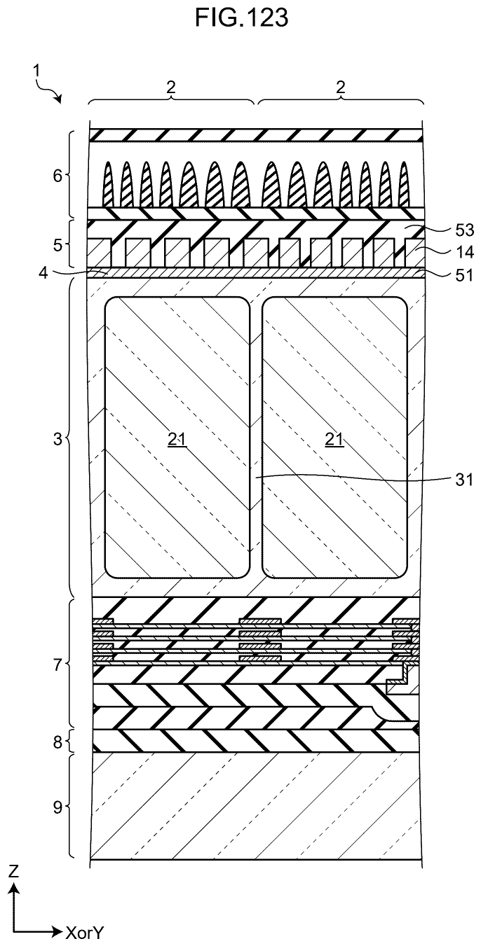

Various filters other than the color filter 13 described above may be used. This will be described with reference to FIGS. 123 to 127.

FIGS. 123 to 127 are diagrams illustrating examples of other filters. In the example illustrated in FIG. 123, the pixel array section 1 includes a surface plasmon filter 14. The surface plasmon filter 14 is an optical element that obtains a light filtering effect using surface plasmon resonance, and a metal conductor thin film is used as a base material. In order to efficiently obtain the effect of surface plasmon resonance, it is necessary to reduce the electrical resistance of the surface of the conductor thin film as much as possible. As the metal conductor thin film, aluminum or an alloy thereof having low electric resistance and easy processing is often used (see, for example, Patent Literature 2).

It is known that the transmittance spectrum of the surface plasmon filter 14 changes with oblique incidence. As illustrated in FIG. 123, it is desirable that the optical layer 6 is provided above the surface plasmon filter 14, and the optical layer 6 is designed such that incident light from the camera lens is perpendicularly incident on a peak wavelength of a spectrum incident at 0 degrees.

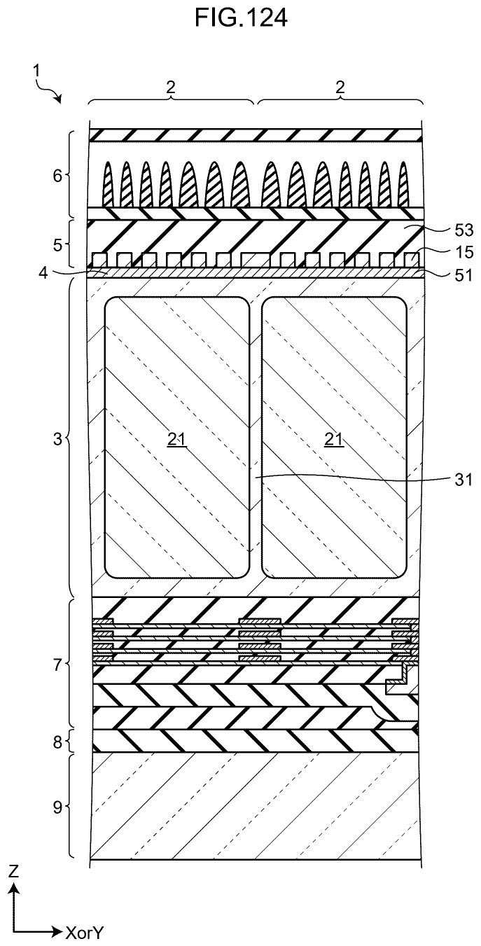

In the example illustrated in FIG. 124, the pixel array section 1 includes a guided mode resonance (GMR) filter 15. The GMR filter 15 is an optical filter capable of transmitting only light in a narrow wavelength band (narrow band) by combining a diffraction grating and a clad core structure. For a more specific configuration and the like, refer to, for example, Patent Literature 3. By using the resonance between the guided mode and the diffracted light generated in the waveguide, light utilization efficiency is high, and a sharp resonance spectrum can be obtained.

It is known that the transmittance spectrum of the GMR filter 15 changes with oblique incidence. As illustrated in FIG. 124, it is desirable that the optical layer 6 is provided above the GMR filter 15, and the optical phase control section is designed such that incident light from the camera lens is perpendicularly incident on a peak wavelength of a spectrum incident at 0 degrees.

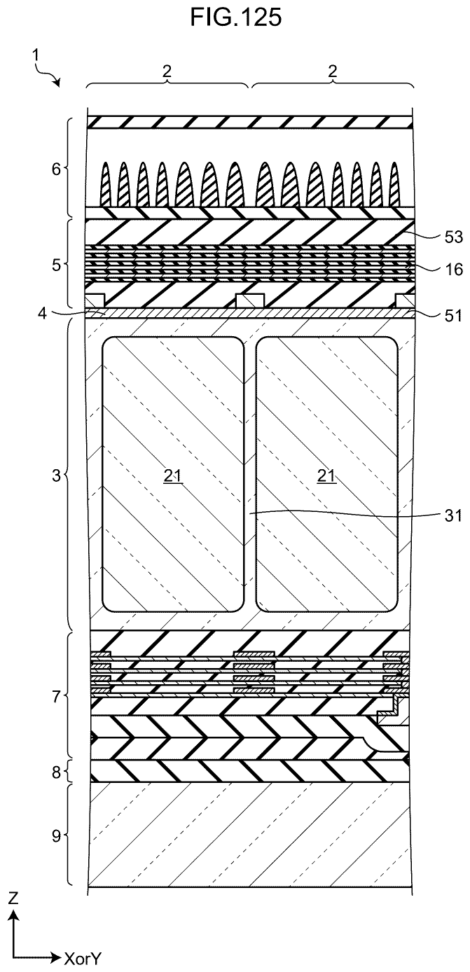

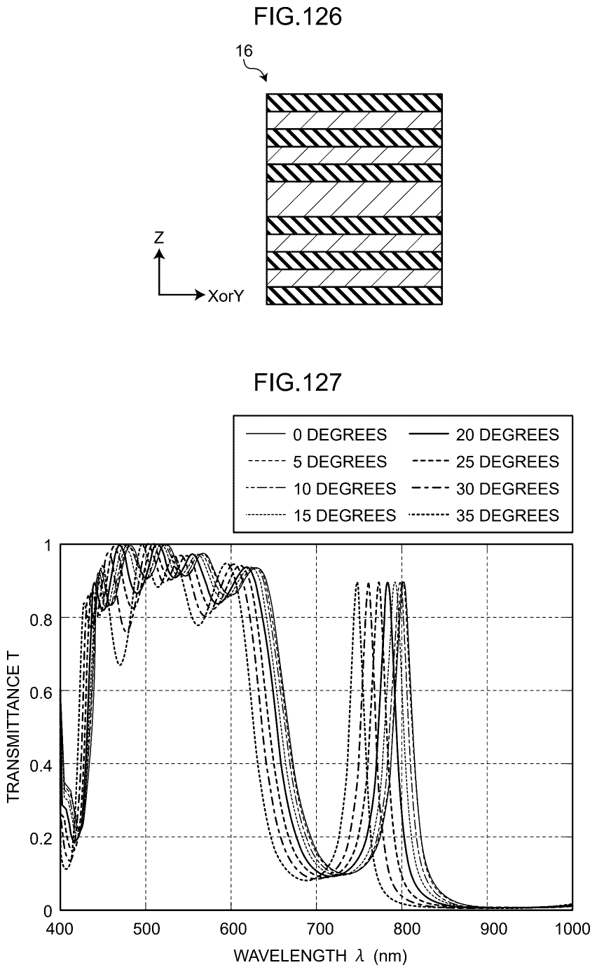

In the example illustrated in FIG. 125, the pixel array section 1 includes a laminated filter 16. FIG. 126 schematically illustrates an enlarged configuration of the laminated filter 16. The laminated filter 16 is a filter in which films having different refractive indexes are laminated. The laminated filter 16 may be a band pass filter or a Fabry-Perot interference filter.

Due to the interference effect of light, the film thicknesses of the films having different refractive indexes can be controlled and alternately laminated to have a specific transmission/reflection spectrum. In addition, it is also possible to design a narrow-band spectrum by setting a pseudo defect layer that disturbs periodicity. However, when light is obliquely incident, the spectrum is shifted by a short wavelength due to a change in the effective film thickness. For example, as illustrated in FIG. 127, the peak wavelength shifts according to the angle. FIG. 127 is a graph illustrating the transmittance T with respect to the wavelength λ in a case where the angle is changed by 5 degrees from 0 degrees to 35 degrees.

For such a laminated filter 16, as illustrated in FIG. 125, it is desirable that the optical layer 6 is provided above the laminated filter 16, and the optical phase control section is designed such that the incident light from the camera lens is perpendicularly incident on the peak wavelength of the spectrum incident at 0 degrees.

Note that the surface plasmon filter 14, the GMR filter 15, and the laminated filter 16 described above may be laminated in the vertical direction so as to obtain a desired spectrum, and the optical layer 6 may be provided thereon.

### <Modification of Multilayering of Optical Layer 6>

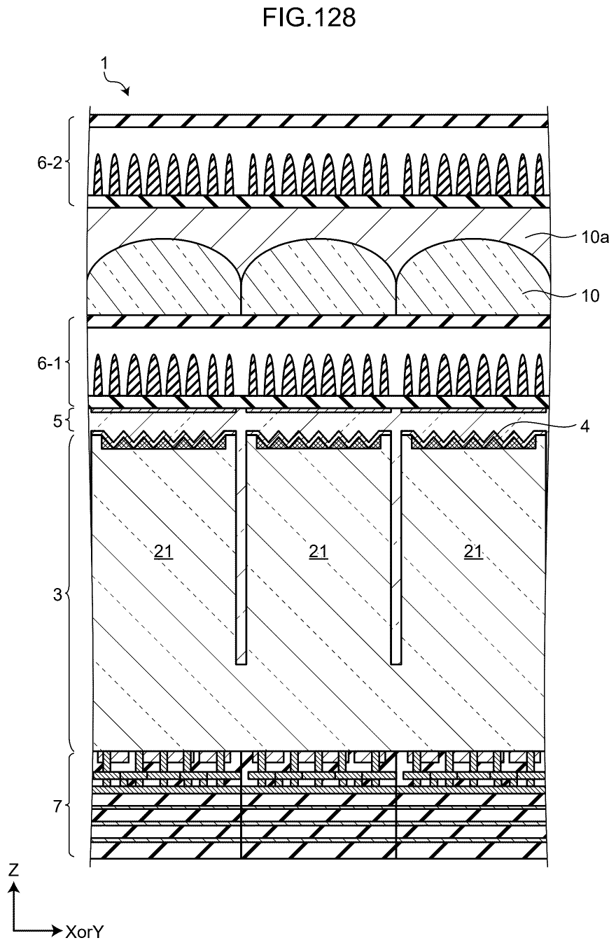

FIG. 128 is a diagram illustrating a modification of multilayering of the optical layer 6. Compared to the configuration of FIG. 82 described above, another element is provided between the optical layer 6-1 and the optical layer 6-2. In the example illustrated in FIG. 128, the lens 10 (inner lens) covered with the insulating film 10a is provided between the optical layer 6-1 and the optical layer 6-2. In addition to the lens 10, more specifically, the insulating layer 5 (light guide section) described so far, the light shielding film 52, the opening 520 which is a pinhole, and the like, and the light shielding wall 11, the cladding portion 12, the color filter 13, the surface plasmon filter 14, the GMR filter 15, the laminated filter 16, and the like may be provided as another element between the optical layer 6-1 and the optical layer 6-2.

### <Section Summary>

The technology according to the second embodiment described above is specified as follows, for example. One of the disclosed techniques is the photodetector 100 (for example, an imaging apparatus). As described with reference to FIGS. 1 to 5, 52 to 60, and the like, the photodetector 100 includes the photoelectric conversion section 21 and the optical layer 6 provided to cover the photoelectric conversion section 21. The optical layer 6 includes a plurality of pillars arranged side by side in a plane direction of the layer so as to guide at least light to be detected among the incident light to the photoelectric conversion section 21. The pillar 62 has a cross-sectional area that continuously changes as it advances in the pillar height direction (Z-axis direction), and at least one of the upper surface 62a and the lower surface 62b of the pillar 62 is a curved surface. As a result, light reflection on at least one of the upper surface 62a and the lower surface 62b of the pillar 62 and the vicinity thereof can be suppressed.

As described with reference to FIG. 60 and the like, at least some pillars 62 among the plurality of pillars 62 have different maximum widths, and the height HA of the pillar 62A having the largest maximum width WA among the plurality of pillars 62 may be larger than the height H2 of the pillar 62B having the smallest maximum width WB. By increasing the height HA of the pillar 62A intended to provide a large phase delay, a large phase delay can be more easily obtained. By reducing the height HB of the pillar 62B intended to provide a small phase delay, a small phase delay can be more easily obtained. In addition, the pillars 62 having a smaller maximum width are more likely to collapse, but the risk can be reduced by reducing the height.

As described with reference to FIGS. 4, 5, 84 to 92, and the like, the plurality of pillars 62 may impart a lens function to the optical layer 6. As a result, the light included in the incident light can be separated for each wavelength, and the light to be detected among the light can be guided (directed) to the photoelectric conversion section 21. The pillars 62 may impart a prism function to the optical layer 6. As a result, light can be condensed on the photoelectric conversion section 21. The plurality of pillars 62 may impart a lens function and a prism function to the optical layer 6.

As described with reference to FIGS. 52 to 54 and the like, the upper surface 62a of the pillar 62 may be a curved surface, the lower surface 62b of the pillar 62 may be a flat surface, and the pillar 62 may have a cross-sectional area that monotonically decreases toward the upper surface 62a. For example, with such a configuration, light reflection on the upper surface 62a of the pillar 62 and the vicinity thereof can be suppressed.

As described with reference to FIGS. 55 to 57 and the like, the upper surface 62a of the pillar 62 may be a flat surface, the lower surface of the pillar 62 may be a curved surface, and the pillar 62 may have a cross-sectional area that monotonically decreases toward the lower surface 62b. For example, with such a configuration, light reflection on the lower surface 62b of the pillar 62 and the vicinity thereof can be suppressed.

As described with reference to FIGS. 58, 59, and the like, both the upper surface 62a and the lower surface 62b of the pillar 62 may be curved surfaces. In this case, the pillar 62 may have a cross-sectional area that monotonically increases and monotonically decreases from one surface to the other surface of the upper surface 62a and the lower surface 62b. For example, with such a configuration, it is possible to suppress both light reflection at the upper surface 62a of the pillar 62 and the vicinity thereof and light reflection at the lower surface 62b of the pillar 62 and the vicinity thereof.

As described with reference to FIGS. 4 and 53 and the like, the optical layer 6 may include the filler 64 provided so as to fill the space between the plurality of pillars 62. The filler 64 may have a refractive index different from the refractive index of the pillar 62 by 0.3 or more. The optical layer 6 may include the protective film 65 provided so as to cover the filler 64. For example, pillar collapse can be suppressed, and tape residue in the assembly process can be suppressed.

As described with reference to FIG. 57 and the like, the upper surface 62a of the pillar 62 is a flat surface, the lower surface 62b of the pillar 62 is a curved surface, the optical layer 6 includes the base layer 620 provided in common on the upper surface 62a of each of the plurality of pillars 62, the optical layer 6 includes the additional layer 66 provided on the base layer 620, and the additional layer 66 may include a plurality of films (for example, the first film 661, the second film 662, and the third film 663) each having a different refractive index. The film may be a reflection suppressing film or a band pass filter. Light reflection can be further suppressed, and incidence of unnecessary light on the photoelectric conversion section 21 can be suppressed. As described with reference to FIG. 82 and the like, the photodetector 100 may include the plurality of laminated optical layers 6. As a result, the height of the pillar 62 can be reduced as compared with the case of the single-layer structure. For example, it is effective in a case where it is difficult to increase the height of the pillars 62 due to pillar collapse in the Wet cleaning. In addition, by changing and combining the design of the pillars 62 of each layer, it is possible to broaden the wavelength, achieve multispectral capabilities, and the like. It is also possible to realize polarization control.

The material of the pillar may include at least one of amorphous silicon, polycrystalline silicon, and germanium, and the pillar 62 may have a height of 200 nm or more. Thus, the optical layer 6 suitable for control of near-infrared light can be obtained.

The material of the pillar 62 includes at least one of titanium oxide, niobium oxide, tantalum oxide, aluminum oxide, hafnium oxide, silicon nitride, silicon oxide, silicon nitride oxide, silicon carbide, silicon carbide oxide, silicon carbide nitride, and zirconium oxide, and the pillar 62 may have a height of 300 nm or more. Thus, the optical layer 6 suitable for visible light control can be obtained.

As described with reference to FIGS. 94 to 98 and the like, (for example, the pixel array section 1 of) the photodetector 100 may include the light shielding film 52 provided between the photoelectric conversion section 21 and the optical layer 6 and having the opening 520 facing at least a part of the photoelectric conversion section 21. As a result, for example, stray light can be blocked, and light can be guided to the photoelectric conversion section 21. The opening 520 of the light shielding film 52 may be a pinhole having an aperture ratio of 25% or less. As a result, effects such as improvement in detection sensitivity due to optical confinement, suppression of chip reflection, and suppression of flare sensitivity can be obtained. The photodetector 100 (for example, the pixel array section 1) may include a plurality of pixels 2 each including the photoelectric conversion section 21, the plurality of pixels 2 may include the image plane phase difference pixel 2d1 (first image plane phase difference pixel) and the image plane phase difference pixel 2d2 (second image plane phase difference pixel), and the light shielding film 52 may have the opening 5201 (first opening) and the opening 5202 (second opening) facing different portions of the photoelectric conversion section 21 of the image plane phase difference pixel 2d1 and the photoelectric conversion section 21 of the image plane phase difference pixel 2d2. As a result, the subject distance is calculated from the shift amount of the image obtained by each of the image plane phase difference pixel 2d1 and the image plane phase difference pixel 2d2, and high-speed focusing processing and distance measurement of the camera lens can be performed.

As described with reference to FIGS. 99 to 104 and the like, (for example, the pixel array section 1 of) the photodetector 100 may include the semiconductor substrate 3 including the plurality of photoelectric conversion sections 21 and having the upper surface 3a facing the optical layer 6, and the element separating portion ES provided so as to extend between the photoelectric conversion sections 21 adjacent to each other in the semiconductor substrate 3 at least from the upper surface 3a of the semiconductor substrate 3. Accordingly, element separation can be enhanced.

As described with reference to FIGS. 109 to 113 and the like, the photodetector 100 (for example, the pixel array section 1) may include the lens 10 provided on at least one of the side opposite to the photoelectric conversion section 21 with the optical layer 6 interposed therebetween and between the photoelectric conversion section 21 and the optical layer 6. As a result, for example, the phase difference required in the optical layer 6 can be reduced.

As described with reference to FIGS. 118, 119, and the like, the photodetector 100 (for example, the pixel array section 1) may include the plurality of pixels 2 each including the photoelectric conversion section 21, and the photoelectric conversion sections 21 of at least some of the plurality of pixels 2 may be the plurality of divided photoelectric conversion sections 21. As a result, the subject distance can be calculated from the shift amount of the image obtained by each of the plurality of photoelectric conversion sections 21, and high-speed focusing processing and distance measurement of the camera lens can be performed.

As described with reference to FIGS. 105 to 108 and the like, the photodetector 100 (for example, the pixel array section 1) may include the semiconductor substrate 3 including the plurality of photoelectric conversion sections 21 and having the upper surface 3a facing the optical layer 6, and the upper surface 3a of the semiconductor substrate 3 may have an uneven shape. As a result, the incident light is obliquely directed, and the detection sensitivity can be improved.

As described with reference to FIGS. 3 and 114 to 117 and the like, (for example, the pixel array section 1 of) the photodetector 100 may include the semiconductor substrate 3 including the plurality of photoelectric conversion sections 21 and the light guide section (for example, the insulating layer 5) provided between the semiconductor substrate 3 and the optical layer 6, and the light guide section may include the light shielding wall 11 provided at a position corresponding to the boundary between the adjacent photoelectric conversion sections 21 among the plurality of photoelectric conversion sections 21. Alternatively, the light guide section may include the cladding portion 12 (which may be a void portion) provided at a position corresponding to a boundary between adjacent photoelectric conversion sections 21 among the plurality of photoelectric conversion sections 21 and having a refractive index lower than that of other portions of the light guide section. This makes it possible to suppress crosstalk that may occur due to a crosstalk path between the optical layer 6 and the semiconductor substrate 3.

As described with reference to FIGS. 120 to 126 and the like, (for example, the pixel array section 1 of) the photodetector 100 includes a filter provided on at least one of the side opposite to the photoelectric conversion section 21 with the optical layer 6 interposed therebetween and between the photoelectric conversion section 21 and the optical layer 6, and the filter may include at least one of the color filter 13, the band pass filter (an example of the laminated filter 16) in which films having different refractive indexes are laminated, the Fabry-Perot interference filter (an example of the laminated filter 16) in which films having different refractive indexes are laminated, the surface plasmon filter 14, and the GMR filter 15. By limiting the wavelength band using such a filter, for example, a design solution of the optical layer 6 can be easily found.

As described with reference to FIGS. 94 to 98, 114 to 117, 120 to 126, 128, and the like, (for example, the pixel array section 1 of) the photodetector 100 includes the optical layer 6-1 (first optical layer), the optical layer 6-2 (second optical layer), and another element provided between the optical layer 6-1 and the optical layer 6-2, and the another element includes at least one of the light shielding film 52 having the opening 520 facing at least a part of the photoelectric conversion section 21, the lens 10, the light shielding wall 11 provided at a position corresponding to a boundary between adjacent photoelectric conversion sections 21 of the plurality of photoelectric conversion sections 21, the cladding portion 12 provided at a position corresponding to a boundary between adjacent photoelectric conversion sections 21 of the plurality of photoelectric conversion sections 21 and having a refractive index lower than that of the peripheral portion, the color filter 13, a band pass filter (an example of the laminated filter 16) in which films having different refractive indexes are laminated, a Fabry-Perot interference filter (an example of the laminated filter 16) in which films having different refractive indexes are laminated, the surface plasmon filter 14, and the GMR filter 15. For example, a combination of the optical layer 6 having such a multilayer configuration and various elements is also possible.

### 3. THIRD EMBODIMENT

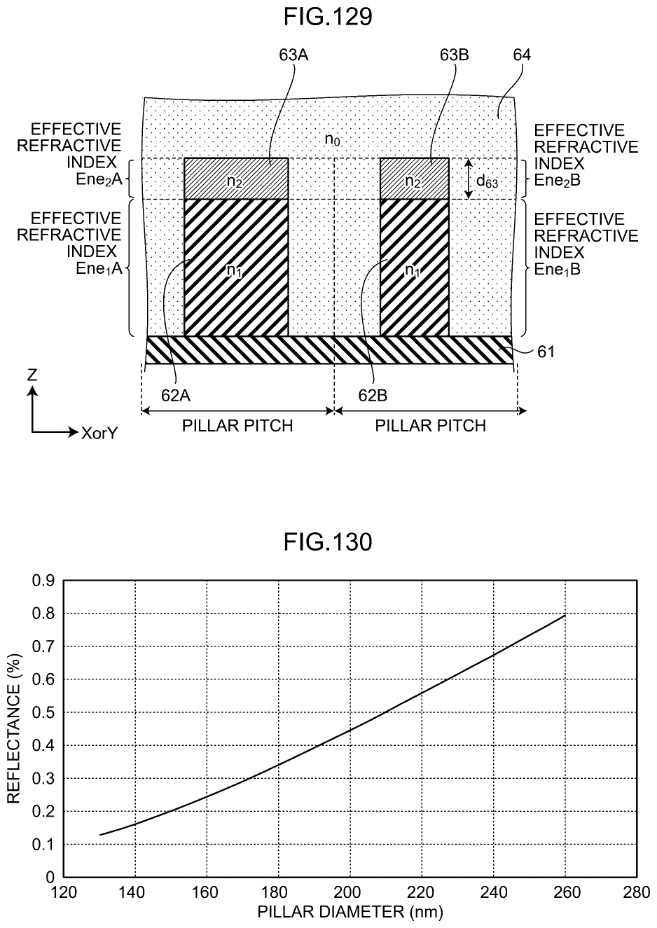

In the third embodiment, light reflection is suppressed by devising the shape of the pillar 62. First, the problem will be described with reference to FIGS. 129 and 130.

FIGS. 129 and 130 are diagrams illustrating comparative examples. FIG. 129 schematically illustrates cross sections of two adjacent pillars 62 and peripheral structures thereof. One pillar 62 is referred to as a pillar 62A in the drawing. The other pillar 62 is referred to as a pillar 62B in the drawing. The pillar 62A and the pillar 62B have different sizes (for example, widths) from each other. In a case where the pillar 62A and the pillar 62B are not particularly distinguished, they are simply referred to as pillars 62. Note that the pillar 62A and the pillar 62B described in the third embodiment may be distinguished and understood from the pillar 62A and the pillar 62B in FIG. 60 described in the second embodiment.

The reflection suppressing film 63 provided on the pillar 62A is referred to as a reflection suppressing film 63A in the drawing. The reflection suppressing film 63 provided on the pillar 62B is referred to as a reflection suppressing film 63B in the drawing. In a case where they are not particularly distinguished, they are simply referred to as a reflection suppressing film 63. The size (for example, the width) of the reflection suppressing film 63 depends on the size of the pillar 62.

The refractive index of the pillar 62 is referred to as a refractive index n₁. The refractive index of the reflection suppressing film 63 is referred to as a refractive index n₂. The thickness of the reflection suppressing film 63 is referred to as a thickness d63. The refractive index of the peripheral materials of the pillar 62 and the reflection suppressing film 63, in this example, the filler 64 is referred to as a refractive index no. The refractive index no, the refractive index n₂, and the refractive index n₁ are designed to increase in this order (n₀<n₂<n₁). The pillar pitch is shorter than a wavelength of light to be detected. As viewed from the light, the effective refractive index of the entire portion (pixel) in which the plurality of pillars 62 are arranged is an average value.

In the optical layer, an effective refractive index of a region where the pillar 62 is located in the Z-axis direction is referred to as an effective refractive index Ene₁. The effective refractive index of the region where the reflection suppressing film 63 is located is referred to as an effective refractive index Ene₂. The effective refractive index Ene₁ varies depending on the size of the pillar 62. The same applies to the effective refractive index Ene₂. Specifically, the effective refractive index of the region where the pillar 62A is located is referred to as an effective refractive index Ene₁A in the drawing. The effective refractive index Ene| of the region where the pillar 62B is located is referred to as an effective refractive index Ene₁B. The effective refractive index Ene₁A and the effective refractive index Ene₁B have different values. Furthermore, the effective refractive index of the region where the reflection suppressing film 63A is located is referred to as an effective refractive index Ene₂A. The effective refractive index Ene₂ of the region where the reflection suppressing film 63B is located is referred to as an effective refractive index Ene₂B. The effective refractive index Ene₂A and the effective refractive index Ene₂B have different values.

The condition for maximizing reflection suppression (antireflection condition) is expressed by the following Formula (3) in the case of normal incidence.

$$\begin{matrix}{Ene}_{2} = \sqrt{{Ene}_{1} {n}_{0}} & {d}_{63} = \frac{λ}{4 {Ene}_{2}}\end{matrix} \qquad ( 3 )$$

Therefore, even in the case of oblique incidence, there is a problem that a sufficient reflection condition cannot be obtained by the uniform reflection suppressing film 63. In addition, there is also a problem that there may be no material having an appropriate refractive index. Specifically, in FIG. 130, the reflectance (%) at the interface between the peripheral material (for example, the filler 64) and the reflection suppressing film 63 when optimized so that the maximum reflectance is minimized for the following conditions is indicated by a graph. Even with normal incidence, the reflectance is up to about 0.8%.
Wavelength λ: 940 nm
Incident angle: 0 degrees (normal incidence)
Refractive index n0: 1.4
Refractive index n1: 3.6
Refractive index n2: 2.0
Pillar pitch: 350 nm
Pillar diameter: 130 nm to 260 nm

Optimized thickness d₆₃ of reflection suppressing film 63: 142 nm

The above-described problem is addressed by the present embodiment. As will be described later, by devising the shape of the upper surface 62a of the pillar 62, optimal reflection conditions can be obtained for each pillar 62, thereby suppressing light reflection.

### Example 1

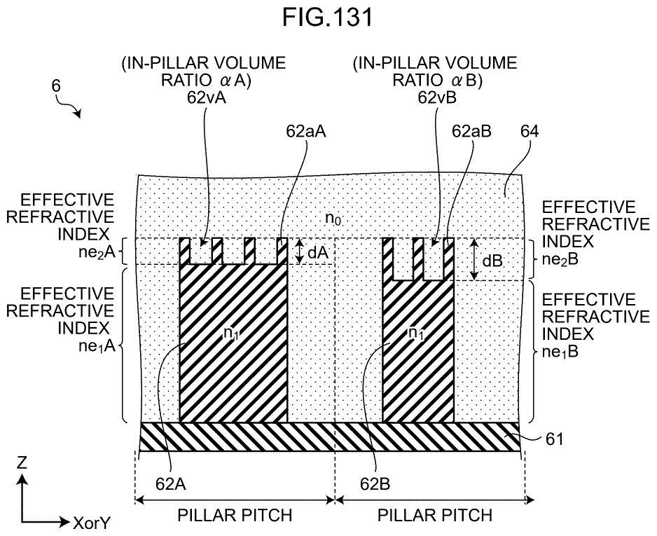

FIG. 131 is a diagram illustrating an example of a schematic configuration of the optical layer 6. The upper surface 62a of the pillar 62A is referred to as an upper surface 62aA in the drawing. The upper surface 62a of the pillar 62B is referred to as an upper surface 62aB in the drawing. In a case where they are not particularly distinguished, they are simply referred to as the upper surface 62a.

In the example illustrated in FIG. 131, the reflection suppressing film 63 is not provided on the upper surface 62a of the pillar 62. The upper surface 62a of the pillar 62 is covered with the filler 64. As described above, the filler 64 is an example of a peripheral material, and the filler 64 and the peripheral material may be appropriately read as long as there is no contradiction.

The upper surface 62a of the pillar 62 has a non-flat portion 62v. It can be said that the upper surface 62a is a non-flat surface, and it can be said that the upper surface 62a is a surface that defines a non-flat shape. The non-flat portion 62v includes at least one of a recess and a protrusion.

The non-flat portion 62v of the upper surface 62aA of the pillar 62A is referred to as a non-flat portion 62vA in the drawing. The non-flat portion 62v of the upper surface 62aB of the pillar 62B is referred to as a non-flat portion 62vB in the drawing. In a case where they are not particularly distinguished, they are simply referred to as non-flat portions 62v.

In the example illustrated in FIG. 131, the cross-sectional area of the recess of the non-flat portion 62v as viewed in the depth direction (Z-axis negative direction) is the same at any depth position. It can also be said that the side surface in the recess extends vertically (in the Z-axis direction).

In the optical layer 6, the effective refractive index of a region where a portion other than the non-flat portion 62v in the pillar 62 (a portion below the bottom surface of the non-flat portion 62v) is located is referred to as an effective refractive index ne₁. The effective refractive index of the region where the non-flat portion 62v of the pillar 62 is located is referred to as an effective refractive index ne₂.

Specifically, the effective refractive index ne₁ and the effective refractive index ne₂ corresponding to the pillar 62A are referred to as an effective refractive index ne₁A and an effective refractive index ne₂A in the drawing. The effective refractive index ne₁ and the effective refractive index ne₂ corresponding to the pillar 62B are referred to as an effective refractive index ne₁B and an effective refractive index ne₂B in the drawing. In a case where they are not particularly distinguished, they are simply referred to as an effective refractive index ne₁ and an effective refractive index ne₂.

The effective refractive index ne₂ has a value between the refractive index no and the effective refractive index ne₁. In this example, the refractive index no, the effective refractive index ne₂, and the effective refractive index ne₁ increase in this order (n₀<ne₂<ne₁). In the optical layer 6, the effective refractive index of each region changes in the order of the refractive index no, the effective refractive index ne₂, and the effective refractive index ne₂ as it advances in the Z-axis negative direction. By changing the effective refractive index stepwise in three stages (increasing the effective refractive index in this example), light reflection on the upper surface 62a of the pillar 62 and the vicinity thereof can be suppressed.

The ratio of the volume occupied by the recess of the non-flat portion 62v in the pillar 62 is referred to as an in-pillar volume ratio α. In the pillar 62A, the in-pillar volume ratio α occupied by the recess of the non-flat portion 62vA is referred to as an in-pillar volume ratio αA. In the pillar 62B, the in-pillar volume ratio α occupied by the recess of the non-flat portion 62vB is referred to as an in-pillar volume ratio αB. In a case where they are not particularly distinguished, they are simply referred to as in-pillar volume ratio α. The effective refractive index ne₂ can be adjusted by adjusting the in-pillar volume ratio α.

The depth (the length in the Z-axis direction) of the recess of the non-flat portion 62v is referred to as a depth d of the recess. The depth of the recess of the non-flat portion 62vA is referred to as a depth dA of the recess in the drawing. The depth of the recess of the non-flat portion 62vB is referred to as a depth dB of the recess in the drawing. In a case where they are not particularly distinguished, they are simply referred to as a depth d of the recess. The effective refractive index ne₂ can be adjusted by adjusting the depth d of the recess.

By adjusting the in-pillar volume ratio α or adjusting the depth d of the recess for each pillar 62, the effective refractive index ne₂ can be adjusted for each pillar 62 to obtain the optimal reflection condition. Therefore, a high light reflection suppressing effect can be obtained.

For example, the in-pillar volume ratio α for each pillar 62 may be adjusted by the size of the pillar 62. In this case, the in-pillar volume ratio αA and the in-pillar volume ratio ab may be different from each other. Note that the in-pillar volume ratio α may be constant regardless of the size of the pillar 62, and in this case, the in-pillar volume ratio αA and the in-pillar volume ratio αB may be the same.

For example, the depth d of the recess of the non-flat portion 62v may be adjusted by the size of the pillar 62. In this case, the depth dA of the recess of the non-flat portion 62vA and the depth dB of the recess of the non-flat portion 62vB may be different from each other. Note that the depth d of the recess of the non-flat portion 62v may be constant regardless of the size of the pillar 62, and in this case, the depth dA of the recess of the non-flat portion 62vA and the depth dB of the recess of the non-flat portion 62vB may be the same.

Note that, in a case where there are a plurality of wavelength regions of the light to be detected (for example, in the case of RGB), the in-pillar volume ratio α and the depth d of the recess corresponding to each pillar 62 may be adjusted for each wavelength region.

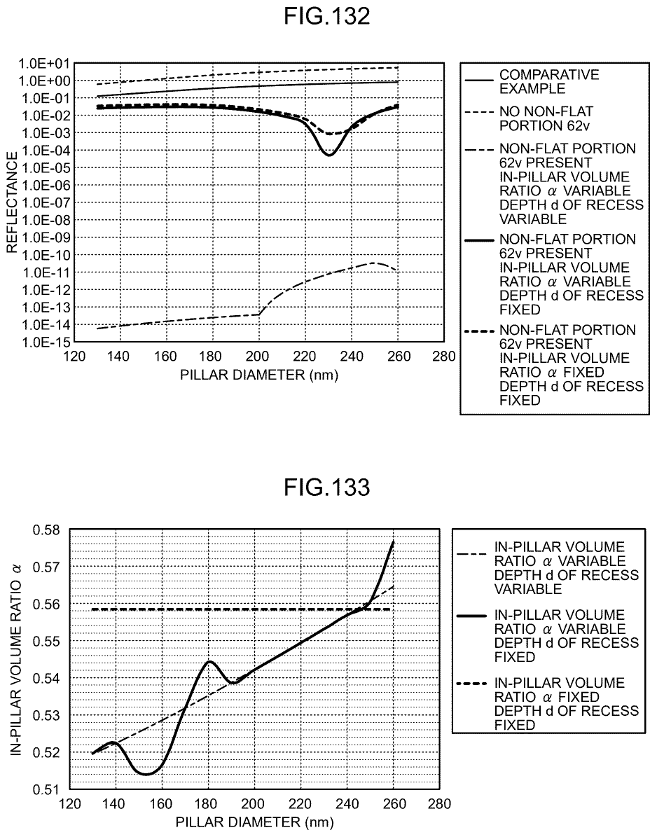

FIG. 132 is a diagram illustrating an example of reflectance. The reflectance at the interface with the peripheral material (for example, filler 64) when optimized by approximate calculation so as to minimize the maximum reflectance for the following conditions is indicated by a graph. In the case of the comparative example described above, the respective reflectances are illustrated in the absence of the non-flat portion 62v, in the case where both the in-pillar volume ratio α and the depth d of the recess are variable in the presence of the non-flat portion 62v, in the case where the in-pillar volume ratio α is variable and the depth d of the recess is fixed in the presence of the non-flat portion 62v, and in the case where both the in-pillar volume ratio α and the depth d of the recess are fixed in the presence of the non-flat portion 62v.
Wavelength λ: 940 nm
Incident angle: 0 degrees (normal incidence)
Refractive index n0: 1.4 (polymer)
Refractive index n1: 3.6 (amorphous silicon)
Pillar pitch: 350 nm
Pillar diameter: 130 nm to 260 nm

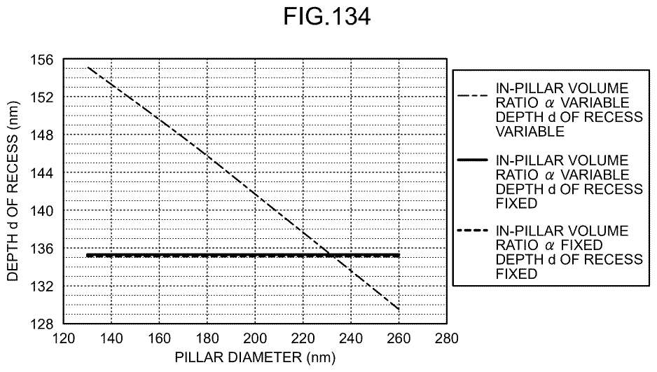

Since the upper surface 62a of the pillar 62 has the non-flat portion 62v, the reflectance is greatly reduced. Even in a case where the in-pillar volume ratio α and the depth d of the recess are fixed, the reflectance can be suppressed to 0.04% or less, and a sufficient effect can be obtained. A description will be given with reference to FIGS. 133 and 134.

FIG. 133 is a diagram illustrating an example of the optimized in-pillar volume ratio α. Even if the in-pillar volume ratio α and the depth d are fixed or variable, the optimal in-pillar volume ratio α does not change so much. Even in a case where the in-pillar volume ratio α is fixed, a sufficient effect can be obtained.

FIG. 134 is a diagram illustrating an example of the optimized depth d of the recess. Even if the in-pillar volume ratio α and the depth d are fixed or variable, the optimal depth d of the recess does not change so much. Even in a case where the depth d of the recess is fixed, a sufficient effect can be obtained.

### Example 2

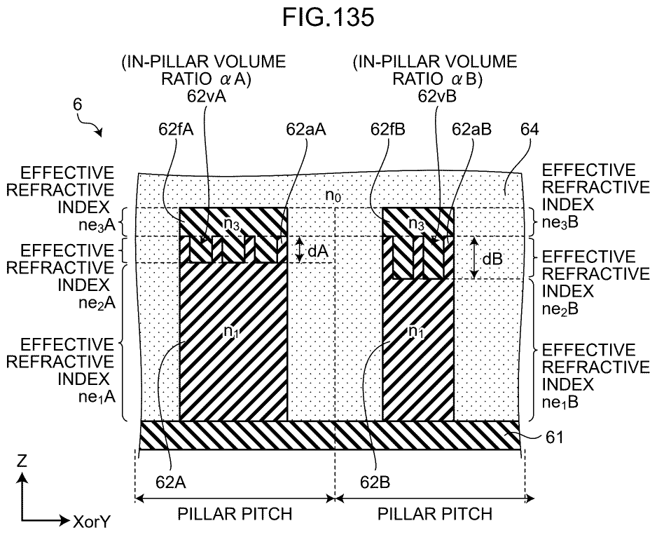

In one embodiment, a film (interlayer film) may be provided between the upper surface 62a of the pillar 62 and the filler 64. This will be described with reference to FIGS. 135 to 138.

FIG. 135 is a diagram illustrating an example of a schematic configuration of the optical layer 6. The optical layer 6 includes an interlayer film 62f. The interlayer film 62f is provided on the upper surface 62a of the pillar 62 so as to fill the recess of the non-flat portion 62v of the upper surface 62a of the pillar 62. The filler 64 is provided on the interlayer film 62f. The refractive index of the interlayer film 62f is referred to as a refractive index n₃. The refractive index n₃ of the interlayer film 62f is larger than the refractive index no of the filler 64 and smaller than the refractive index n₁ of the pillar 62 (n₁>n₃>n₀).

The interlayer film 62f provided on the upper surface 62aA of the pillar 62A is referred to as an interlayer film 62fA in the drawing. The interlayer film 62f provided on the upper surface 62aB of the pillar 62B is referred to as an interlayer film 62fB in the drawing.

In the optical layer 6, the effective refractive index of the region where the interlayer film 62f is located is referred to as an effective refractive index ne₃. Specifically, the effective refractive index ne₃ of the region where the interlayer film 62fA is located is referred to as an effective refractive index ne₃A in the drawing. The effective refractive index ne₃ of the peripheral region where the interlayer film 62fB is located is referred to as an effective refractive index ne₃B in the drawing.

The effective refractive index ne₃ is a value between the refractive index no and the effective refractive index ne₂. In this example, the refractive index no, the effective refractive index ne₃, the effective refractive index ne₂, and the effective refractive index ne₁ increase in this order (n₀<ne₃<ne₂<ne₁). In the optical layer 6, the effective refractive index of each region changes in the order of the refractive index no, the effective refractive index ne₃, the effective refractive index ne₂, and the effective refractive index ne₁ as it advances in the Z-axis negative direction. Light reflection can be further suppressed by changing the effective refractive index stepwise in four stages (increasing the effective refractive index in this example). Note that the interlayer film 62f may be selected from the viewpoint of processing (the degree of freedom in processing increases).

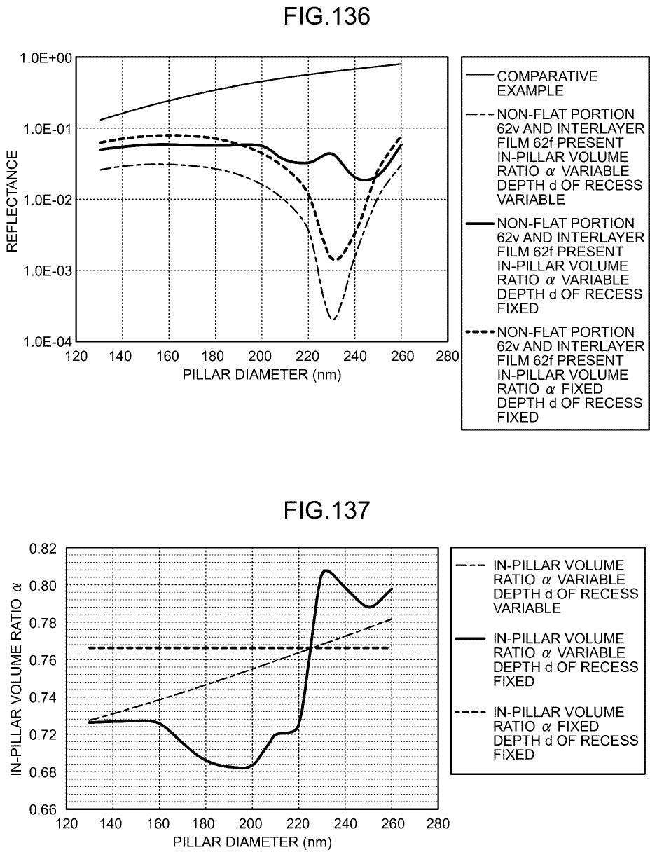

FIG. 136 is a diagram illustrating an example of reflectance. The reflectance (%) at the interface with the peripheral material (for example, the filler 64) when optimized by approximate calculation so as to minimize the maximum reflectance for the following conditions is indicated by a graph. Also in this case, the reflectance is greatly reduced. Note that the thickness of the reflection suppressing film 63 in the comparative example is 142 nm. In a case where the non-flat portion 62v and the interlayer film 62f are present and both the in-pillar volume ratio α and the depth d of the recess are variable, the thickness of the interlayer film 62f is 135 nm. In a case where the non-flat portion 62v and the interlayer film 62f are present, the in-pillar volume ratio α is variable, and the depth d of the recess is fixed, the thickness of the interlayer film 62f is 135 nm. In a case where the non-flat portion 62v and the interlayer film 62f are present and both the in-pillar volume ratio α and the depth d of the recess are fixed, the thickness of the interlayer film 62f is 134 nm.
Wavelength λ: 940 nm
Incident angle: 0 degrees (normal incidence)
Refractive index n0: 1.4 (polymer)
Refractive index n1: 3.6 (amorphous silicon)
Refractive index n3: 2.0 (Si3N4)
Pillar pitch: 350 nm
Pillar diameter: 130 nm to 260 nm

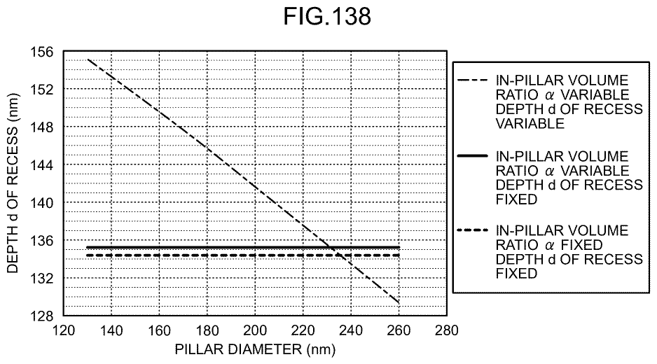

Even in a case where the in-pillar volume ratio α and the depth d of the recess are fixed, the reflectance can be suppressed to 0.04% or less, and a sufficient effect can be obtained. A description will be given with reference to FIGS. 137 and 138.

FIG. 137 is a diagram illustrating an example of the optimized in-pillar volume ratio α. Even if the in-pillar volume ratio α and the depth d are fixed or variable, the optimal in-pillar volume ratio α does not change so much. Even in a case where the in-pillar volume ratio α is fixed, a sufficient effect can be obtained.

FIG. 138 is a diagram illustrating an example of the optimized depth d of the recess. Even if the in-pillar volume ratio α and the depth d are fixed or variable, the optimal depth d of the recess does not change so much. Even in a case where the depth d of the recess is fixed, a sufficient effect can be obtained.

### Example 3

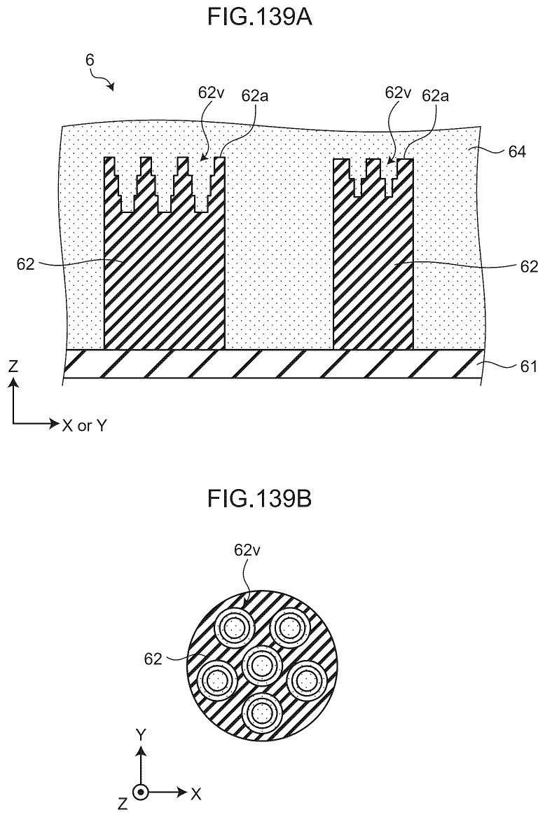

Some examples of the shape of the non-flat portion 62v will be described with reference to FIGS. 139 to 141.

FIGS. 139 to 141 are diagrams illustrating examples of shapes of the non-flat portion 62v and a peripheral structure thereof. Note that the pillar 62A and the pillar 62B are not distinguished from each other, and are simply described as a pillar 62. The same applies to the other portions. (B) of each drawing schematically illustrates a cross section of a portion including the non-flat portion 62v in plan view (as viewed in the Z-axis direction). The effective refractive index changes stepwise in the Z-axis direction.

In the example illustrated in FIG. 139, the cross-sectional area of the recess of the non-flat portion 62v when viewed in the depth direction (Z-axis negative direction) decreases stepwise as it advances in the depth direction. It can also be said that the recess has a stair shape.

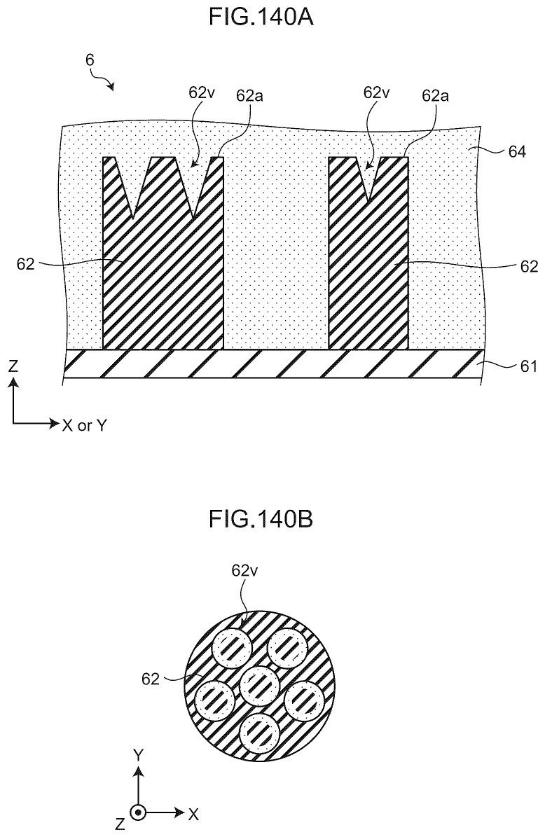

In the example illustrated in FIG. 140, the cross-sectional area of the recess of the non-flat portion 62v continuously decreases as it advances in the depth direction. It can also be said that the inside of the recess has a tapered shape.

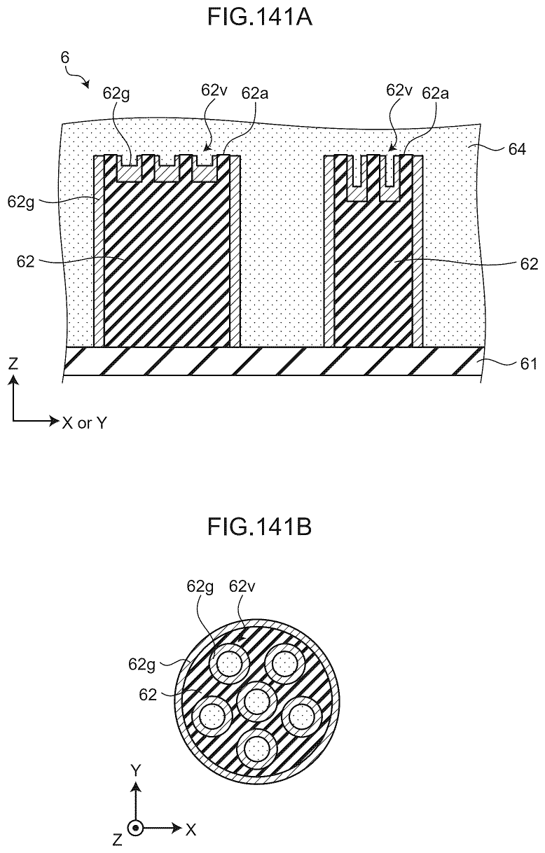

In the example illustrated in FIG. 141, the optical layer 6 includes a thin film 62g. The thin film 62g is provided in the recess of the non-flat portion 62v (for example, on the bottom surface) and on the side surface 62c of the pillar 62. The filler 64 is provided so as to cover the pillar 62 and the thin film 62g. The filler 64 is also provided on the thin film 62g located in the recess so as to fill the recess covered with the thin film 62g. The refractive index of the thin film 62g may be similar to the refractive index of the interlayer film 62f described above. By making the thin film 62g multilayered, the effective refractive index further changes stepwise.

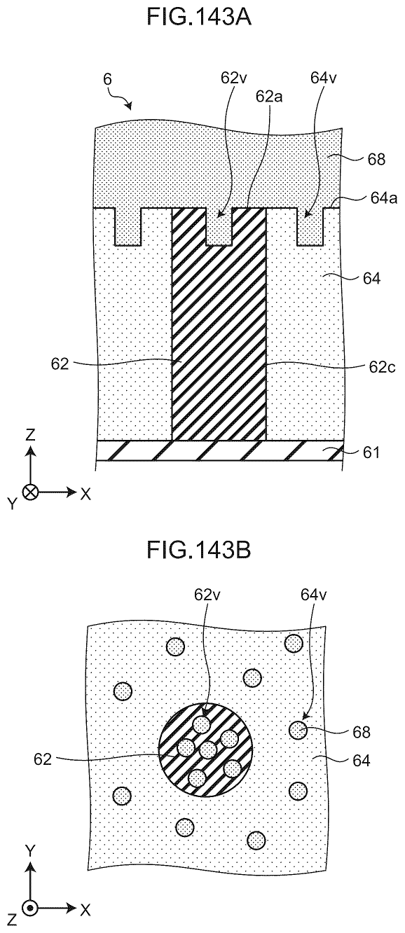

Note that not the filler 64 but an upper layer film (upper layer film 68 in FIG. 143 and the like) described later may be provided so as to fill the recess covered with the thin film 62g.

### Example 4

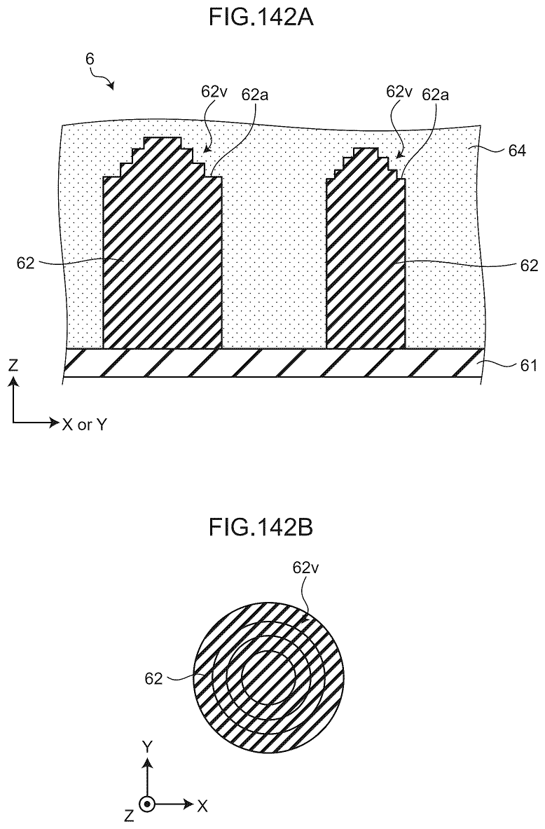

Some examples of further shapes of the non-flat portion 62v will be described with reference to FIGS. 142 to 148.

FIGS. 142 to 148 are diagrams illustrating examples of shapes of the non-flat portion 62v and a peripheral structure thereof. The effective refractive index changes stepwise in the Z-axis direction.

In the example illustrated in FIG. 142, the cross-sectional area of the protrusion of the non-flat portion 62v when viewed in the height direction (Z-axis positive direction) decreases stepwise as it advances in the height direction. It can also be said that the protrusion has a stair shape.

In the example illustrated in FIG. 143, the filler 64 is provided between adjacent pillars 62 along the side surface 62c of the pillar 62. The upper surface of the filler 64 is referred to as an upper surface 64a in the drawing. In this example, the upper surface 64a of the filler 64 has a non-flat portion 64v. The non-flat portion 64v includes at least one of a recess and a protrusion. A more specific shape may be similar to the non-flat portion 62v of the pillar 62 described above.

The optical layer 6 includes an upper layer film 68. The upper layer film 68 is provided so as to cover the pillars 62 and the filler 64. Specifically, the upper layer film 68 is provided on the upper surface 62a of the pillar 62 and the upper surface 64a of the filler 64 so as to fill the recess of the non-flat portion 62v of the pillar 62 and the recess of the non-flat portion 64v of the filler 64. The material of the upper layer film 68 may be a material different from the filler 64, and the refractive indexes thereof may be different from each other. For example, the refractive index of the upper layer film 68, the refractive index of the filler 64, and the refractive index of the pillar 62 increase in this order.

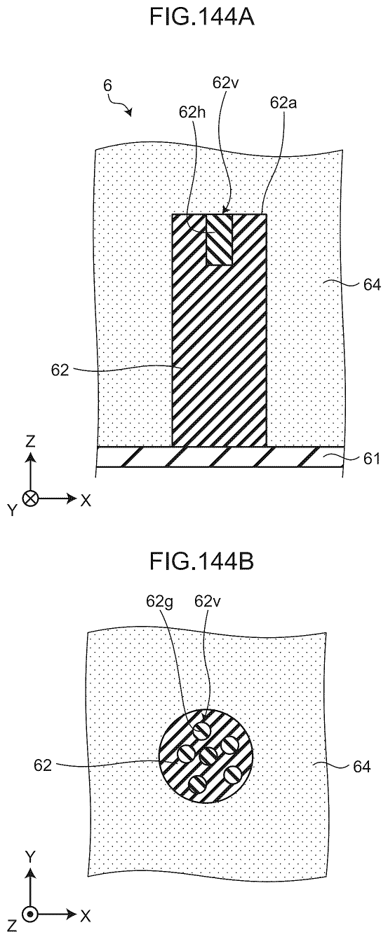

In the example illustrated in FIG. 144, the optical layer 6 includes a heterogeneous film 62h. The heterogeneous film 62h may have a refractive index between the refractive index of the filler 64 and the refractive index of the pillar 62. The heterogeneous film 62h is provided so as to fill the recess of the non-flat portion 62v. Note that the heterogeneous film 62h may not be provided, and in that case, the recess is a void (has a cavity).

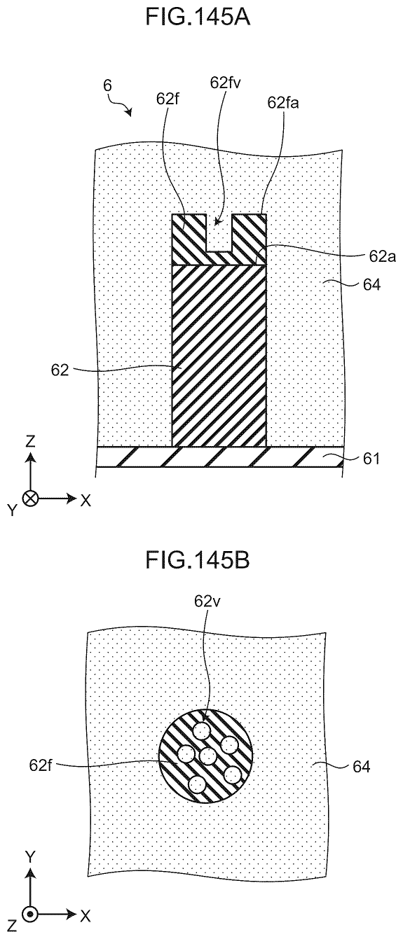

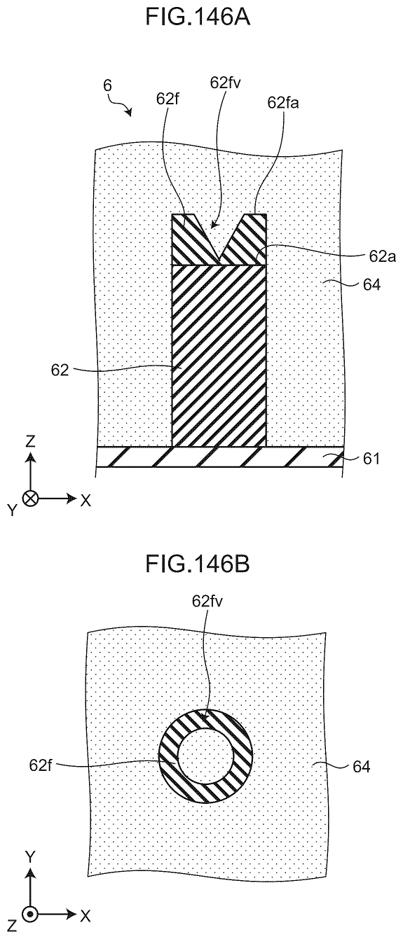

In the example illustrated in FIGS. 145 and 146, the interlayer film 62f is provided on the upper surface 62a of the pillar 62. An upper surface 62fa of the interlayer film 62f has a non-flat portion 62fv. The shape of the non-flat portion 62fv may be similar to the shape of the non-flat portion 62v described above, and the description will not be repeated. The filler 64 is provided so as to fill the non-flat portion 62fv.

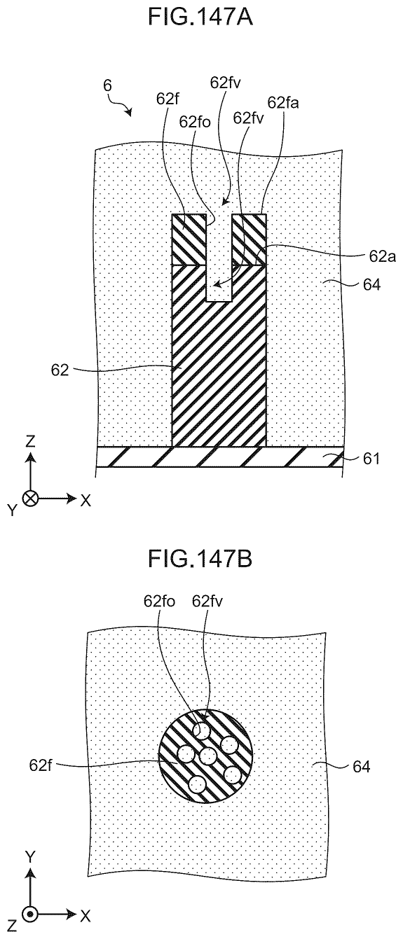

In the example illustrated in FIG. 147, the non-flat portion 62fv of the interlayer film 62f has an opening 62fo. The opening 62fo communicates with the recess of the non-flat portion 62v of the upper surface 62a of the pillar 62.

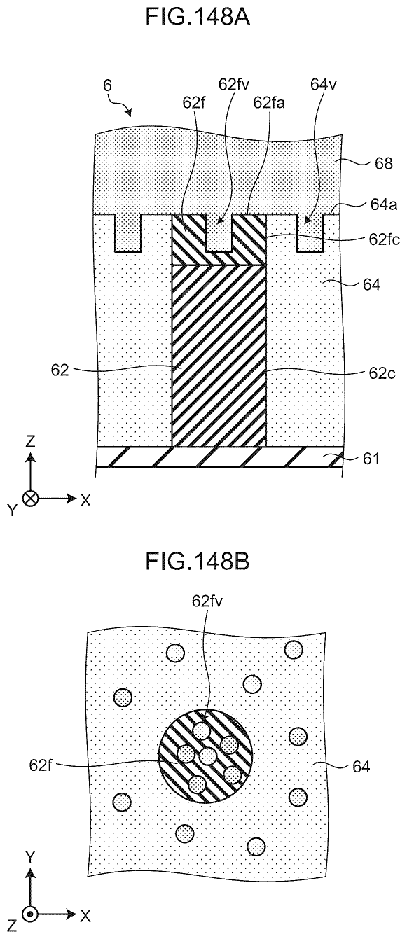

In the example illustrated in FIG. 148, the interlayer film 62f is provided on the upper surface 62a of the pillar 62. The upper surface 62fa of the interlayer film 62f has the non-flat portion 62fv. The filler 64 is provided between the pillars 62 and the interlayer films 62f adjacent to each other along the side surface 62c of the pillar 62 and the side surface 62fc of the interlayer film 62f. The upper layer film 68 is provided on the upper surface 62fa of the interlayer film 62f and the upper surface 64a of the filler 64 so as to fill the recess of the non-flat portion 62fv of the interlayer film 62f and the recess of the non-flat portion 64v of the filler 64.

### <Example of Manufacturing Method>

FIGS. 149 to 182 are diagrams illustrating an example of a manufacturing method. (A) of each drawing schematically illustrates a cross section of a characteristic portion in plan view (as viewed in the 2-axis direction). (B) of each drawing illustrates a cross section of the characteristic portion when viewed in side view (when viewed in the Y-axis direction).

### Example 5

FIGS. 149 to 154 illustrate an example of a manufacturing method capable of obtaining the non-flat portion 62v in which the in-pillar volume ratio α and the depth d of the recess are variable.

As illustrated in FIG. 149, the pillar material 62m is formed on a substrate, in this example, on the reflection suppressing film 61, and the photoresist PR is formed thereon. For example, hole patterns PRhp having different area ratios and depths are formed in the photoresist PR of the pillar region using a nanoimprint lithography technique.

As illustrated in FIG. 150, dry etching using the photoresist PR as a mask is performed to form hole patterns 62hp having different area ratios and depths on the pillar material 62m.

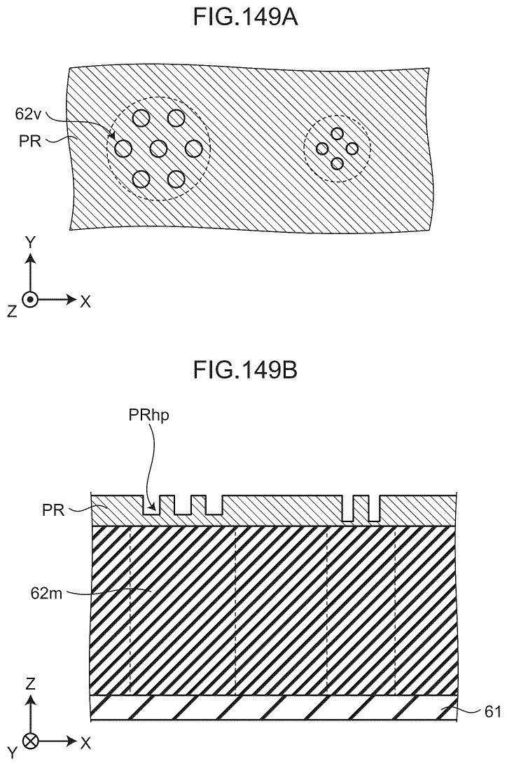

As illustrated in FIG. 151, after the photoresist PR is removed, a hard mask HM is formed.

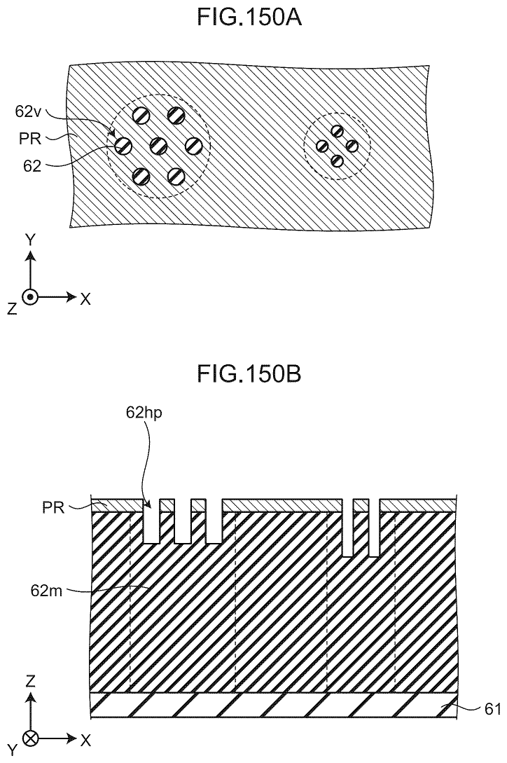

As illustrated in FIG. 152, the photoresist PR having a pattern matching the pillar shape is formed on the hard mask HM using an optical lithography technique.

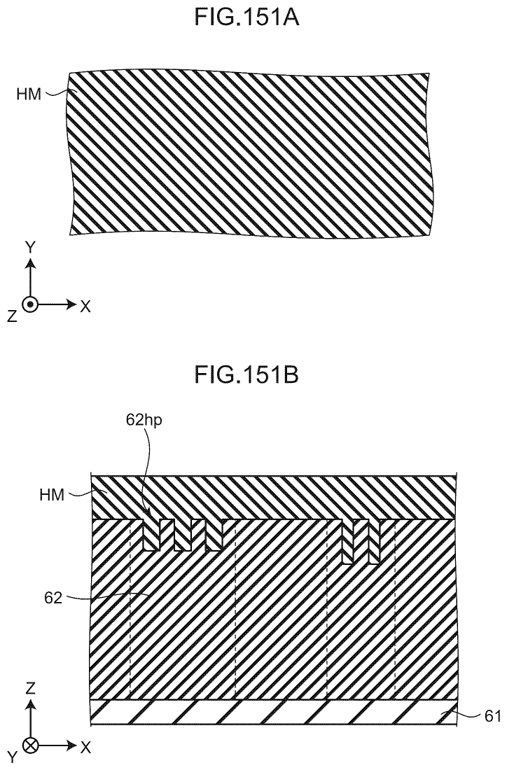

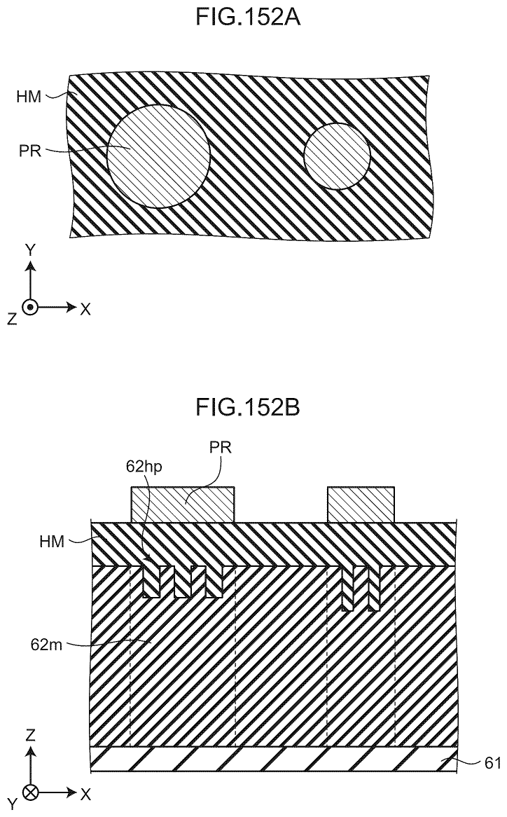

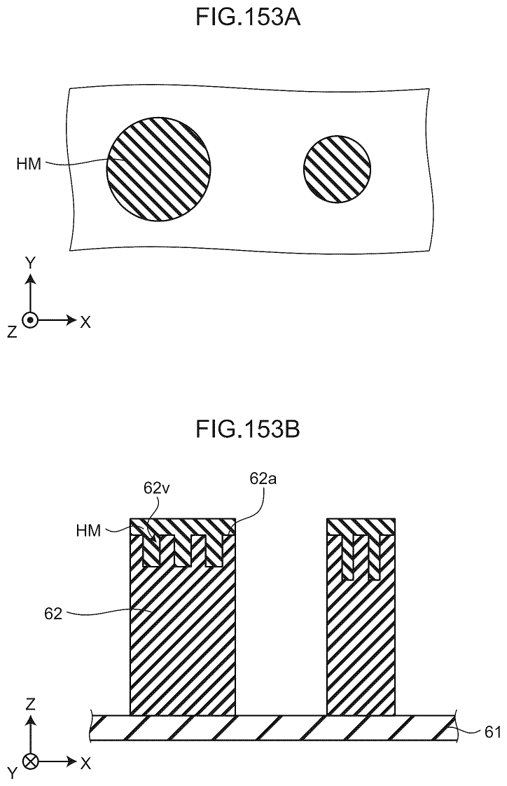

As illustrated in FIG. 153, dry etching using the photoresist PR as a mask is performed, and dry etching using the hard mask HM as a mask is further performed. The pillar 62 having the non-flat portion 62v on the upper surface 62a is obtained.

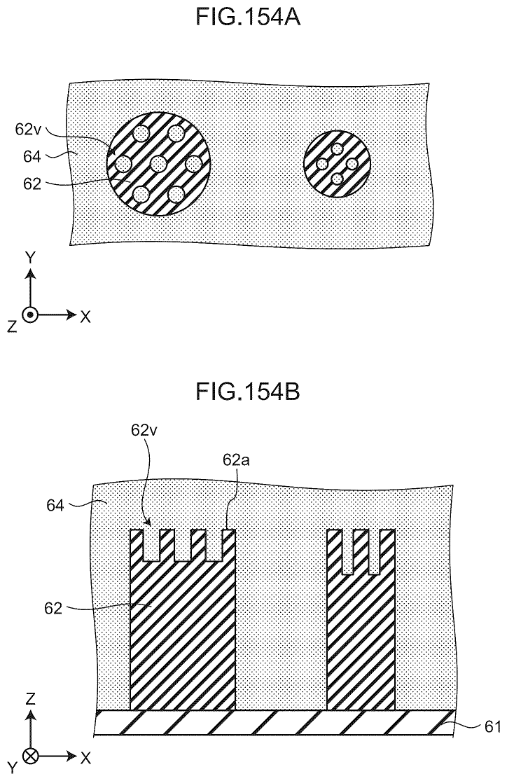

As illustrated in FIG. 154, after the hard mask HM is removed, the filler 64 is formed so as to cover the pillars 62.

### Example 6

FIGS. 155 to 162 illustrate an example of a manufacturing method capable of obtaining the non-flat portion 62v in which the in-pillar volume ratio α is variable.

As illustrated in FIG. 155, the pillar material 62m and the hard mask HM are formed on the substrate, that is, on the reflection suppressing film 61 in this example. A neutral material N (specifically, PS-r-PMMA) is applied thereon in a thickness of, for example, about 8 nm, and a self-assembling material S (specifically, PS-b-PMMA) is further applied in a thickness of, for example, about 60 nm.

As illustrated in FIG. 156, in the upper portion of the pillar material 62m, a region where a non-flat portion is not formed is irradiated with light having a wavelength of 193 nm, for example, through the mask M. The irradiated light is schematically indicated by white arrows in (B) of FIG. 156. The PS in the self-assembling material S in the light-irradiated region is crosslinked.

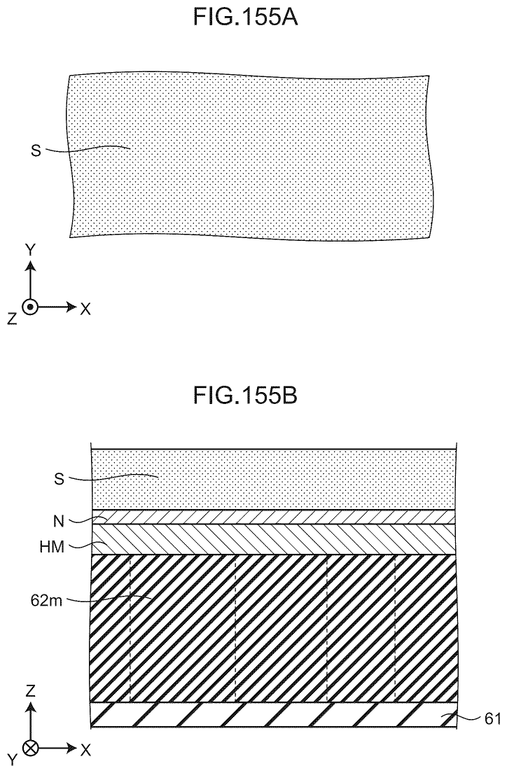

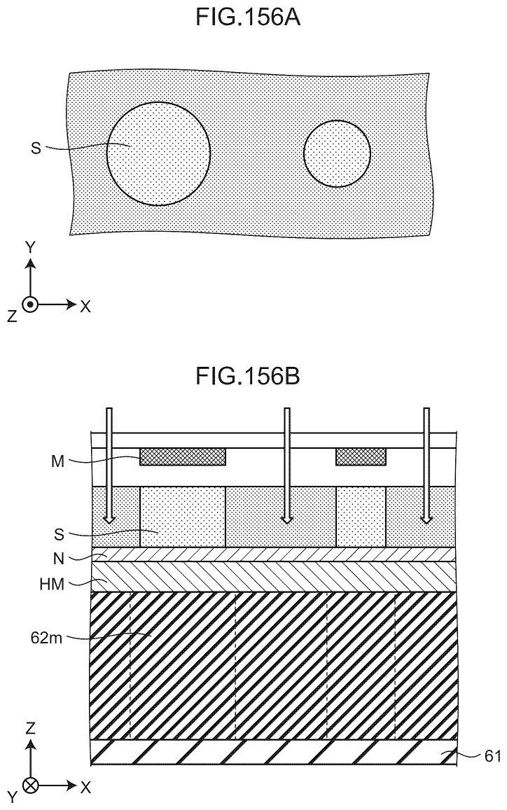

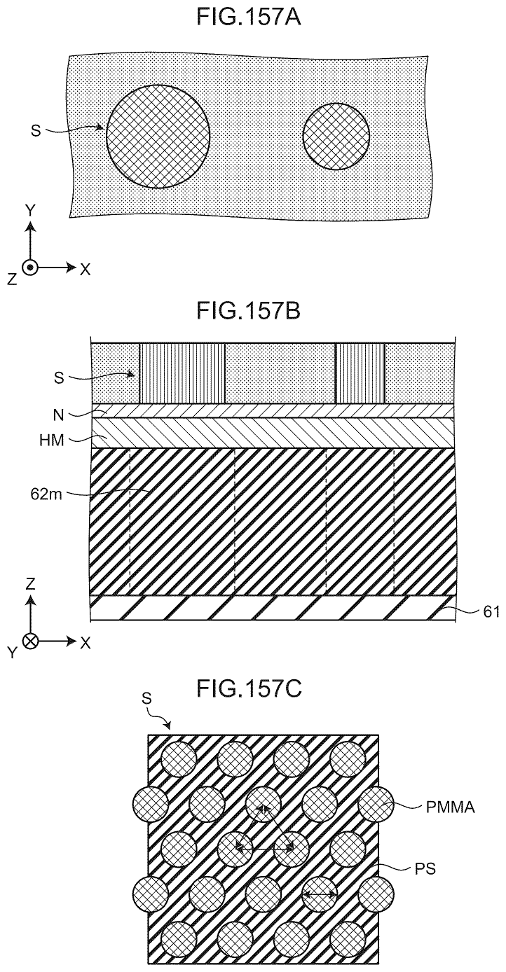

As illustrated in FIG. 157, the substrate is baked under a N₂ atmosphere, for example, at a temperature of about 250° C. for about 5 minutes. As a result, the self-assembling material S that is not crosslinked is phase-separated into PS and cylindrical PMMA. (C) of FIG. 157 schematically illustrates PMMA and PS in the self-assembling material S. For example, the diameter of PMMA is about 26 nm, and the distance between PMMAs is about 40 nm.

Thereafter, the entire surface is irradiated with UV light having a wavelength of 172 nm, for example. This completely crosslinks the PS and cleaves the PMMA.

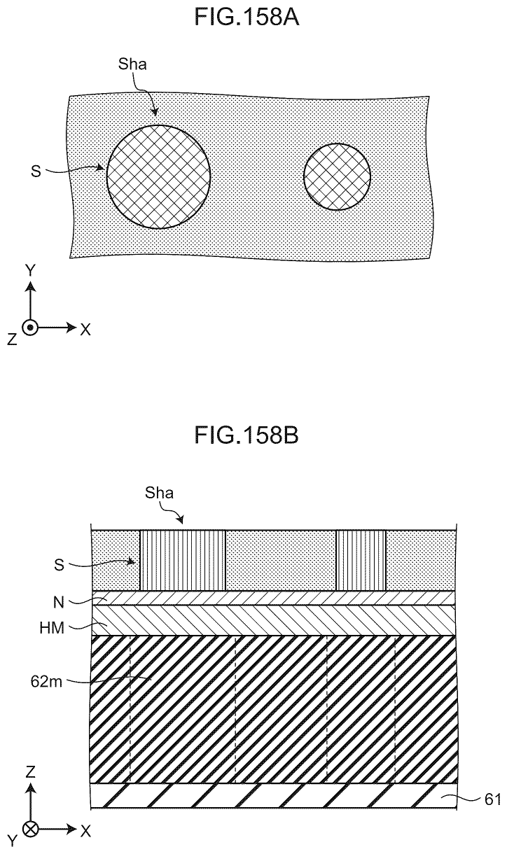

As illustrated in FIG. 158, only PMMA is completely removed with an organic developer which is IPA. As a result, a fine hole array Sha is formed.

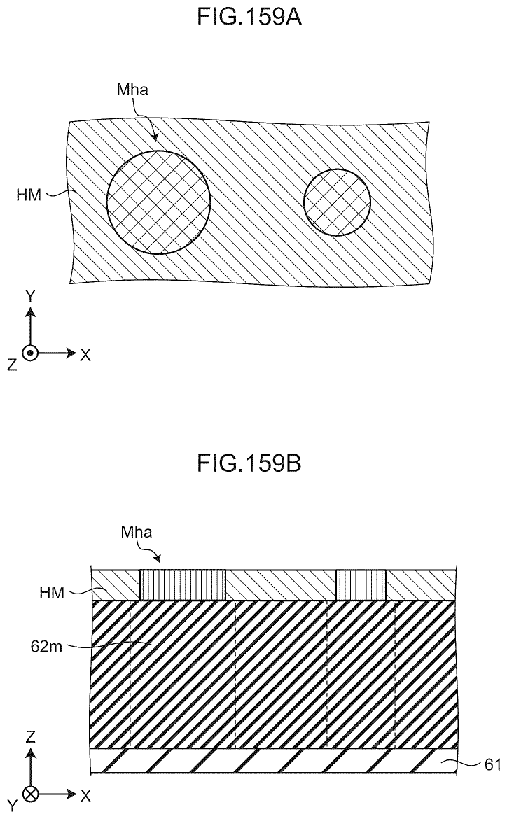

As illustrated in FIG. 159, the fine hole array Mha is formed in the hard mask HM by dry etching. At this time, a desired hole diameter is adjusted according to etching conditions. Thereafter, the self-assembling material S and the neutral material N are removed.

As illustrated in FIG. 160, dry etching is performed using the hard mask HM as a mask to form the fine hole array 62mha on the pillar material 62m.

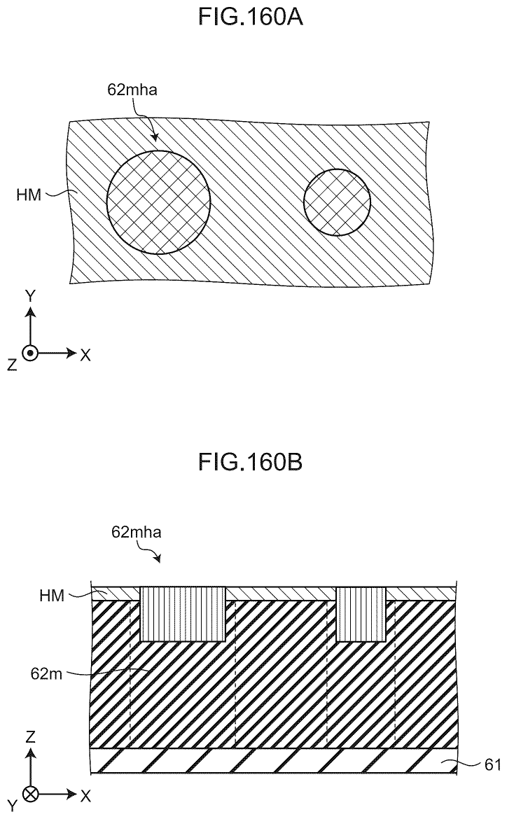

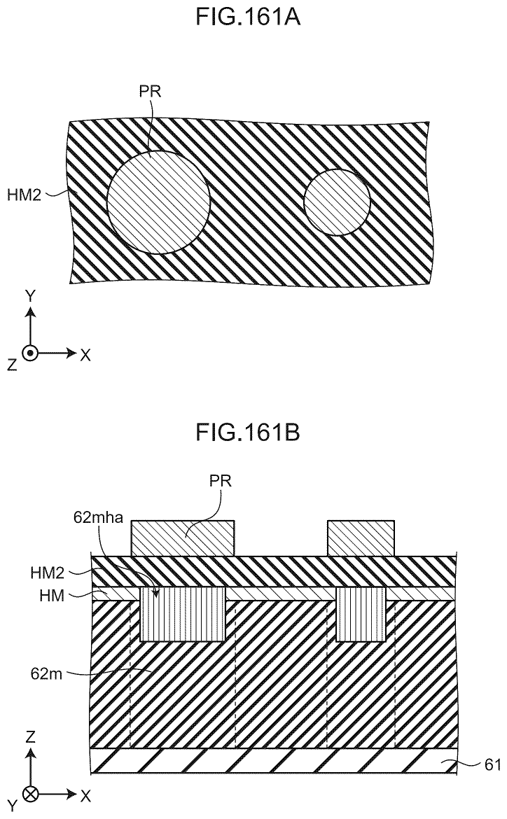

As illustrated in FIG. 161, a hard mask HM2 is formed on the upper portion. Thereafter, the photoresist PR having a pattern matching the pillar shape is formed using an optical lithography technique.

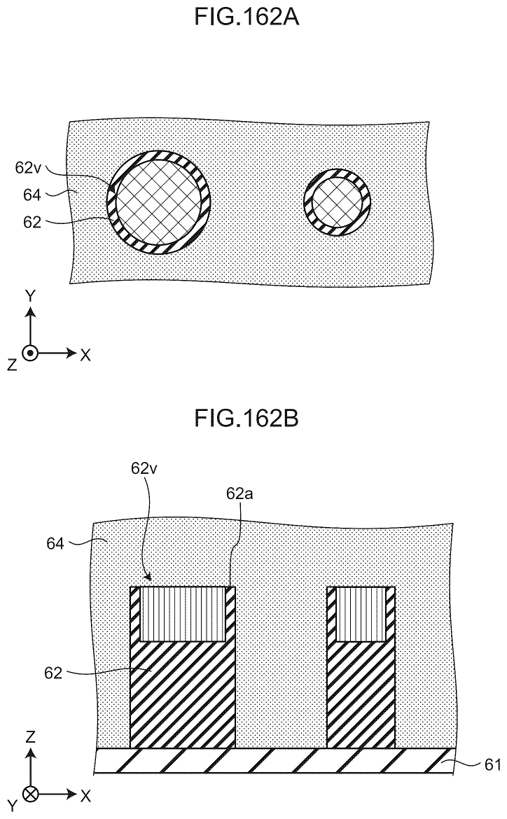

As illustrated in FIG. 162, the pillar 62 is formed and the filler 64 is further formed by a process similar to the process described above with reference to FIGS. 153 and 154 and the like. The fine hole array 62mha becomes the non-flat portion 62v, and the pillar 62 having the non-flat portion 62v on the upper surface 62a is obtained.

### Example 7

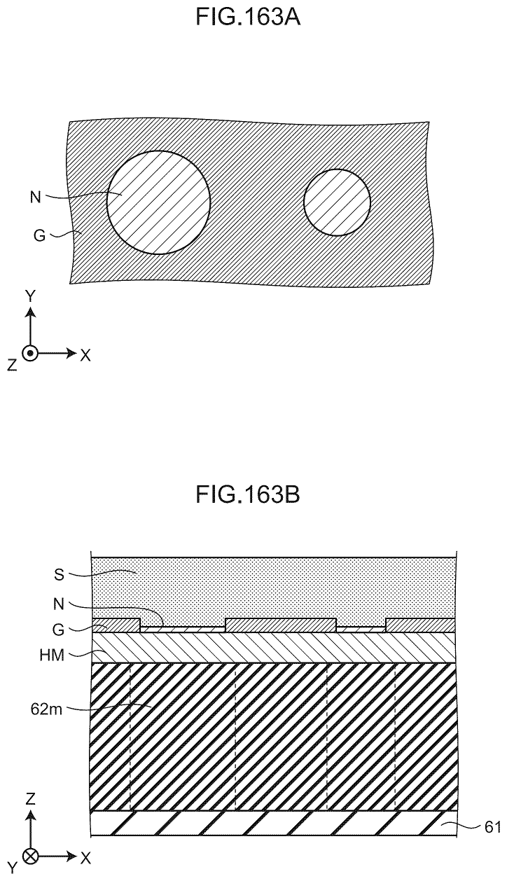

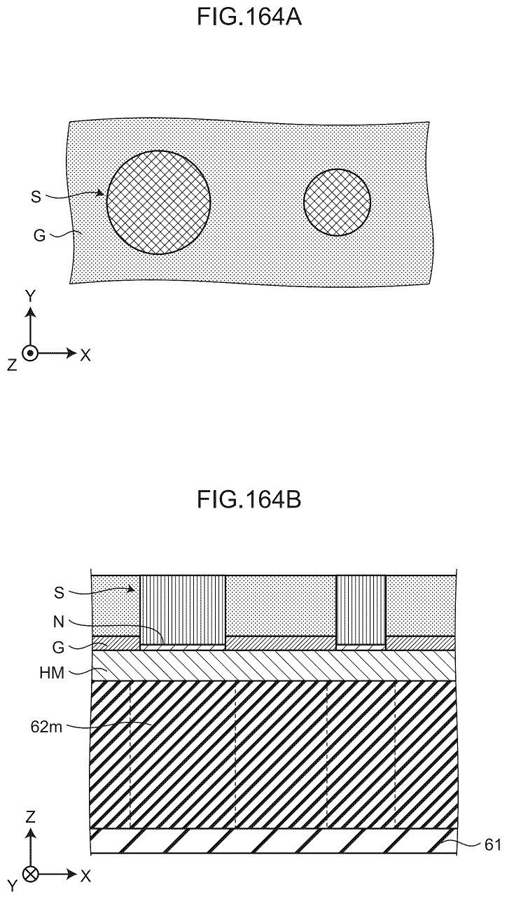

FIGS. 163 and 164 illustrate an example of a manufacturing method capable of obtaining the non-flat portion 62v in which the in-pillar volume ratio α is variable.

As illustrated in FIG. 163, the pillar material 62m and the hard mask HM are formed on the substrate, that is, on the reflection suppressing film 61 in this example. A region where the non-flat portion is not formed is covered with the guide pattern G. The neutral material N is applied to a region where there is no guide pattern G, and the self-assembling material S is applied. The coating thickness may be similar to that described above.

As illustrated in FIG. 164, phase separation is performed only in a region where the guide pattern G is opened by a self-assembling process. By a process similar to the process described above with reference to FIGS. 158 to 162 and the like, the pillar 62 in which the upper surface 62a has the non-flat portion 62v is obtained.

### Example 8

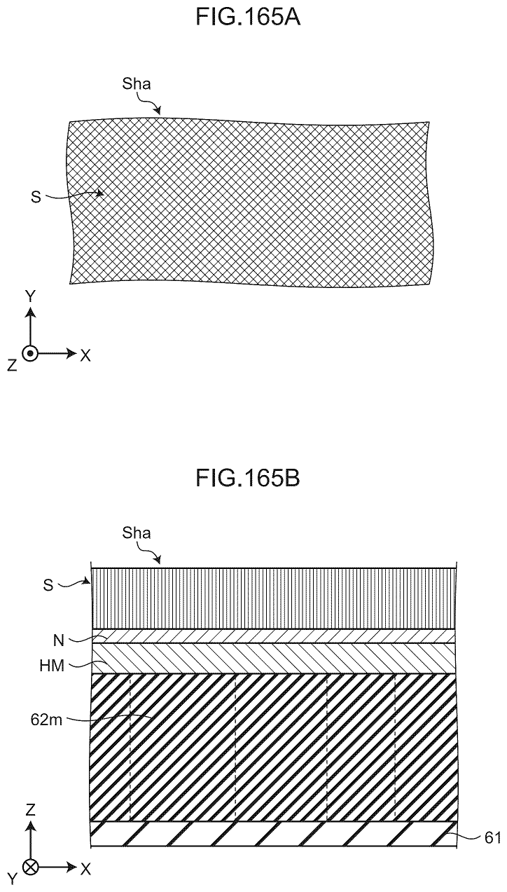

FIGS. 165 to 169 illustrate an example of a manufacturing method capable of obtaining the non-flat portion 62v having a uniform uneven pattern. As a premise, it is assumed that the process of FIG. 155 described above is completed.

As illustrated in FIG. 165, a phase separation pattern is formed by a self-assembling process.

Thereafter, the fine hole array Sha is formed by UV irradiation and organic development.

As illustrated in FIG. 166, the fine hole array Sha formed by the self-assembling process is transferred to the hard mask HM by dry etching. It is further transferred to the pillar material 62m. Thereafter, the self-assembling material S itself and the hard mask HM are removed. The fine hole array 62mha is formed on the pillar material 62m.

As illustrated in FIG. 167, the hard mask HM is formed on the upper portion. Thereafter, the photoresist PR having a pattern matching the pillar shape is formed using an optical lithography technique.

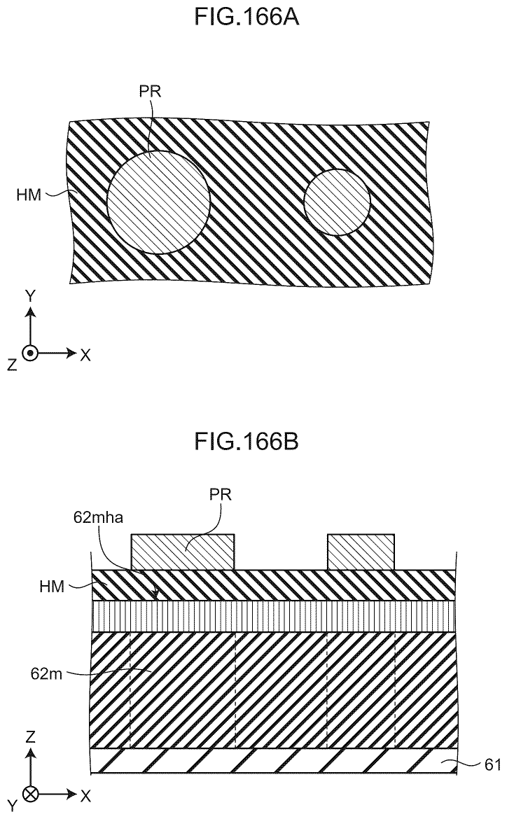

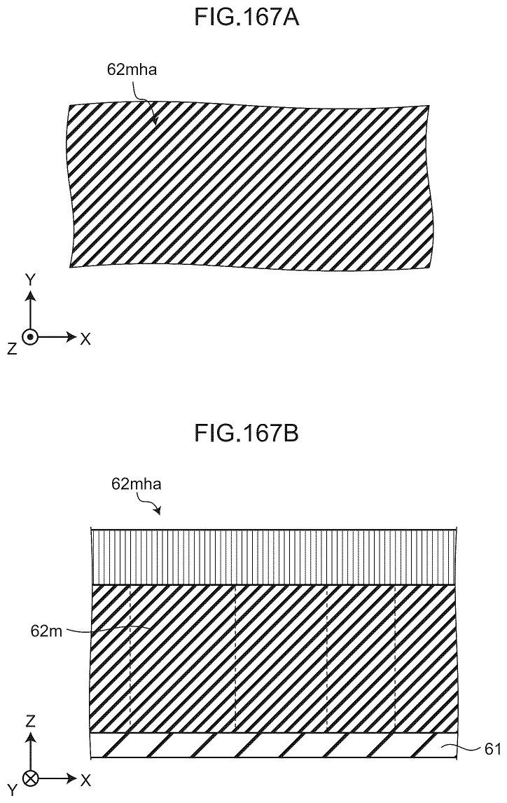

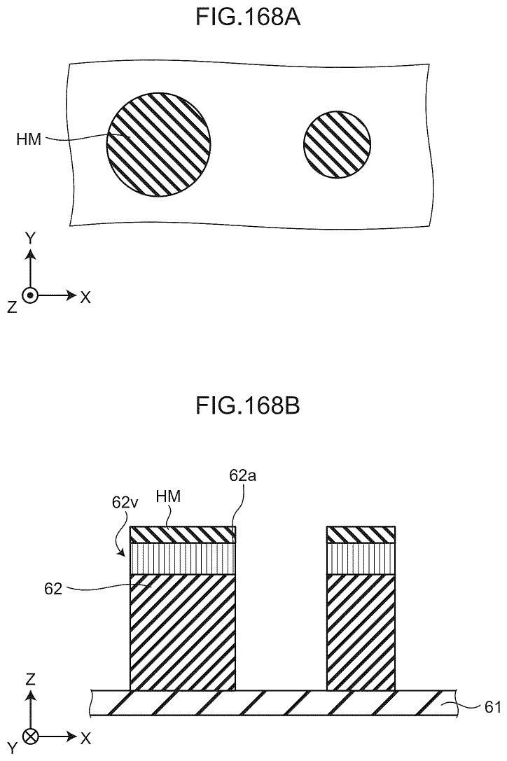

As illustrated in FIG. 168, the hard mask HM is dry-etched using the photoresist PR as a mask, and the pillar material 62m is dry-etched using the hard mask HM as a mask. The fine hole array 62mha becomes the non-flat portion 62v, and the pillar 62 having the non-flat portion 62v on the upper surface 62a is obtained.

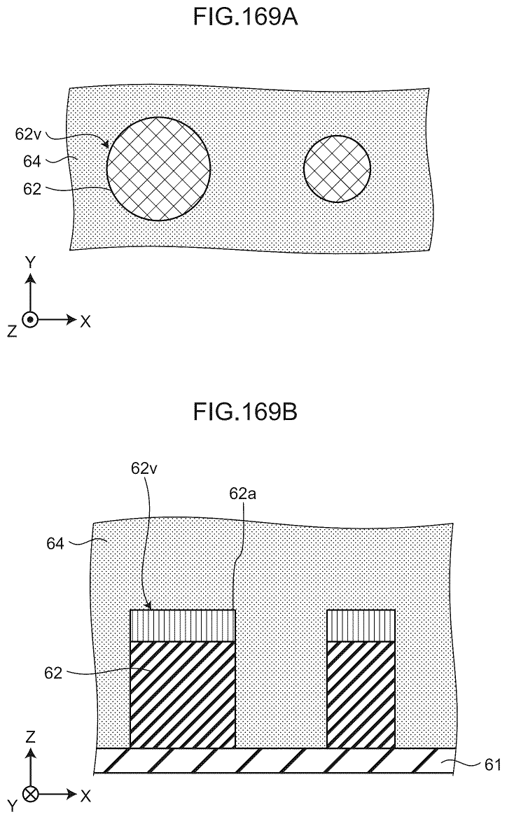

As illustrated in FIG. 169, after the hard mask HM is removed, the filler 64 is deposited.

### Example 9

FIGS. 170 to 172 illustrate an example of a manufacturing method capable of obtaining the non-flat portion 62v having a uniform uneven pattern.

As illustrated in FIG. 170, the pillar material 62m is formed on the substrate, that is, on the reflection suppressing film 61 in this example. Thereafter, the surface is roughened with Ar plasma to form the uneven layer CC.

As illustrated in FIG. 171, the ALD film A is formed using the ALD technique.

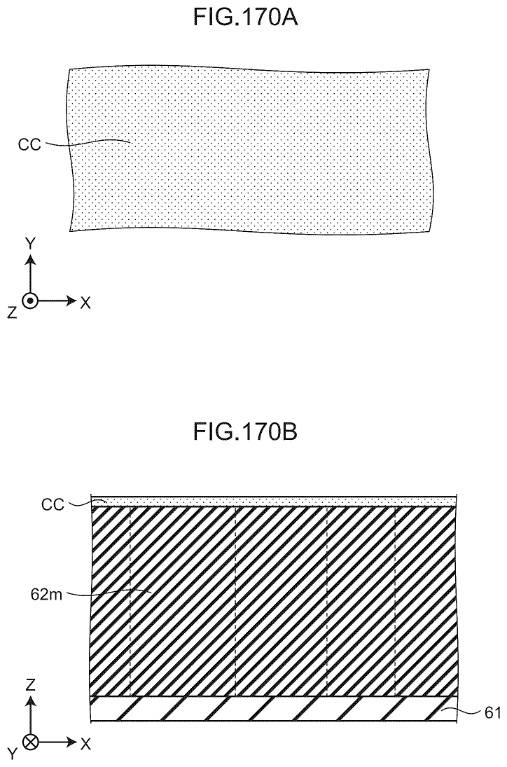

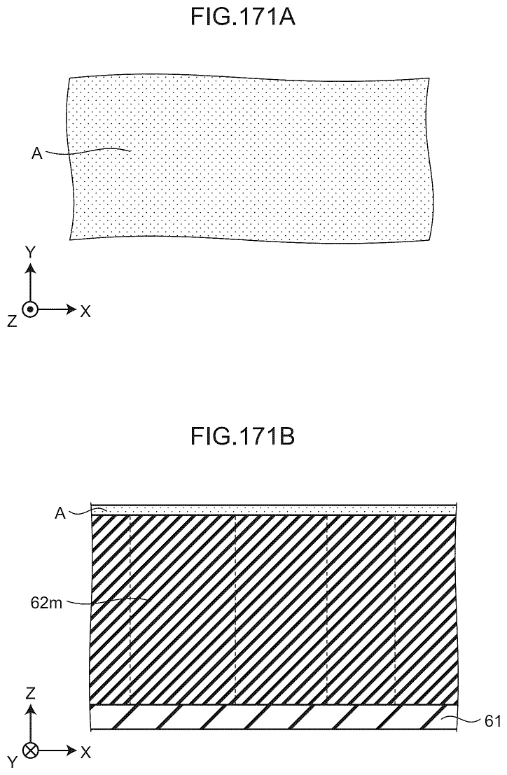

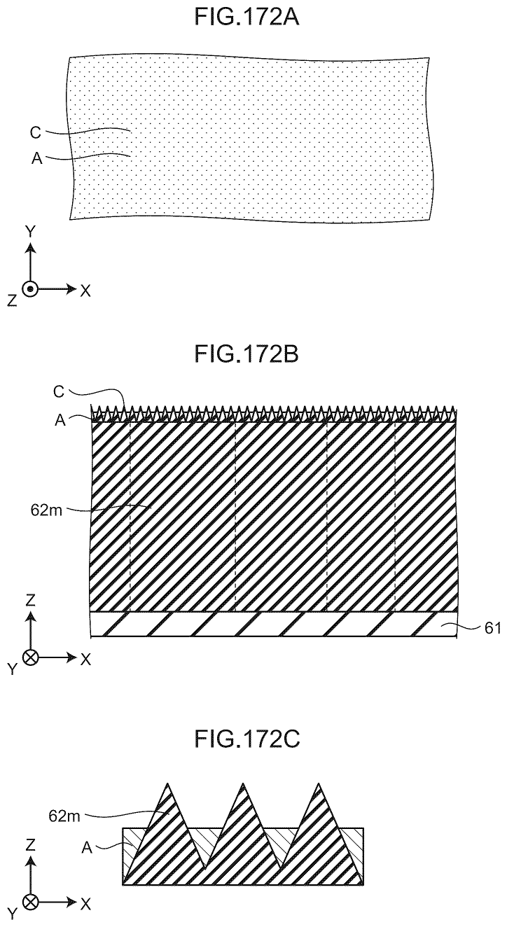

As illustrated in FIG. 172, the ALD film A is etched back to expose the protrusions on the upper portion of the pillar material 62m. Note that (C) of FIG. 172 schematically illustrates an enlarged view of the portion. Thereafter, the pillar material 62m is etched using the remaining ALD film A as a mask to form a fine hole array on the pillar material 62m. Since the subsequent process is similar to that described above, the description thereof is omitted.

### Example 10

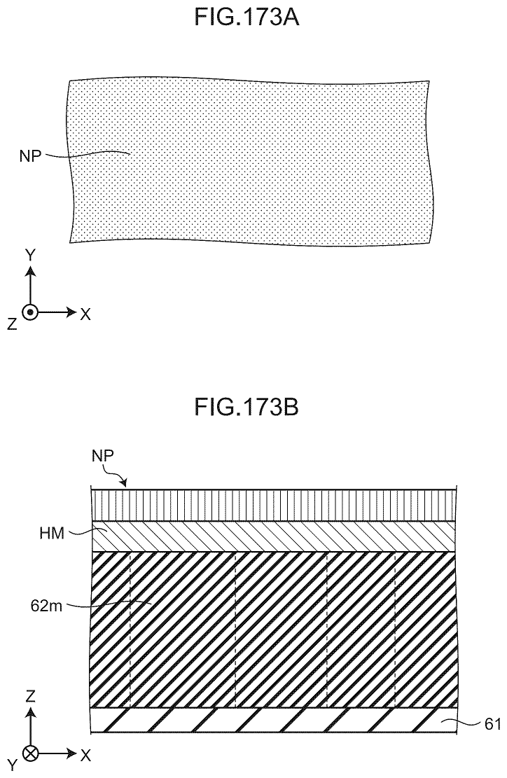

FIG. 173 illustrates an example of a manufacturing method capable of obtaining the non-flat portion 62v having a uniform uneven pattern. The pillar material 62m and the hard mask HM are formed on the substrate, that is, on the reflection suppressing film 61 in this example. Nanoparticles NP are sprayed thereon. By etching the hard mask HM using the nanoparticles NP as a mask, a fine hole array is formed on the pillar material 62m. Since the subsequent process is similar to that described above, the description thereof is omitted.

### Example 11

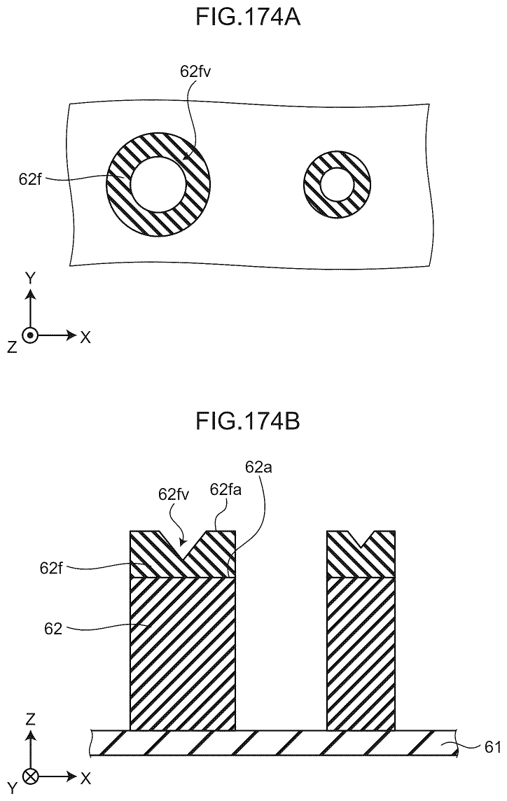

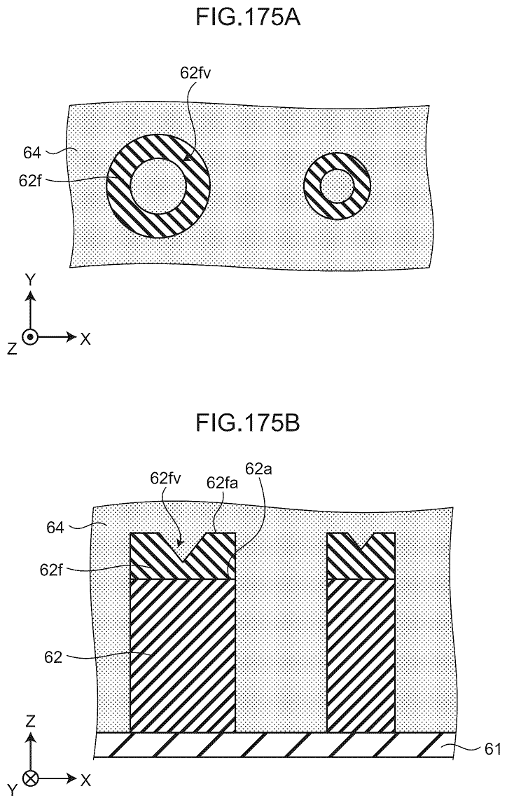

FIGS. 174 and 175 illustrate an example of a manufacturing method capable of obtaining the upper layer reflection suppressing film, more specifically, the interlayer film 62f having the non-flat portion 62fv and provided on the upper surface 62a of the pillar 62.

As illustrated in FIG. 174, the pillars 62 are formed on the substrate, that is, on the reflection suppressing film 61 in this example, using a lithography technique and a dry etching technique. At this time, the pattern of the interlayer film 62f is used as a mask. The non-flat portion is formed on the upper portion of the pattern by etching under the condition that the deposition from the periphery is large. The upper portion has a small deposition and is easily etched. The interlayer film 62f in which the upper surface 62fa has the non-flat portion 62fv is obtained.

As illustrated in FIG. 175, the filler 64 is deposited.

### Example 12

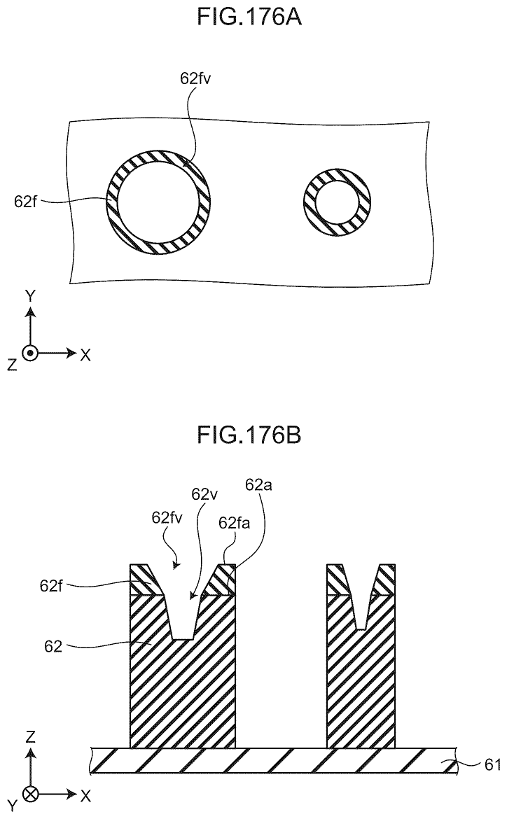

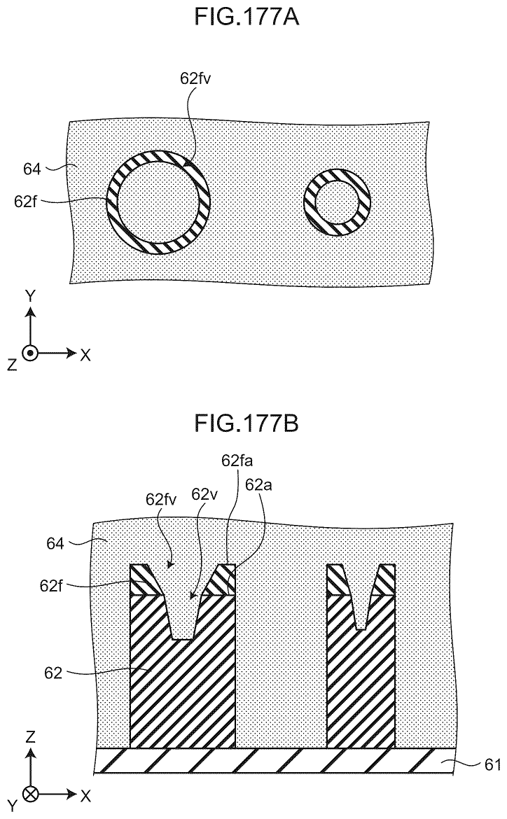

FIGS. 176 and 177 illustrate an example of a manufacturing method capable of obtaining the interlayer film 62f in which the upper surface 62fa has the non-flat portion 62fv and the pillar 62 in which the upper surface 62a has the non-flat portion 62v. As a premise, it is assumed that the process of FIG. 174 described above is completed.

As illustrated in FIG. 176, the pattern of the interlayer film 62f is etched back, and the pillars 62 are dry-etched using the interlayer film 62f as a mask. The interlayer film 62f having the non-flat portion 62fv on the upper surface 62fa and the pillar 62 having the non-flat portion 62v on the upper surface 62a are obtained. In this example, both the non-flat portion 62fv and the non-flat portion 62v have a tapered shape.

As illustrated in FIG. 177, the filler 64 is deposited.

### Example 13

FIGS. 178 to 181 illustrate an example of a manufacturing method capable of obtaining the non-flat portion 62v having a cross-sectional area changing stepwise (in stages).

As illustrated in FIG. 178, the hard mask HM and the hard mask HM2 are formed on the pillar material 62m. Thereafter, the photoresist PR having a pattern matching the pillar shape is formed using an optical lithography technique. The hard mask HM2 is dry-etched using the photoresist PR as a mask.

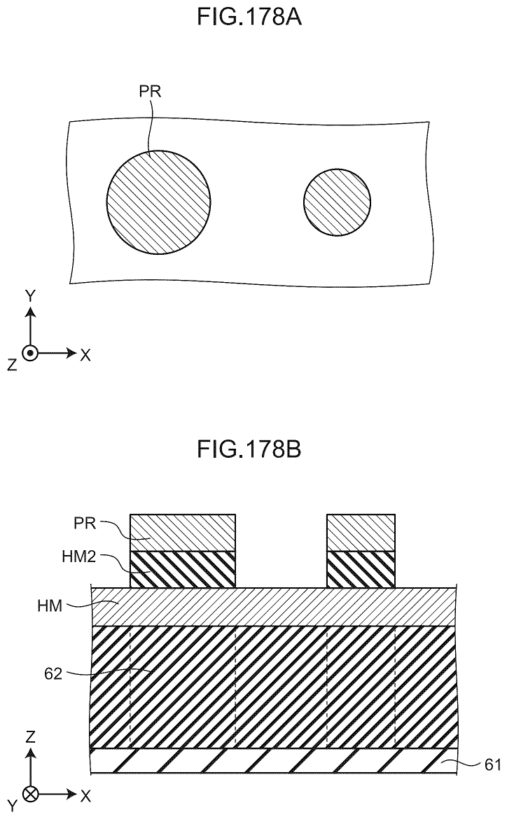

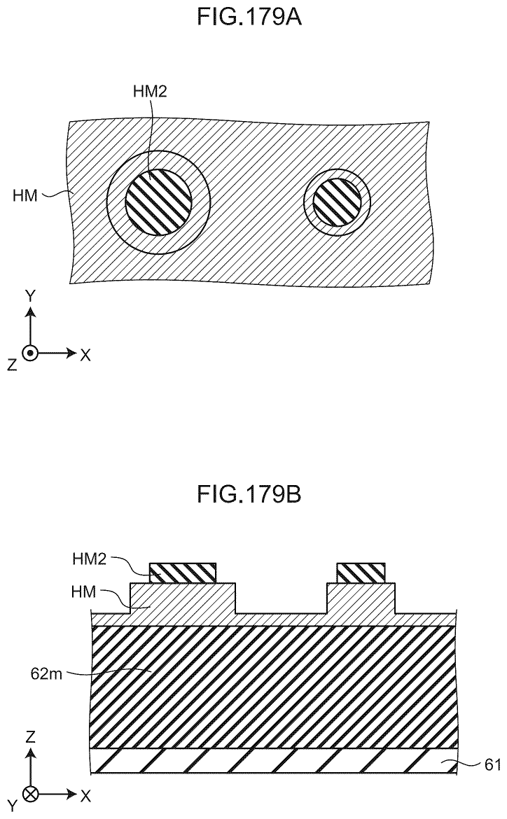

As illustrated in FIG. 179, the hard mask HM is anisotropically dry-etched using the pattern of the hard mask HM2 as a mask. Thereafter, the hard mask HM2 is isotropically etched.

As illustrated in FIG. 180, the stepwise hard mask HM is obtained by repeating the anisotropic etching and the isotropic etching to etch back the hard mask HM.

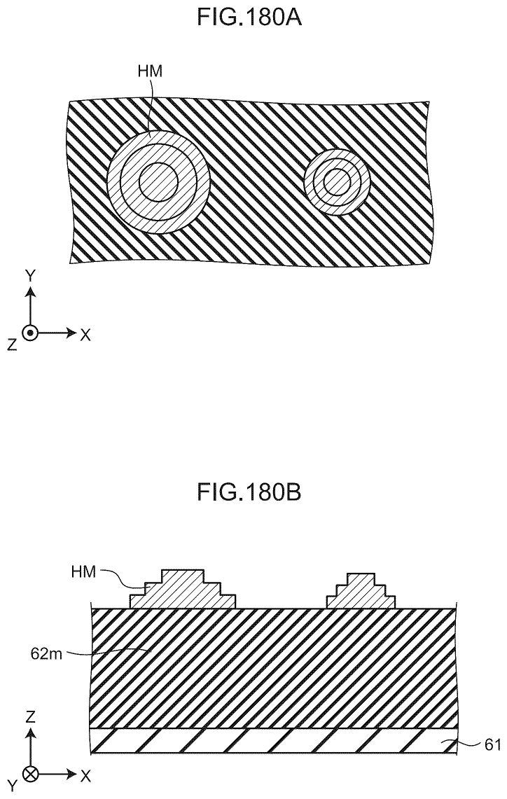

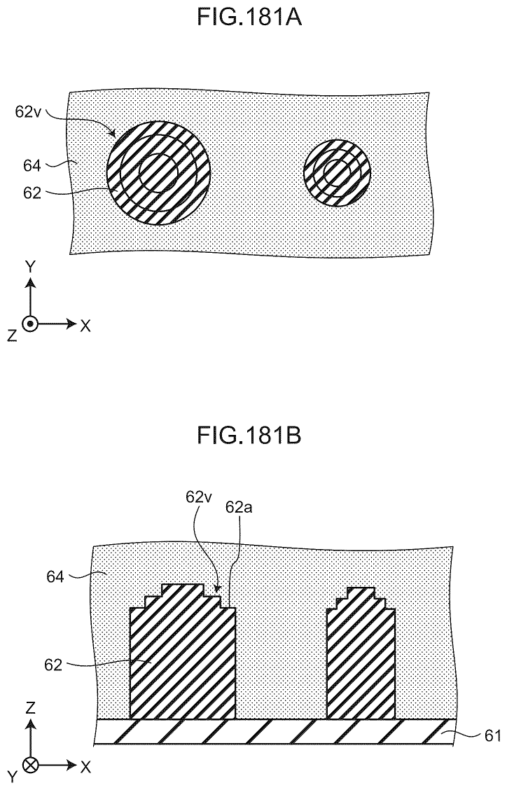

As illustrated in FIG. 181, the pillar material 62m is dry-etched using the hard mask HM as a mask. The pillar 62 having the non-flat portion 62v on the upper surface 62a is obtained. Thereafter, a film of the filler 64 is formed.

### Example 14

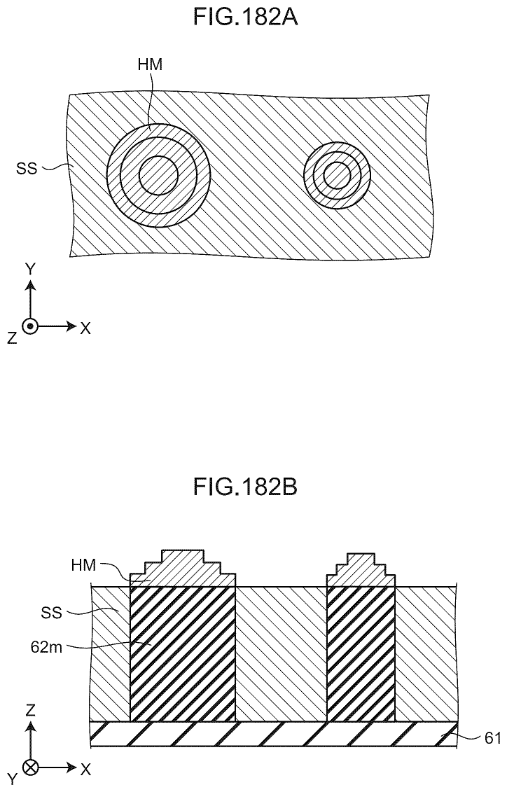

FIG. 182 illustrates an example of a manufacturing method capable of obtaining the non-flat portion 62v in which the cross-sectional area changes stepwise (in stages).

As illustrated in FIG. 182, after the pillar material 62m is formed, a sacrificial layer SS is formed in the periphery. Thereafter, as described above with reference to FIG. 180 and the like, the stepwise hard mask HM is formed. By anisotropically etching the pillar material 62m using the hard mask HM as a mask, the upper portion thereof becomes stepwise. Thereafter, by removing the sacrificial layer SS and further forming the filler 64, the pillar 62 having the non-flat portion 62v on the upper surface 62a is obtained, similarly to FIG. 181 described above.

### <Section Summary>

The technology according to the third embodiment described above is specified as follows, for example. One of the disclosed techniques is the photodetector 100. As described with reference to FIGS. 1 to 5, 131, 135, 139 to 148, and the like, the photodetector 100 includes the photoelectric conversion section 21 and the optical layer 6 provided to cover the photoelectric conversion section 21. The optical layer 6 includes the plurality of pillars 62 arranged side by side in a plane direction (XY planar direction) of the layer so as to guide at least light to be detected among the incident light to the photoelectric conversion section 21. The upper surface 62a of the pillar 62 has the non-flat portion 62v including at least one of a recess and a protrusion. As a result, the effective refractive index can be changed stepwise to suppress light reflection on the upper surface 62a of the pillar 62 and the vicinity thereof.

As described with reference to FIGS. 135, 145 to 148, and the like, the optical layer 6 may include the interlayer film 62f provided on the upper surface 62a of the pillar 62 so as to fill the recess of the non-flat portion 62v. As a result, the effective refractive index can be further changed stepwise to further suppress light reflection.

As described with reference to FIG. 148 and the like, the optical layer 6 may include the interlayer film 62f provided on the upper surface 62a of the pillar 62 and the upper layer film 68 provided on the interlayer film. For example, also with such a configuration, the effective refractive index can be changed stepwise to suppress light reflection.

As described with reference to FIG. 144 and the like, the recess of the non-flat portion 62v may be filled with the heterogeneous film 62h or may be a void. For example, also with such a configuration, the effective refractive index can be changed stepwise to suppress light reflection.

As described with reference to FIGS. 129, 131, and the like, at least some of 62 the plurality of pillars 62 have different sizes, and the ratio of the volume occupied by the recess of the non-flat portion 62v in each of the pillars 62 having different sizes may be different from each other or may be the same. Further, the depths of the recesses of the non-flat portions 62v in the pillars 62 having different sizes may be different from each other or may be the same. By adjusting the in-pillar volume ratio α or adjusting the depth d of the recess for each pillar 62, the effective refractive index ne₂ can be adjusted for each pillar 62 to obtain the optimal reflection condition. Therefore, a high light reflection suppressing effect can be obtained.

As described with reference to FIG. 131 and the like, the cross-sectional area of the recess of the non-flat portion 62v as viewed in the depth direction (Z-axis negative direction) of the recess may be the same at any depth position. As described with reference to FIG. 139 and the like, the cross-sectional area of the recess may decrease stepwise as it advances in the depth direction. As described with reference to FIG. 140 and the like, the cross-sectional area of the recess may continuously decrease as it advances in the depth direction. As described with reference to FIG. 142 and the like, the cross-sectional area of the protrusion of the non-flat portion 62v as viewed in the height direction (Z-axis positive direction) may decrease stepwise as it advances in the height direction. For example, since the upper surface 62a of the pillar 62 has the non-flat portion 62v having such a cross-sectional shape, light reflection can be suppressed.

As described with reference to FIG. 143 and the like, the optical layer 6 may include the filler 64 provided so as to fill the space between the plurality of pillars 62, and the upper layer film 68 provided so as to cover the pillars 62 and the filler. The upper surface 64a of the filler 64 has the non-flat portion 64v including at least one of a recess and a protrusion, and the upper layer film 68 may be provided on the upper surface 62a of the pillar 62 and the upper surface 64a of the filler 64 so as to fill the recess of the non-flat portion 62v of the pillar 62 and the recess of the non-flat portion 64v of the filler 64. For example, light reflection can also be suppressed by such a configuration.

As described with reference to FIG. 141 and the like, the optical layer 6 may include the thin film 62g provided in the recess of the non-flat portion 62v and on the side surface 62c of the pillar 62. The thin film 62g may be provided so as to fill the recess of the non-flat portion 62v, and the optical layer 6 may include the filler 64 or an upper layer film provided so as to fill the recess of the non-flat portion 62v covered with the thin film 62g. For example, light reflection can also be suppressed by such a configuration.

### 4. FOURTH EMBODIMENT

In the fourth embodiment, light reflection is suppressed by devising the material and composition of the reflective film.

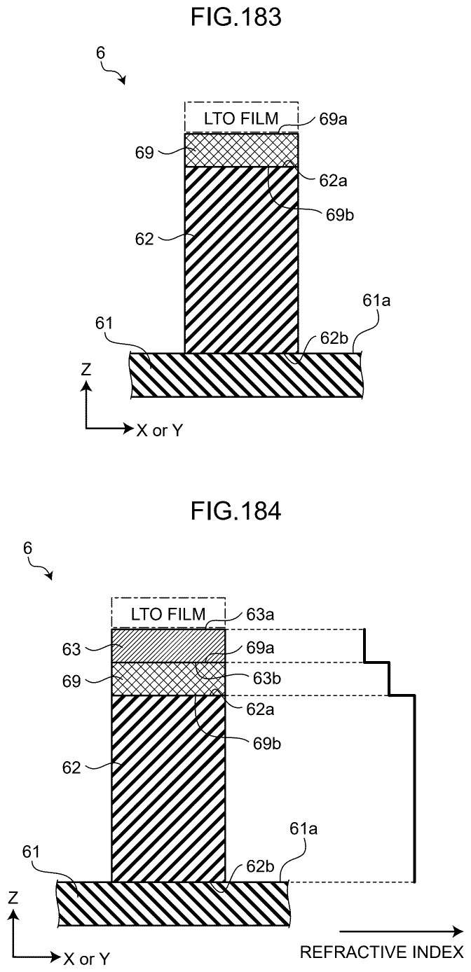

FIG. 183 is a diagram illustrating an example of a schematic configuration of the pillar 62 and its peripheral structure. The optical layer 6 includes a reflection suppressing film 69. In this example, the reflection suppressing film 69 is provided on the upper surface 62a of the pillar 62. The upper surface of the reflection suppressing film 69 is referred to as an upper surface 69a in the drawing. The lower surface of the reflection suppressing film 69 is referred to as a lower surface 69b in the drawing. The lower surface 69b of the reflection suppressing film 69 is in surface contact with the upper surface 62a of the pillar 62. Note that, although not essential, an LTO film may be further provided on the upper surface 69a of the reflection suppressing film 69 as virtually indicated by an alternate long and short dash line.

The reflection suppressing film 69 may be provided instead of the reflection suppressing film 63 (the material is, for example, SiN) described above with reference to FIG. 4 and the like. The material of the reflection suppressing film 69 contains TiO₂.

Since TiO₂ has a refractive index close to the refractive index of SiN, light reflection can also be suppressed by providing the reflection suppressing film 69 made of TiO₂ on the upper surface 62a of the pillar 62. The thickness of the reflection suppressing film 69 may be designed by a method similar to that of the reflection suppressing film 63. In addition, for example, in a case where the material of the pillar 62 is amorphous silicon, a processing selection ratio is easily obtained, and the reflection suppressing film 69 can be used as it is as a hard mask.

Furthermore, by using the reflection suppressing film 63 as an additional reflection suppressing film, the refractive index can be changed stepwise, and light reflection can be further suppressed. This will be described with reference to FIGS. 184 to 186.

FIGS. 184 to 186 are diagrams illustrating an example of a schematic configuration of the pillar 62 and its peripheral structure. The optical layer 6 includes not only the reflection suppressing film 69 but also the reflection suppressing film 63.

In the example illustrated in FIG. 184, the reflection suppressing film 63 is provided on the upper surface 69a of the reflection suppressing film 69. The reflection suppressing film 69 is provided between the pillar 62 and the reflection suppressing film 63. The upper surface 69a of the reflection suppressing film 69 is in surface contact with the lower surface 63b of the reflection suppressing film 63. The lower surface 69b of the reflection suppressing film 69 is in surface contact with the upper surface 62a of the pillar 62.

On the right side of FIG. 184, the effective refractive index at each position from the position at the same height as the upper surface 63a of the reflection suppressing film 63 to the position at the same height as the lower surface 62b of the pillar 62 in the optical layer 6 is schematically illustrated. The refractive index of the reflection suppressing film 69 is a value between the refractive index of the reflection suppressing film 63 and the refractive index of the pillar 62. The refractive index gradually changes in two stages. By providing such a refractive index gradient, light reflection can be suppressed.

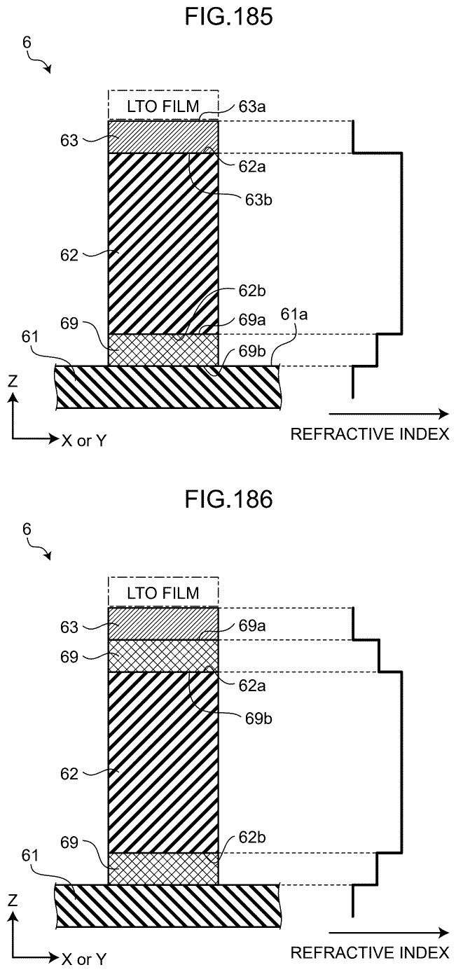

In the example illustrated in FIG. 185, the reflection suppressing film 69 is provided on the lower surface 62b of the pillar 62. The reflection suppressing film 63 is provided on the upper surface 62a of the pillar 62. The upper surface 69a of the reflection suppressing film 69 is in surface contact with the lower surface 62b of the pillar 62. The lower surface 69b of the reflection suppressing film 69 is in surface contact with the upper surface 61a of the reflection suppressing film 61. The refractive index gradually changes in two stages. By providing such a refractive index gradient, light reflection can be suppressed.

In the example illustrated in FIG. 186, the reflection suppressing film 69 is provided on both the upper surface 62a and the lower surface 62b of the pillar 62. The reflection suppressing film 63 is provided on the upper surface 69a of the reflection suppressing film 69 provided on the upper surface 62a of the pillar 62. The refractive index gradually changes in four stages. By providing a smoother refractive index gradient, light reflection can be further suppressed.

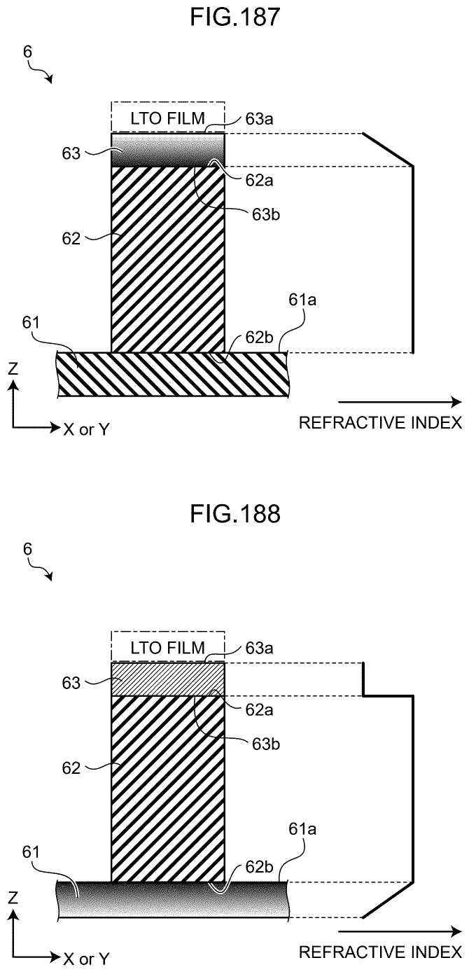

In the above description, a method of suppressing light reflection using the reflection suppressing film 69 containing TiO₂ as a material has been described. Another method will be described with reference to FIGS. 187 to 189.

FIGS. 187 to 189 are diagrams illustrating an example of a schematic configuration of the pillar 62 and its peripheral structure. By continuously changing the refractive index of at least one of the reflection suppressing film 61 and the reflection suppressing film 63, light reflection can be further suppressed.

In the example illustrated in FIG. 187, the refractive index of the reflection suppressing film 63 provided on the upper surface 62a of the pillar 62 continuously changes as it advances in the thickness direction (Z-axis direction). Specifically, the refractive index of the reflection suppressing film 63 has a gradient so as to approach the refractive index of the pillar 62 toward the pillar 62. In this example, the refractive index of the reflection suppressing film 63 is lower than the refractive index of the pillar 62. The refractive index of the reflection suppressing film 63 has a gradient so as to increase toward the pillar 62. Light reflection on the upper surface 62a of the pillar 62 hardly occurs. Light reflection can be further suppressed.

The material of the reflection suppressing film 63 may contain nitrogen. The nitrogen content in the reflection suppressing film 63 having the refractive index gradient as described above gradually increases from the pillar 62 side (the interface with the pillar 62). Such a reflection suppressing film 63 is obtained, for example, by gradually changing the gas flow rate at the time of film formation of SiNx. When the SiNx film is formed, the reflection suppressing film 63 is formed so that the nitrogen content gradually increases from the pillar 62 side, that is, the refractive index gradually decreases.

In order to cancel the reflection on the upper surface 63a of the reflection suppressing film 63, the upper region of the reflection suppressing film 63 may be an air region. The reflection suppressing film 63 may be covered with the filler 64, and in this case, for example, the thickness of the LTO layer (hard mask) may be adjusted by making the refractive index of the LTO layer higher than the refractive index of the filler 64.

In the example illustrated in FIG. 188, the refractive index of the reflection suppressing film 61 provided on the lower surface 62b of the pillar 62 continuously changes as it advances in the thickness direction. Specifically, the refractive index of the reflection suppressing film 61 has a gradient so as to approach the refractive index of the pillar 62 toward the pillar 62. In this example, the refractive index of the reflection suppressing film 61 is lower than the refractive index of the pillar 62. The refractive index of the reflection suppressing film 61 has a gradient so as to decrease toward the pillar 62. Light reflection hardly occurs on the lower surface 62b of the pillar 62. Light reflection can be further suppressed.

The material of the reflection suppressing film 61 may contain nitrogen. The nitrogen content in the reflection suppressing film 61 having the refractive index gradient as described above gradually increases from the pillar 62 side. Such a reflection suppressing film 63 is obtained, for example, by gradually changing the gas flow rate at the time of film formation of SiNx. When the SiNx film is formed, the reflection suppressing film 61 is formed so that the nitrogen content gradually increases from the pillar 62 side, that is, the refractive index gradually decreases.

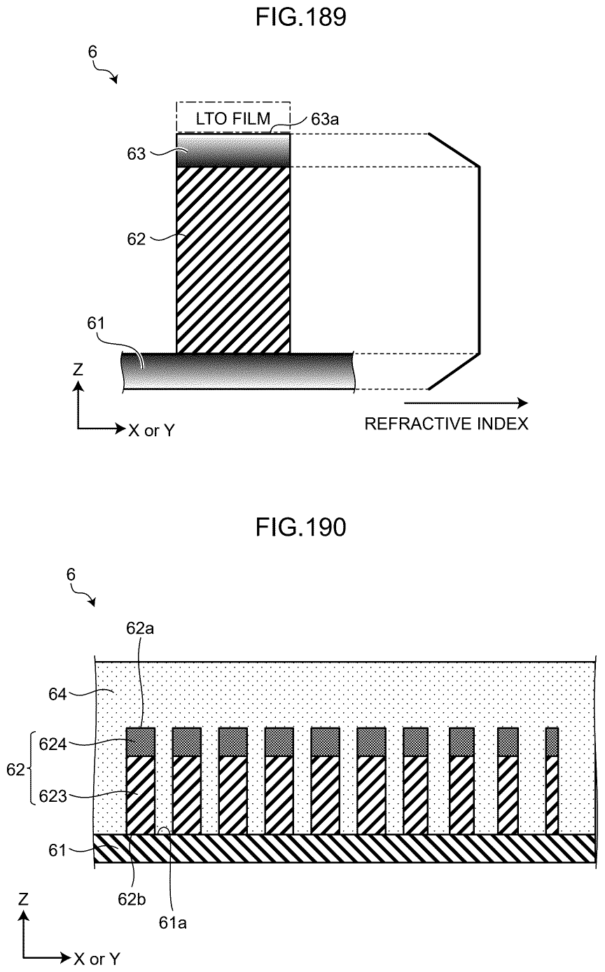

In the example illustrated in FIG. 189, both the refractive index of the reflection suppressing film 63 provided on the upper surface 62a of the pillar 62 and the refractive index of the reflection suppressing film 61 provided on the lower surface 62b of the pillar 62 have the above-described gradient. Light reflection can be further suppressed.

In one embodiment, the material of the reflection suppressing film 63 may be changed from SiN to SiOx. The material of the reflection suppressing film 63 contains oxygen, and the oxygen content in the reflection suppressing film 63 gradually increases from the pillar 62 side. The refractive index can have a gradient by gradually changing the gas flow rate at the time of film formation. When the SiOx film is formed on the pillar 62, the reflection suppressing film 63 is formed so that the oxygen content gradually increases from the pillar 62 side, that is, the refractive index gradually decreases. With such a configuration as well, light reflection can be suppressed.

There are further advantages. For example, even if the filler 64 (FIG. 4 and the like) is provided so as to cover the upper surface 63a of the reflection suppressing film 63, since the filler 64 has a refractive index similar to that of SiO₂, light reflection on the upper surface 63a of the reflection suppressing film 63 hardly occurs. The surface SiOx can also be used as a processing hard mask.

In one embodiment, the material of the reflection suppressing film 61 may be changed from SiN to SiOx. The material of the reflection suppressing film 61 contains oxygen, and the oxygen content in the reflection suppressing film 61 gradually increases from the pillar 62 side. The refractive index can have a gradient by gradually changing the gas flow rate at the time of film formation. When the SiOx film is formed under the pillar 62, the reflection suppressing film 61 is formed so that the oxygen content gradually increases from the pillar 62 side, that is, the refractive index gradually decreases. With such a configuration as well, light reflection can be suppressed.

There are further advantages. For example, even if the filler 64 (FIG. 4 and the like) is provided so as to cover the upper surface 61a of the reflection suppressing film 61, since the filler 64 has a refractive index similar to that of SiO₂, light reflection on the upper surface 61a of the reflection suppressing film 61 hardly occurs. The surface SiOx can also be used as a processing hard mask.

Of course, the materials of both the reflection suppressing film 63 and the reflection suppressing film 61 may be changed from SiN to SiOx as described above. Light reflection can be further suppressed.

In one embodiment, the material of the reflection suppressing film 63 may be changed from SiN to SiNyOz+SiNx. The material of the reflection suppressing film 63 contains nitrogen and oxygen, and the nitrogen content and the oxygen content in the reflection suppressing film 63 gradually increase from the pillar 62 side. By gradually changing the amounts of oxygen and nitrogen during film formation, the refractive index can have a gradient. When the SiNx film is formed on the pillar 62, the SiNx film is formed so that the nitrogen content gradually increases from the pillar 62 side, that is, the refractive index gradually decreases. Further, when a film of SiNyOz is formed on SiNx, the film is formed so that the oxygen content gradually increases from the SiNx interface, that is, the refractive index gradually decreases. With such a configuration as well, light reflection can be suppressed.

In one embodiment, the material of the reflection suppressing film 61 may be changed from SiN to SiNyOz+SiNx. The material of the reflection suppressing film 61 contains nitrogen and oxygen, and the nitrogen content and the oxygen content in the reflection suppressing film 61 gradually increase from the pillar 62 side. By gradually changing the amounts of oxygen and nitrogen during film formation, the refractive index can have a gradient. When the SiNx film is formed under the pillar 62, the SiNx film is formed so that the nitrogen content gradually increases from the pillar 62 side, that is, the refractive index gradually decreases. Further, when the SiNyOz film is formed under the pillar 62, the SiNyOz film is formed so that the oxygen content gradually increases from the SiNx interface, that is, the refractive index gradually decreases. With such a configuration as well, light reflection can be suppressed.

Of course, the materials of both the reflection suppressing film 63 and the reflection suppressing film 61 may be changed from SiN to SiNyOz+SiNx as described above.

### <Section Summary>

The technology according to the fourth embodiment described above is specified as follows, for example. One of the disclosed techniques is the photodetector 100. As described with reference to FIGS. 1 to 5, 183 to 186, and the like, the photodetector 100 includes the photoelectric conversion section 21 and the optical layer 6 provided to cover the photoelectric conversion section 21. The optical layer 6 includes the plurality of pillars 62 arranged side by side in a plane direction (XY planar direction) of the layer so as to guide at least light to be detected among the incident light to the photoelectric conversion section 21, and the reflection suppressing film 69 provided on at least one of the upper surface 62a and the lower surface 62b of the pillar 62. The material of the reflection suppressing film 69 contains TiO₂. As a result, light reflection can be suppressed similarly to the case where the material is SiN.

As described with reference to FIG. 186 and the like, the reflection suppressing film 69 may be provided on both the upper surface 62a and the lower surface 62b of the pillar 62. Thus, light reflection can be further suppressed.

As described with reference to FIGS. 184, 186, and the like, the optical layer 6 may include the reflection suppressing film 63 (additional reflection suppressing film) provided on the upper surface 69a of the reflection suppressing film 69, and the material of the reflection suppressing film 63 may include SiN. As a result, the refractive index is changed stepwise, and light reflection can be further suppressed.

The photodetector 100 described with reference to FIGS. 1 to 5 and 187 to 189 and the like is also one of the disclosed techniques. The photodetector 100 includes the photoelectric conversion section 21 and the optical layer 6 provided to cover the photoelectric conversion section 21. The optical layer 6 includes the plurality of pillars 62 arranged side by side in a plane direction (XY planar direction) of the layer so as to guide at least light to be detected among the incident light to the photoelectric conversion section 21, and the reflection suppressing film (reflection suppressing film 63 and reflection suppressing film 61) provided on at least one of the upper surface 62a and the lower surface 62b of the pillar 62. The refractive index of the reflection suppressing film has a gradient so as to approach the refractive index of the pillar 62 toward the pillar 62. For example, the refractive index of the reflection suppressing film may be lower than the refractive index of the pillar 62, and the refractive index of the reflection suppressing film may have a gradient so as to increase toward the pillar 62. In other words, the refractive index of the reflection suppressing film is high on the pillar 62 side in the cross-sectional view. With such a configuration as well, light reflection can be suppressed.

As described with reference to FIGS. 187 to 189 and the like, the material of the reflection suppressing film (reflection suppressing film 63 and reflection suppressing film 61) may contain at least one of nitrogen and oxygen, and the content thereof in the reflection suppressing film may gradually increase from the pillar 62 side. For example, in this way, a reflection suppressing film having a gradient refractive index can be obtained.

### 5. FIFTH EMBODIMENT

In the fifth embodiment, light reflection is suppressed by devising the composition of the pillars 62.

FIG. 190 is a diagram illustrating an example of a schematic configuration of the optical layer 6. The pillar 62 includes an unaltered layer 623 and an altered layer 624. In the pillar height direction (Z-axis direction), the unaltered layer 623 and the altered layer 624 are connected to each other.

The unaltered layer 623 is a portion made of the material (amorphous silicon or the like) of the pillars 62 described above. The refractive index of the unaltered layer 623 is the same as the refractive index of the pillar 62 described above. In this example, the unaltered layer 623 is a portion including the lower surface 62b of the pillar 62.

The altered layer 624 has a refractive index different from the refractive index of the other portion of the pillar 62, that is, the unaltered layer 623. In this example, the altered layer 624 is a portion including the upper surface 62a of the pillar 62, and is located between the unaltered layer 623 and the altered layer 624.

The altered layer 624 has a refractive index different from the refractive index of the unaltered layer 623. The refractive index of the altered layer 624 may be a value between the refractive index of the unaltered layer 623 and the refractive index of the filler 64. Since the refractive index gradually (stepwise in this example) changes in the pillar height direction (Z-axis direction), light reflection is suppressed.

The altered layer 624 may have a thickness that is an integral multiple of λ/4n (n is a refractive index of the medium). Light reflection there may be minimized. In practice, it is desirable to optimize by optical simulation or actual measurement in consideration of the interference effect and oblique incidence characteristics of the multilayer film.

The unaltered layer 623 and the altered layer 624 are obtained by ion-implanting boron or the like into a part of amorphous silicon which is a material of the pillars 62. In the pillars 62, a portion into which ions are implanted becomes the altered layer 624, and a portion into which ions are not implanted becomes the unaltered layer 623.

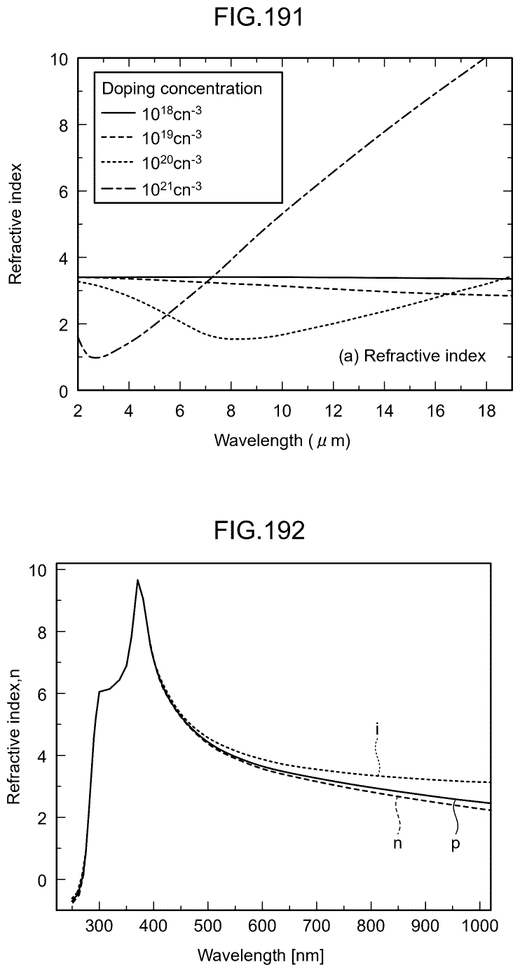

The refractive index can be finely adjusted by changing the dose amount. For example, the concentration dependence of the refractive index of P-type silicon is known. It is known as illustrated in Non Patent Literature 1 and Non Patent Literature 2. FIG. 191 is a diagram that cites Non Patent Literature 1. FIG. 192 is a diagram that cites Non Patent Literature 2.

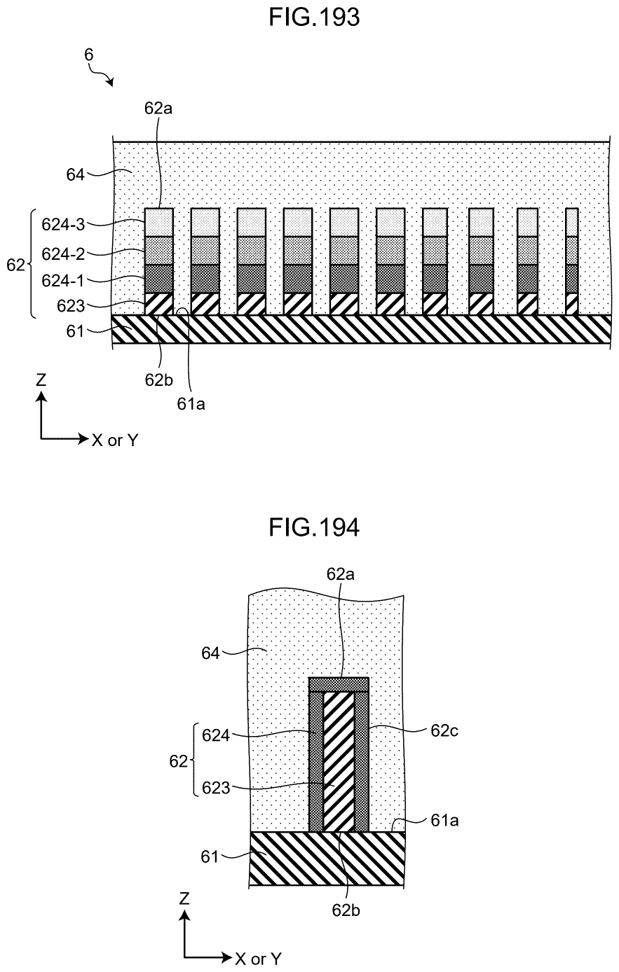

In one embodiment, the optical layer 6 may include a plurality of unaltered layers 623. This will be described with reference to FIG. 193.

FIG. 193 is a diagram illustrating an example of a schematic configuration of the optical layer 6. The pillar 62 includes a plurality of laminated altered layers 624. As the plurality of altered layers 624, three altered layers 624 are illustrated in FIG. 193. Each altered layer 624 is referred to as an altered layer 624-1, an altered layer 624-2, and an altered layer 624-3 in the drawing so as to be distinguishable. The altered layer 624-1, the altered layer 624-2, and the altered layer 624-3 are laminated in this order on the unaltered layer 623.

Each of the plurality of altered layers 624 has different refractive indexes such that the refractive index of the altered layer 624 gradually changes in the pillar height direction (Z-axis direction). The altered layer 624 located closer to the unaltered layer 623 has a refractive index closer to the refractive index of the unaltered layer 623. In the example illustrated in FIG. 193, the refractive index of the altered layer 624-1 among the altered layer 624-1 to the altered layer 624-3 is closest to the refractive index of the unaltered layer 623. The refractive index of the altered layer 624-3 is closest to the refractive index of the filler 64. The refractive index of the altered layer 624-2 is a value between the refractive index of the altered layer 624-1 and the refractive index of the altered layer 624-3.

By providing the plurality of altered layers 624 as described above, the refractive index can be more smoothly changed in the pillar height direction (Z-axis direction). Light reflection can be further suppressed.

In one embodiment, the pillar 62 may include an altered layer 624 not only on its upper portion but also on its side portion. The altered layer 624 may also be formed to include the side surface 62c of the pillar 62 including the altered layer. This will be described with reference to FIG. 194.

FIG. 194 is a diagram illustrating an example of a schematic configuration of the pillar 62 and its peripheral structure. The altered layer 624 is also provided on the side portion of the pillar 62. The altered layer 624 is a portion including the upper surface 62a and the side surface 62c of the pillar 62. Thus, the effect of suppressing light reflection can be further enhanced.

### <Manufacturing Method>

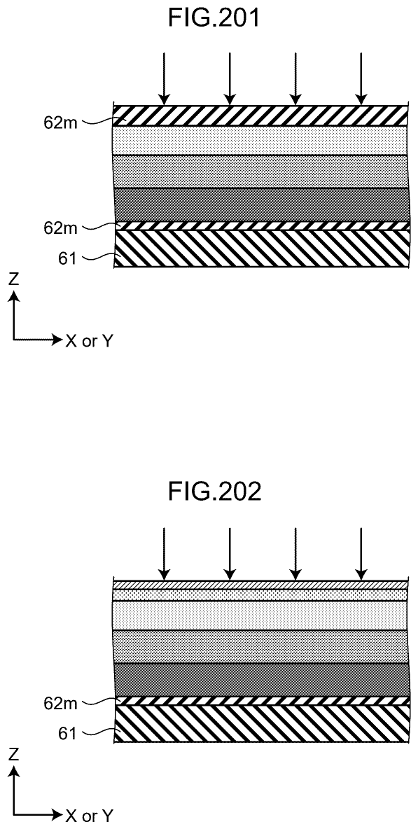

FIGS. 195 to 211 are diagrams illustrating an example of a manufacturing method. The pillar material 62m may be amorphous silicon or TiOx.

FIGS. 195 to 198 illustrate an example of a manufacturing method for obtaining the pillar 62 having the single altered layer 624.

As illustrated in FIG. 195, the pillar material 62m is formed on the reflection suppressing film 61.

As illustrated in FIG. 196, ions are implanted from the upper surface of the pillar material 62m. The upper portion of the pillar material 62m is altered.

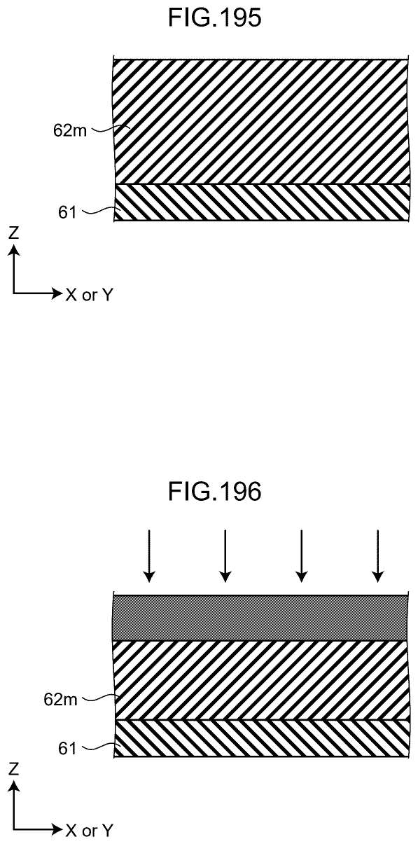

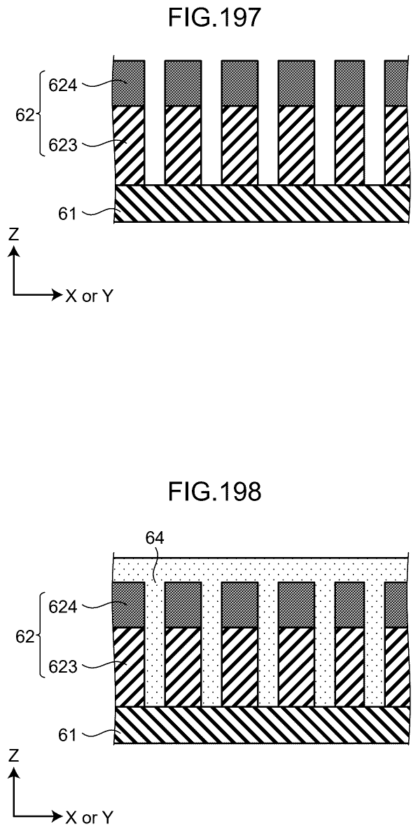

As illustrated in FIG. 197, lithography, dry etching, and cleaning are performed to obtain the pillars 62 including the unaltered layer 623 and the altered layer 624.

As illustrated in FIG. 198, the filler 64 is provided so as to fill the space between the pillars 62 and cover the reflection suppressing film 61 and the pillars 62.

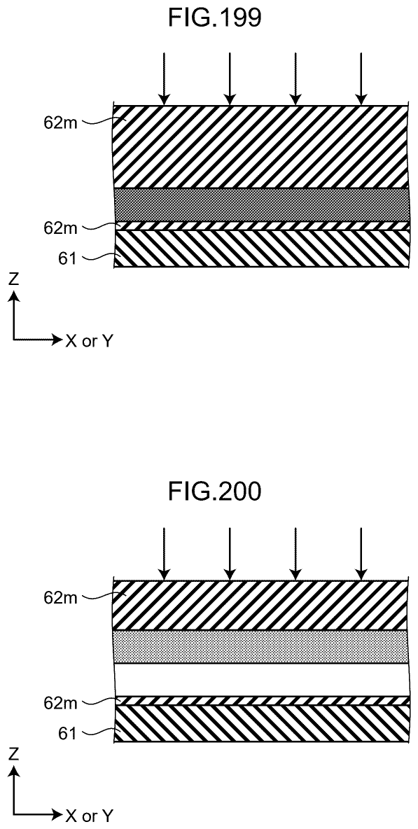

FIGS. 199 to 204 illustrate examples of a manufacturing method for obtaining the pillar 62 having the plurality of altered layers 624. As a premise, it is assumed that the process of FIG. 195 described above is completed.

As illustrated in FIG. 199, ions are implanted at a position deeper than the upper surface of the pillar material 62m.

As illustrated in FIGS. 200 to 202, ion implantation is performed a plurality of times up to the upper surface of the pillar material 62m while changing the dose amount and the implantation depth.

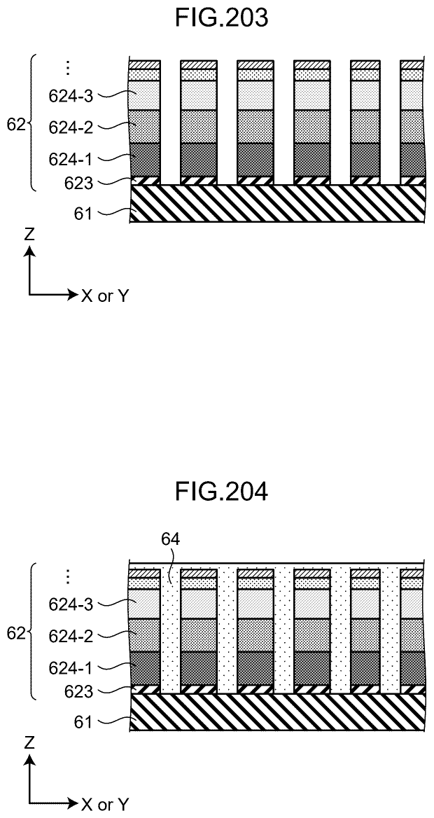

As illustrated in FIG. 203, lithography, dry etching, and cleaning are performed to obtain the pillar 62 including the unaltered layer 623 and the plurality of altered layers 624.

As illustrated in FIG. 204, the filler 64 is provided so as to fill the space between the pillars 62 and cover the reflection suppressing film 61 and the pillars 62.

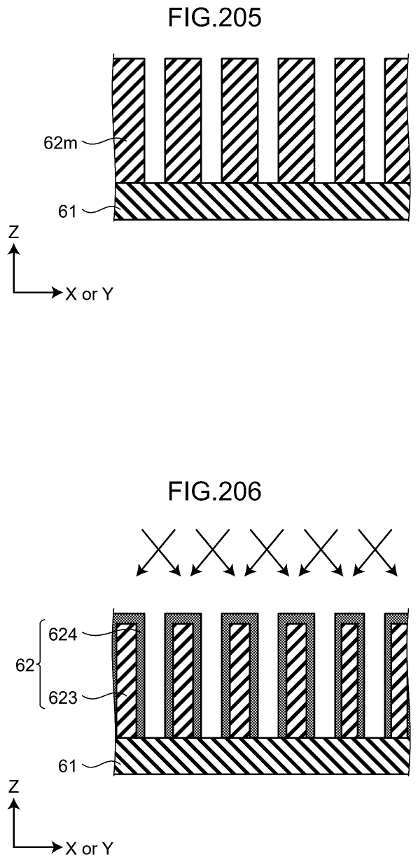

FIGS. 205 to 207 illustrate an example of a manufacturing method for obtaining the pillar 62 including the altered layer 624 on the upper portion and the side portion. As a premise, it is assumed that the process of FIG. 195 described above is completed.

As illustrated in FIG. 205, lithography, dry etching, and cleaning are performed to process the pillar material 62m so as to have the shape of the pillar 62.

As illustrated in FIG. 206, the upper portion and the side portion of the pillar material 62m are modified by oblique ion implantation. The pillar 62 including the unaltered layer 623 and the altered layer 624 is obtained. Note that plasma doping may be used instead of oblique ion implantation.

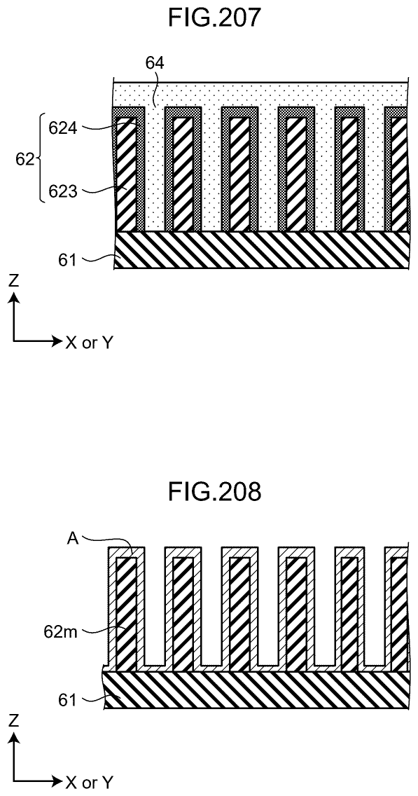

As illustrated in FIG. 207, the filler 64 is provided so as to fill the space between the pillars 62 and cover the reflection suppressing film 61 and the pillars 62.

FIGS. 208 to 211 illustrate an example of a manufacturing method for obtaining the pillar 62 including the altered layer 624 on the upper portion and the side portion using solid-phase diffusion. As a premise, it is assumed that the process of FIG. 205 described above is completed.

As illustrated in FIG. 208, a film covering the pillar material 62m is generated using atomic layer deposition (ALD) so as to cover the pillar material 62m. The generated film is referred to as an ALD film A in the drawing.

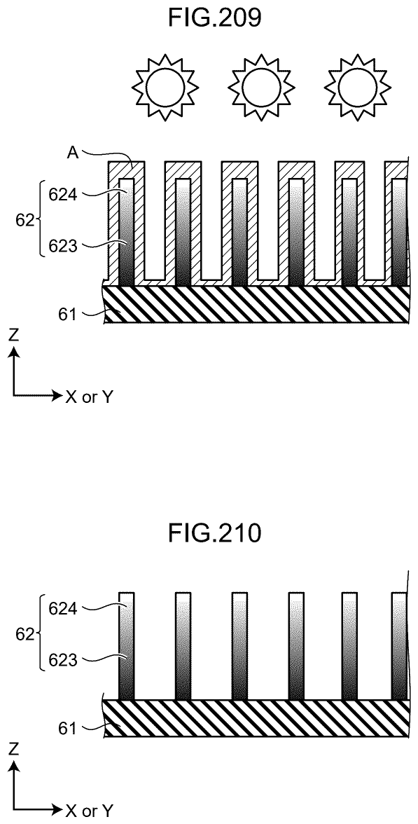

As illustrated in FIG. 209, diffusion is performed by Laser ANL. A portion near the ALD film A in the pillar material 62m, that is, the upper portion and the side portion are altered to become the altered layer 624. The pillar 62 including the unaltered layer 623 and the altered layer 624 is obtained.

As illustrated in FIG. 210, the ALD film A is peeled off.

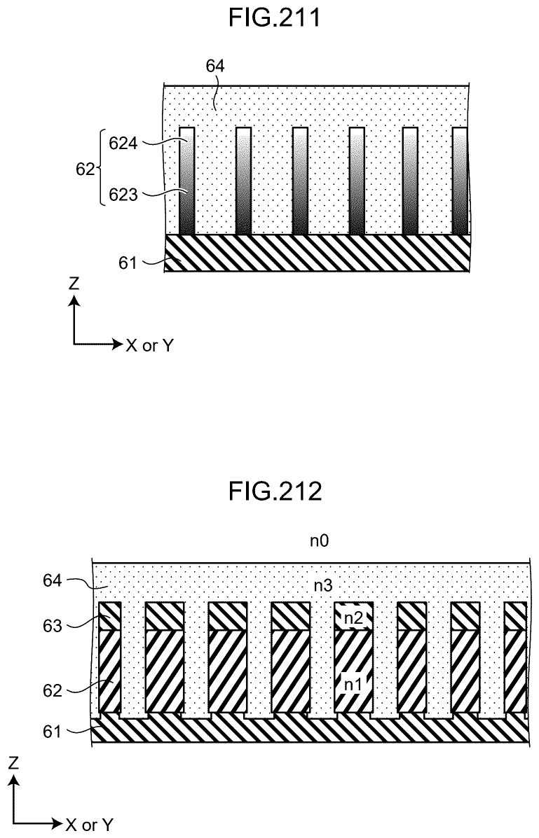

As illustrated in FIG. 211, the filler 64 is provided so as to fill the space between the pillars 62 and cover the reflection suppressing film 61 and the pillars 62.

### <Section Summary>

The technology according to the fifth embodiment described above is specified as follows, for example. One of the disclosed techniques is the photodetector 100. As described with reference to FIGS. 1 to 5, 190, 193, 194, and the like, the photodetector 100 includes the photoelectric conversion section 21 and the optical layer 6 provided to cover the photoelectric conversion section 21. The optical layer 6 includes the plurality of pillars 62 arranged side by side in a plane direction (XY planar direction) of the layer so as to guide at least light to be detected among the incident light to the photoelectric conversion section 21. The pillar 62 includes the unaltered layer 623 including the lower surface 62b of the pillar 62, and the altered layer 624 including the upper surface 62a of the pillar 62 and having a refractive index different from the refractive index of the unaltered layer 623. As a result, the refractive index can be gradually changed in the pillar height direction to suppress light reflection.

As described with reference to FIG. 190 and the like, the altered layer 624 may be a portion of the pillar 62 into which ions are implanted, and the unaltered layer 623 may be a portion of the pillar 62 into which ions are not implanted. For example, in this way, the unaltered layer 623 and the altered layer 624 having different refractive indexes can be obtained.

As described with reference to FIG. 193 and the like, each pillar 62 may have a different refractive index and include a plurality of laminated altered layers 624. Among the plurality of altered layers 624, the altered layer 624 located closer to the unaltered layer 623 may have a refractive index closer to the refractive index of the unaltered layer 623. As a result, the refractive index can be more smoothly changed, and light reflection can be further suppressed.

As described with reference to FIG. 194 and the like, the altered layer 624 may also include the side surface 62c of the pillar 62. Thus, light reflection can be further suppressed.

### 6. SIXTH EMBODIMENT

In the sixth embodiment, light reflection is suppressed by using the plurality of optical layers 6. First, the problem will be described with reference to FIG. 212.

FIG. 212 is a diagram illustrating a comparative example. The refractive index of the pillar 62 is referred to as a refractive index n₁. The refractive index of the reflection suppressing film 63 is referred to as a refractive index n₂. The refractive index of the filler 64 is referred to as a refractive index n₃. The refractive index of the upper region of the filler 64 is defined as a refractive index n₀. The refractive index n₂ of the reflection suppressing film 63 is a value (for example, average value=(n₃+n₁)/2) between the refractive index n₁ of the pillar 62 and the refractive index n₃ of the filler 64. The thickness of the reflection suppressing film 63 is, for example, λ/4. Since the width (for example, diameter) is different for each pillar 62, there is a problem that the effect of suppressing reflection is low even if the same reflection suppressing film 63 is provided. In the present embodiment, the problem is addressed by using the plurality of optical layers 6.

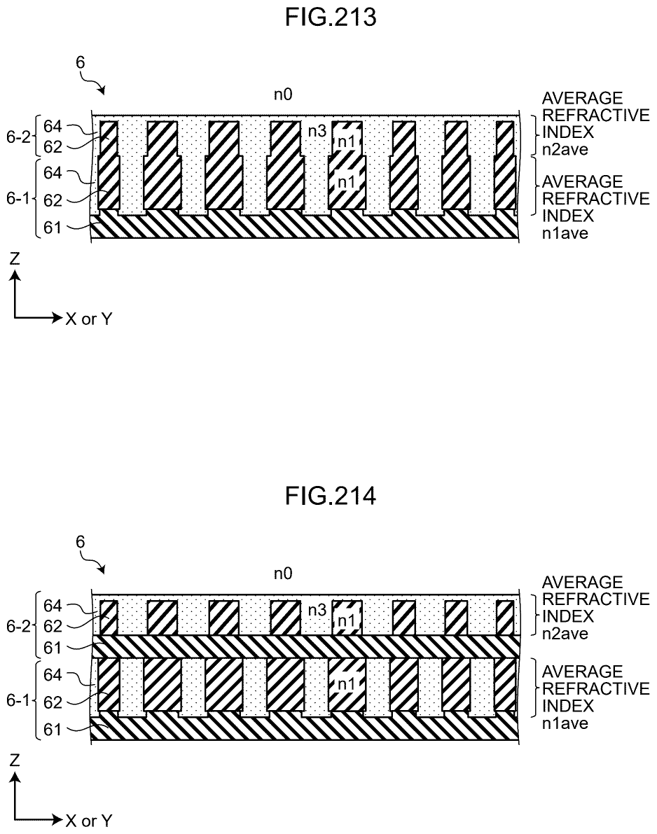

FIGS. 213 and 214 are diagrams illustrating an example of a schematic configuration of the optical layer 6. A plurality of optical layers 6, in this example, two optical layers 6 are laminated (lamination of the optical layers 6 is not limited to two). The first optical layer 6 (first-stage optical layer 6) is referred to as an optical layer 6-1 in the drawing. The second optical layer 6 (second-stage optical layer 6) is referred to as an optical layer 6-2 in the drawing. In a case where they are not particularly distinguished, they are simply referred to as the optical layer 6.

As illustrated in FIG. 214, the reflection suppressing film 61 may be further provided between the pillar 62 of the optical layer 6-1 and the pillar 62 of the optical layer 6-2. The reflection suppressing film 61 may be a component of the optical layer 6-2 as illustrated in FIG. 214. Note that, in the above-described configuration of FIG. 213 without such a reflection suppressing film 61, it is not necessary to consider the reflection suppressing film 61 in the calculation of the average refractive index (average refractive index average refractive index n2ave to be described later) of the optical layer 6-2, so that the possibility of easily performing the reflection suppressing design is increased.

The optical layer 6-1 is provided so as to cover the photoelectric conversion section 21. The optical layer 6-1 is configured to have the light control function described above. The optical layer 6-2 is provided so as to cover the optical layer 6-2. The optical layer 6-2 is configured to function as a reflection suppressing layer.

The average refractive index (also referred to as an effective refractive index) of the optical layer 6-1 is referred to as an average refractive index n1ave. The average refractive index of the optical layer 6-2 is referred to as an average refractive index n2ave. In a case where they are not particularly distinguished, they are simply referred to as average refractive indexes. Note that, for easy understanding, here, the average refractive index is the average refractive index of the portions of the pillar 62 and the filler 64.

The average refractive index n2ave of the optical layer 6-2 is a value different from the average refractive index n1ave of the optical layer 6-1, more specifically, a value between the refractive index no and the average refractive index n1ave of the optical layer 6-1. More specifically, in this example, the average refractive index n2ave is higher than the refractive index n₀ and lower than the average refractive index n1ave (n₀<n2ave<n1ave). The average refractive index n2ave may be an average value of the refractive index n₀ and the average refractive index n1ave (n2ave=(no+n1ave)/2). By providing such an optical layer 6-2 on the optical layer 6-1, the average refractive index of each position in the Z-axis direction of the optical layer 6 is changed stepwise, and light reflection can be suppressed. Note that the thickness of the optical layer 6-2 may be smaller than the wavelength of the light to be detected (for example, λ/4).

The average refractive index is calculated, for example, by weighting and averaging the refractive index of each element within the target range by the volume of each element. Specifically, assuming that the volume of the pillar 62 (refractive index n1) in the optical layer 6 is volume V1 and the volume of the filler 64 (refractive index n₃) is volume V3, the average refractive index of the optical layer 6 is calculated as the following Formula (4).

$$Average refractive index = \frac{V 1 \times n 1 + V 3 \times n 3}{V 1 + V 3} \qquad ( 4 )$$

A desired average refractive index can be obtained by adjusting the volume V1 of the pillars 62 in the optical layer 6. The volume V1 of the pillar 62 can be adjusted by changing the width, height, and the like of the pillar 62. The range of the calculation target of the average refractive index in the optical layer 6 may be variously determined. Some examples are described with reference to FIG. 212.

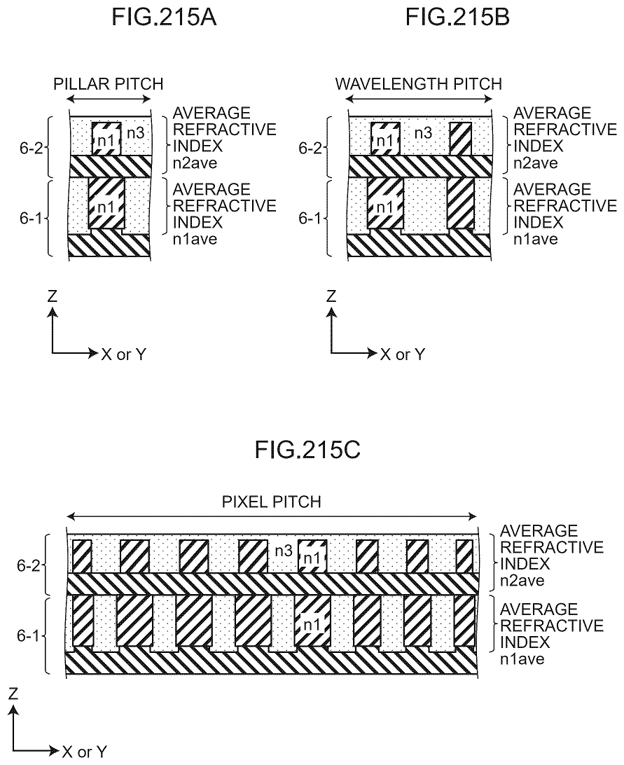

FIG. 215 is a diagram illustrating an example of calculation of the average refractive index. In the example illustrated in (A) of FIG. 215, the average refractive index is calculated for each pillar pitch. The refractive index of each element within the range of the same length as the pillar pitch is weighted average by the volume of each element. For example, the average refractive index n1ave of the optical layer 6-1 and the average refractive index n2ave of the optical layer 6-2 are calculated using the above Formula (4). In the example illustrated in (B) of FIG. 215, the average refractive index is calculated for each wavelength pitch. The refractive index of each element within a range having the same length as the wavelength of the light to be detected in the medium is weighted and averaged by the volume of each element. In the example illustrated in (C) of FIG. 215, the average refractive index is calculated for each pixel pitch. The refractive index of each element within the range of the same length as the pixel pitch is weighted average by the volume of each element.

In one embodiment, the pillars 62 of the optical layer 6-2 may have a width that is different from the width (which may be a diameter, a cross-sectional area, or the like) of the corresponding pillars 62 of the optical layer 6-1, for example smaller than the width of the corresponding pillars 62 of the optical layer 6-1. For example, in this way, the average refractive index n2ave different from the average refractive index n1ave can be obtained. The average refractive index n2ave can also be made lower than the average refractive index n1ave (n2ave<n1ave). Note that the pillar 62 of the corresponding optical layer 6-1 may be, for example, the pillar 62 of the optical layer 6-2 located so as to at least partially overlap with the pillar 62 of the optical layer 6-1 when viewed in the pillar height direction (Z-axis direction).

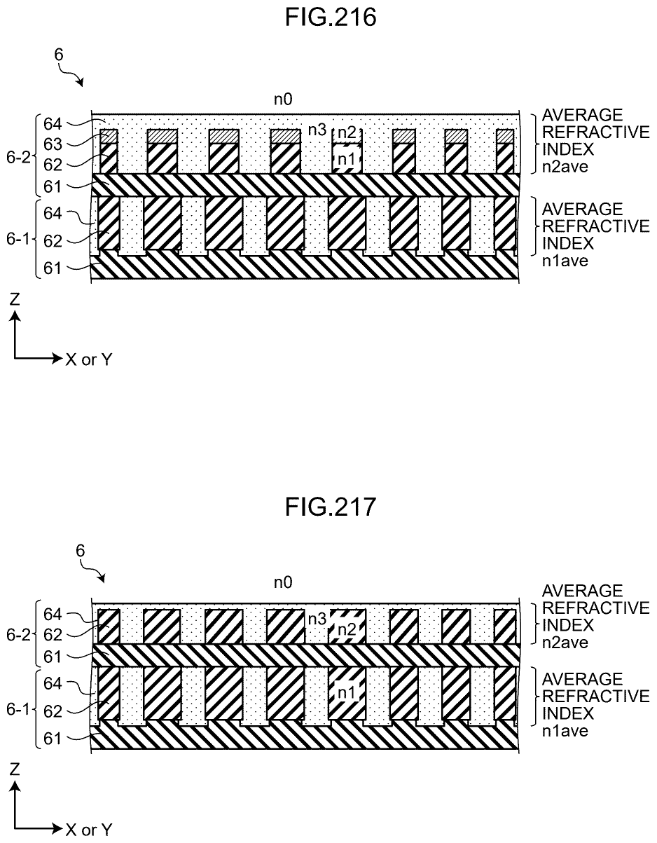

Some modifications of the plurality of optical layers 6 will be described with reference to FIGS. 216 to 219.

FIGS. 216 to 220 are diagrams illustrating modifications. In the example illustrated in FIG. 216, the reflection suppressing film 63 (refractive index n₂) is provided on the upper surface 62a of the pillar 62 of the optical layer 6-2. Thus, the effect of suppressing light reflection can be further enhanced.

In the example illustrated in FIG. 217, the material of the pillars 62 of the optical layer 6-2 is different from the material of the pillars 62 of the optical layer 6-1. The refractive index of the pillar 62 of the optical layer 6-2 may be a value between the refractive index n₁ and the refractive index n₃, and is the refractive index n₂ in this example. By using pillar materials having different refractive indexes, for example, it is possible to widen the design range of the average refractive index n1ave of the optical layer 6-1 and the average refractive index n2ave of the optical layer 6-2.

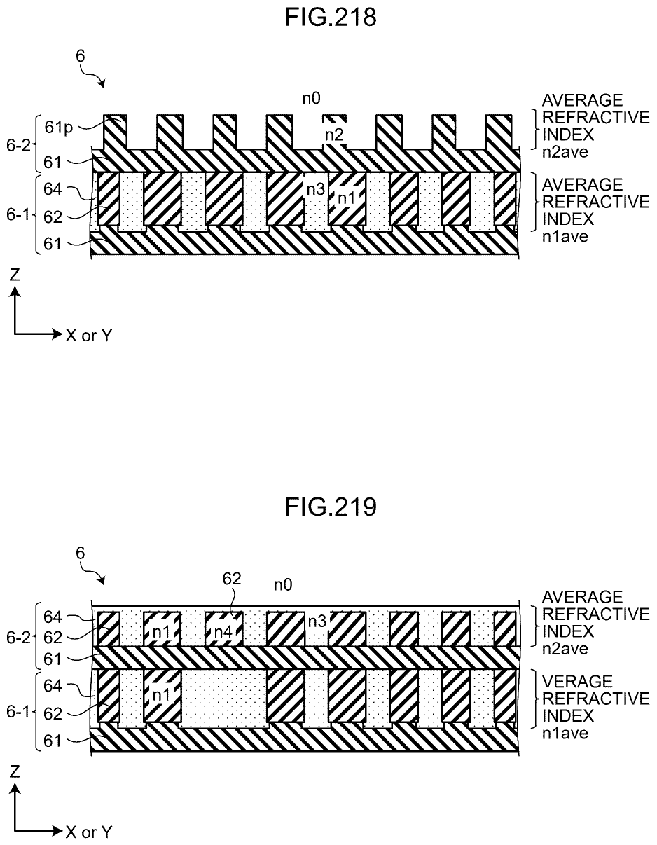

In the example illustrated in FIG. 218, the reflection suppressing film 61 of the optical layer 6-2 has an extending portion 61p extending upward (Z-axis positive direction). The extending portion 61p functions as the pillar 62 described above. In this example, no filler 64 is provided. A void may be formed between adjacent extending portions 61p.

In the example illustrated in FIG. 219, the plurality of pillars 62 of the optical layer 6-2 include two types of pillars 62 made of different materials from each other. The refractive index of the pillar 62 including one material is the refractive index n₁ described above. The refractive index of the pillar 62 including the other material is referred to as a refractive index n4. The refractive index n4 may be lower than the refractive index n₃ (n₄<n₃). By using two types of pillar materials, the design range of the average refractive index n2ave of the optical layer 6-2 can be expanded.

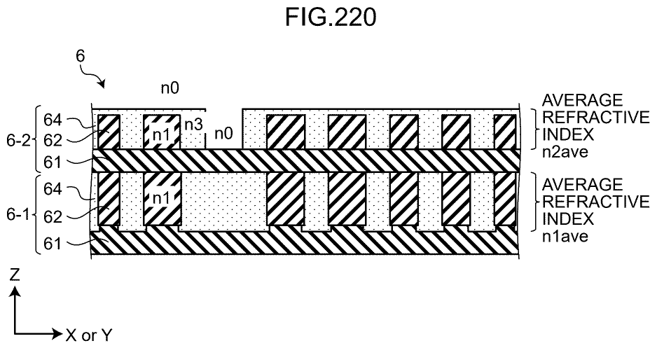

In the example illustrated in FIG. 220, in the optical layer 6-2, a region (refractive index n₀) without the filler 64 is provided between some adjacent pillars 62. This portion is, for example, a void portion. The refractive index no is lower than the refractive index n₃ (n₀<n₃). By also using the region of the refractive index no, the design range of the average refractive index n2ave of the optical layer 6-2 can be further expanded.

### <Section Summary>

The technology according to the sixth embodiment described above is specified as follows, for example. One of the disclosed techniques is the photodetector 100. As described with reference to FIGS. 1 to 5, 213 to 220, and the like, the photodetector 100 includes the photoelectric conversion section 21, the optical layer 6-1 (first optical layer) provided to cover the photoelectric conversion section 21, and the optical layer 6-1 (second optical layer) provided to cover the optical layer 6-2. The optical layer 6-1 includes the plurality of pillars 62 arranged side by side in a plane direction (XY planar direction) of the layer so as to guide at least light to be detected among the incident light to the photoelectric conversion section 21. The optical layer 6-2 includes the plurality of pillars 62 arranged side by side in the plane direction of the layer so as to have an average refractive index n2ave different from the average refractive index n1ave of the optical layer 6-1. As a result, the optical layer 6-2 functions as a reflection suppressing layer covering the optical layer 6-1, and light reflection can be suppressed.

As described with reference to FIGS. 213, 214, and the like, the average refractive index n2ave of the optical layer 6-2 may be a value between the refractive index n₀ of the upper region of the optical layer 6-2 and the average refractive index n1ave of the optical layer 6-1. For example, the average refractive index n2ave of the optical layer 6-2 may be an average value of the refractive index no of the upper region of the optical layer 6-2 and the average refractive index n1ave of the optical layer 6-1. The average refractive index n2ave of the optical layer 6-2 may be lower than the average refractive index n1ave of the optical layer 6-1. For example, with such a configuration, light reflection can be suppressed.

As described with reference to FIGS. 213, 214, and the like, the pillars 62 of the optical layer 6-2 may have a width smaller than the width of the corresponding pillars 62 of the optical layer 6-1. As a result, for example, the average refractive index n2ave of the optical layer 6-2 can be made lower than the average refractive index n1ave of the optical layer 6-1.

As described with reference to FIG. 216 and the like, the optical layer 6-2 may include the reflection suppressing film 63 provided on the upper surface 62a of the pillar 62. Thus, light reflection can be further suppressed.

As described with reference to FIG. 217 and the like, the pillar material of the optical layer 6-2 may be different from the pillar material of the optical layer 6-1. As a result, for example, the design range of the average refractive index n1ave of the optical layer 6-1 and the average refractive index n2ave of the optical layer 6-2 can be widened.

As described with reference to FIG. 219 and the like, the plurality of pillars 62 of the optical layer 6-2 may include two types of pillars 62 (pillar 62 having refractive index n1 and pillar 62 having refractive index n4) configured to include different materials. As a result, for example, the design range of the average refractive index n2ave of the optical layer 6-2 can be widened.

### 7. SEVENTH EMBODIMENT

In the seventh embodiment, light reflection is suppressed by devising the shape of the etching stopper layer.

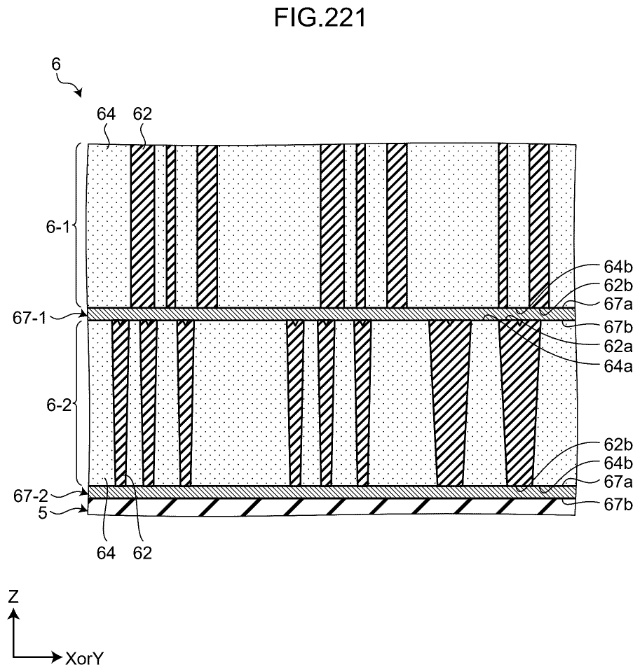

FIG. 221 is a diagram illustrating an example of a schematic configuration of the optical layer 6. The optical layer 6 includes two optical layers 6 and two etching stopper layers 67.

The first optical layer 6 of the two optical layers 6 is referred to as an optical layer 6-1 in the drawing. The second optical layer 6 is referred to as an optical layer 6-2 in the drawing. As described above, each of the optical layer 6-1 and the optical layer 6-2 includes the plurality of pillars 62 and the filler 64 provided so as to fill the space between the plurality of pillars 62. The upper surface 62a and the lower surface 62b of the pillar 62, and the upper surface 64a of the filler 64 are illustrated with reference signs similar to those described above. Further, the lower surface of the filler 64 is referred to as a lower surface 64b in the drawing.

A first etching stopper layer 67 of two etching stopper layers 67 is referred to as an etching stopper layer 67-1 in the drawing. A second etching stopper layer 67 is referred to as an etching stopper layer 67-2 in the drawing.

Note that, in a case where the optical layer 6-1 and the optical layer 6-2 are not particularly distinguished, they are simply referred to as the optical layer 6. Similarly, the etching stopper layer 67-1 and the etching stopper layer 67-2 are simply referred to as an etching stopper layer 67 unless otherwise distinguished. The upper surface (the surface on the Z-axis positive direction side) of the etching stopper layer 67 is referred to as an upper surface 67a in the drawing. The lower surface (the surface on the Z-axis negative direction side) of the etching stopper layer 67 is referred to as a lower surface 67b in the drawing.

The optical layer 6-2 is located between the optical layer 6-1 and the photoelectric conversion section 21 (FIG. 1) of the semiconductor substrate 3. The etching stopper layer 67-1 is located between the optical layer 6-1 and the optical layer 6-2. The etching stopper layer 67-2 is located on the side opposite to the etching stopper layer 67-1 with the optical layer 6-2 interposed therebetween. The insulating layer 5, the etching stopper layer 67-2, the optical layer 6-2, the etching stopper layer 67-1, and the optical layer 6-1 are laminated in this order in the Z-axis positive direction.

The etching stopper layer 67 is provided on at least one of the upper surface 62a and the lower surface 62b of the pillar 62. The etching stopper layer 67 is also provided on at least one of the upper surface 64a and the lower surface 64b of the filler 64.

Specifically, in the example illustrated in FIG. 221, the etching stopper layer 67-1 is provided on the lower surface 62b of the pillar 62 of the optical layer 6-1 and the lower surface 64b of the filler 64, and is provided on the upper surface 62a of the pillar 62 of the optical layer 6-2 and the upper surface 64a of the filler 64. The etching stopper layer 67-2 is provided on the lower surface 62b of the pillar 62 of the optical layer 6-2 and the lower surface 64b of the filler 64.

As described above, the pillar 62 has a refractive index higher than the refractive index of the filler 64. The refractive index of the pillar 62 is also referred to as a high refractive index. For example, in a case where the material of the pillar 62 is TiO, the refractive index can be about 2.47. The refractive index of the filler 64 is also referred to as a low refractive index. For example, in a case where the material of the filler 64 is TEOS, the refractive index may be about 1.47. The etching stopper layer 67 has a refractive index different from the refractive index of the pillar 62 and also has a refractive index different from the refractive index of the filler 64.

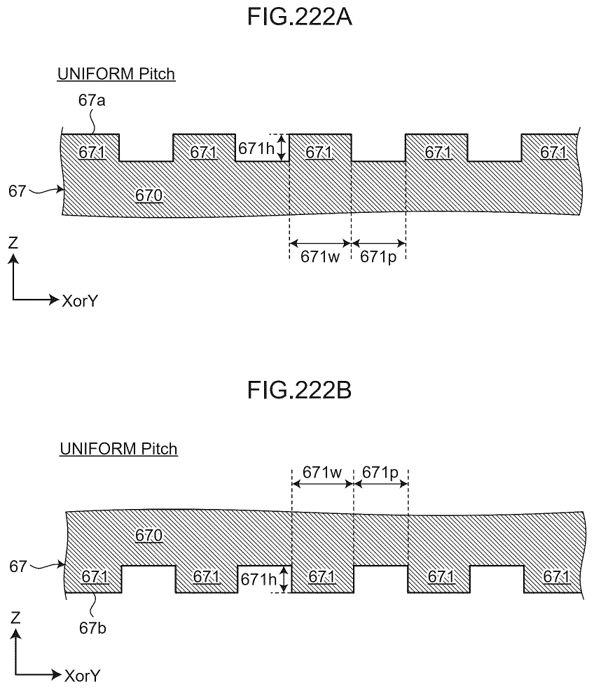

A contact surface between the etching stopper layer 67 and the pillar 62 and a contact surface between the etching stopper layer 67 and the filler 64 having different refractive indexes become a refractive index boundary surface. In order to suppress light reflection at this interface, the shape of the etching stopper layer 67 is devised as described below. This will be described with reference to FIG. 222.

FIG. 222 is a diagram illustrating an example of a schematic configuration of the etching stopper layer 67. At least one of the upper surface 67a and the lower surface 67b of the etching stopper layer 67 has an uneven shape.

In the example illustrated in (A) of FIG. 222, the upper surface 67a of the etching stopper layer 67 has an uneven shape. The etching stopper layer 67 includes a base portion 670 and a plurality of protruding portions 671. The base portion 670 has a constant thickness and extends in the XY planar direction. The protruding portion 671 protrudes upward (in the Z-axis positive direction) from the base portion 670. An uneven shape is defined by the base portion 670 and the plurality of protruding portions 671.

The length of the protruding portion 671 in the 2-axis direction is referred to as a height 671h. The length of the protruding portion 671 in the XY planar direction is referred to as a width 671w. The distance between the adjacent protruding portions 671 is referred to as a pitch 671p. In the example illustrated in (A) of FIG. 222, the plurality of protruding portions 671 are arranged at equal intervals, and the pitch 671p is constant (uniform pitch).

The height 671h and the pitch 671p may be set to small values such that light diffraction does not occur, for example. An example of the numerical value is about 40 nm.

In the example illustrated in (B) of FIG. 222, the lower surface 67b of the etching stopper layer 67 has an uneven shape. The plurality of protruding portions 671 project downward (in the Z-axis positive direction) from the base portion 670.

In a case where both the upper surface 67a and the lower surface 67b of the etching stopper layer 67 have an uneven shape, the configurations of (A) and (B) of FIG. 222 described above are combined. That is, the etching stopper layer 67 includes a plurality of protruding portions 671 protruding upward from the base portion 670 and a plurality of protruding portions 671 protruding downward from the base portion 670.

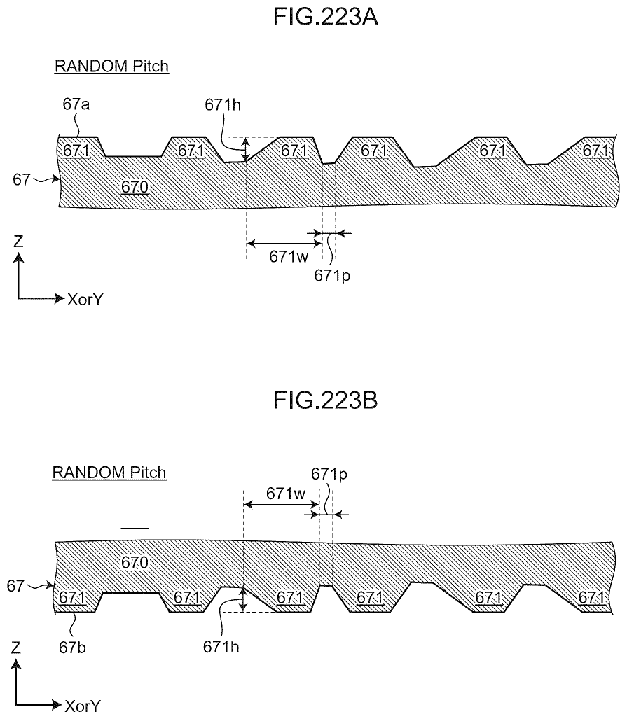

The pitch 671p may not be uniform. An example will be described with reference to FIG. 223.

FIG. 223 is a diagram illustrating an example of a schematic configuration of the etching stopper layer 67. For example, as illustrated in (A) of FIG. 223, on the upper surface 67a of the etching stopper layer 67, the pitch 671p of the plurality of protruding portions 671 defining the uneven shape may be randomly designed. As illustrated in (B) of FIG. 223, on the lower surface 67b of the etching stopper layer 67, the pitch 671p of the plurality of protruding portions 671 defining the uneven shape may be randomly designed. Naturally, a configuration in which (A) and (B) of FIG. 223 are combined is also possible.

For example, at least one of the upper surface 67a and the lower surface 67b of the etching stopper layer 67 has the uneven shape as described above. Hereinafter, it is assumed that the etching stopper layer 67-1 of the etching stopper layer 67-1 and the etching stopper layer 67-2 have an uneven shape. In particular, in a case where a two-layer structure such as the optical layer 6-1 and the optical layer 6-2 is adopted, light reflection at an interface between the etching stopper layer 67-1 located therebetween and each of the optical layer 6-1 and the optical layer 6-2 may become a problem, but the light reflection can be suppressed.

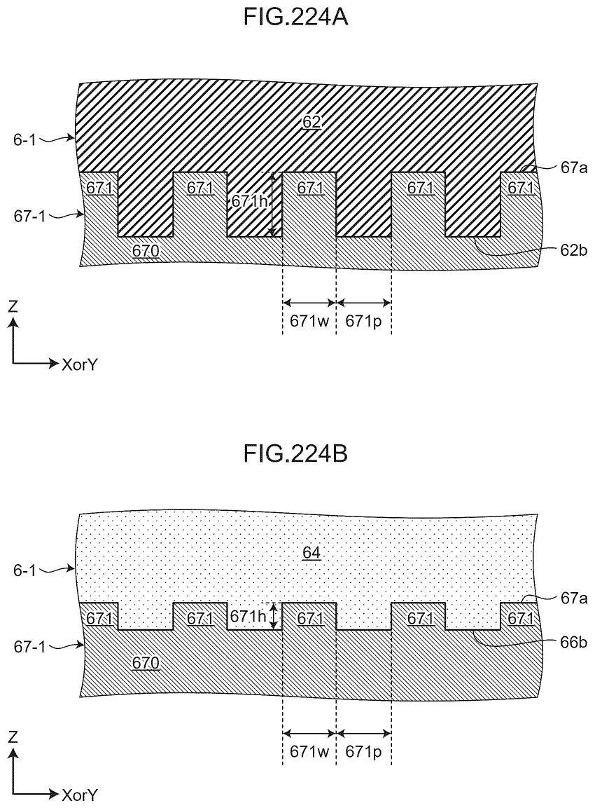

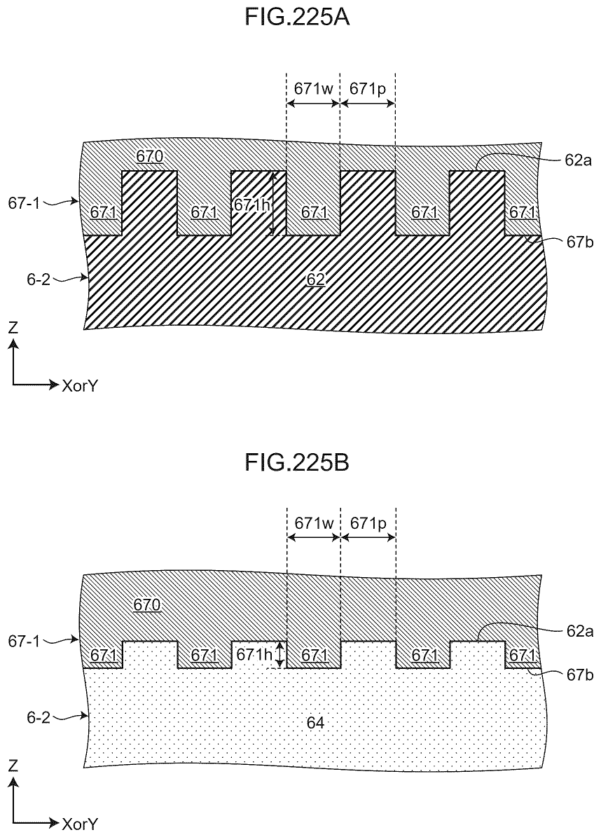

Specifically, the pillar 62 and the filler 64 (FIG. 221) are brought into surface contact with the etching stopper layer 67-1 having an uneven shape. This will be described with reference to FIGS. 224 and 225.

FIGS. 224 and 225 are diagrams illustrating an example of a schematic configuration of an interface between the etching stopper layer 67-1 and the pillar 62 and the filler 64 and its periphery.

In the example illustrated in FIG. 224, the upper surface 67a of the etching stopper layer 67-1 has an uneven shape. That is, the etching stopper layer 67-1 includes the plurality of protruding portions 671 protruding upward from the base portion 670.

As illustrated in (A) of FIG. 224, the pillar 62 of the optical layer 6-1 is provided on the upper surface 67a of the etching stopper layer 67-1 so as to fill the space between the plurality of protruding portions 671 of the etching stopper layer 67-1 (so as to fill the recess). As illustrated in (B) of FIG. 224, the filler 64 of the optical layer 6-1 is provided on the upper surface 67a of the etching stopper layer 67-1 so as to fill the space between the plurality of protruding portions 671 of the etching stopper layer 67-1.

In the example illustrated in FIG. 225, the lower surface 67b of the etching stopper layer 67-1 has an uneven shape. That is, the etching stopper layer 67-1 includes a plurality of protruding portions 671 protruding downward from the base portion 670.

As illustrated in (A) of FIG. 225, the pillar 62 of the optical layer 6-2 is provided on the lower surface 67b of the etching stopper layer 67-1 so as to fill the space between the plurality of protruding portions 671 of the etching stopper layer 67-1. As illustrated in (B) of FIG. 225, the filler 64 of the optical layer 6-2 is provided on the lower surface 67b of the etching stopper layer 67-1 so as to fill the space between the plurality of protruding portions 671 of the etching stopper layer 67-1.

In one embodiment, the uneven shape at the boundary surface between the etching stopper layer 67 and the pillar 62 and the uneven shape at the interface between the etching stopper layer 67 and the filler 64 may be different from each other. Examples of the difference in the uneven shape include a difference in height 671h, a difference in width 671w, and a difference in pitch 671p of the plurality of protruding portions 671 in each uneven shape. For example, the uneven shape for suppressing light reflection at the interface between the etching stopper layer 67 and the pillar 62 (high refractive index) and the uneven shape for suppressing light reflection at the interface between the etching stopper layer 67 and the filler 64 (low refractive index) can be individually optimized and designed.

Since the etching stopper layer 67-1 has the uneven shape as described above, the executed refractive index at the interface portion with the pillar 62 and the interface portion with the filler 64 is gradually changed, and light reflection can be suppressed. That is, the effective refractive index of the interface portion between the etching stopper layer 67-1 and the pillar 62 gradually changes between the refractive index of the etching stopper layer 67-1 and the refractive index of the pillar 62 in the vertical direction (Z-axis direction). As a result, light reflection at the interface between the etching stopper layer 67-1 and the pillar 62 can be suppressed. In addition, the effective refractive index of the interface portion between the etching stopper layer 67-1 and the filler 64 gradually changes between the refractive index of the etching stopper layer 67-1 and the refractive index of the filler 64 in the vertical direction. As a result, light reflection at the interface between the etching stopper layer 67-1 and the filler 64 can be suppressed.

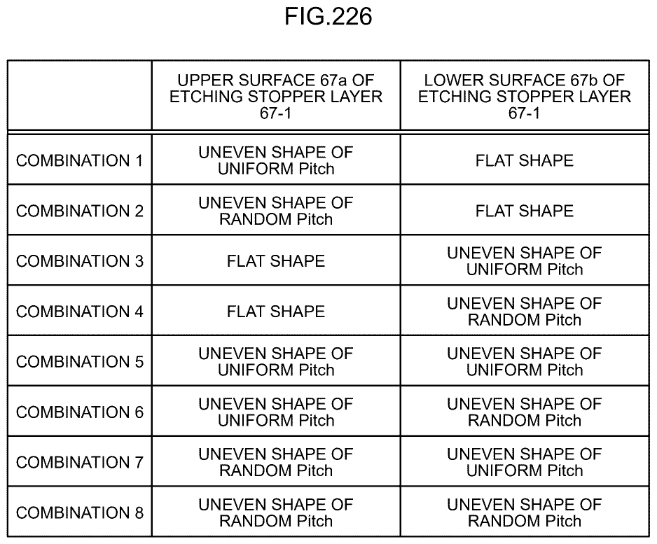

Various combinations of the upper surface 67a and the lower surface 67b of the etching stopper layer 67-1 and the shapes thereof are possible. This will be described with reference to FIG. 226.

FIG. 226 is a diagram illustrating an example of a combination of shapes of the upper surface 67a and the lower surface 67b of the etching stopper layer 67-1. The shape of each of the upper surface 67a and the lower surface 67b of the etching stopper layer 67-1 may be any of an uneven shape of a uniform pitch, an uneven shape of a random pitch, and a flat shape. The uneven shape of the uniform pitch is an uneven shape having a constant pitch 671p (FIG. 222). The uneven shape of the random pitch is an uneven shape having a random pitch 671p (FIG. 223). The flat shape is, for example, a shape of only the base portion 670 without the protruding portion 671.

The above-described three types of shapes are arbitrarily combined within a range in which at least one of the upper surface 67a and the lower surface 67b of the etching stopper layer 67-1 has an uneven shape. For example, eight combinations of combination 1 to combination 8 as illustrated in FIG. 226 are possible.

According to the optical layer 6 described above, it is possible to suppress light reflection at the interface between the etching stopper layer 67 and each of the pillar 62 and the filler 64 and the vicinity thereof. As a low reflection structure is obtained, there is a high possibility that the Qe (photodetection efficiency) can be improved.

In addition, the etching stopper layer 67, the pillars 62, and the filler 64 are provided so as to be fitted by the uneven shape. Since each adhesion is improved, reliability can be improved, for example, the film becomes strong against peeling during a manufacturing process, a reliability test, or the like.

### <Example of Range of Uneven Shape>

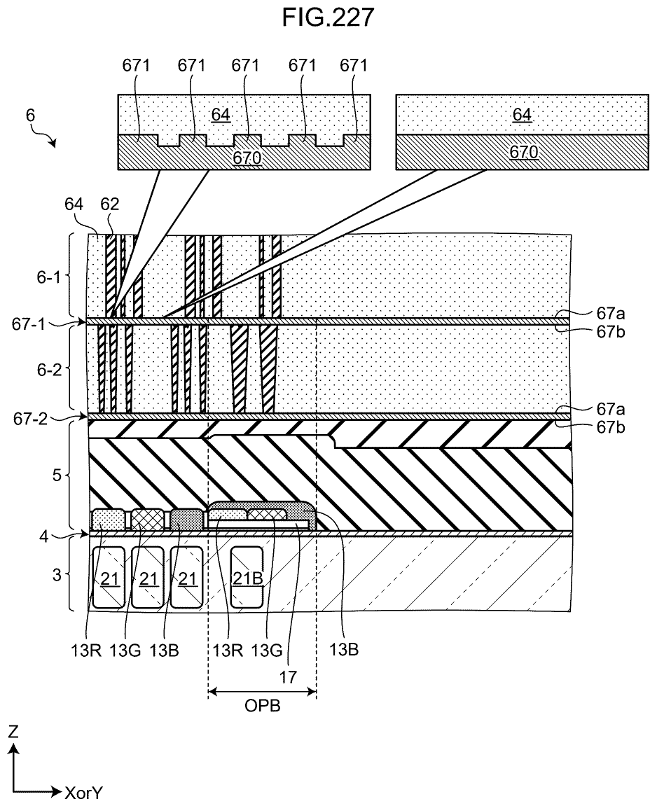

At least one of the upper surface 67a and the lower surface 67b of the etching stopper layer 67 may have an uneven shape over the entire surface, or may have an uneven shape only in a part thereof. A description will be given with reference to FIG. 227.

FIG. 227 is a diagram illustrating an example of a schematic configuration of the optical layer 6. The fixed charge film 4 and the semiconductor substrate 3 located below the insulating layer 5 are also illustrated. As the color filter 13 included in the insulating layer 5, a color filter 13R, a color filter 13G, and a color filter 13B are also illustrated. The color filter 13R allows red light to pass therethrough. The color filter 13G allows green light to pass therethrough. The color filter 13B allows blue light to pass therethrough. In addition, the photoelectric conversion section 21 included in the semiconductor substrate 3 is also illustrated. Each photoelectric conversion section 21 is covered with the color filter 13 of a corresponding color.

The optical layer 6 includes an optical black (OPB) region, and a photoelectric conversion section included in the OPB region is referred to as a photoelectric conversion section 21B in the drawing. The OPB region is used to obtain a pixel signal level when light is not incident on the photoelectric conversion section 21B. The photoelectric conversion section 21B may have a configuration similar to the photoelectric conversion section 21. In the OPB region, the insulating layer 5 includes a light shielding film 17 (for example, a metal film) provided to cover the photoelectric conversion section 21B. Furthermore, in order to suppress light reflection at the light shielding film 17, the color filter 13R, the color filter 13G, and the color filter 13B are provided so as to cover the light shielding film 17.

Among the photoelectric conversion section 21 and the photoelectric conversion section 21B, it can be said that the photoelectric conversion section 21 is a photoelectric conversion section that is not shielded from light, and the photoelectric conversion section 21B is a photoelectric conversion section that is shielded from light.

There may be uneven shape at various positions on the upper surface 67a and the lower surface 67b of the etching stopper layer 67. For example, at least one of the upper surface 67a and the lower surface 67b of the etching stopper layer 67 may have an uneven shape over the entire surface. On the contrary, only a part of the surface may have an uneven shape. In the example illustrated in FIG. 227, the upper surface 67a of the etching stopper layer 67-1 has an uneven shape in a part thereof and has a flat shape in the other part.

In one embodiment, at least one of the upper surface 67a and the lower surface 67b of the etching stopper layer 67 may have an uneven shape in a portion facing one of the photoelectric conversion section 21 and the photoelectric conversion section 21B. That is, at least one of the upper surface 67a and the lower surface 67b of the etching stopper layer 67 may have an uneven shape only in a portion corresponding to the photoelectric conversion section 21 that is not shielded from light, or may have an uneven shape only in a portion corresponding to the photoelectric conversion section 21B that is shielded from light (that is, the OPB region). At least one of the upper surface 67a and the lower surface 67b of the etching stopper layer 67 may have an uneven shape only in a portion of the photoelectric conversion section 21 corresponding to a more specific photoelectric conversion section 21, or may have an uneven shape only in a portion corresponding to a part of the OPB region.

### <Example of Manufacturing Method>

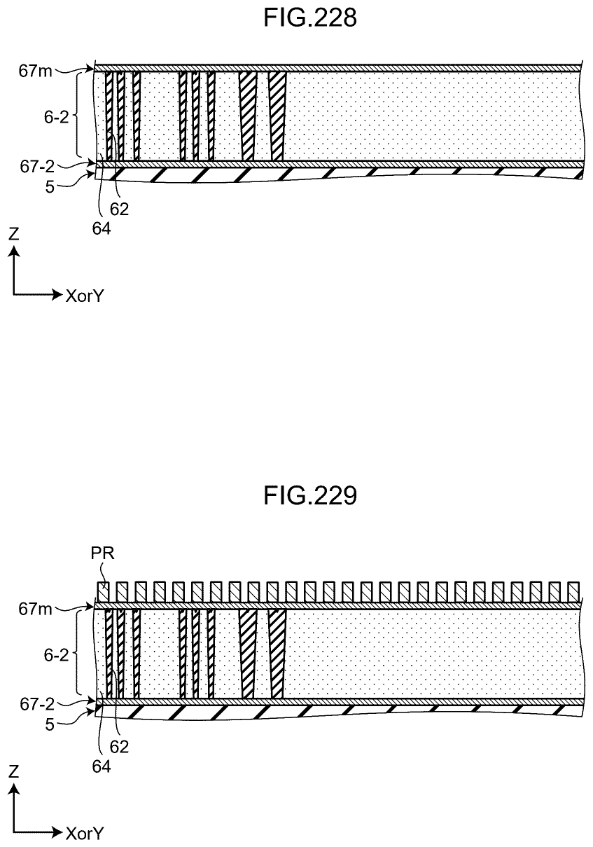

FIGS. 228 to 243 are diagrams illustrating an example of a manufacturing method. The material of the etching stopper layer 67 is referred to as an etching stopper material 67m.

### <Upper Surface 67a and Uniform Pitch>

FIGS. 228 to 234 illustrate an example of a manufacturing method in a case where the upper surface 67a of the etching stopper layer 67-1 has a uniform pitch uneven shape. As a premise, it is assumed that a configuration up to the etching stopper layer 67-2 and the optical layer 6-2 sequentially laminated on the insulating layer 5 is obtained.

As illustrated in FIG. 228, the etching stopper material 67m is provided (for example, a film is formed) so as to cover the optical layer 6-2.

As illustrated in FIG. 229, the photoresist PR for DSA lithography is provided on the etching stopper material 67m. The photoresist PR is patterned in accordance with an uneven shape to be provided to the etching stopper layer 67-1. The interval between the adjacent protruding portions (corresponding to the pitch 671p described above) can be set to a small interval at which diffraction does not occur.

As illustrated in FIG. 230, the etching stopper material 67m is processed to have a uniform uneven shape by DSA lithography. As illustrated in an enlarged manner in the drawing, the uneven shape of the uniform pitch is obtained. Thereafter, the filler 64 is provided on the etching stopper material 67m. A material of the filler 64 is processed by dry etching or the like and cleaned so as to obtain a void portion (also referred to as a recess or the like) corresponding to the pillar 62.

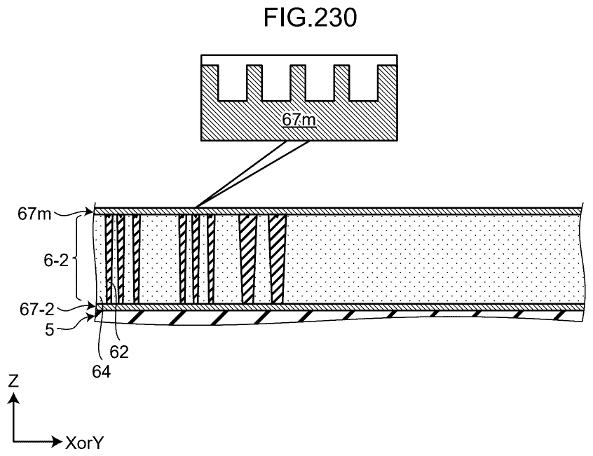

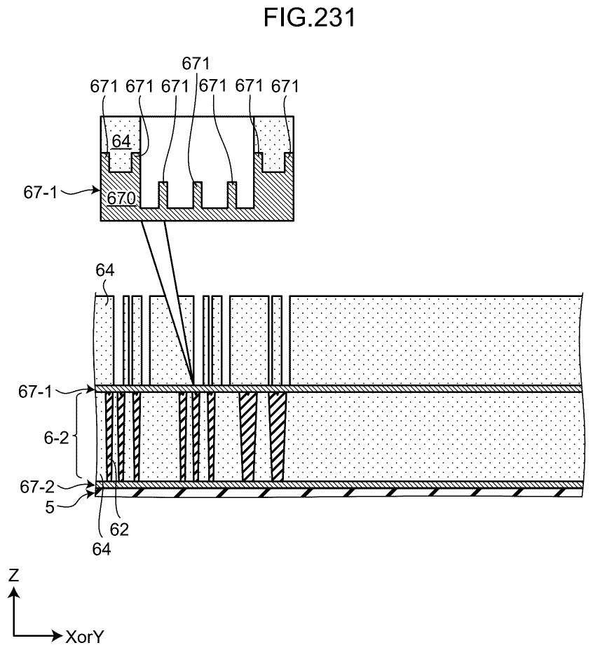

As illustrated in FIG. 231, the uneven shape is transferred even after the material of the filler 64 is processed. During the processing, a portion of the etching stopper material 67m that is not covered with the material of the filler 64 is also processed, and the etching stopper layer 67-1 is obtained. In the portion of the filler 64 not covered with the material, the distance (corresponding to the pitch 671p) between the adjacent protruding portions 671 is increased by thinning the protruding portion 671 or the like. The uneven shape of this portion and the uneven shape of the other portion are different from each other.

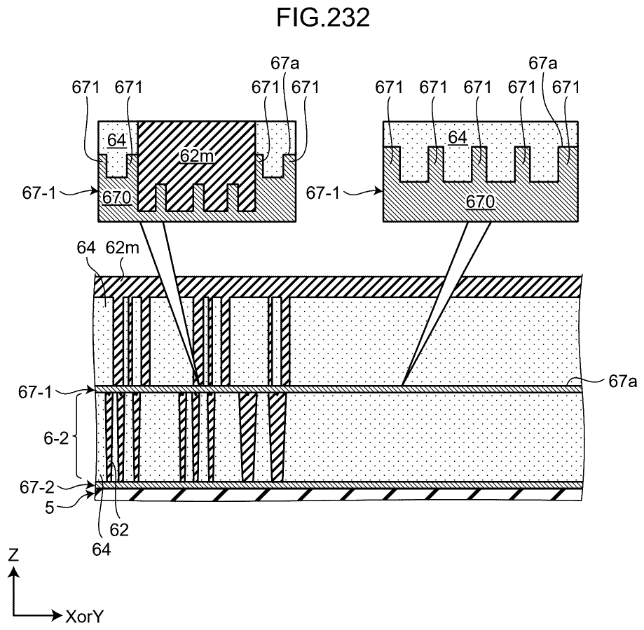

As illustrated in FIG. 232, the pillar material 62m is provided (for example, a film is formed) so as to cover the filler 64 and the etching stopper layer 67-1. The upper surface 67a of the etching stopper layer 67-1 has an uneven shape defined by the base portion 670 and the plurality of protruding portions 671. The uneven shape at the interface between the etching stopper layer 67-1 and the pillar material 62m thereon and the uneven shape at the interface between the etching stopper layer 67-1 and the filler 64 thereon are different from each other. In this example, each uneven shape is an uneven shape of a uniform pitch.

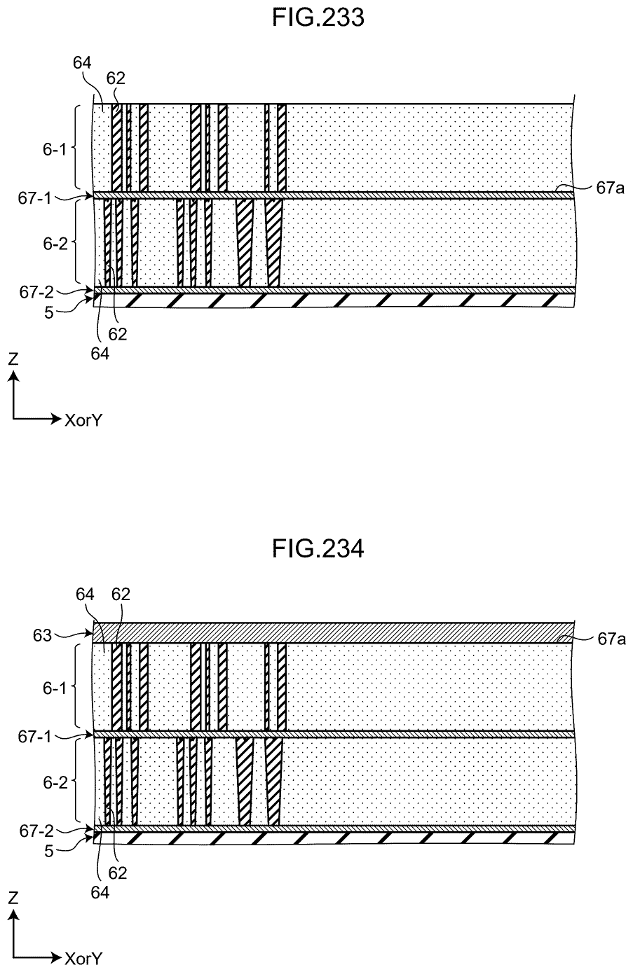

As illustrated in FIG. 233, the pillar material 62m is planarized by CMP. The optical layer 6-1 including the plurality of pillars 62 and the filler 64 provided so as to fill the space therebetween is obtained.

Note that, as illustrated in FIG. 234, the reflection suppressing film 63 may be further provided (for example, may be formed) so as to cover the optical layer 6-1. The light reflection suppressing effect can be further enhanced.

Note that, since the upper surface 67a of the etching stopper layer 67-1 has an uneven shape, there is also an advantage that resistance to peeling derived from film stress and CMP is improved in the process of forming the pillar material 62m and forming the CMP and reflection suppressing film 63 (FIGS. 232 to 234) described above, for example.

### <Upper Surface 67a and Random Pitch>

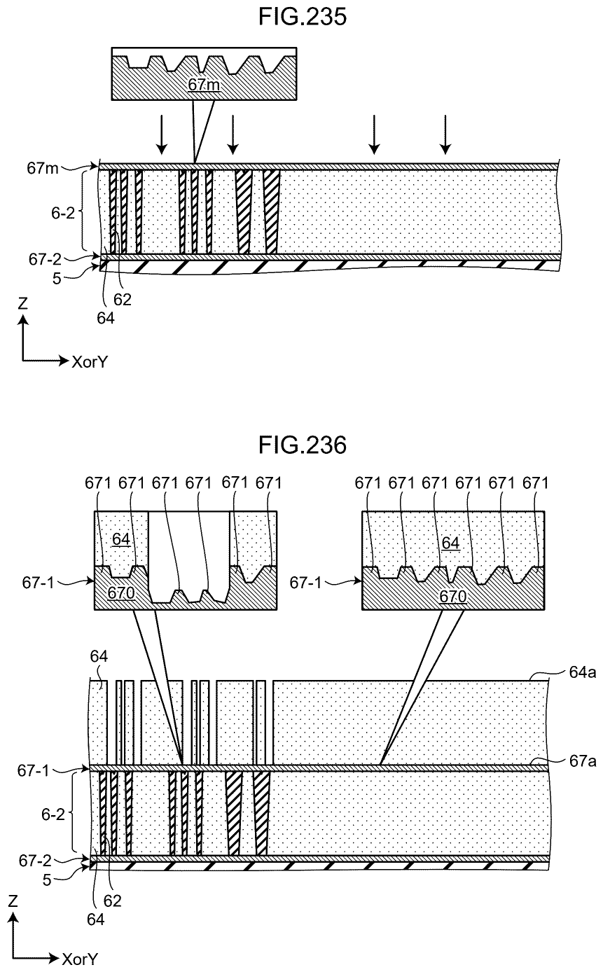

FIGS. 235 to 238 illustrate an example of a manufacturing method in a case where the upper surface 67a of the etching stopper layer 67-1 has a random pitch uneven shape. As a premise, it is assumed that a configuration similar to that of FIG. 228 described above is obtained.

As illustrated in FIG. 235, sputtering including He/Ar plasma irradiation, for example, is performed on the upper surface (the surface on the Z-axis positive direction side) of the etching stopper material 67m. Various known processing apparatuses, film forming apparatuses, and the like may be used. As illustrated in an enlarged manner in the drawing, random irregularities are formed in the etching stopper material 67m. Thereafter, the filler 64 is provided on the etching stopper material 67m. The material of the filler 64 is processed by dry etching or the like and cleaned so as to obtain a void portion corresponding to the pillar 62.

As illustrated in FIG. 236, the uneven shape is transferred even after the material of the filler 64 is processed. During the processing, a portion of the etching stopper material 67m that is not covered with the material of the filler 64 is also processed, and the etching stopper layer 67-1 is obtained. In the portion of the filler 64 not covered with the material, the distance (corresponding to the pitch 671p) between the adjacent protruding portions 671 is increased by thinning the protruding portion 671 or the like. The uneven shape of this portion and the uneven shape of the other portion are different from each other.

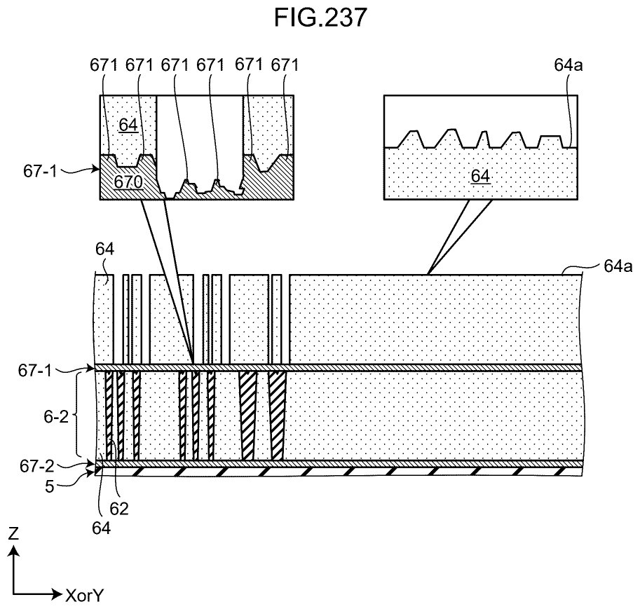

The steps illustrated in FIG. 237 are optional and may optionally be employed. In this step, further sputtering is performed, thereby further increasing the distance between the protruding portions 671 of the portion of the etching stopper layer 67-1 not covered with the material of the filler 64. In addition, the roughness of the upper surface 64a of the filler 64 may increase.

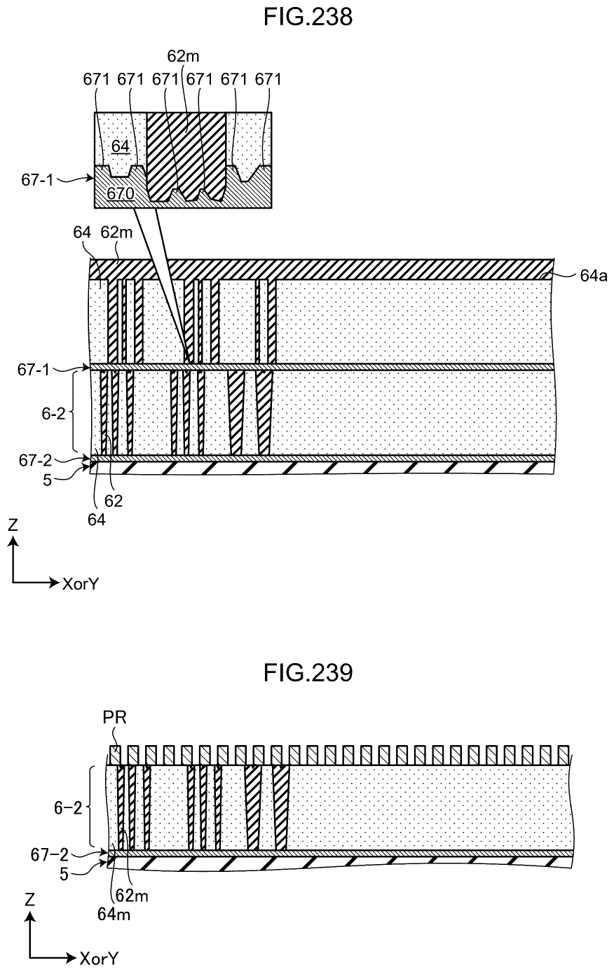

After the step of FIG. 236 or 237 described above, as illustrated in FIG. 238, the pillar material 62m is provided (for example, a film is formed) so as to cover the filler 64 and the etching stopper layer 67-1. The upper surface 67a of the etching stopper layer 67-1 has an uneven shape defined by the base portion 670 and the plurality of protruding portions 671. The uneven shape at the interface between the etching stopper layer 67-1 and the pillar material 62m thereon and the uneven shape at the interface between the etching stopper layer 67-1 and the filler 64 thereon are different from each other. In this example, each uneven shape is an uneven shape of a random pitch.

Thereafter, similarly to FIGS. 233 and 234 described above, the pillar material 62m is planarized by CMP, and the reflection suppressing film 63 is provided.

### <Lower Surface 67b and Uniform Pitch>

FIGS. 239 to 241 illustrate an example of a manufacturing method in a case where the lower surface 67b of the etching stopper layer 67-1 has a uniform pitch uneven shape. As a premise, it is assumed that a configuration including the etching stopper layer 67-2 sequentially laminated on the insulating layer 5 and the materials of the pillar material 62m and the filler 64 is obtained. The material of the filler 64 is also referred to as a filler material 64m.

As illustrated in FIG. 239, the photoresist PR for DSA lithography is provided on the optical layer 6-2 so as to cover the pillar material 62m and the filler material 64m of the optical layer 6-2. The photoresist PR is patterned in accordance with an uneven shape to be provided to the etching stopper layer 67-1. The interval between the adjacent protruding portions (corresponding to the pitch 671p described above) can be set to a small interval at which diffraction does not occur.

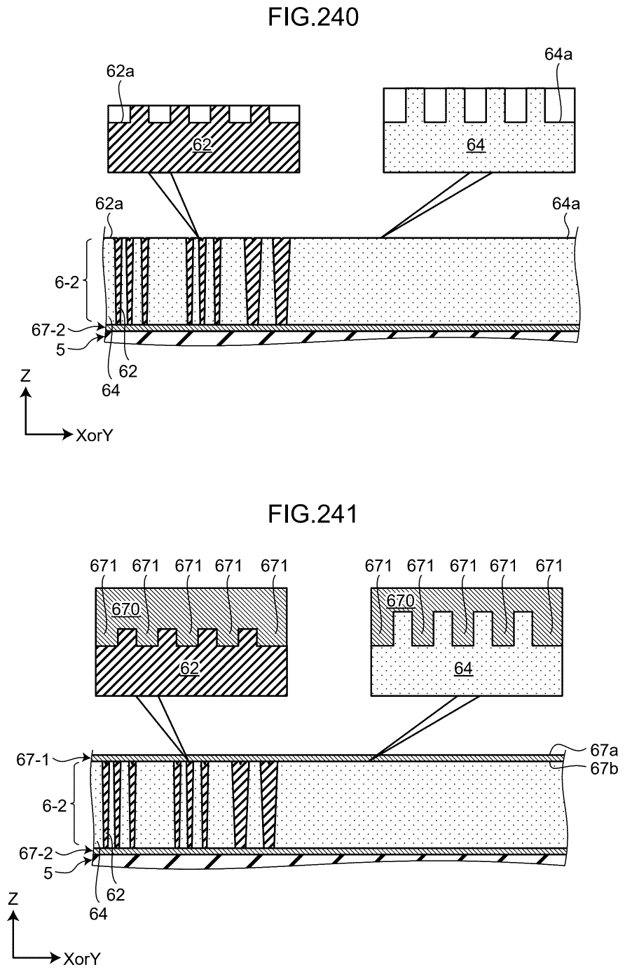

As illustrated in FIG. 240, the pillar material 62m and the filler material 64m of the optical layer 6-2 are processed by DSA lithography so as to have a uniform uneven shape, thereby obtaining the pillar 62 and the filler 64. As illustrated in an enlarged manner in the drawing, the uneven shape of the uniform pitch is obtained.

At this time, due to the difference in the etching rate, the uneven shape on the upper surface 62a of the pillar 62 and the uneven shape on the upper surface 64a of the filler 64 are processed so as to be different (for example, so as to have different uneven depths). For example, in a case where the filler material 64m is TEOS and the pillar material 62m is Tio, the filler 64 can be etched deeply by using CF gas, and the pillar 62 can be etched deeply by using Cl gas. By using different dry etching conditions, it is possible to select which of the pillar 62 and the filler 64 is to be deeply etched.

As illustrated in FIG. 241, the etching stopper layer 67-1 is provided on the optical layer 6-2 so as to cover the pillars 62 and the filler 64 of the optical layer 6-2. The lower surface 67b of the etching stopper layer 67-1 has an uneven shape defined by the base portion 670 and the plurality of protruding portions 671. The uneven shape at the interface between the etching stopper layer 67-1 and the pillar 62 of the optical layer 6-2 and the uneven shape at the interface between the etching stopper layer 67-1 and the filler 64 of the optical layer 6-2 are different from each other. In this example, each uneven shape is an uneven shape of a uniform pitch.

Although not illustrated, by providing the optical layer 6-1 and the reflection suppressing film 63 on the etching stopper layer 67-1, the optical layer 6 in which the lower surface 67b of the etching stopper layer 67-1 has an uneven shape is obtained. In a case where the upper surface 67a of the etching stopper layer 67-1 also has an uneven shape, a process similar to that in FIGS. 229 to 234 described above may be used.

### <Lower Surface 67b and Random Pitch>

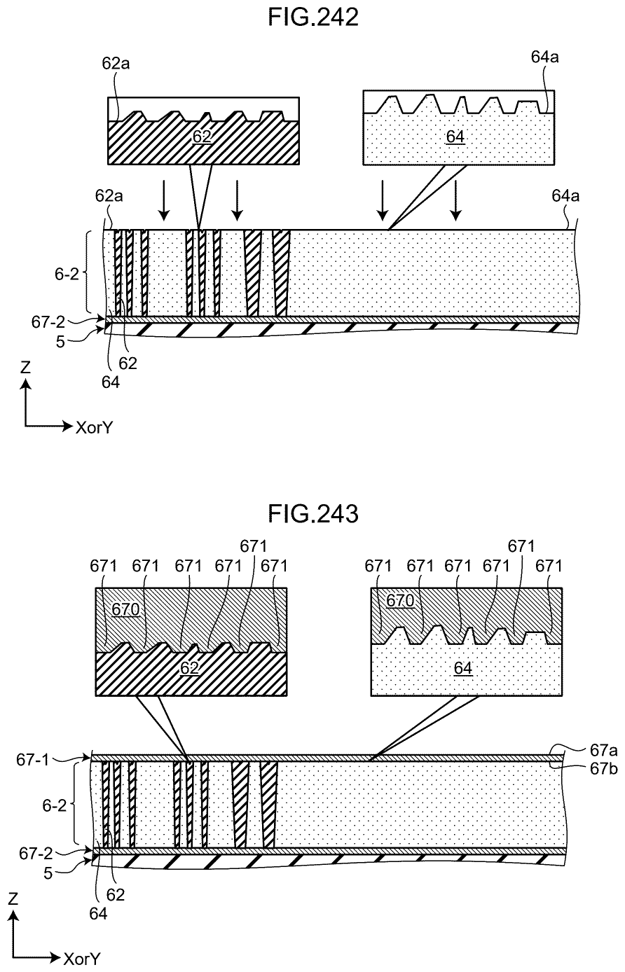

FIGS. 242 and 243 illustrate an example of a manufacturing method in a case where the lower surface 67b of the etching stopper layer 67-1 has a random pitch uneven shape. As a premise, it is assumed that a configuration including the etching stopper layer 67-2 sequentially laminated on the insulating layer 5, the pillar material 62m, and the filler material 64m is obtained.

As illustrated in FIG. 242, sputtering including He/Ar plasma irradiation, for example, is performed on the upper surfaces of the pillar material 62m and the filler material 64m. As illustrated in an enlarged manner in the drawing, the pillars 62 and the filler 64 having random uneven shapes are obtained. At this time, due to the difference in the etching rate, the uneven shape on the upper surface 62a of the pillar 62 and the uneven shape on the upper surface 64a of the filler 64 are processed so as to be different (for example, so as to have different uneven depths).

As illustrated in FIG. 243, the etching stopper layer 67-1 is provided on the optical layer 6-2 so as to cover the pillars 62 and the filler 64 of the optical layer 6-2. The lower surface 67b of the etching stopper layer 67-1 has an uneven shape defined by the base portion 670 and the plurality of protruding portions 671. The uneven shape at the interface between the etching stopper layer 67-1 and the pillar 62 of the optical layer 6-2 and the uneven shape at the interface between the etching stopper layer 67-1 and the filler 64 of the optical layer 6-2 are different from each other. In this example, each uneven shape is an uneven shape of a random pitch.

### EXAMPLES

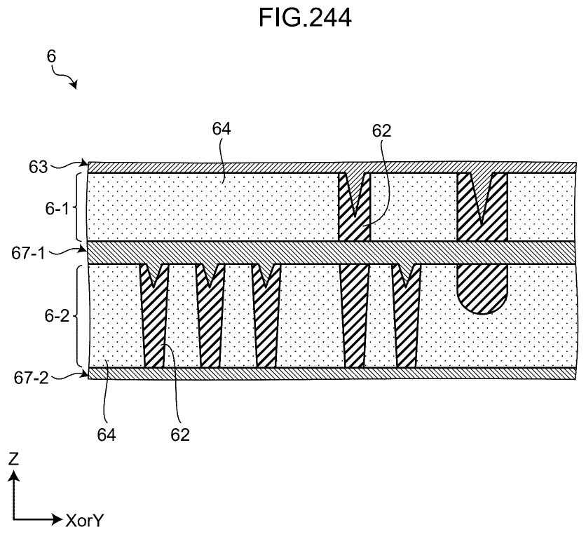

FIG. 244 is a diagram illustrating an example. An example of a configuration of the optical layer 6 based on the configuration described above is schematically illustrated.

The pillar 62 may be an inorganic film, and may be specifically TiO, SiN, SiON, c-Si, p-Si, a-Si, GaP, GaN, GaAs, SiC, or the like. These may be arbitrarily combined and used as the pillar 62.

The filler 64 may also be an inorganic film, and specifically, may be Sio, Air, or the like. These may be combined and used as the filler 64.

The thickness of each layer (film thickness of each film) may be, for example, about 100 nm to 2000 nm. The diameter of the pillar 62 in plan view may be about 80 nm to 800 nm.

Examples of the material of the reflection suppressing film 63 include SiN and Sio, but are not limited thereto. The reflection suppressing film 63 may have a single-layer structure or a laminated structure.

Examples of the material of the etching stopper layer 67 include SiN, SiON, HfO, and ALO.

The optical layer 6 may be provided and used on the semiconductor substrate 3 including the photoelectric conversion section 21 as described above. It can also be said that the optical layer 6 is incorporated (integrated) into a sensor such as the photodetector 100 and used. The present invention can also be applied to various sensors other than the photodetector 100.

The optical layer 6 may be provided on a glass substrate or the like. It can also be completely handled as an element (device or the like) having a prism function, a lens function, and the like by the optical layer 6.

### <Section Summary>

The technology according to the seventh embodiment described above is specified as follows, for example. One of the disclosed techniques is the photodetector 100. As described with reference to FIGS. 1 to 5, 221 to 227, 244, and the like, the photodetector 100 includes the photoelectric conversion section 21 and the optical layer 6 provided to cover the photoelectric conversion section 21. The optical layer 6 includes the plurality of pillars 62 arranged side by side in a plane direction (XY planar direction) of the layer so as to guide at least light to be detected among the incident light to the photoelectric conversion section 21, and the etching stopper layer 67 provided on at least one of the upper surface 62a and the lower surface 62b of the pillar 62. At least one of the upper surface 67a and the lower surface 67b of the etching stopper layer 67 has an uneven shape. As a result, light reflection at the interface (and the vicinity thereof) between the pillar 62 and the etching stopper layer 67 can be suppressed.

As described with reference to FIGS. 221 to 225, 227, and the like, the optical layer 6 includes the filler 64 provided so as to fill the space between the plurality of pillars 62, and the uneven shape at the interface between the etching stopper layer 67 and the pillars 62 and the uneven shape at the interface between the etching stopper layer 67 and the filler 64 may be different from each other. For example, the etching stopper layer 67 includes a plurality of protruding portions 671 defining an uneven shape, and the difference in the uneven shape may include at least one of the height 671h, the width 671w, and the pitch 671p of the plurality of protruding portions 671. Each uneven shape can be individually optimized and designed.

As described with reference to FIGS. 221 to 227 and the like, the optical layer 6 includes the optical layer 6-1 (first optical layer) and the optical layer 6-2 (second optical layer) located between the optical layer 6-1 and the photoelectric conversion section 21, the etching stopper layer 67 includes the etching stopper layer 67-1 (first etching stopper layer) located between the optical layer 6-1 and the optical layer 6-2, and the etching stopper layer 67-2 (second etching stopper layer) located on the opposite side to the etching stopper layer 67-1 with the optical layer 6-2 interposed therebetween, and at least one surface of the upper surface 67a and the lower surface 67b of the etching stopper layer 67-1 of the etching stopper layer 67-1 and the etching stopper layer 67-2 may have an uneven shape. Both the upper surface 67a and the lower surface 67b of the etching stopper layer 67-1 may have an uneven shape. In particular, it is possible to suppress light reflection at an interface between the etching stopper layer 67-1 and each of the optical layer 6-1 and the optical layer 6-2, which may be a problem in a case where a two-layer structure such as the optical layer 6-1 and the optical layer 6-2 is adopted.

As described with reference to FIG. 227 and the like, at least one of the upper surface 67a and the lower surface 67b of the etching stopper layer 67 may have an uneven shape over the entire surface. The photoelectric conversion section 21 includes the photoelectric conversion section 21 that is not shielded from light and the photoelectric conversion section 21B that is shielded from light, and at least one surface of the upper surface 67a and the lower surface 67b of the etching stopper layer 67 may have an uneven shape in a portion facing one photoelectric conversion section of the photoelectric conversion section 21 that is not shielded from light and the photoelectric conversion section 21B that is shielded from light. For example, as described above, it is possible to impart an uneven shape to various ranges of the etching stopper layer 67 to suppress light reflection at the portions.

### 8. CONCLUSION

The embodiments of the present disclosure have been described above. Light reflection can be suppressed by various techniques described so far. Note that the effects described in the present disclosure are merely examples and are not limited to the disclosed contents. There may be other effects.

The technical scope of the present disclosure is not limited to the above-described embodiments as it is, and various modifications can be made without departing from the gist of the present disclosure. In addition, components of different embodiments and modifications may be appropriately combined.

Note that the disclosed technology can also have the following configurations.

(1)

A photodetector comprising:
a photoelectric conversion section; and
an optical layer provided to cover the photoelectric conversion section, wherein
the optical layer includes:
a plurality of pillars arranged side by side in a plane direction of a layer to guide at least light to be detected among incident light to the photoelectric conversion section; and
a reflection suppressing film provided on at least one of an upper surface and a lower surface of the pillar, and
the reflection suppressing film has a non-flat portion including at least one of a recess and a protrusion.

(2)

The photodetector according to (1), wherein
the reflection suppressing film has a refractive index higher than a refractive index of an upper region of the reflection suppressing film, and
the non-flat portion of the reflection suppressing film has a shape in which a cross-sectional area when viewed in a thickness direction of the reflection suppressing film gradually decreases as it advances upward.

(3)

The photodetector according to (1) or (2), wherein
the non-flat portion includes the recess, and
a shape of the recess includes at least one of a pyramid shape and a rectangular shape.

(4)

The photodetector according to any one of (1) to (3), wherein
the light to be detected includes infrared light, and
the non-flat portion has a height of 400 nm or less.

(5)

The photodetector according to any one of (1) to (4), wherein
the optical layer includes the reflection suppressing film provided on the upper surface of the pillar.

(6)

The photodetector according to any one of (1) to (5), wherein
the optical layer includes the reflection suppressing film provided on the lower surface of the pillar.

(7)

The photodetector according to any one of (1) to (6), wherein
the optical layer includes:
the reflection suppressing film provided on the upper surface of the pillar; and
the reflection suppressing film provided on the lower surface of the pillar.

(8)

A photodetector comprising:
a photoelectric conversion section; and
an optical layer provided to cover the photoelectric conversion section, wherein
the optical layer includes a plurality of pillars arranged side by side in a plane direction of a layer to guide at least light to be detected among incident light to the photoelectric conversion section,
the pillar has a cross-sectional area that continuously changes as it advances in a pillar height direction, and
at least one of an upper surface and a lower surface of the pillar is a curved surface.

(9)

The photodetector according to (8), wherein
at least some of the plurality of pillars have different maximum widths, and
a height of the pillar having a largest maximum width among the plurality of pillars is larger than a height of the pillar having a smallest maximum width.

(10)

The photodetector according to (8) or (9), wherein
the plurality of pillars provide a lens function to the optical layer.

(11)

The photodetector according to any one of (8) to (10), wherein
the plurality of pillars provide a prism function to the optical layer.

(12)

The photodetector according to any one of (8) to (11), wherein
the plurality of pillars provide a lens function and a prism function to the optical layer.

(13)

The photodetector according to any one of (8) to (12), wherein
the upper surface of the pillar is a curved surface,
the lower surface of the pillar is a flat surface, and
the pillar has a cross-sectional area that monotonically decreases toward the upper surface.

(14)

The photodetector according to any one of (8) to (12), wherein
the upper surface of the pillar is a flat surface,
the lower surface of the pillar is a curved surface, and
the pillar has a cross-sectional area that monotonically decreases toward the lower surface.

(15)

The photodetector according to any one of (8) to (12), wherein the upper surface and the lower surface of the pillar are
curved surfaces.

(16)

The photodetector according to (15), wherein
the pillar has a cross-sectional area that monotonically increases and monotonically decreases from one surface to the other surface of the upper surface and the lower surface.

(17)

The photodetector according to any one of (8) to (16), wherein
the optical layer includes a filler provided to fill a space between the plurality of pillars.

(18)

The photodetector according to (17), wherein
the filler has a refractive index different from a refractive index of the pillar by 0.3 or more.

(19)

The photodetector according to (17) or (18), wherein
the optical layer includes a protective film provided to cover the filler.

(20)

The photodetector according to (17) or (18), wherein
the upper surface of the pillar is a flat surface,
the lower surface of the pillar is a curved surface,
the optical layer includes a base layer provided in common on the upper surface of each of the plurality of pillars,
the optical layer includes an additional layer provided on the base layer, and
the additional layer includes a plurality of films each having a different refractive index.

(21)

The photodetector according to (20), wherein the film is a reflection suppressing film or a band pass filter.

(22)

The photodetector according to any one of (8) to (21), further comprising
a plurality of the optical layer laminated.

(23)

The photodetector according to any one of (8) to (22), wherein
a material of the pillar includes at least one of amorphous silicon, polycrystalline silicon, and germanium, and the pillar has a height of 200 nm or more.

(24)

The photodetector according to any one of (8) to (22), wherein
a material of the pillar includes at least one of titanium oxide, niobium oxide, tantalum oxide, aluminum oxide, hafnium oxide, silicon nitride, silicon oxide, silicon nitride oxide, silicon carbide, silicon carbide oxide, silicon carbide nitride, and zirconium oxide, and
the pillar has a height of 300 nm or more.

(25)

The photodetector according to any one of (8) to (24), further including
a light shielding film provided between the photoelectric conversion section and the optical layer and having an opening facing at least a part of the photoelectric conversion section.

(26)

The photodetector according to (25), in which
the opening of the light shielding film is a pinhole having an aperture ratio of 25% or less.

(27)

The photodetector according to (25), further including
a plurality of pixels each including the photoelectric conversion section, in which
the plurality of pixels includes a first image plane phase difference pixel and a second image plane phase difference pixel, and
the light shielding film includes a first opening and a second opening facing different portions of the photoelectric conversion section of the first image plane phase difference pixel and the photoelectric conversion section of the second image plane phase difference pixel.

(28)

The photodetector according to any one of (8) to (27), further including:
a semiconductor substrate including a plurality of the photoelectric conversion section and having an upper surface facing the optical layer; and
an element separating portion provided to extend at least from the upper surface of the semiconductor substrate between adjacent photoelectric conversion sections in the semiconductor substrate.

(29)

The photodetector according to any one of (8) to (28), further including
a lens provided on at least one of a side opposite to the photoelectric conversion section with the optical layer interposed therebetween and between the photoelectric conversion section and the optical layer.

(30)

The photodetector according to any one of (8) to (29), further including
a plurality of pixels each including the photoelectric conversion section, in which
the photoelectric conversion sections of at least some of the plurality of pixels are a plurality of photoelectric conversion sections divided.

(31)

The photodetector according to any one of (8) to (30), further including
a semiconductor substrate including a plurality of the photoelectric conversion section and having an upper surface facing the optical layer, in which
the upper surface of the semiconductor substrate has an uneven shape.

(32)

The photodetector according to any one of (8) to (31), further including:
a semiconductor substrate including a plurality of the photoelectric conversion section; and
a light guide section provided between the semiconductor substrate and the optical layer, in which the light guide section includes a light shielding wall provided at a position corresponding to a boundary between adjacent photoelectric conversion sections among the plurality of photoelectric conversion section.

(33)

The photodetector according to any one of (8) to (31), further including:
a semiconductor substrate including a plurality of the photoelectric conversion section; and
a light guide section provided between the semiconductor substrate and the optical layer, in which
the light guide section includes a cladding portion provided at a position corresponding to a boundary between adjacent photoelectric conversion sections among the plurality of photoelectric conversion section and having a refractive index lower than a refractive index of other portions of the light guide section.

(34)

The photodetector according to (33), in which the cladding portion is a void portion.

(35)

The photodetector according to any one of (8) to (34), further including
a filter provided on at least one of a side opposite to the photoelectric conversion section with the optical layer interposed therebetween and between the photoelectric conversion section and the optical layer, in which
the filter includes
at least one of:
a color filter;
a band pass filter in which films having different refractive indexes are laminated;
a Fabry-Perot interference filter in which films having different refractive indexes are laminated;
a surface plasmon filter; and
a Guided Mode Resonance (GMR) filter.

(36)

The photodetector according to any one of (8) to (35), further including:
a first optical layer;
a second optical layer; and
another element provided between the first optical layer and the second optical layer, in which
the another element includes
at least one of:
a light shielding film having an opening facing at least a part of the photoelectric conversion section;
a lens;
a light shielding wall provided at a position corresponding to a boundary between adjacent photoelectric conversion sections among the plurality of photoelectric conversion section;
a cladding portion provided at a position corresponding to a boundary between adjacent photoelectric conversion sections among the plurality of photoelectric conversion section and having a refractive index lower than a refractive index of a peripheral portion;
a color filter;
a band pass filter in which films having different refractive indexes are laminated;
a Fabry-Perot interference filter in which films having different refractive indexes are laminated;
a surface plasmon filter; and
a Guided Mode Resonance (GMR) filter.

(37)

A photodetector comprising:
a photoelectric conversion section; and an optical layer provided to cover the photoelectric conversion section, wherein
the optical layer includes a plurality of pillars arranged side by side in a plane direction of a layer to guide at least light to be detected among incident light to the photoelectric conversion section, and
an upper surface of the pillar includes a non-flat portion including at least one of a recess and a protrusion.

(38)

The photodetector according to (37), wherein
the optical layer includes an interlayer film provided on the upper surface of the pillar to fill the recess of the non-flat portion.

(39)

The photodetector according to (37) or (38), wherein
the optical layer includes:
an interlayer film provided on the upper surface of the pillar; and
an upper layer film provided on the interlayer film.

(40)

The photodetector according to any one of (37) to (39), wherein
the recess of the non-flat portion is filled with a heterogeneous film or is a void.

(41)

The photodetector according to any one of (37) to (40), wherein
at least some of the plurality of pillars have different sizes, and
ratios of volumes occupied by the recesses of the non-flat portions in the pillars having different sizes are different from each other.

(42)

The photodetector according to any one of (37) to (40), wherein
at least some of the plurality of pillars have different sizes, and
ratios of volumes occupied by the recesses of the non-flat portions in the pillars having different sizes are the same.

(43)

The photodetector according to any one of (37) to (42), wherein
at least some of the plurality of pillars have different sizes, and
depths of the recesses of the non-flat portions in the pillars having different sizes are different from each other.

(44)

The photodetector according to any one of (37) to (42), wherein
at least some of the plurality of pillars have different sizes, and
depths of the recesses of the non-flat portions in the pillars having different sizes are the same.

(45)

The photodetector according to any one of (37) to (44), wherein
a cross-sectional area of the recess of the non-flat portion when viewed in a depth direction is the same at any depth position.

(46)

The photodetector according to any one of (37) to (44), wherein
a cross-sectional area of the recess of the non-flat portion when viewed in a depth direction decreases stepwise as it advances in the depth direction.

(47)

The photodetector according to any one of (37) to (44), wherein
a cross-sectional area of the recess of the non-flat portion when viewed in a depth direction continuously decreases as it advances in the depth direction.

(48)

The photodetector according to any one of (37) to (47), wherein
a cross-sectional area of the protrusion of the non-flat portion when viewed in a height direction decreases stepwise as it advances in the height direction.

(49)

The photodetector according to any one of (37) to (48), wherein
the optical layer includes:
a filler provided to fill a space between the plurality of pillars; and
an upper layer film provided to cover the pillar and the filler.

(50)

The photodetector according to (49), wherein
an upper surface of the filler has a non-flat portion including at least one of a recess and a protrusion, and
the upper layer film is provided on the upper surface of the pillar and the upper surface of the filler to fill the recess of the non-flat portion of the pillar and the recess of the non-flat portion of the filler.

(51)

The photodetector according to any one of (37) to (50), wherein
the optical layer includes a thin film provided in the recess of the non-flat portion and on a side surface of the pillar.

(52)

The photodetector according to (51), wherein
the thin film is provided to fill the recess of the non-flat portion, and
the optical layer includes a filler or an upper layer film provided to fill the recess of the non-flat portion covered with the thin film.

(53)

A photodetector including:
a photoelectric conversion section; and
an optical layer provided to cover the photoelectric conversion section, in which
the optical layer includes:
a plurality of pillars arranged side by side in a plane direction of a layer to guide at least light to be detected among incident light to the photoelectric conversion section; and
a reflection suppressing film provided on at least one of an upper surface and a lower surface of the pillar, and
a material of the reflection suppressing film contains TiO₂.

(54)

The photodetector according to (53), in which
the reflection suppressing film is provided on both the upper surface and the lower surface of the pillar.

(55)

The photodetector according to (53) or (54), in which
the optical layer includes an additional reflection suppressing film provided on an upper surface of the reflection suppressing film, and
a material of the additional reflection suppressing film contains SiN.

(56)

A photodetector comprising:
a photoelectric conversion section; and
an optical layer provided to cover the photoelectric conversion section, wherein
the optical layer includes:
a plurality of pillars arranged side by side in a plane direction of a layer to guide at least light to be detected among incident light to the photoelectric conversion section; and
a reflection suppressing film provided on at least one of an upper surface and a lower surface of the pillar, and
a refractive index of the reflection suppressing film has a gradient to approach a refractive index of the pillar toward the pillar.

(57)

The photodetector according to (56), wherein
the refractive index of the reflection suppressing film is lower than the refractive index of the pillar, and
the refractive index of the reflection suppressing film has a gradient to be higher toward the pillar.

(58)

The photodetector according to claim 57), wherein
a material of the reflection suppressing film contains nitrogen, and
a nitrogen content in the reflection suppressing film gradually increases from the pillar side.

(59)

The photodetector according to (57) or (58), wherein
a material of the reflection suppressing film contains oxygen, and
an oxygen content in the reflection suppressing film gradually increases from the pillar side.

(60)

The photodetector according to any one of (57) to (59), wherein
a material of the reflection suppressing film contains nitrogen and oxygen, and
a nitrogen content and an oxygen content in the reflection suppressing film gradually increase from the pillar side.

(61)

A photodetector comprising:
a photoelectric conversion section; and
an optical layer provided to cover the photoelectric conversion section, wherein
the optical layer includes a plurality of pillars arranged side by side in a plane direction of a layer to guide at least light to be detected among incident light to the photoelectric conversion section, and
the pillar includes:
an unaltered layer including a lower surface of the pillar; and
an altered layer including an upper surface of the pillar and having a refractive index different from a refractive index of the unaltered layer.

(62)

The photodetector according to (61), wherein
the altered layer is a portion of the pillar into which ions are implanted, and
the unaltered layer is a portion of the pillar into which the ions are not implanted.

(63)

The photodetector according to (61) or (62), wherein
the pillars each have a different refractive index and include a plurality of the altered layer laminated.

(64)

The photodetector according to (63), wherein
the altered layer located closer to the unaltered layer among the plurality of altered layers has a refractive index closer to a refractive index of the unaltered layer.

(65)

The photodetector according to any one of (61) to (64), wherein
the altered layer also includes a side surface of the pillar.

(66)

A photodetector comprising:
a photoelectric conversion section;
a first optical layer provided to cover the photoelectric conversion section; and
a second optical layer provided to cover the first optical layer, wherein
the first optical layer includes a plurality of pillars arranged side by side in a plane direction of a layer to guide at least light to be detected among incident light to the photoelectric conversion section, and
the second optical layer includes a plurality of pillars arranged side by side in the plane direction of the layer to have an average refractive index different from an average refractive index of the first optical layer.

(67)

The photodetector according to (66), wherein
the pillar of the second optical layer has a width smaller than a width of the pillar corresponding of the first optical layer.

(68)

The photodetector according to (66) or (67), wherein
the average refractive index of the second optical layer is a value between a refractive index of an upper region of the second optical layer and the average refractive index of the first optical layer.

(69)

The photodetector according to (68), wherein
the average refractive index of the second optical layer is an average value of a refractive index of an upper region of the second optical layer and the average refractive index of the first optical layer.

(70)

The photodetector according to (68) or (69), wherein
the average refractive index of the second optical layer is lower than the average refractive index of the first optical layer.

(71)

The photodetector according to any one of (66) to (70), wherein
the second optical layer includes a reflection suppressing film provided on the upper surface of the pillar.

(72)

The photodetector according to any one of (66) to (71), wherein
a pillar material of the second optical layer is different from a pillar material of the first optical layer.

(73)

The photodetector according to any one of (66) to (72), wherein
the plurality of pillars of the second optical layer include two types of pillars configured to include different materials.

(74)

A photodetector comprising:
a photoelectric conversion section; and
an optical layer provided to cover the photoelectric conversion section, wherein
the optical layer includes:
a plurality of pillars arranged side by side in a plane direction of a layer to guide at least light to be detected among incident light to the photoelectric conversion section; and
an etching stopper layer provided on at least one of an upper surface and a lower surface of the pillar, and
at least one of an upper surface and a lower surface of the etching stopper layer has an uneven shape.

(75)

The photodetector according to (74), wherein
the optical layer includes a filler provided to fill a space between the plurality of pillars, and
the uneven shape at an interface between the etching stopper layer and the pillar is different from the uneven shape at an interface between the etching stopper layer and the filler.

(76)

The photodetector according to (75), wherein
the etching stopper layer includes a plurality of protruding portions defining the uneven shape, and
difference in the uneven shape includes at least one of a height, a width, and a pitch of the plurality of protruding portions.

(77)

The photodetector according to any one of (74) to (76), wherein
the optical layer includes:
a first optical layer; and
a second optical layer located between the first optical layer and the photoelectric conversion section,
the etching stopper layer includes:
a first etching stopper layer located between the first optical layer and the second optical layer; and
a second etching stopper layer located on a side opposite to the first etching stopper layer with the second optical layer interposed in between, and
at least one of an upper surface and a lower surface of at least the first etching stopper layer of the first etching stopper layer and the second etching stopper layer has an uneven shape.

(78)

The photodetector according to (77), wherein
both the upper surface and the lower surface of the first etching stopper layer have an uneven shape.

(79)

The photodetector according to any one of (74) to (78), wherein
at least one of the upper surface and the lower surface of the etching stopper layer has an uneven shape over the entire surface.

(80)

The photodetector according to any one of (74) to (78), wherein
the photoelectric conversion section includes:
a photoelectric conversion section that is not shielded from light; and
a photoelectric conversion section that is shielded from light, and at least one of the upper surface and the lower surface of the etching stopper layer has an uneven shape in a portion facing one photoelectric conversion section of the photoelectric conversion section that is not shielded from light and the photoelectric conversion section that is shielded from light.

### REFERENCE SIGNS LIST

1 PIXEL ARRAY SECTION
2 PIXEL
21 PHOTOELECTRIC CONVERSION SECTION
22 CHARGE HOLDING SECTION
23 TRANSISTOR
24 TRANSISTOR
25 TRANSISTOR
26 TRANSISTOR
3 SEMICONDUCTOR SUBSTRATE
3a UPPER SURFACE
3b LOWER SURFACE
31 SEPARATION REGION
4 FIXED CHARGE FILM
5 INSULATING LAYER
51 INSULATING FILM
52 LIGHT SHIELDING FILM
521 LIGHT SHIELDING FILM
522 LIGHT SHIELDING FILM
53 INSULATING FILM
6 OPTICAL LAYER
61 REFLECTION SUPPRESSING FILM
61a UPPER SURFACE
61b LOWER SURFACE
61v NON-FLAT PORTION
62 PILLAR
62a UPPER SURFACE
62b LOWER SURFACE
62c SIDE SURFACE
62f INTERLAYER FILM
62g THIN FILM
62h HETEROGENEOUS FILM
62v NON-FLAT PORTION
620 BASE LAYER
621 UPPER END PORTION
622 LOWER END PORTION
623 UNALTERED LAYER
624 ALTERED LAYER
63 REFLECTION SUPPRESSING FILM
63a UPPER SURFACE
63b LOWER SURFACE
63v NON-FLAT PORTION
64 FILLER
64a UPPER SURFACE
64v NON-FLAT PORTION
65 PROTECTIVE FILM
66 ADDITIONAL LAYER
661 FIRST FILM
662 SECOND FILM
663 THIRD FILM
67 ETCHING STOPPER LAYER
68 UPPER LAYER FILM
69 REFLECTION SUPPRESSING FILM
69a UPPER SURFACE
69b LOWER SURFACE
7 WIRING LAYER
8 INSULATING LAYER
9 SUPPORT SUBSTRATE
10 LENS
11 LIGHT SHIELDING WALL
12 CLADDING PORTION
13 COLOR FILTER
13R COLOR FILTER
13G COLOR FILTER
13B COLOR FILTER
14 SURFACE PLASMON FILTER
15 GMR FILTER
16 LAMINATED FILTER
17 LIGHT SHIELDING FILM
100 PHOTODETECTOR

What is claimed is:

1. A light detecting device, comprising:
a photoelectric conversion section;
a first optical layer above the photoelectric conversion section, wherein
the first optical layer comprises a first portion,
the first portion comprises a first plurality of columnar structures in a cross-sectional view, and
the first optical layer is configured to guide at least light to be detected among incident light to the photoelectric conversion section; and
a second optical layer above the first optical layer, wherein
the second optical layer comprises a second portion,
the second portion comprises a second plurality of columnar structures in the cross-sectional view, and
an average refractive index of the second optical layer is smaller than an average refractive index of the first optical layer.

2. The light detecting device according to claim 1, wherein a refractive index of the second portion is smaller than a refractive index of the first portion.

3. The light detecting device according to claim 2, wherein
the first optical layer further comprises a first medium,
the second optical layer further comprises a second medium,
the refractive index of the first portion is higher than a refractive index of the first medium, and
the refractive index of the second portion is higher than a refractive index of the second medium.

4. The light detecting device according to claim 1, further comprising an etching stopper layer between the first portion and the second portion.

5. The light detecting device according to claim 4, wherein the etching stopper layer is selected from a group consisting of silicon nitride, silicon oxynitride, hafnium oxide, and aluminium oxide.

6. The light detecting device according to claim 5, wherein the etching stopper layer includes aluminium oxide.

7. The light detecting device according to claim 1, wherein the second optical layer includes a reflection suppressing layer.

8. The light detecting device according to claim 1, wherein a height of the first portion is larger than a height of the second portion.

9. The light detecting device according to claim 1, wherein the first optical layer further comprises a first reflection supressing film below the first portion.

10. The light detecting device according to claim 9, wherein
the second optical layer comprises a second reflection suppressing film, and
the second reflection suppressing film is between the first portion and the second portion.

11. The light detecting device according to claim 1, wherein the first portion provides a lens function and a prism function to the first optical layer.

12. The light detecting device according to claim 1, wherein the second portion provides a lens function and a prism function to the second optical layer.

13. The light detecting device according to claim 1, wherein
the first optical layer includes a filler provided to fill a space between the first plurality of columnar structures.

14. The light detecting device according to claim 1, wherein the second optical layer includes a filler provided to fill a space between the second plurality of columnar structures.

15. The light detecting device according to claim 1, wherein a width of each of the second plurality of columnar structures of the second optical layer is smaller than a width of each of the first plurality of columnar structures corresponding of the first optical layer.

16. The light detecting device according to claim 1, wherein the average refractive index of the second optical layer is a value between a refractive index of an upper region of the second optical layer and the average refractive index of the first optical layer.

17. The light detecting device according to claim 1, wherein a material of the first portion is different from a material of the second portion.

18. The light detecting device according to claim 1, wherein the second optical layer is configured to suppress light reflection.
